(19) United States
(12) Patent Application Publication
(10) Pub. No.: US 2024/0107872 A1
(43) Pub. Date: Mar. 28, 2024

(54) Metal complexes

(71) Applicant: UDC IRELAND LIMITED, Dublin 15 (IE)

(72) Inventors: Philipp Stoessel, Darmstadt (DE); Armin Auch, Darmstadt (DE)

(21) Appl. No.: 18/351,881

(22) Filed: Jul. 13, 2023

(30) Foreign Application Priority Data
Jul. 27, 2022 (EP) 22187158.5
Oct. 18, 2022 (EP) 22202099.2

(51) Int. Cl. H10K 85/30; C07F 15/00; C09K 11/06

(52) U.S. Cl. CPC H10K 85/342; C07F 15/0033; C09K 11/06; H10K 50/12

(57) ABSTRACT

The present invention relates to iridium complexes suitable for use in organic electroluminescent devices, particularly as emitters.

### CROSS-REFERENCE TO RELATED APPLICATIONS

The present application claims priority under 35 U.S.C. § 119(a)-(d) to European Application No. 22187158.5, filed Jul. 27, 2022, and European Application No. 22202099.2, filed Oct. 18, 2022, all of which applications are incorporated herein by reference in their entireties.

### FIELD

The present invention relates to iridium complexes suitable for use in organic electroluminescent devices, particularly as emitters.

### BACKGROUND

According to the prior art, tris-ortho-metallated iridium complexes with aromatic ligands are mainly used as triplet emitters in phosphorescent organic electroluminescent devices (OLEDs), where the ligands bind to the metal via a negatively charged carbon atom and a neutral nitrogen atom or via a negatively charged carbon atom and a neutral carbene carbon atom. Examples of such complexes include tris(phenylpyridyl) iridium(III) and derivatives thereof, as well as a variety of related complexes. Such complexes are also known with polypodal ligands, as for example described in U.S. Pat. No. 7,332,232. These complexes with polypodal ligands show advantages over complexes otherwise having the same ligand structure, whose individual ligands are not polypodally bridged, such as higher thermal stability and fixed coordination geometry, avoiding ligand scrambling and facial-meridional isomerism during synthesis. However, they have the disadvantage that the introduction of the bridging unit linking the individual ligands is also accompanied by an increase in the sublimation temperature. Therefore, especially in the case of polypodally linked complexes, there is still a need for improvement with regard to the sublimation temperature of the complexes.

Therefore, the object of the present invention is to provide new metal complexes which are suitable as emitters for use in OLEDs and which have a lower sublimation temperature compared to comparable polypodally linked complexes of the prior art.

### SUMMARY OF THE INVENTION

The present invention relates to compounds of formula (1)

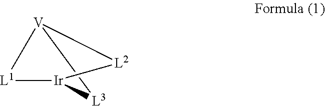

wherein the used symbols are defined as follows:
V is a group of formula (2),

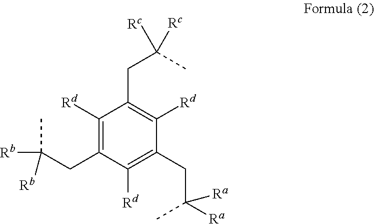

wherein the dashed bonds represent the bond to L¹, L² and L³, respectively, and the hydrogen atoms not shown may also be partially or completely replaced by deuterium;
R^{a} at each occurrence is the same or different and is a straight-chain alkyl group having 1 to 6 C atoms or a branched or cyclic alkyl group having 3 to 6 C atoms, wherein in each case one or more H atoms may be replaced by D or F; in this context, two radicals R^{a}, which bond to the same carbon atom, may also form, together with one another and with the carbon atom to which they bond, a cyclopentyl or cyclohexyl group in which one or more H atoms may be replaced by D or F;
R^{b}, R^{c} at each occurrence is the same or different and is H, D, or R^{a};
R^{d} at each occurrence is the same or different and is H, D, or a methyl group, which may also be partially or fully deuterated;
L¹, L², L³ at each occurrence is the same or different and each is a bidentate, monoanionic partial ligand according to formula (L-1) or (L-2),

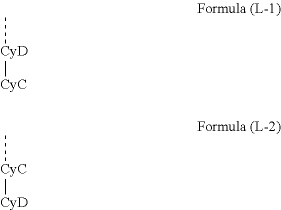

wherein the dashed bond represents the bond to V and the bond between CyC and CyD represents a covalent bond;
CyC at each occurrence is the same or different and is an aryl or heteroaryl group having 5 to 14 aromatic ring atoms, each of which is coordinated to the metal via a carbon atom, and which may be substituted by one or more R radicals;
CyD at each occurrence of is the same or different and is a heteroaryl group with 5 to 14 aromatic ring atoms, which is coordinated to the metal via a nitrogen atom or via a carbene-carbon atom and which can be substituted by one or more radicals R;
R at each occurrence is the same or different and is H, D, F, Cl, Br, I, N(R¹)₂, OR¹, SR¹, CN, NO₂, COOH, C(═O)N(R¹)₂, Si(R¹)₃, Ge(R¹)₃, B(OR¹)₂, C(═O)R¹, P(═O)(R¹)₂, S(═O)R¹, S(═O)₂R¹, OSO₂R¹, a straight chain alkyl group with 1 to 20 C atoms or an alkenyl or alkynyl group with 2 to 20 C atoms or a branched or cyclic alkyl group with 3 to 20 C atoms, wherein the alkyl, alkenyl or alkynyl group may in each case be substituted by one or more radicals R¹ and wherein one or more non-adjacent CH₂ groups may be replaced by Si(R¹)₂, C═O, NR¹, O, S or CONR¹, or an aromatic or heteroaromatic ring system having 5 to 40 aromatic ring atoms, which may in each case be substituted by one or more radicals R¹; wherein two radicals R can also form a ring system with one another;
R¹ at each occurrence is the same or different and is H, D, F, Cl, Br, I, N(R²)₂, OR², SR², CN, NO₂, Si(R²)₃, Ge(R²)₃, B(OR²)₂, C(═O)R², P(═O)(R²)₂, S(═O)R², S(═O)₂R², OSO₂R², a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R² and wherein one or more non-adjacent CH₂ groups may be replaced by Si(R²)₂, C═O, NR², O, S or CONR², or an aromatic or heteroaromatic ring system having 5 to 40 aromatic ring atoms, which may in each case be substituted by one or more radicals R²; wherein two or more radicals R¹ can form a ring system with one another;
R² at each occurrence of is the same or different and is H, D, F or an aliphatic, aromatic and/or heteroaromatic organic radical, in particular a hydrocarbon radical, having 1 to 20 C atoms, in which one or more H atoms may also be replaced by D or F;
wherein the three bidentate partial ligands L¹, L² and L³ can be joined not only by the bridge V but also by a further bridge to form a cryptate.

### DETAILED DESCRIPTION

Surprisingly, it was found that metal complexes with a hexadentate tripodal ligand having the structure described below solve this problem and are very suitable for use in an organic electroluminescence device. In particular, these complexes exhibit a significantly lower sublimation temperature compared to similar prior art polypodal complexes that contain a tris(ethylene)benzene bridgehead instead of the bridgehead of the invention, in which all ethylene groups are unsubstituted or in which all ethylene groups are each substituted with four methyl groups. Due to the lower sublimation temperature, the complexes are in particular easier to purify by sublimation, and they are easier to process in the manufacture of OLEDs. Furthermore, metal complexes in which the bridgehead is substituted with longer alkyl groups exhibit higher solubility in organic solvents than metal complexes with an unsubstituted tris(ethylene)benzene bridgehead, which in turn has advantages for processing the complexes from solution. These metal complexes and organic electroluminescent devices containing these complexes are therefore the subject of the present invention.

The subject-matter of the invention is a compound of formula (1),

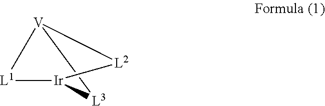

wherein the used symbols are defined as follows:
V is a group of formula (2),

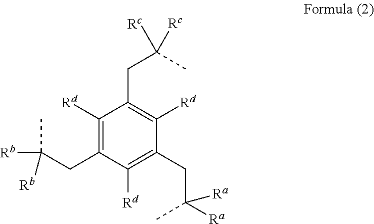

wherein the dashed bonds represent the bond to L¹, L² and L³, respectively, and the hydrogen atoms not shown may also be partially or completely replaced by deuterium;
R^{a} at each occurrence is the same or different and is a straight-chain alkyl group having 1 to 6 C atoms or a branched or cyclic alkyl group having 3 to 6 C atoms, wherein in each case one or more H atoms may be replaced by D or F; in this context, two radicals R^{a}, which bond to the same carbon atom, may also form, together with one another and with the carbon atom to which they bond, a cyclopentyl or cyclohexyl group in which one or more H atoms may be replaced by D or F;
R^{b}, R^{c} at each occurrence is the same or different and is H, D, or R^{a};
R^{d} at each occurrence is the same or different and is H, D, or a methyl group, which may also be partially or fully deuterated;
L¹, L², L³ at each occurrence is the same or different and each is a bidentate, monoanionic partial ligand according to formula (L-1) or (L-2),

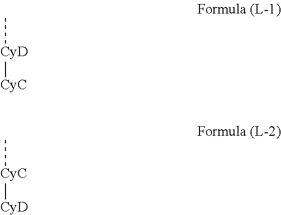

wherein the dashed bond represents the bond to V and the bond between CyC and CyD represents a covalent bond;
CyC at each occurrence is the same or different and is an aryl or heteroaryl group having 5 to 14 aromatic ring atoms, each of which is coordinated to the metal via a carbon atom, and which may be substituted by one or more R radicals;
CyD at each occurrence of is the same or different and is a heteroaryl group with 5 to 14 aromatic ring atoms, which is coordinated to the metal via a nitrogen atom or via a carbene-carbon atom and which can be substituted by one or more radicals R;
R at each occurrence is the same or different and is H, D, F, Cl, Br, I, N(R¹)₂, OR¹, SR¹, CN, NO₂, COOH, C(═O)N(R¹)₂, Si(R¹)₃, Ge(R¹)₃, B(OR¹)₂, C(═O)R¹, P(═O)(R¹)₂, S(═O)R¹, S(═O)₂R¹, OSO₂R¹, a straight chain alkyl group with 1 to 20 C atoms or an alkenyl or alkynyl group with 2 to 20 C atoms or a branched or cyclic alkyl group with 3 to 20 C atoms, wherein the alkyl, alkenyl or alkynyl group may in each case be substituted by one or more radicals R¹ and wherein one or more non-adjacent CH₂ groups may be replaced by Si(R¹)₂, C═O, NR¹, O, S or CONR¹, or an aromatic or heteroaromatic ring system having 5 to 40 aromatic ring atoms, which may in each case be substituted by one or more radicals R¹; wherein two radicals R can also form a ring system with one another;
R¹ at each occurrence is the same or different and is H, D, F, Cl, Br, I, N(R²)₂, OR², SR², CN, NO₂, Si(R²)₃, Ge(R²)₃, B(OR²)₂, C(═O)R², P(═O)(R²)₂, S(═O)R², S(═O)₂R², OSO₂R², a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R² and wherein one or more non-adjacent CH₂ groups may be replaced by Si(R²)₂, C═O, NR², O, S or CONR², or an aromatic or heteroaromatic ring system having 5 to 40 aromatic ring atoms, which may in each case be substituted by one or more radicals R²; wherein two or more radicals R¹ can form a ring system with one another;
R² at each occurrence of is the same or different and is H, D, F or an aliphatic, aromatic and/or heteroaromatic organic radical, in particular a hydrocarbon radical, having 1 to 20 C atoms, in which one or more H atoms may also be replaced by D or F;
wherein the three bidentate partial ligands L¹, L² and L³ can be joined not only by the bridge V but also by a further bridge to form a cryptate.

The ligand is thus a hexadentate, tripodal ligand with the three bidentate partial ligands L¹, L² and L³. Here, bidentate means that the respective partial ligand in the complex coordinates or binds to the iridium via two coordination sites. Tripodal means that the ligand has three partial ligands bound to the bridge V or the bridge of formula (2). Since the ligand has three bidentate partial ligands, this results in a total of one hexadentate ligand, i.e., a ligand that coordinates or binds to the iridium via six coordination sites. For the purposes of this application, the term “bidentate partial ligand” means that L¹, L² or L³ would each be a bidentate ligand if the bridge V or the bridge of formula (2) were not present. However, due to the formal abstraction of a hydrogen atom from this bidentate ligand and the linkage to the bridge V or the bridge of formula (2), this is no longer a separate ligand but a part of the resulting hexadentate ligand, so that the term “part ligand” is used for this.

It is essential to the invention that the bridgehead is substituted on at least one of the ethylene groups in the defined position with two alkyl groups R^{a}, since the presence of these alkyl groups is responsible for the lower sublimation temperature of the compounds in the case of short alkyl groups and for the higher solubility of the compounds in the case of longer alkyl groups.

The binding of the ligand to the iridium can be a coordination bond or a covalent bond, or the covalent portion of the bond can vary depending on the ligand. When the present application mentions that the ligand or the part ligand coordinates or binds to the iridium, this means in the sense of the present application any type of binding from the ligand or part ligand to the iridium, irrespective of the covalent portion of the binding.

If two radicals R or R¹ form a ring system with each other, this can be mono- or polycyclic, aliphatic, heteroaliphatic, aromatic or heteroaromatic. In this context, these radicals forming a ring system with one another may be adjacent, i.e., these radicals may be bonded to the same carbon atom or to carbon atoms that are bonded directly to one another, or they may be further away from one another. Preference is given to such ring formation in the case of radicals bonded to carbon atoms directly bonded to each other, or to ring formation between a radical R on CyC and a radical R on CyD.

The formulation that two or more radicals can form a ring with each other should be understood in the context of the present description to mean, among other things, that the two radicals are linked to each other by a chemical bond with formal elimination of two hydrogen atoms. This is illustrated by the following diagram.

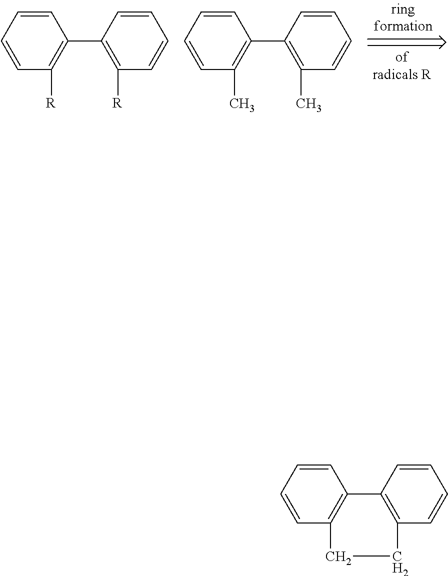

Furthermore, however, the above formulation should also be understood to mean that in the case where one of the two radicals represents hydrogen, the second radical binds to the position to which the hydrogen atom was attached, forming a ring. This is to be clarified by the following scheme:

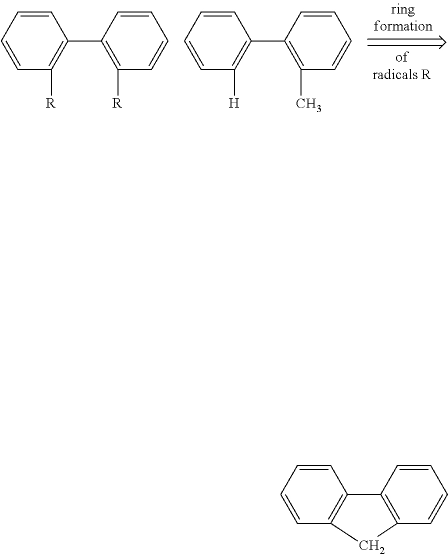

An aryl group within the meaning of this invention contains 6 to 40 C atoms, a heteroaryl group within the meaning of this invention contains 2 to 40 C atoms and at least one heteroatom, with the proviso that the sum of C atoms and heteroatoms is at least 5. The heteroatoms are preferably selected from N, O and/or S. In this context, the heteroaryl group preferably contains a maximum of three heteroatoms. In this context, an aryl group or heteroaryl group is understood to be either a simple aromatic cycle, i.e., benzene, or a simple heteroaromatic cycle, for example pyridine, pyrimidine, thiophene, etc., or a condensed aryl or heteroaryl group, for example naphthalene, anthracene, phenanthrene, quinoline, isoquinoline, etc.

An aromatic ring system within the meaning of this invention contains 6 to 40 C atoms in the ring system. A heteroaromatic ring system in the sense of the present invention contains 1 to 40 C atoms and at least one heteroatom in the ring system, with the proviso that the sum of C atoms and heteroatoms is at least 5. The heteroatoms are preferably selected from N, O and/or S. An aromatic or heteroaromatic ring system within the meaning of the present invention is intended to be a system which does not necessarily contain only aryl or heteroaryl groups, but in which several aryl or heteroaryl groups may also be interrupted by a non-aromatic unit (preferably less than 10% of the atoms other than H), such as a C, N or O atom or a carbonyl group. For example, systems such as 9,9′-spirobifluorene, 9,9-diarylfluorene, triarylamine, diaryl ether, stilbene, etc. are also to be understood as aromatic ring systems in the sense of the present invention, and likewise systems in which two or more aryl groups are interrupted, for example, by a linear or cyclic alkyl group or by a silyl group. Furthermore, systems in which two or more aryl or heteroaryl groups are directly bonded to one another, such as biphenyl, terphenyl, quaterphenyl or bipyridine, are also to be understood as aromatic or heteroaromatic ring systems.

In the context of the present invention, the term alkyl group is used as a generic term for both linear or branched alkyl groups and cyclic alkyl groups. Similarly, the terms alkenyl group or alkynyl group are used as generic terms for both linear or branched alkenyl or alkynyl groups and cyclic alkenyl or alkynyl groups.

A cyclic alkyl, alkoxy or thioalkoxy group as used in the present invention is understood to mean a monocyclic, a bicyclic or a polycyclic group.

In the context of the present invention, a C₁- to C₂₀-alkyl group, in which individual H atoms or CH₂ groups may also be substituted by the above-mentioned groups, means, for example, the radicals methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyln-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl are understood. By an alkenyl group is understood, for example, ethenyl, propenyl, butenyl, pentenyl, cyclopentenyl, hexenyl, cyclohexenyl, heptenyl, cycloheptenyl, octenyl, cyclooctenyl or cyclooctadienyl. By an alkynyl group is understood, for example, ethynyl, propynyl, butynyl, pentynyl, hexynyl, heptynyl or octynyl. By a group OR¹ is understood, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system with 5-40 aromatic ring atoms, which may be substituted with the above-mentioned radicals, and which may be linked via any positions on the aromatic or heteroaromatic ring. Heteroaromatic ring system are understood to be groups derived from benzene, naphthalene, anthracene, benzanthracene, phenanthrene, benzophenanthrene, pyrene, chrysene, perylene, fluoranthene, benzfluoranthene, benzophenanthrene, pyrene, chrysene, perylene, fluoranthene, benzfluoranthene, naphthacene, pentacene, benzpyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, Pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,-2-thiazole, 1,3-thiazole, benzothiazole, pyridazine, benzopyridazine, pyrimidine, benzpyrimidine, quinoxaline, 1,5-diaza anthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxa diazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

Preferred embodiments of bridgehead V, i.e., the structure of formula (2), are elaborated below.

Depending on the choice of R^{b} and R^{c}, the group V has a structure according to one of the formulas (2-1), (2-2) or (2-3),

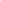

wherein the symbols used have the meanings given above and the hydrogen atoms not shown may also be partially or completely replaced by deuterium.

Preferably, the group is a group of formula (2-1) or (2-2), wherein preferred embodiments are the groups of the following formulae (2-1-1) or (2-2-1), respectively,

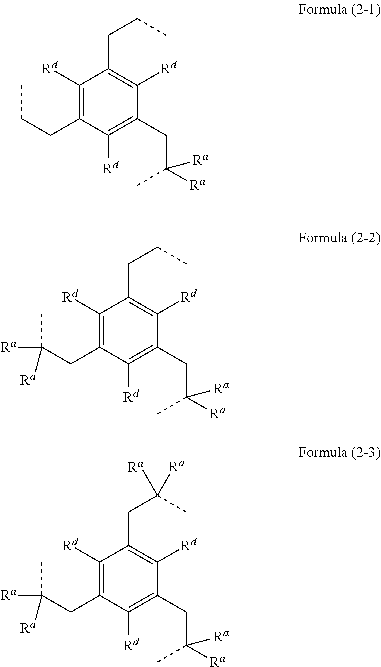

wherein the symbols used have the meanings given above and the hydrogen atoms not shown may also be partially or completely replaced by deuterium.

In another preferred embodiment of the invention, each occurrence of R^{d} in formula (2) or (2-1), (2-2) and (2-3) is the same or different and is H or D. Thus, in a preferred embodiment of formula (2), it is the following formula (2a) and in preferred embodiments of formulae (2-1), (2-2) and (2-3), it is the following formulae (2-1a), (2-2a) and (2-3a), respectively,

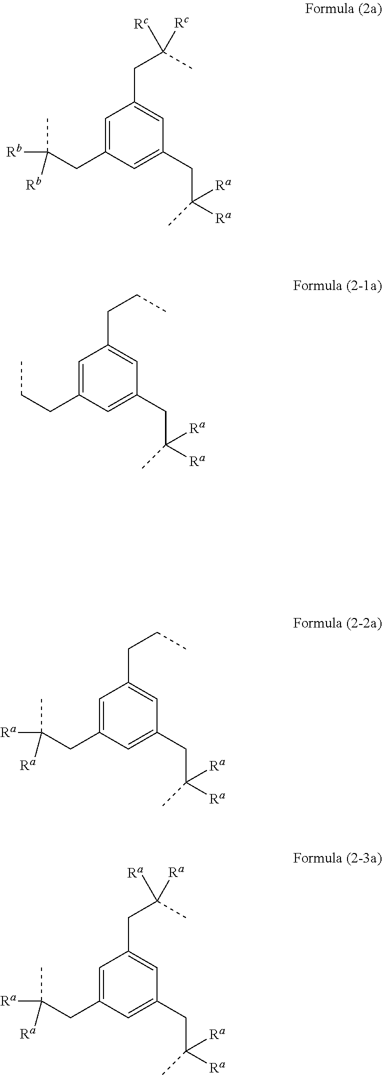

wherein the symbols used have the meanings given above and the hydrogen atoms not shown may also be partially or completely replaced by deuterium.

Preferably, the group is a group of formula (2-1a) or (2-2a), wherein preferred embodiments are the groups of the following formulae (2-1-1a) or (2-2-1a), respectively,

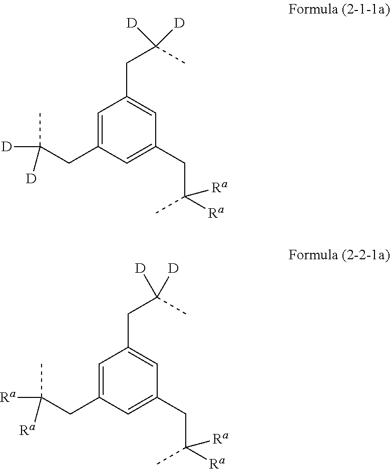

wherein the symbols used have the meanings given above and the hydrogen atoms not shown may also be partially or completely replaced by deuterium.

In a preferred embodiment of the invention, each pair of radicals R^{a} that are bonded to the same carbon atom are chosen to be the same to each other. Particularly preferably, all the radicals R^{a} within the structure of formula (2), (2a), (2-1) to (2-3), (2-1-1), (2-2-1), (2-1a) to (2-3a), (2-1-1a) and (2-2-1a), respectively, are chosen to be the same.

In this context, each occurrence of R^{a} is preferably the same or different and is methyl, ethyl, propyl, iso-propyl or neo-pentyl, or a pair of R^{a} that bind to the same carbon atom together form a cyclopentyl or cyclohexyl group, in all of which groups one or more H atoms may be replaced by D. When the compound according to the invention is processed by sublimation, it is particularly preferred if the compound has two, four or six groups R^{a} which stand for methyl, or if it has two or four groups R^{a} which stand for ethyl, or if it has two groups R^{a} which stand for neo-pentyl, in each of which one or more H atoms may also be replaced by D. Particularly preferably, R^{a} stands for a methyl group in which one or more H atoms may also be replaced by D. The structures of the formulae (2-1a) to (2-3a) are thus preferably the structures of the following formulae (2-1 b) to (2-3b),

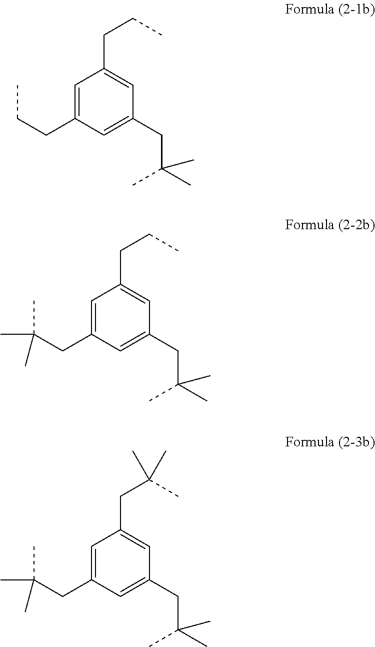

wherein the symbols used have the meanings given above and the hydrogen atoms not shown may also be partially or completely replaced by deuterium.

Preferably, the group is a group of formula (2-1 b) or (2-2b), wherein preferred embodiments are the groups of the following formulae (2-1-1 b) or (2-2-1 b), respectively,

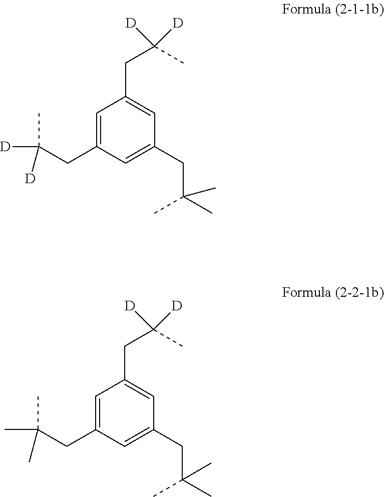

wherein the symbols used have the meanings given above and the hydrogen atoms which are not drawn in may also be partially or completely replaced by deuterium.

The bidentate partial ligands L¹, L² and L³ are described below. CyD coordinates before via a neutral nitrogen atom or via a carbene carbon atom. Furthermore, CyC coordinates via an anionic carbon atom. In one embodiment, the partial ligands L¹, L² and L³ each coordinate to the iridium via a carbon atom and a nitrogen atom.

It is further preferred if the metallacycle formed by the iridium and the partial ligand L¹, L² or L³ is a five-membered ring. The formation of a five-membered ring is shown schematically below for carbon and nitrogen as coordinating atoms:

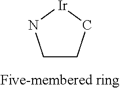

wherein N is a coordinating nitrogen atom and C is a coordinating carbon atom and the carbon atoms shown represent atoms of the partial ligand L¹, L² or L³.

If several of the substituents R on CyC and CyD form a ring system with each other, the formation of a ring system from substituents attached to directly adjacent carbon atoms is possible. However, it is also possible for the substituents on CyC and CyD to form a ring with each other, whereby CyC and CyD can also together form a single fused heteroaryl group as a bidentate partial ligand.

In this case, all of the partial ligands L¹, L² and L³ may have a structure of the formula (L-1), so that a pseudo facial complex is formed, or all of the partial ligands L¹, L² and L³ may have a structure of the formula (L-2), so that a pseudo facial complex is formed, or one or two of the part ligands L¹, L² and L³ have a structure of formula (L-1), and the others of the part ligands have a structure of formula (L-2), so that a pseudo meridional complex is formed. Preferably, all of the partial ligands L¹, L² and L³ exhibit a structure of formula (L-1), or all of the partial ligands L¹, L² and L³ exhibit a structure of formula (L-2). Particularly preferably, all partial ligands L¹, L² and L³ have a structure of formula (L-1).

In a preferred embodiment of the present invention, CyC is an aryl or heteroaryl group having 6 to 13 aromatic ring atoms. Particularly preferably, CyC is an aryl group having 6 aromatic ring atoms, i.e., a phenyl group, or a heteroaryl group having 13 aromatic ring atoms, each of which may be substituted with one or more R radicals.

Preferred embodiments of the group CyC are the structures of the following formulae (CyC-1) to (CyC-20), wherein the group CyC binds to CyD at the position indicated by #, respectively, and coordinates to the iridium at the position indicated by *,

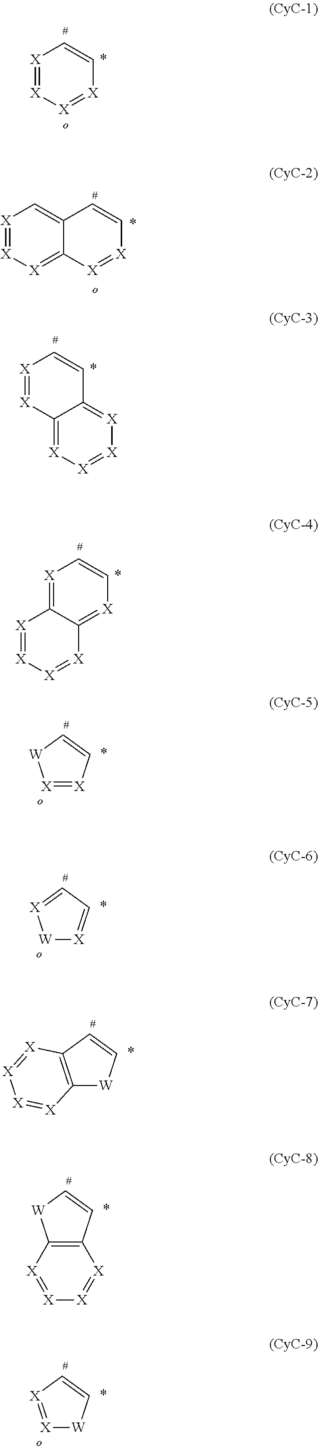

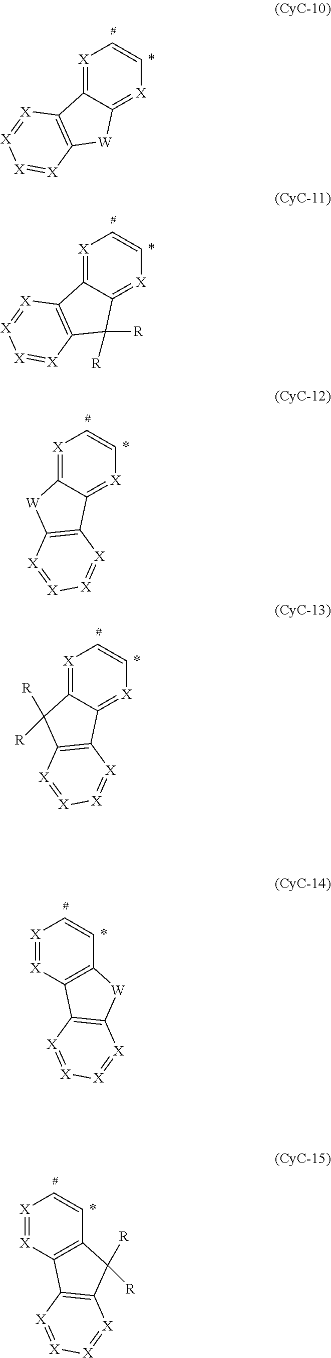

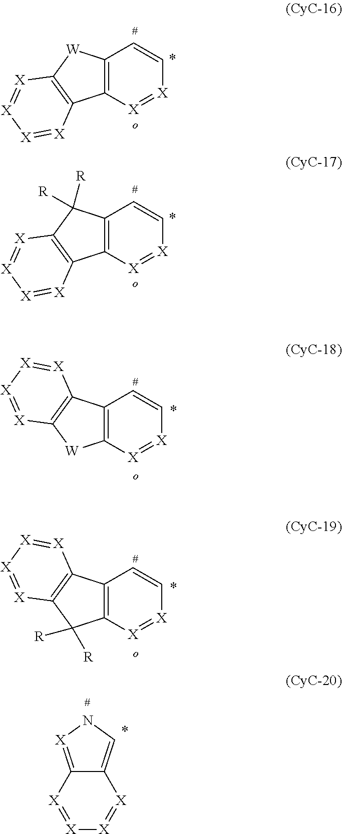

where R has the meaning given above and the following symbols are defined as:
X at each occurrence is the same or different and is CR or N, with the proviso that a maximum of two symbols X per cycle represent N;
W at each occurrence is the same or different and is NR, O or S;
with the proviso that if the bridge V is bonded to CyC, one symbol X stands for C and the bridge V is bonded to this carbon atom. If the group CyC is bonded to the bridge V, then the binding is preferably carried out via the position marked with “o” in the formulas shown above, so that then preferably, the symbol X marked with “o” stands for C. The structures shown above, which do not contain a symbol X marked with “o”, are not directly bound to the bridge V, because such a binding to the bridge in these structures is not advantageous for steric reasons.

Preferably, at most one symbol X in CyC stands for N, and particularly preferably all symbols X stand for CR, with the proviso that if the bridge V is bonded to CyC, one symbol X stands for C and the bridge V is bonded to this carbon atom.

Particularly preferred groups CyC are those of the following formulae (CyC-1a) to (CyC-20a),

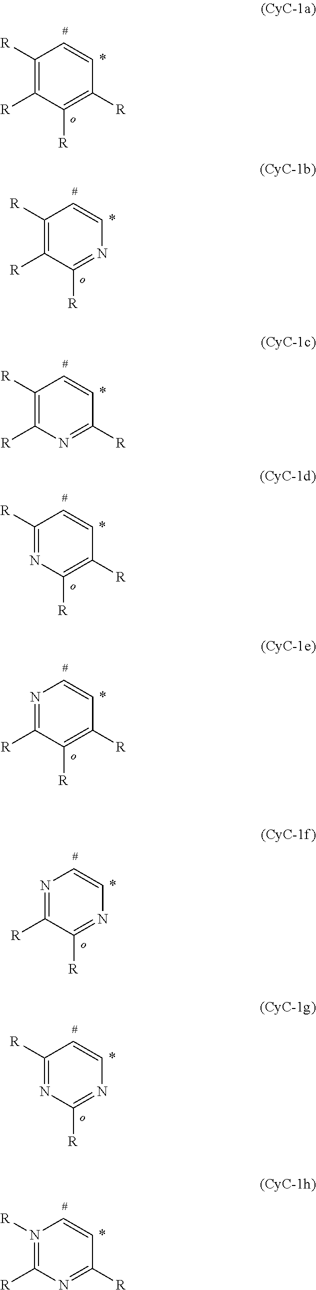

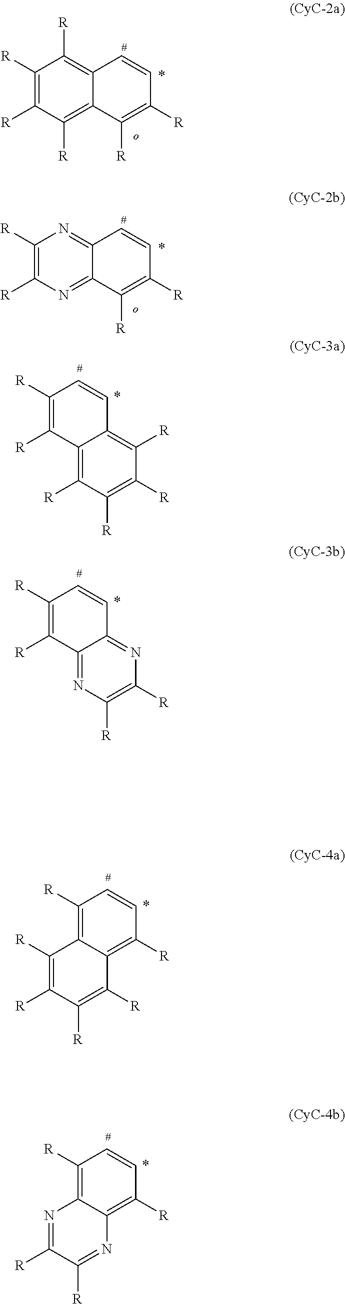

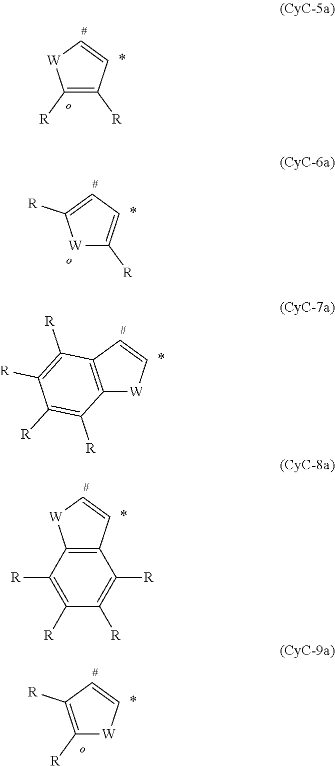

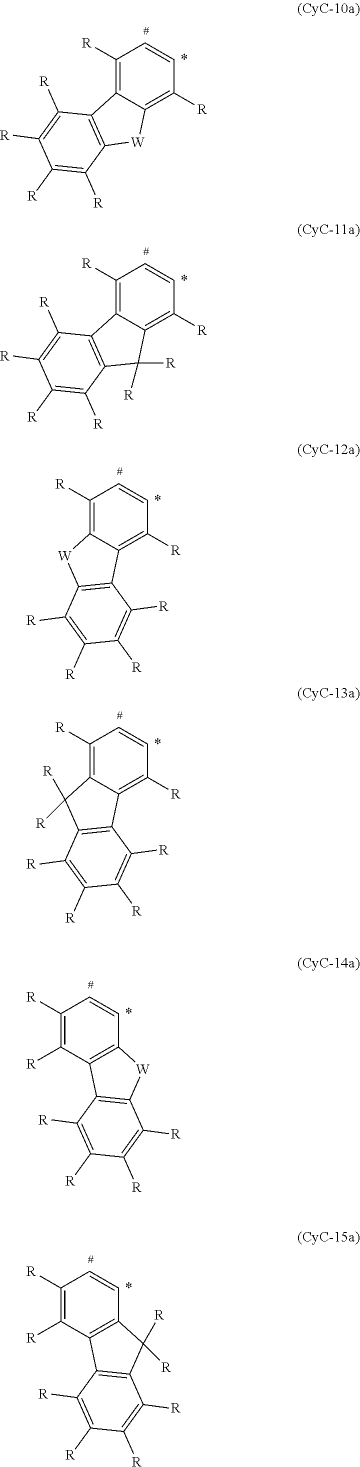

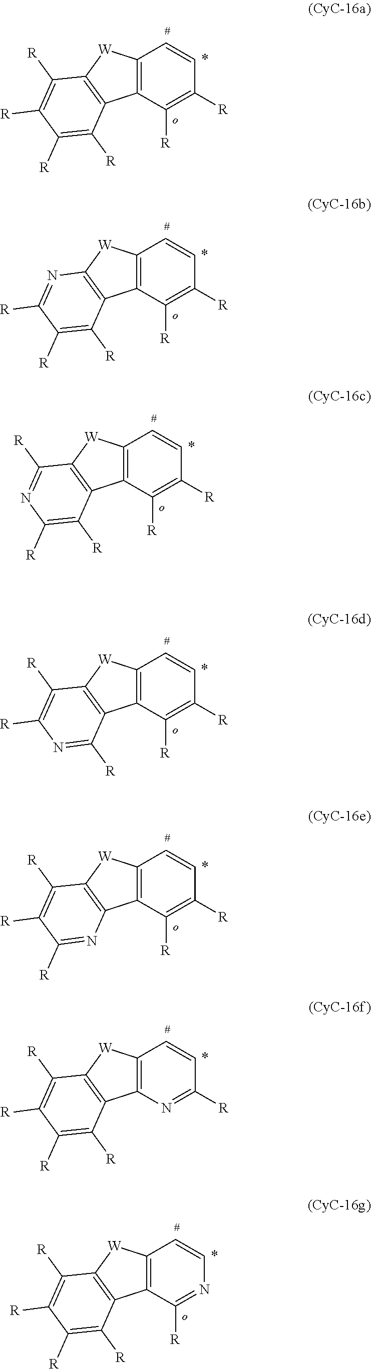

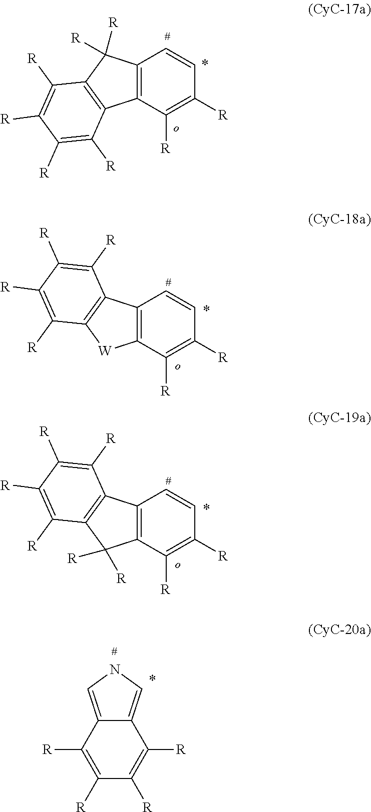

wherein the symbols used have the meanings given above and, if the bridge V is bonded to CyC, a radical R is not present, and the bridge V is bonded to the corresponding carbon atom. If the group CyC is bonded to the bridge V, the bonding preferably occurs via the position marked with “o” in the formulas shown above, so that the radical R is then preferably not present in this position. The structures shown above, which do not contain a carbon atom marked with “o”, are preferably not directly bonded to the bridge V.

Preferred groups among the groups (CyC-1) to (CyC-20) are the groups (CyC-1), (CyC-2) and (CyC-16), especially (CyC-1) and (CyC-16), particularly preferred are the groups (CyC-1a), (CyC-2a), (CyC-16a) and (CyC-16b), especially (CyC-1a), (CyC-16a) and (CyC-16b).

In another preferred embodiment of the invention, CyD is a heteroaryl group having 5 to 13 aromatic ring atoms, particularly preferably having 6 to 10 aromatic ring atoms, which is coordinated to the metal via a neutral nitrogen atom or via a carbene carbon atom and which may be substituted with one or more radicals R, and which is linked to CyC via a covalent bond.

Preferred embodiments of the group CyD are the structures of the following formulae (CyD-1) to (CyD-18), wherein the group CyD binds to CyC at the position indicated by #, respectively, and coordinates to the iridium at the position indicated by *,

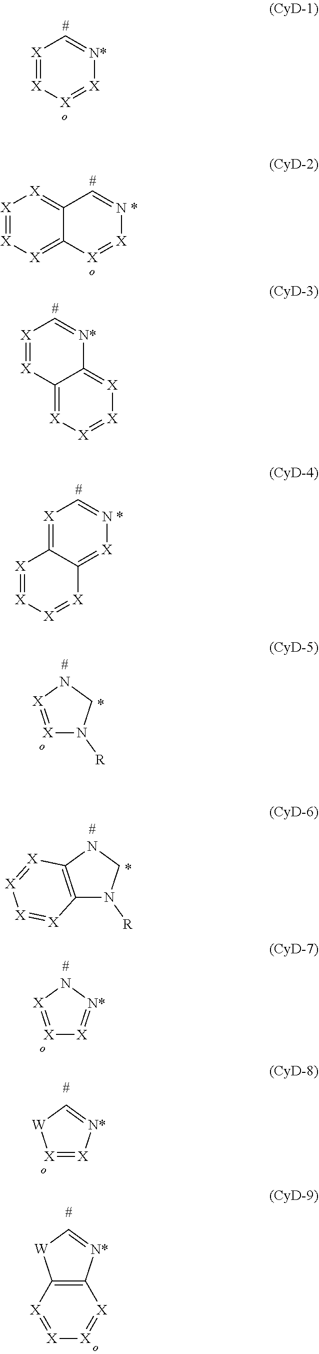

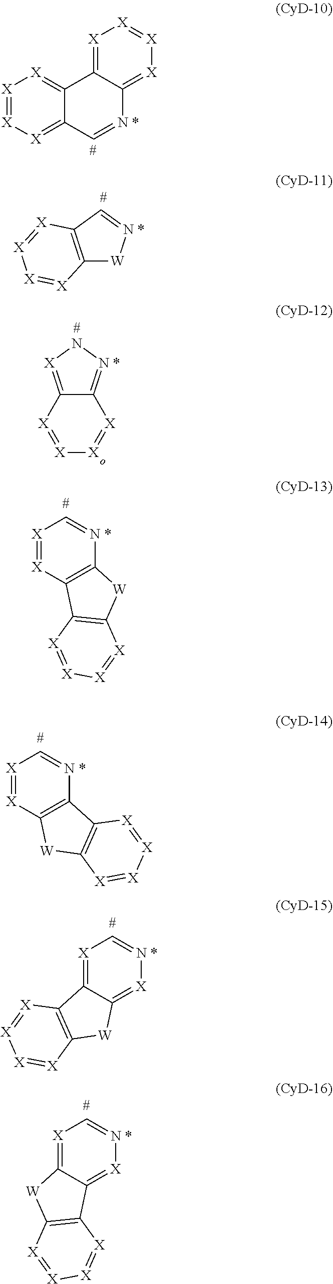

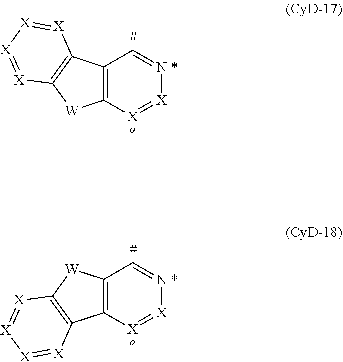

wherein X and R are as defined above and W is CR₂, NR, O or S, with the proviso that when the bridge V is bonded to CyD, one symbol X is C and the bridge V is bonded to that carbon atom. When the group CyD is bonded to the bridge V, the bonding preferably occurs via the position marked “o” in the formulas shown above, so that then preferably the symbol X marked “o” stands for C. The structures shown above that do not contain a symbol X marked with “o” are preferably not directly bound to the bridge V, since such a binding to the bridge in these structures is not advantageous for steric reasons.

Here, the groups (CyD-1) to (CyD-4) and (CyD-7) to (CyD-18) coordinate to the iridium via a neutral nitrogen atom and (CyD5-) and (CyD-6) coordinate to the iridium via a carbene carbon atom.

Preferably, at most one symbol X in CyD represents N, and particularly preferably all symbols X represent CR, with the proviso that when the bridge V is bonded to CyD, one symbol X represents C, and the bridge V is bonded to that carbon atom.

Particularly preferred groups CyD are those of the following formulae (CyD-1a) to (CyD-18a),

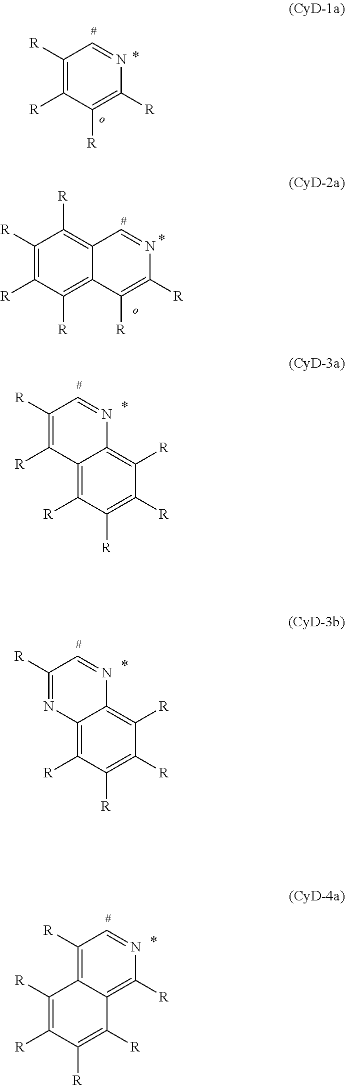

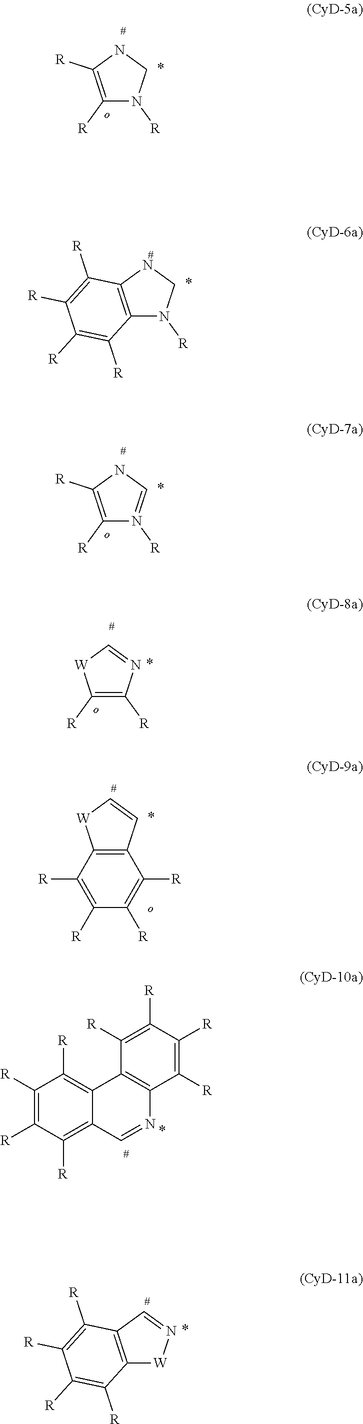

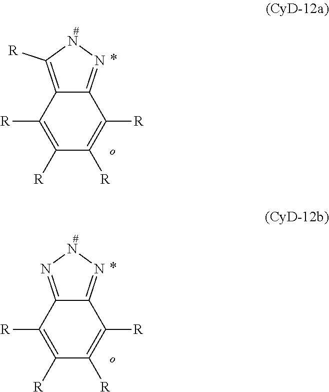

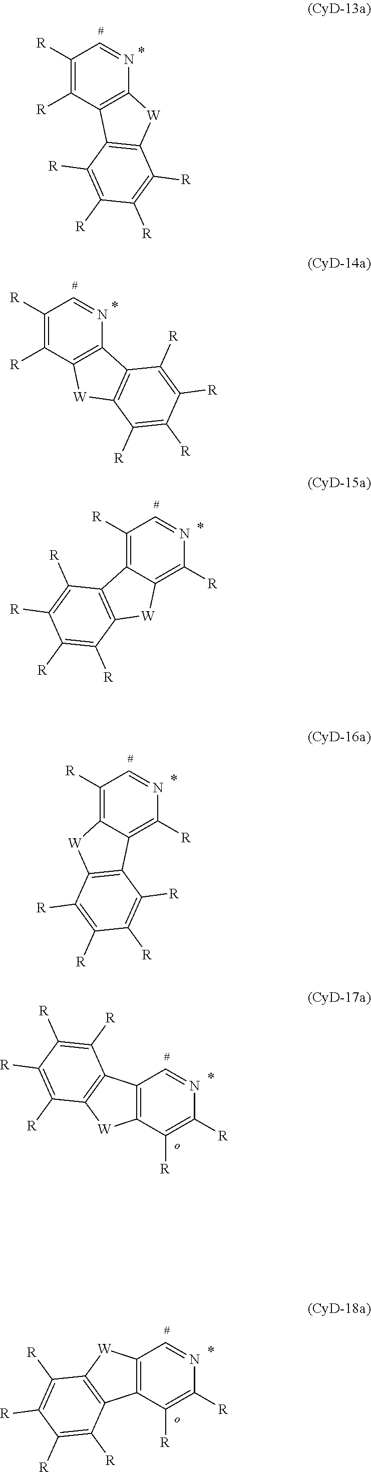

wherein the symbols used have the meanings given above and, if the bridge V is bonded to CyD, a radical R is not present, and the bridge V is bonded to the corresponding carbon atom. If the group CyD is bound to the bridge V, then the binding occurs preferably via the position marked with “o” in the formulas shown above, so that the radical R is then not present in this position. The structures shown above which do not contain a carbon atom marked with “o” are preferably not bonded directly to the bridge V. The carbon atoms are not directly bonded to the bridge. Preferably, a maximum of three substituents R are not H or D, particularly preferably a maximum of two substituents R and very particularly preferably a maximum of one substituent.

Preferred groups among the groups (CyD-1) to (CyD-18) are the groups (CyD-1), (CyD-2), (CyD-3), (CyD-4), (CyD-5) and (CyD-6), in particular (CyD-1), (CyD-2) and (CyD-3), particularly preferred are the groups (CyD-1a), (CyD-2a), (CyD-3a), (CyD-4a), (CyD-5a) and (CyD-6a), especially (CyD-1a).

In a preferred embodiment of the invention, CyC is an aryl or heteroaryl group having 6 to 13 aromatic ring atoms, and at the same time CyD is a heteroaryl group having 5 to 13 aromatic ring atoms. Particularly preferred is CyC a phenyl group or heteroaryl group with 13 aromatic ring atoms, in particular a phenyl, dibenzofuran or azadibenzofuran group, and at the same time CyD is a heteroaryl group with 5 to 10 aromatic ring atoms, particularly preferred with 6 to 10 aromatic ring atoms, in particular a pyridine group. In this context, CyC and CyD may each be substituted with one or more radicals R.

The above-mentioned preferred groups (CyC-1) to (CyC-20) and (CyD-1) to (CyD-18) can be combined with each other as desired, provided that at least one of the groups CyC or CyD has a suitable linkage site to the bridge V, suitable linkage sites being denoted by “o” in the above-mentioned formulae.

In particular, it is preferred if the groups CyC and CyD mentioned above as particularly preferred, i.e. the groups of the formulae (CyC1a)- to (CyC-20a) and the groups of the formulae (CyD1-a) to (CyD18a) are combined with one another, provided that at least one of the preferred groups CyC or CyD has a suitable point of attachment to the bridge V, suitable points of attachment in the formulae mentioned above being denoted by “o”. Combinations in which neither CyC nor CyD has such a suitable linkage site for the bridge V are therefore not preferred.

It is particularly preferred if one of the groups (CyC-1), (CyC-2) and (CyC-16), and in particular the groups (CyC-1a), (CyC-2a), (CyC-16a) and (CyC-16b), is combined with one of the groups (CyD-1), (CyD-2) and (CyD-3), and in particular with one of the groups (CyD-1a), (CyD-2a) and (CyD-3a). Very preferably, one of the groups (CyC-1a), (CyC-2a), (CyC-16a) and (CyC-16b) is combined with the group (CyD-1a).

Preferred partial ligands (L-1) are the structures of formulae (L-1-1) to (L-1-3), and preferred partial ligands (L-2) are the structures of formulae (L-2-1) to (L-2-5),

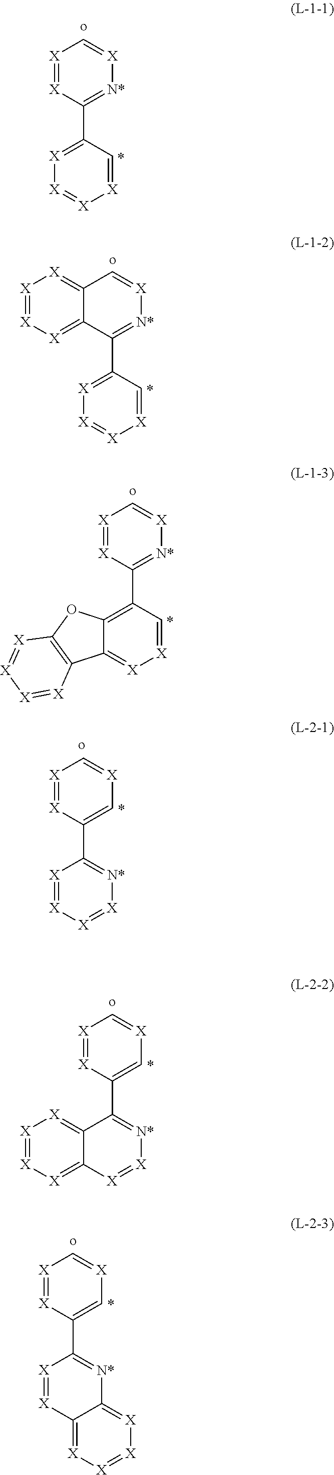

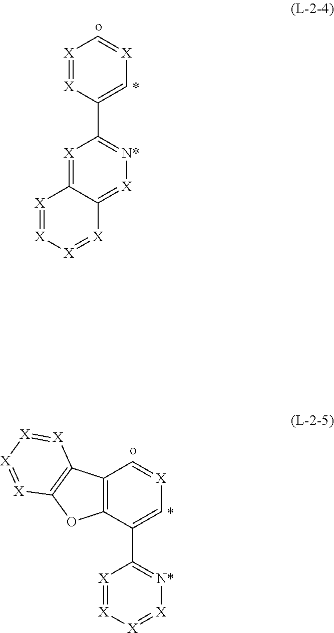

wherein the symbols used have the meanings given above, * represents the positions of coordination to the iridium, and “o” represents the position of binding to the bridge V.

Particularly preferred partial ligands (L-1) are the structures of the formulae (L-1-1a) to (L-1-3b), and particularly preferred partial ligands (L2)—are the structures of the formulae (L-2-1a) to (L-2-5b),

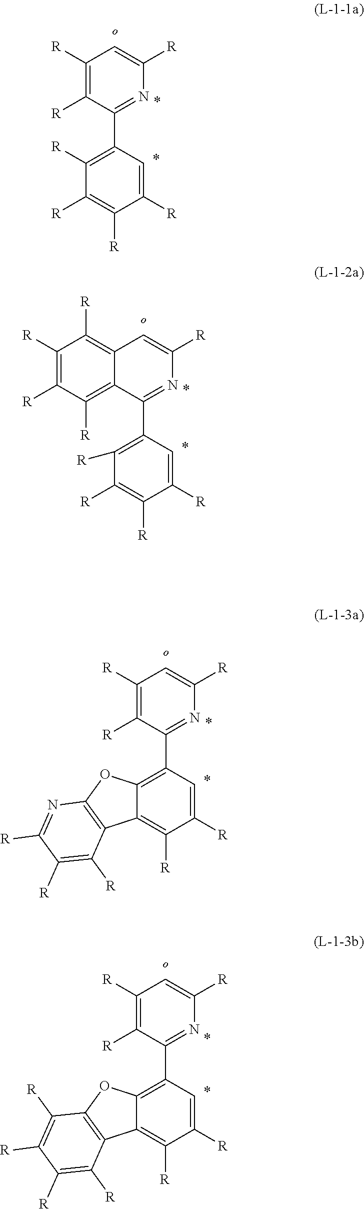

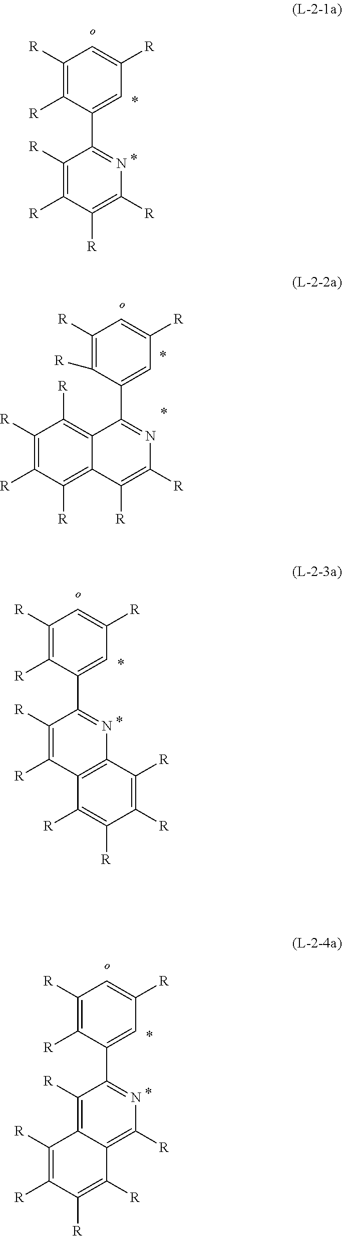

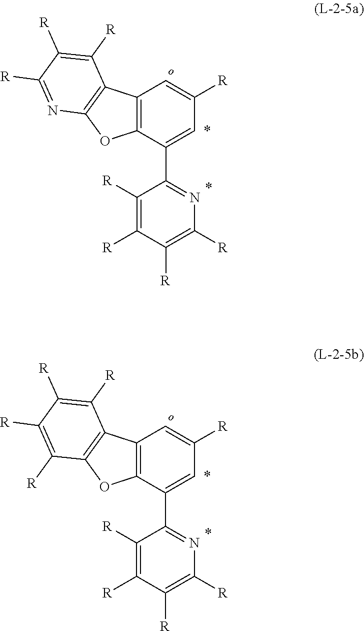

wherein the symbols used have the meanings given above, * represents the positions of coordination to the iridium and “o” represents the position of the bond to the bridge V. Preferably, a maximum of three substituents R are not H or D, particularly preferably a maximum of two substituents R and most preferably a maximum of one substituent.

If two radicals R, one of which is bonded to CyC and the other to CyD, together form an aromatic ring system with bridged part ligands and, for example, also partial ligands that together represent a single larger heteroaryl group, such as benzo[h]quinoline, etc., can result. The ring formation between the substituents on CyC and CyD is preferably carried out by a group according to one of the following formulae (3) to (12),

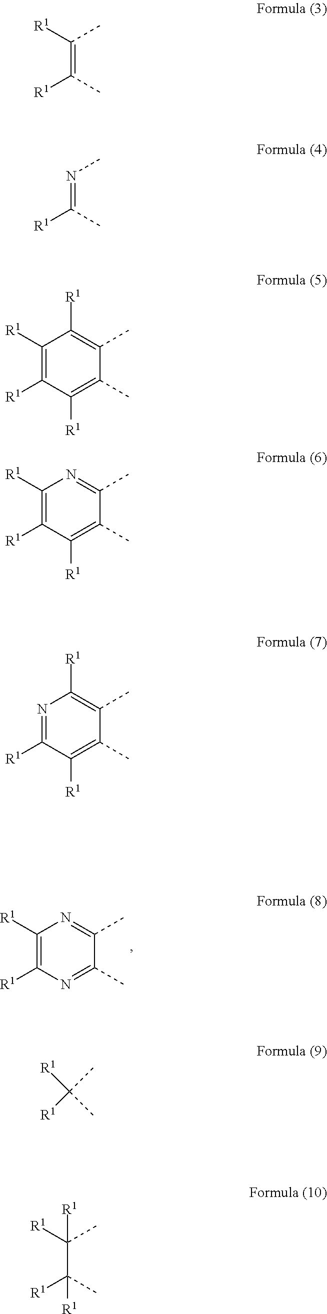

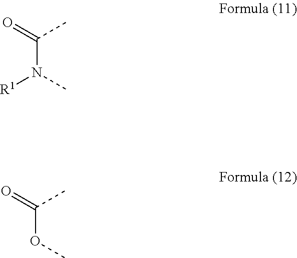

wherein R¹ has the above meanings, and the dashed bonds indicate the bonds to CyC and CyD, respectively. In this context, the asymmetric groups mentioned above can be incorporated in either of the two ways, for example, in the group of formula (12), the oxygen atom can bond to the group CyC and the carbonyl group to the group CyD, or the oxygen atom can bond to the group CyD and the carbonyl group to the group CyC. In this regard, the group of formula (9) is particularly preferred when it results in the formation of a ring to form a six-membered ring, as illustrated, for example, by formulae (L-21) and (L-22) below.

Preferred ligands formed by ring formation of two radicals R on CyC and CyD are the structures of formulae (L-3) to (L-30) listed below,

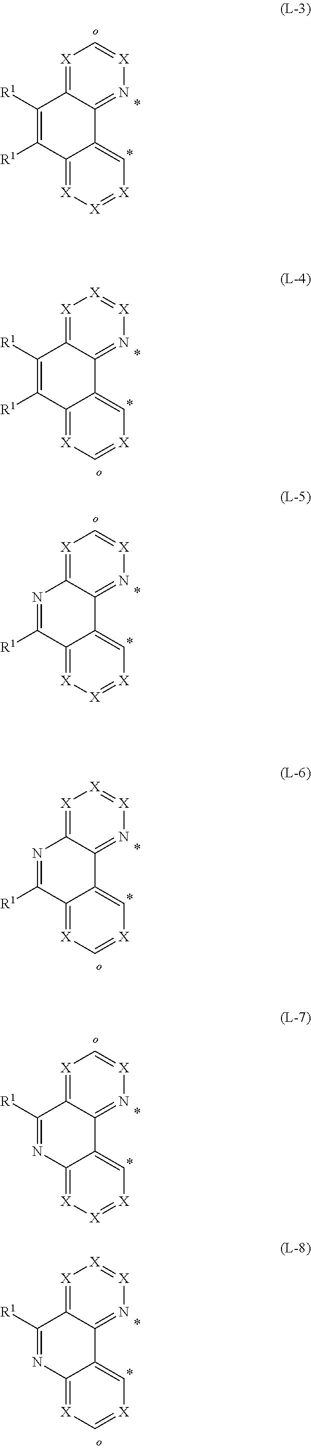

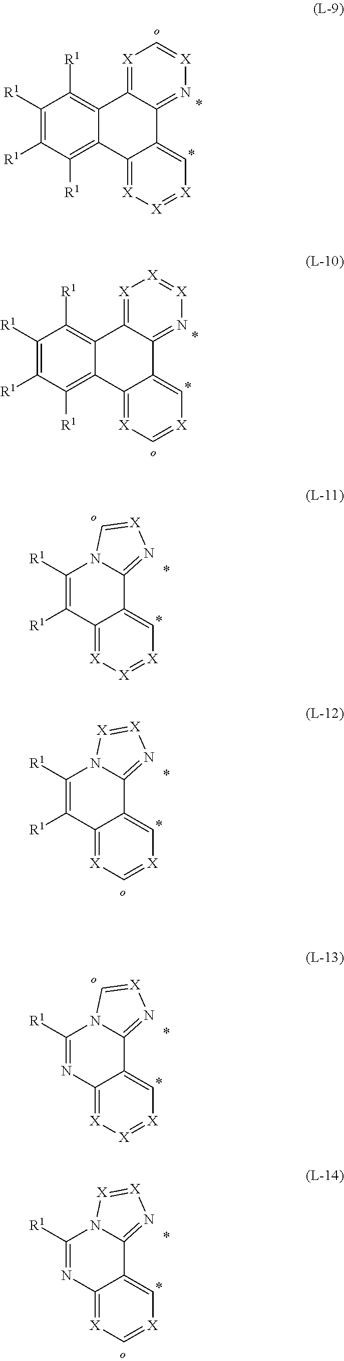

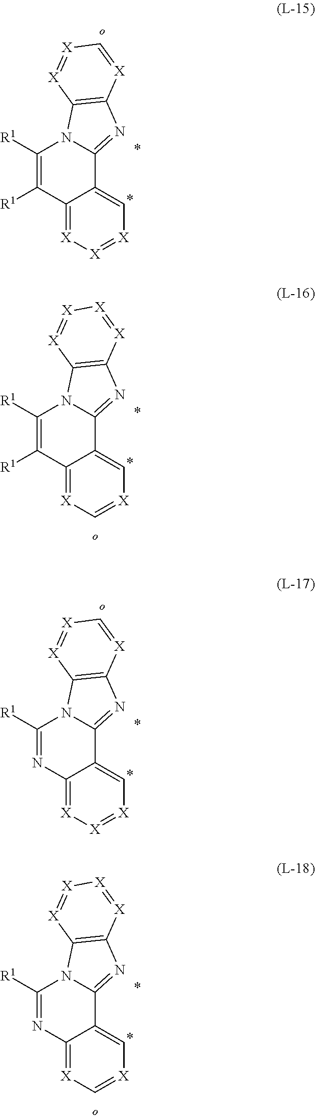

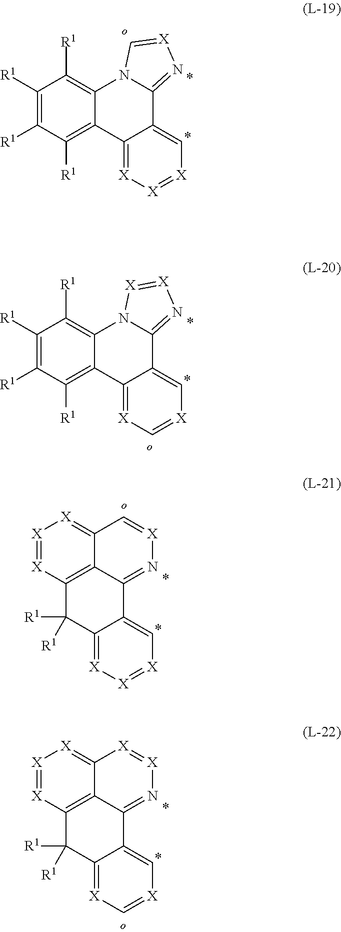

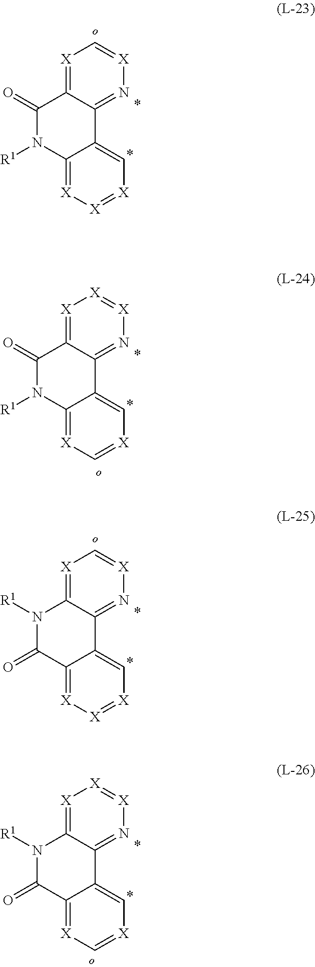

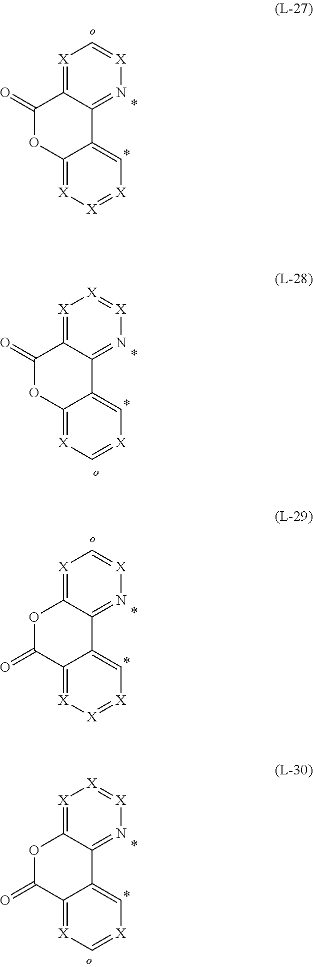

wherein the symbols used indicate the above meanings at, * represents the positions of coordination to the iridium, and “o” indicates the position at which this partial ligand is linked to the bridge V.

In a preferred embodiment of the partial ligands of formulae (L-3) to (L-30), a total of one symbol X represents N and the other symbols X represent CR, or all symbols X represent CR.

Preferred substituents as may be present on the partial ligands L¹, L² and L³ are described below.

In a further embodiment of the invention, it is preferred that when, in the groups (CyC-1) to (CyC-20) or (CyD-1) to (CyD-18) or in the partial ligands (L-3) to (L-30) one of the atoms X stands for N, then adjacent to this nitrogen atom a group R is bonded as substituent which is not hydrogen or deuterium. This applies analogously to the preferred structures (CyC-1a) to (CyC-20a) or (CyD-1a) to (CyD-18a), in which a group R is preferably bonded as substituent adjacent to a non-coordinating nitrogen atom which is not hydrogen or deuterium. This substituent R is preferably a group selected from CF₃, OCF₃, alkyl groups having 1 to 10 C atoms, in particular branched or cyclic alkyl groups having 3 to 10 C atoms, OR¹, wherein R¹ is an alkyl group having 1 to 10 C atoms, in particular a branched or cyclic alkyl group having 3 to 10 C atoms, a dialkyl amino group having 2 to 10 C atoms, aromatic or heteroaromatic ring systems, or a group of the formula heteroaromatic ring systems or aralkyl or heteroaralkyl groups. These groups can also be partially or completely deuterated. These groups are sterically demanding groups. Preferably, this radical R can also form a cycle with an adjacent radical R.

In a further embodiment of the invention, the metal complex according to the invention contains two substituents R which are bonded to adjacent carbon atoms, and which together form an aliphatic ring according to one of the formulae described below. The aliphatic ring formed by the ring formation of two substituents R with one another is preferably described by one of the following formulae (13) to (19),

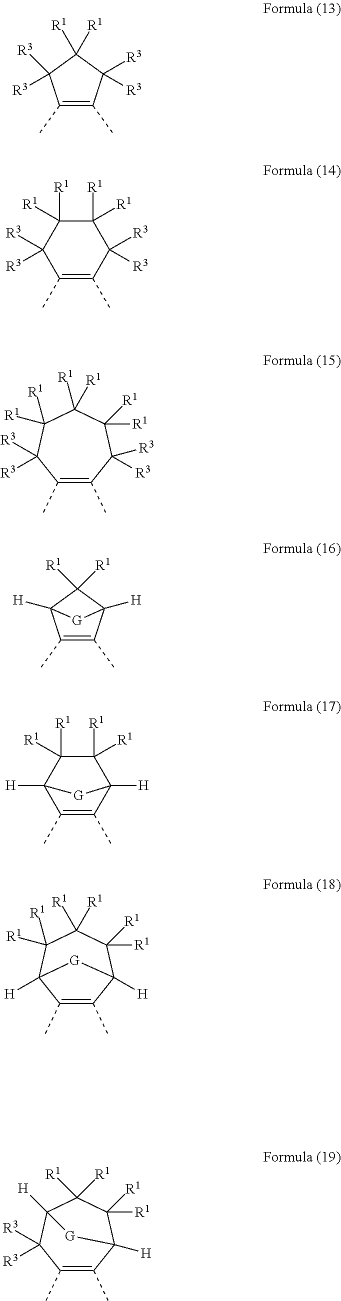

wherein R¹ and R² have the above meanings, the dashed bonds indicate the linkage of the two carbon atoms in the ligand, and further:
G is an alkylene group having 1, 2 or 3 carbon atoms, which may be substituted by one or more radicals R², —CR²═CR²— or an ortho-linked arylene or heteroarylene group having 5 to 14 aromatic ring atoms, which may be substituted by one or more radicals R²;
R³ at each occurrence is the same or different and is H, D, F, a straight-chain alkyl or alkoxy group having 1 to 10 C atoms, a branched or cyclic alkyl or alkoxy group having 3 to 10 C atoms, it being possible for the alkyl or alkoxy group in each case to be substituted by one or more radicals R², it being possible for one or more non-adjacent CH₂ groups to be replaced by R²C═CR², C≡C, Si(R²)₂, C═O, NR², O, S or CONR², or an aromatic or heteroaromatic ring system having 5 to 24 aromatic ring atoms, each of which may be substituted by one or more radicals R², or an aryloxy or hetero aryloxy group having 5 to 24 aromatic ring atoms, each of which may be substituted by one or more radicals R²; wherein two radicals R³ that are bonded to the same carbon atom can form an aliphatic or aromatic ring system with one another and thus form a spiro system; furthermore, R³ can form an aliphatic ring system with an adjacent radical R or R¹.

If adjacent radicals in the structures according to the invention form an aliphatic ring system, then it is preferred if this does not have acidic benzylic protons. Benzylic protons mean protons that bind to a carbon atom that is directly bonded to the ligand. This can be achieved by ensuring that the carbon atoms of the aliphatic ring system that bind directly to an aryl or heteroaryl group are fully substituted and contain no hydrogen atoms bonded. Thus, the absence of acidic benzylic protons in formulas (13) to (15) is achieved by R³ not being hydrogen or deuterium. This can further be achieved by the fact that the carbon atoms of the aliphatic ring system which bind directly to an aryl or heteroaryl group are the bridgeheads of a bi- or polycyclic structure. The protons bonded to bridgehead carbon atoms are much less acidic than benzylic protons on carbon atoms not bonded in a bi- or polycyclic structure, due to the spatial structure of the bi- or polycycle, and are considered non-acidic protons for the purposes of the present invention. Thus, the absence of acidic benzylic protons is achieved in formulas (16) to (19) by being a bicyclic structure, whereby R¹, when H or D, is significantly less acidic than benzylic protons because the corresponding anion of the bicyclic structure is not mesomerically stabilized. Therefore, even though R¹ in formulas (16) to (19) is H or D, it is a non-acidic proton within the meaning of the present application. In a preferred embodiment of the invention, R³ is not H or D.

Preferred embodiments of the groups of formulae (13) to (19) can be found in applications WO 2014/023377, WO 2015/104045 and WO 2015/117718.

In another preferred embodiment of the invention, at least one of the partial ligands L¹, L² and L³, respectively, and preferably exactly one of the partial ligands L¹, L² and L³, respectively, is a partial ligand according to one of the following formulae (L-31) and (L-32),

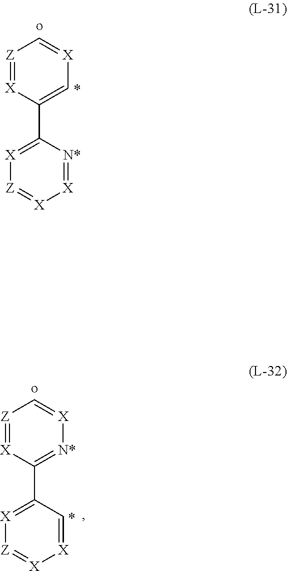

wherein * represent the positions of the coordination to the iridium, “o” denotes the position of the linkage to the bridge V the following definitions apply:
X at each occurrence is the same or different and is CR or N;
Z is CR′, CR or N, with the proviso that exactly one Z stands for CR′ and the other Z stands for CR or N;
wherein a maximum of one of the symbols X or Z per ring stands for N and preferably none of the symbols X or Z stands for N;
R′ is a group according to any of the following formulae (20), (21), (22), (23), (24), (25), (26) or (27),

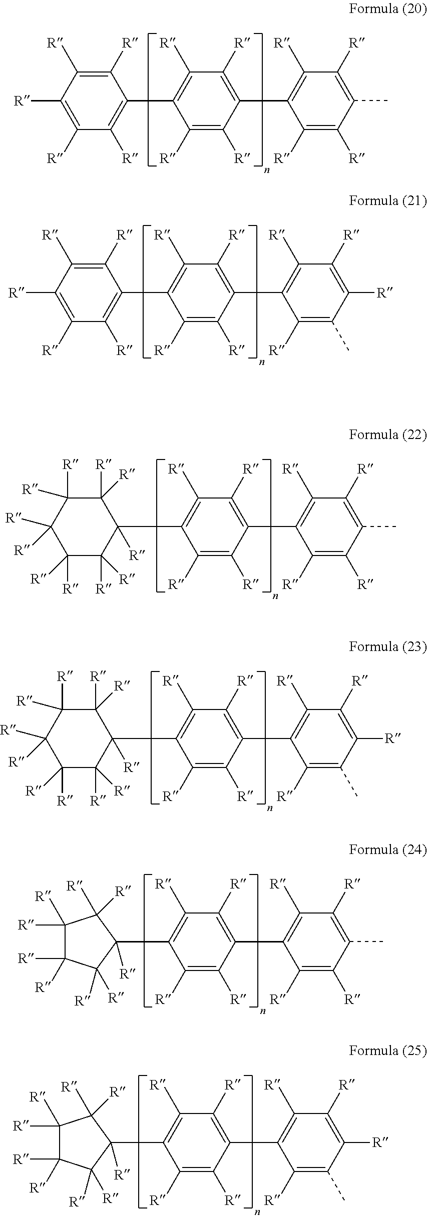

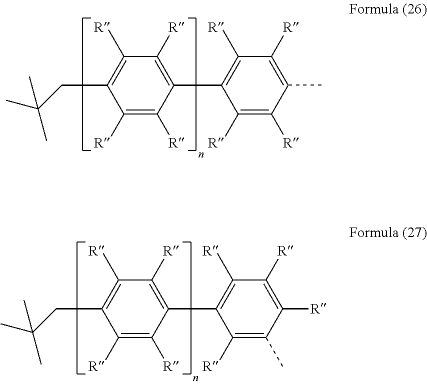

wherein the dashed bond indicates the linkage of the group to the partial ligands of the formula (L-31) or (L-32), H atoms not explicitly shown may also be replaced by D, and the following definitions apply:
R″ at each occurrence is the same or different and is H, D, F, ON, a straight-chain alkyl group having 1 to 10 C atoms, in which one or more H atoms may also be replaced by D or F, or a branched or cyclic alkyl group having 3 to 10 C atoms, in which one or more H atoms may also be replaced by D or F, or an alkenyl group having 2 to 10 C atoms, in which one or more H atoms may also be replaced by D or F; wherein two adjacent radicals R″ or two radicals R″ on adjacent phenyl groups may together form a ring system; or two R″ on adjacent phenyl groups may together represent a group selected from C(R¹)₂, NR¹, O or S, so that the two phenyl rings together with the bridging group represent a carbazole, fluorene, dibenzofuran or dibenzothiophene, and the further R″ are as defined above;
n is 0, 1, 2, 3, 4 or 5.

If two R″ on adjacent phenyl groups together stand for a group C(R¹)₂ or NR¹, the radical R¹ on the carbon or nitrogen substance is as defined above and preferably stands for an alkyl group with 1 to 10 C atoms or an aromatic or heteroaromatic ring system with 6 to 24 aromatic ring atoms, which can be substituted by one or more radicals R², particularly preferably for an aromatic or heteroaromatic ring system having 6 to 18 aromatic ring atoms, which can be substituted by one or more radicals R², but is preferably unsubstituted. One or more H atoms may also be replaced by deuterium.

In a preferred embodiment of the invention, n=0, 1 or 2, preferably 0 or 1, and most preferably 0.

In another preferred embodiment of the invention, both substituents R′, which are bonded in the ortho-positions to the carbon atom with which the group of formula (20) to (27) is bonded to the partial ligands L¹, L² and L³, respectively, are the same or different H or D.

In a preferred embodiment of the invention, each occurrence of X is the same or different and is CR. Further preferably, one group Z represents CR, and the other group Z represents CR′. Particularly preferably, in the partial ligand (L-31) or (L-32), each occurrence of the group X is the same or different and is CR, whilst at the same time one group Z stands for CR and the other group Z stands for CR′. The partial ligand L¹, L² or L³ preferably has a structure according to one of the following formulae (L-31a) or (L-32a),

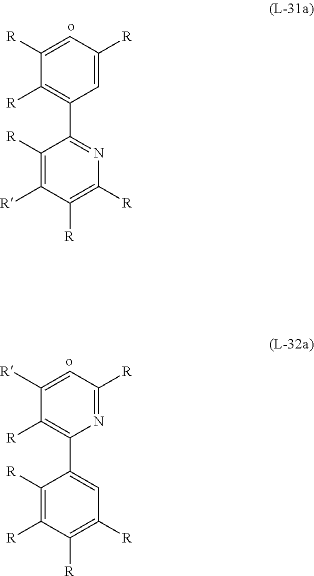

wherein the link to the bridge V is made via the position marked “o” and the symbols used have the meanings given above.

Particularly preferably, the partial ligand of formula (L-31) or (L-32) has a structure according to one of the following formulae (L-31 b) or (L-32b),

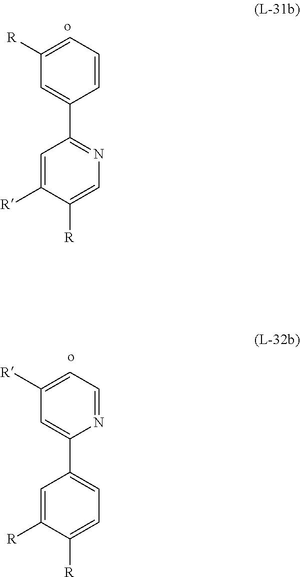

wherein the symbols used have the above meanings.

The radicals R on the partial ligand of the formula (L-31) or (L-32) or the preferred embodiments are preferably selected from the group consisting of H, D, CN, OR¹, a straight-chain alkyl group having 1 to 6 C atoms, preferably having 1, 2 or 3 C atoms, or a branched or cyclic alkyl group having 3, 4, 5 or 6 C atoms or an alkenyl group having 2 to 6 C atoms, preferably having 2, 3 or 4 C atoms, which may each be substituted by one or more radicals R¹, or a phenyl group which may be substituted by one or more non-aromatic radicals R¹, it also being possible for all these groups to be partially or completely deuterated. In this context, two or more adjacent radicals R may also form a ring system with one another.

In this context, the substituent R, which is bonded in the ortho-position to the coordinating atom, is preferably selected from the group consisting of H, D, F or methyl, particularly preferably H, D or methyl and especially H or D, it also being possible for the methyl group to be partially or completely deuterated.

Furthermore, it is preferred if all substituents R that are in ortho position to R′ are H or D.

If radicals R on the partial ligand of the formula (L-31) or (L-32) together form a ring system, this is preferably an aliphatic, heteroaliphatic or heteroaromatic ring system. Furthermore, ring formation between two radicals R on the two rings of the partial ligand is preferred, forming a phenanthridine or a phenanthridine which may contain other nitrogen atoms. If radicals R together form a heteroaromatic ring system, this preferably forms a structure which is selected from the group consisting of quinoline, isoquinoline, dibenzofuran, dibenzothiophene and carbazole, each of which may be substituted by one or more radicals R¹ and where, in the dibenzofuran, dibenzothiophene and carbazole, individual carbon atoms may also be replaced by N. Particularly preferred are quinoline, isoquinoline, dibenzofuran and azadibenzofuran. The fused-on structures can be bound in any possible position. Preferred partial ligands with fused-on benzo groups are the structures according to formula (L-31c) to (L-32f), wherein the linkage to the bridge V takes place via the position indicated by “o”:

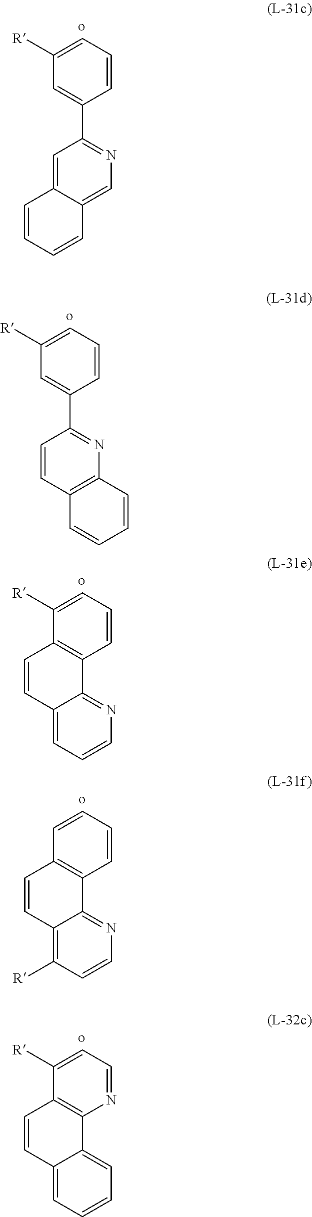

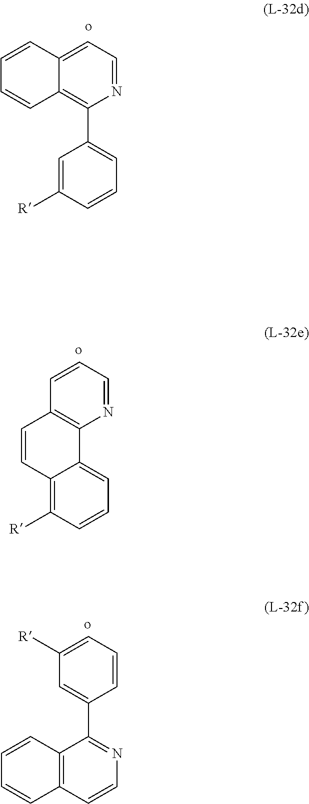

wherein the partial ligands may each also be substituted by one or more further radicals R and the fused-on structure may be substituted by one or more radicals R¹. Preferably, no further radicals R or R¹ are present.

Preferred partial ligands of the formula (L-32) with a condensed benzofuran or aza benzofuran group are the structures Formula (L-32g) and (L-32h) listed below according to, the linkage to the bridge V being via the position indicated by “o”:

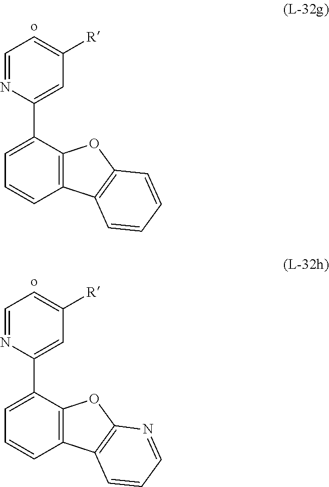

wherein the ligands may each also be substituted by one or more further radicals R and the fused-on structure may be substituted by one or more radicals R¹. Preferably, no further radicals R or R¹ are present. When substituents R and/or R¹ are present in these structures, these are preferably selected from the group consisting of D, F, CN, cyclopentyl, cyclohexyl or phenyl, wherein in each case one or more H atoms may be replaced by D. Similarly, in these structures O may be replaced by S or NR¹.

As described above, R′ is a group according to one of the formulae (20) to (27). Here, the groups of formulae (20) and (21) differ only in that the group of formula (20) in the para position and the group of formula (21) in the meta position are linked to the partial ligand L¹. The same applies to the groups of formulae (22) and (23), to the groups of formulae (24) and (25) and to the groups of formulae (26) and (27).

In another preferred embodiment of the invention, both substituents R″, which are bonded in the ortho-positions to the carbon atom with which the group of formula (20) to (27) is bonded to the partial ligand, are the same or different H, D or methyl, in which one or more H atoms may also be replaced by D.

Preferred embodiments of the structure of formula (20) are the structures of formulae (20a) to (20h), and preferred embodiments of the structure of formula (21) are the structures of formulae (21a) to (21h),

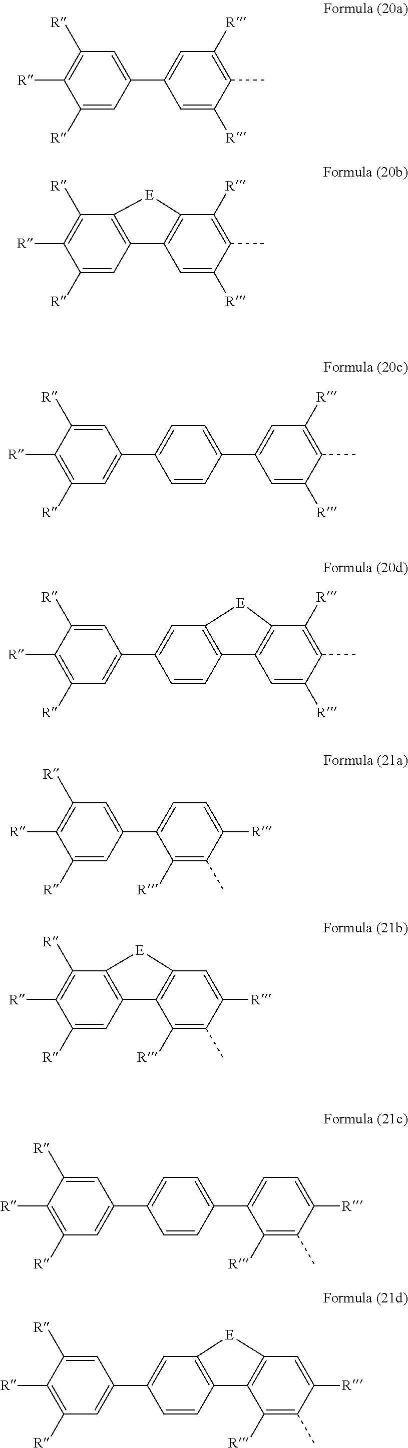

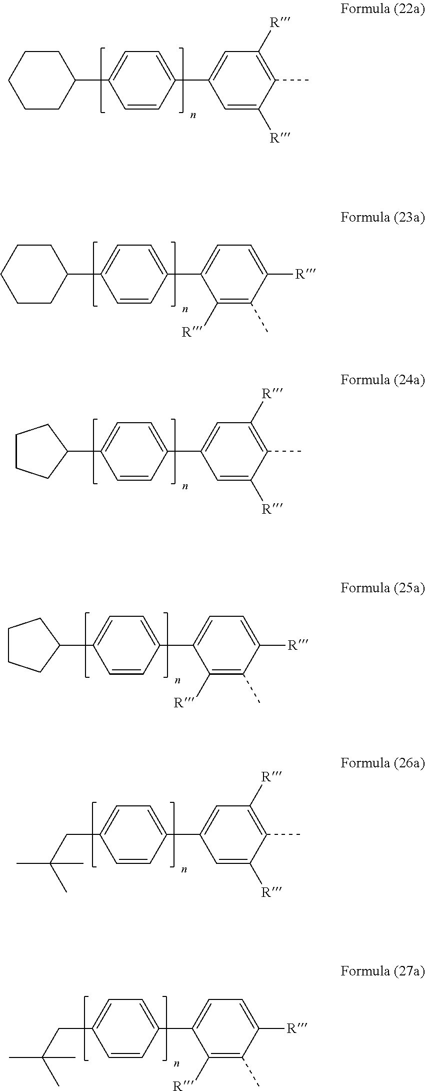

wherein each occurrence of E is O, S, C(R¹)₂ or NR¹, R′″, which may be the same or different and is H, D or an alkyl group having 1 to 5 carbon atoms in which one or more H atoms may also be replaced by D, the other symbols used have the abovementioned meanings, and the H atoms not explicitly shown may also be replaced by deuterium. In this context, each occurrence of R′″ preferably stands, being the same or different, for H, D or a methyl group in which one or more H atoms may also be replaced by D. In this context, when E=NR¹, R¹ preferably stands for an aromatic or heteroaromatic ring system having 6 to 18 aromatic ring atoms, which can also be deuterated and can be substituted by one or more radicals R², but is preferably unsubstituted. Furthermore, when E=C(R¹)₂, each occurrence of R¹ preferably is the same or different and stands for an alkyl group with 1 to 6 C atoms, preferably with 1 to 4 C atoms, particularly preferably methyl groups, each of which can also be deuterated.

Preferred substituents R″ on the groups of the formula (20) to (27) or the preferred embodiments are selected from the group consisting of H, D, CN and an alkyl group having 1 to 4 C atoms, particularly preferably H, D, methyl, cyclopentyl, 1-methylcyclopentyl, cyclohexyl or 1-methylcyclohexyl, in particular H, D or methyl, it being possible for these groups in each case also to be partially or fully substituted.

Preferably, none of the partial ligands other than the group of formula (20) to (27) has aromatic or heteroaromatic substituents with more than 10 aromatic ring atoms.

If the compounds according to the invention have radicals R which do not correspond to the radicals R described above, then these radicals R in each occurrence are the same or different and are preferably selected from the group consisting of H, D, F, Br, I, N(R¹)₂, CN, Si(R¹)₃, B(OR¹)₂, C(═O)R¹, a straight-chain alkyl group having 1 to 10 C atoms or an alkenyl group having 2 to 10 C atoms or a branched or cyclic alkyl group having 3 to 10 C atoms, it being possible for the alkyl or alkenyl group in each case to be substituted by one or more radicals R¹, or an aromatic or hetero aromatic ring system having 5 to 30 aromatic ring atoms, which in each case can be substituted by one or more radicals R¹; two adjacent radicals R or R with R¹ may also form together a mono- or polycyclic, aliphatic or aromatic ring system. Particularly preferably, these radicals R are the same or different for each occurrence selected from the group consisting of H, D, F, N(R¹)₂, a straight chain alkyl group having 1 to 6 C atoms or a branched or cyclic alkyl group having 3 to 10 carbon atoms, wherein one or more H atoms may be replaced by D or F, or an aromatic or heteroaromatic ring system having 5 to 24 aromatic ring atoms, each of which may be substituted by one or more radicals R¹; two adjacent radicals R or R with R¹ can also together form or a mono- or polycyclic, aliphatic or aromatic ring system.

Preferred radicals R¹, which are bonded to R, are in each occurrence, identically or differently, H, D, F, N(R²)₂, CN, a straight-chain alkyl group having 1 to 10 C atoms or an alkenyl group having 2 to 10 C atoms or a branched or cyclic alkyl group having 3 to 10 C atoms, wherein the alkyl group may in each case be substituted by one or more radicals R² or an aromatic or heteroaromatic ring system having 5 to 24 aromatic ring atoms, which may in each case be substituted by one or more radicals R²; wherein two or more adjacent radicals R¹ can together form a mono- or polycyclic aliphatic ring system. Particularly preferred radicals R¹, which are bonded to R, are in each occurrence the same or different H, F, CN, a straight-chain alkyl group having 1 to 5 C atoms or a branched or cyclic alkyl group having 3 to 5 C atoms, which may each be substituted by one or more radicals R² sub or an aromatic or heteroaromatic ring system having 5 to 13 aromatic ring atoms, which may each be substituted by one or more radicals R²; wherein two or more adjacent radicals R¹ may form with one another a mono- or polycyclic aliphatic ring system.

It is preferred that each occurrence of radical R² is the same or different and is H, F or an aliphatic carbon radical having 1 to 5 C atoms or an aromatic carbon radical having 6 to 12 C atoms; wherein two or more substituents R² can also form a mono- or polycyclic aliphatic ring system with one another.

The above-mentioned preferred embodiments can be combined with each other as desired. In a particularly preferred embodiment of the invention, the above preferred embodiments apply simultaneously.

Examples of suitable structures according to the invention are the compounds illustrated below.

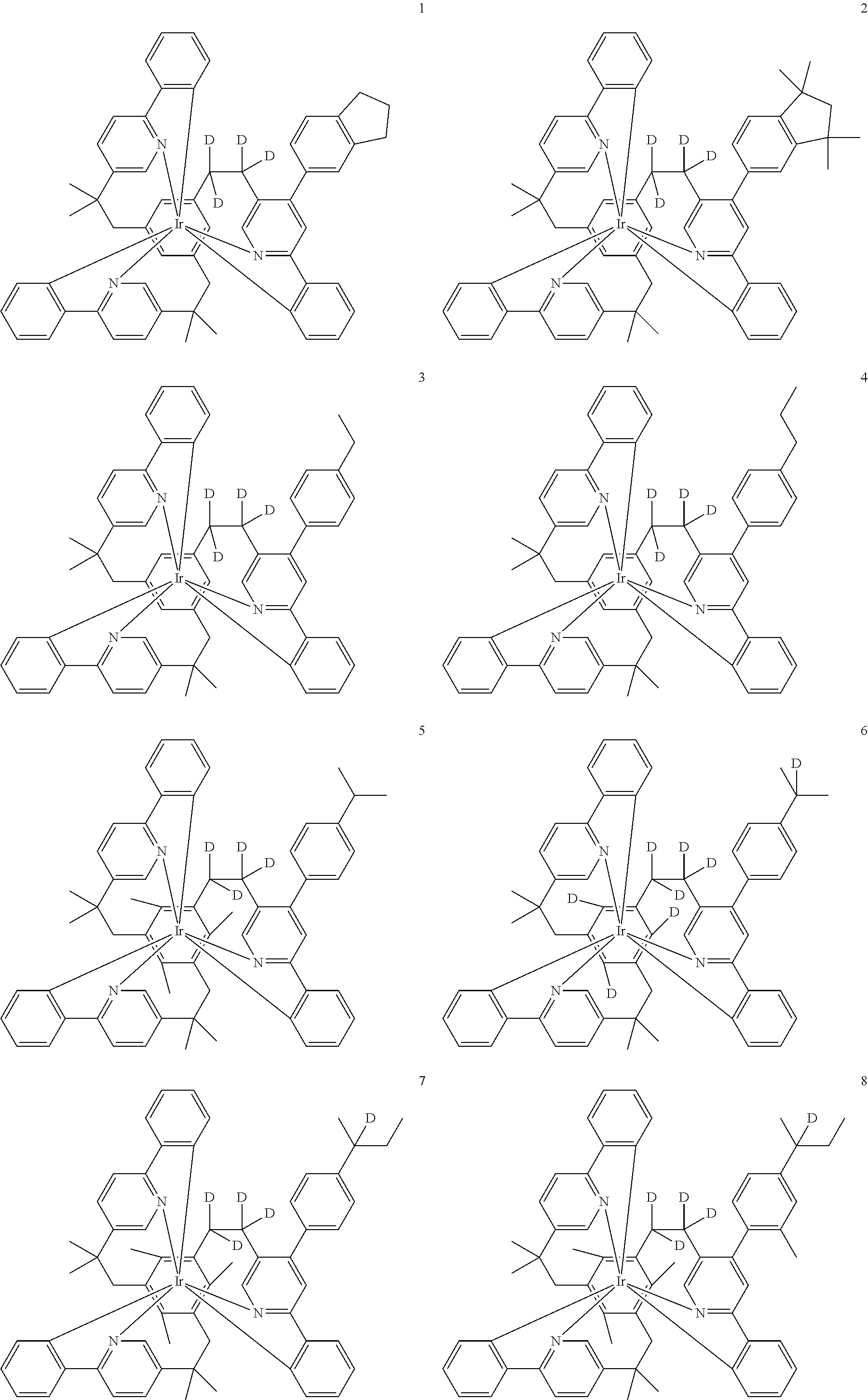

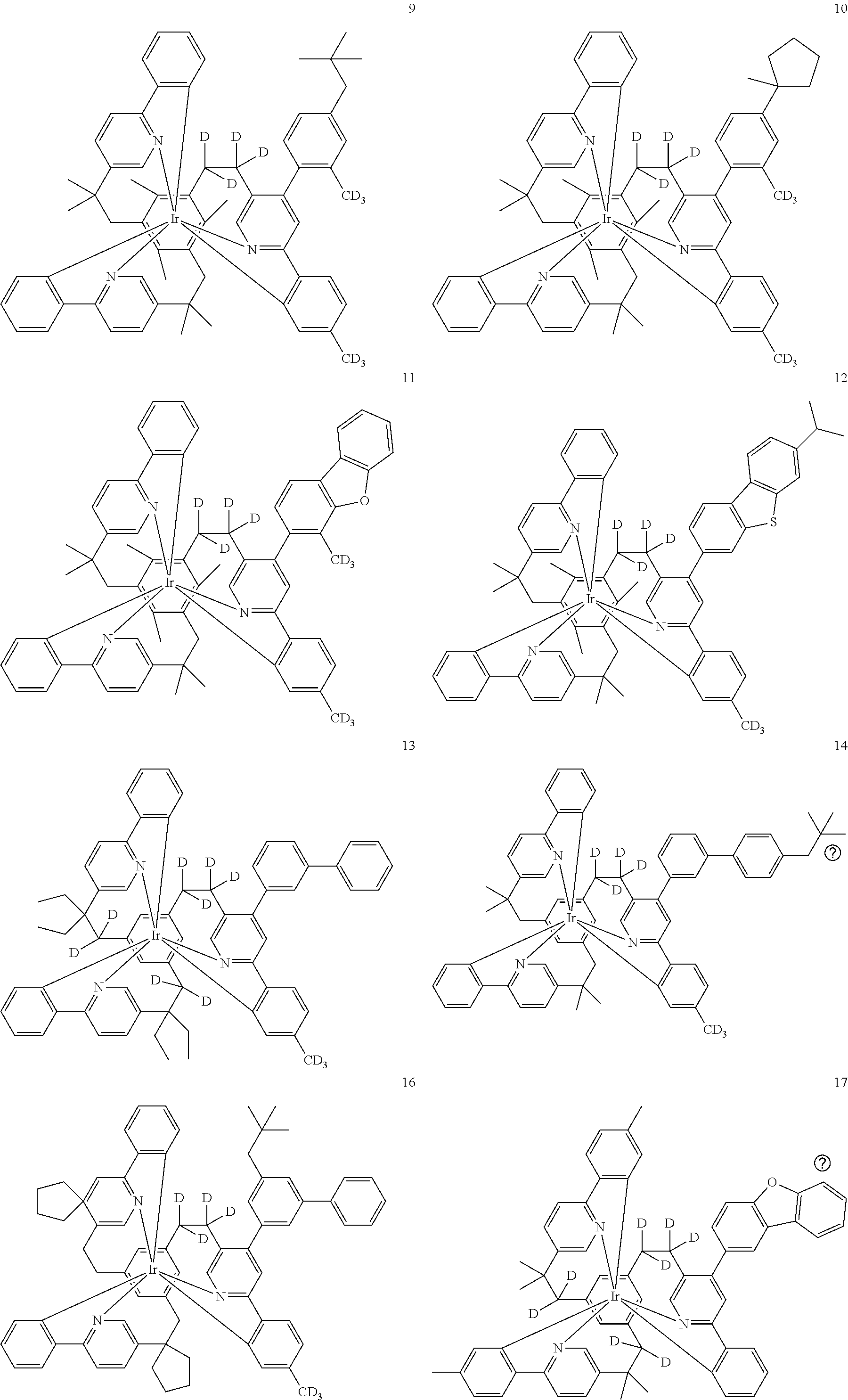

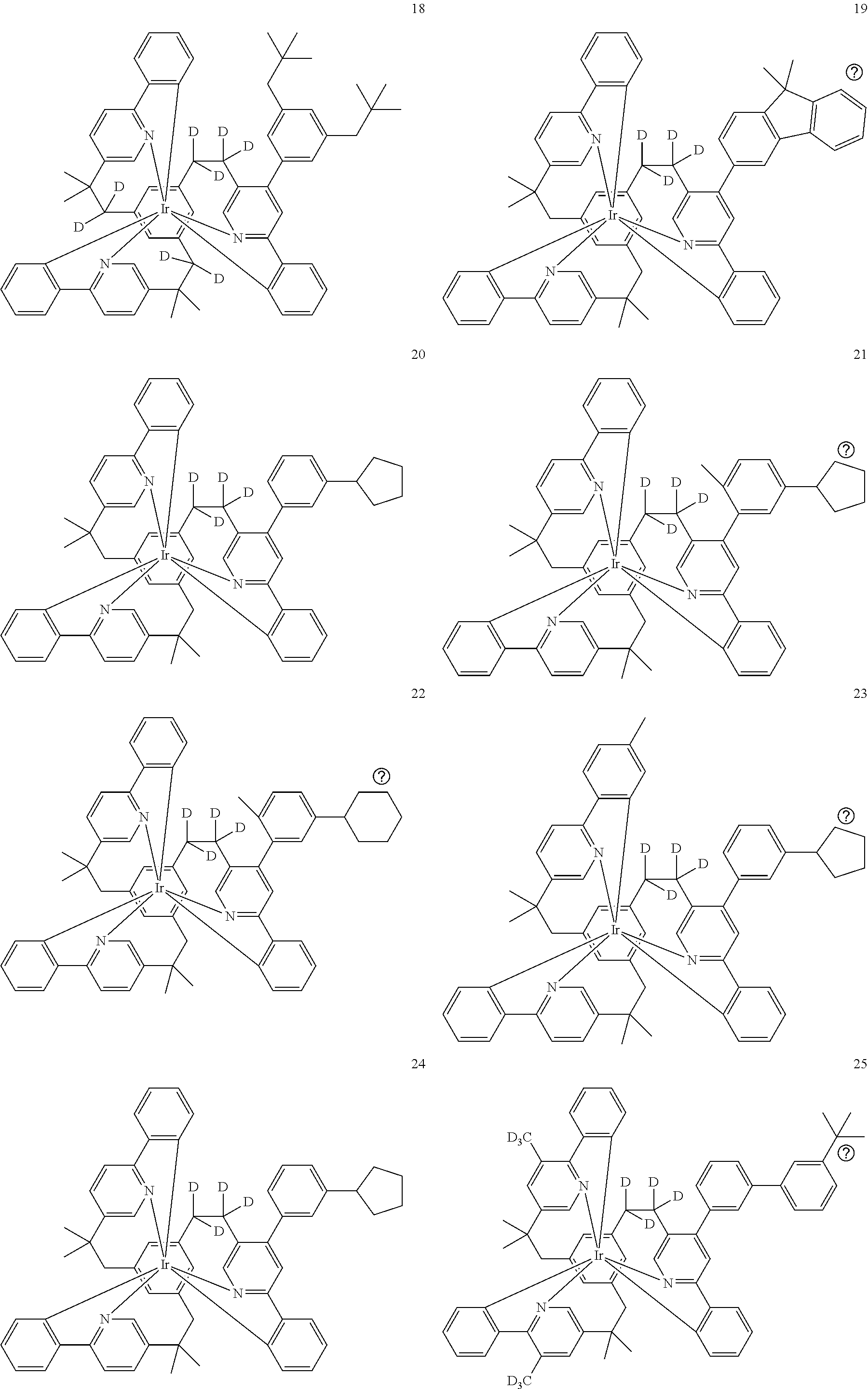

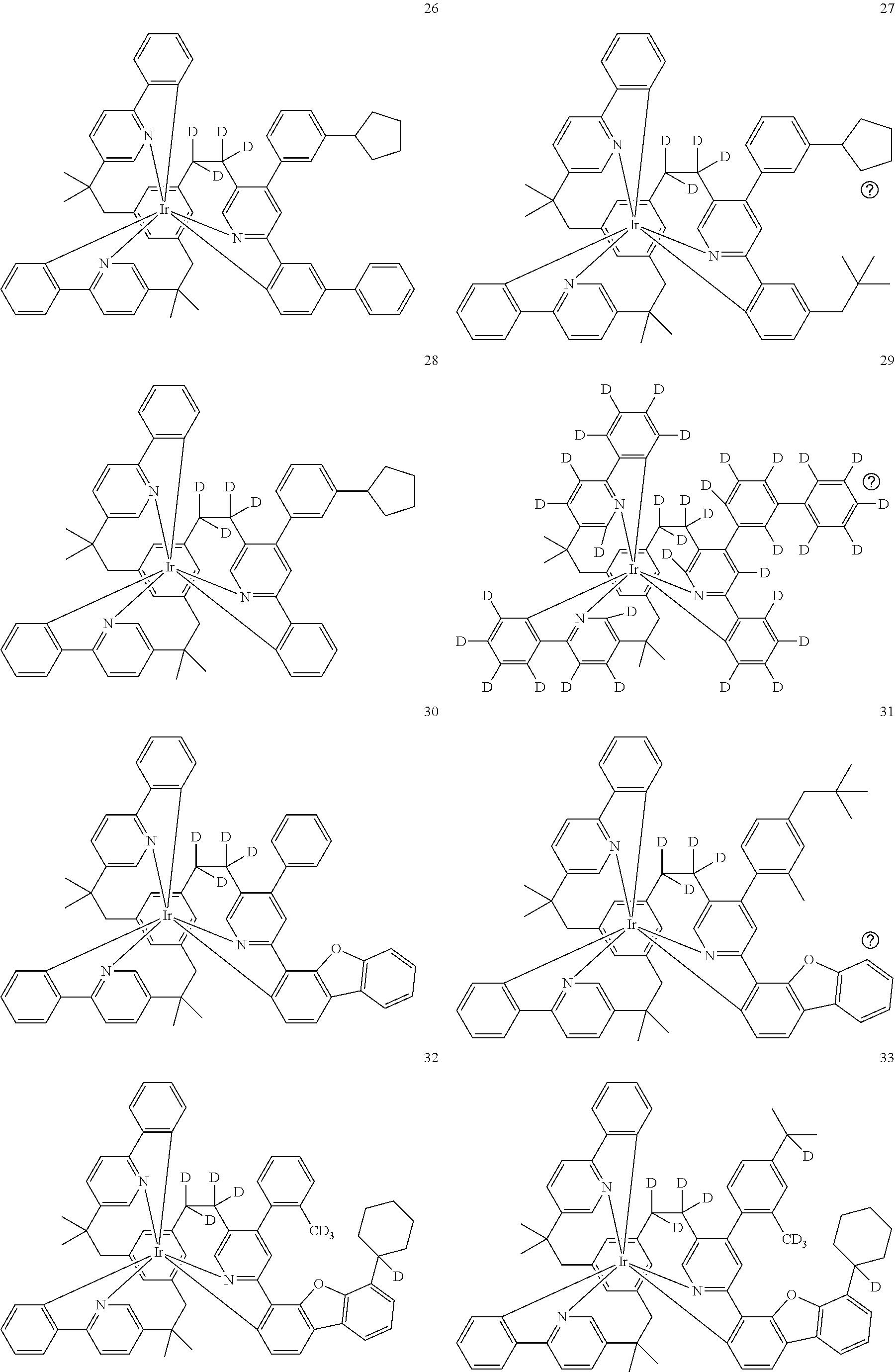

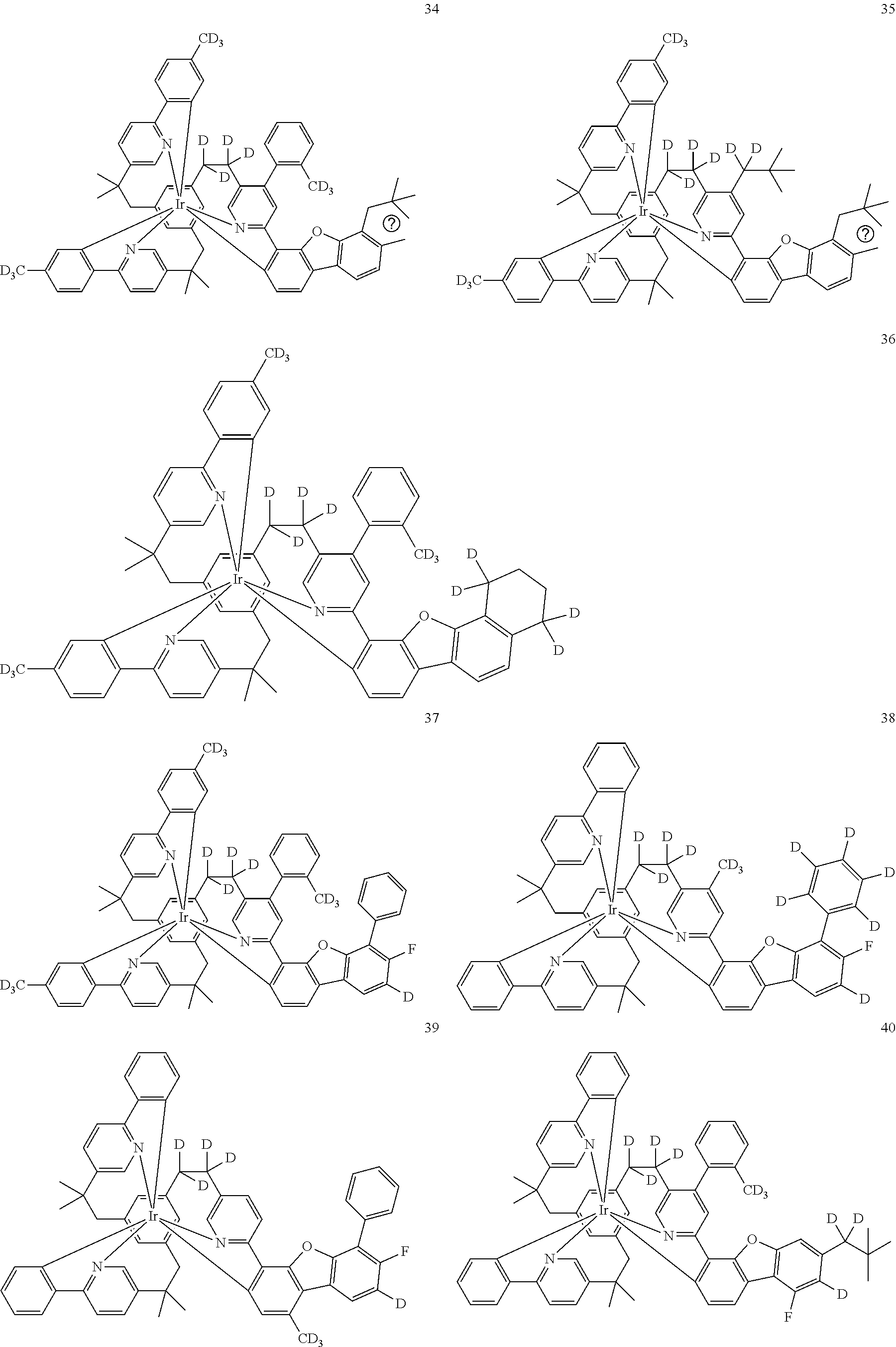

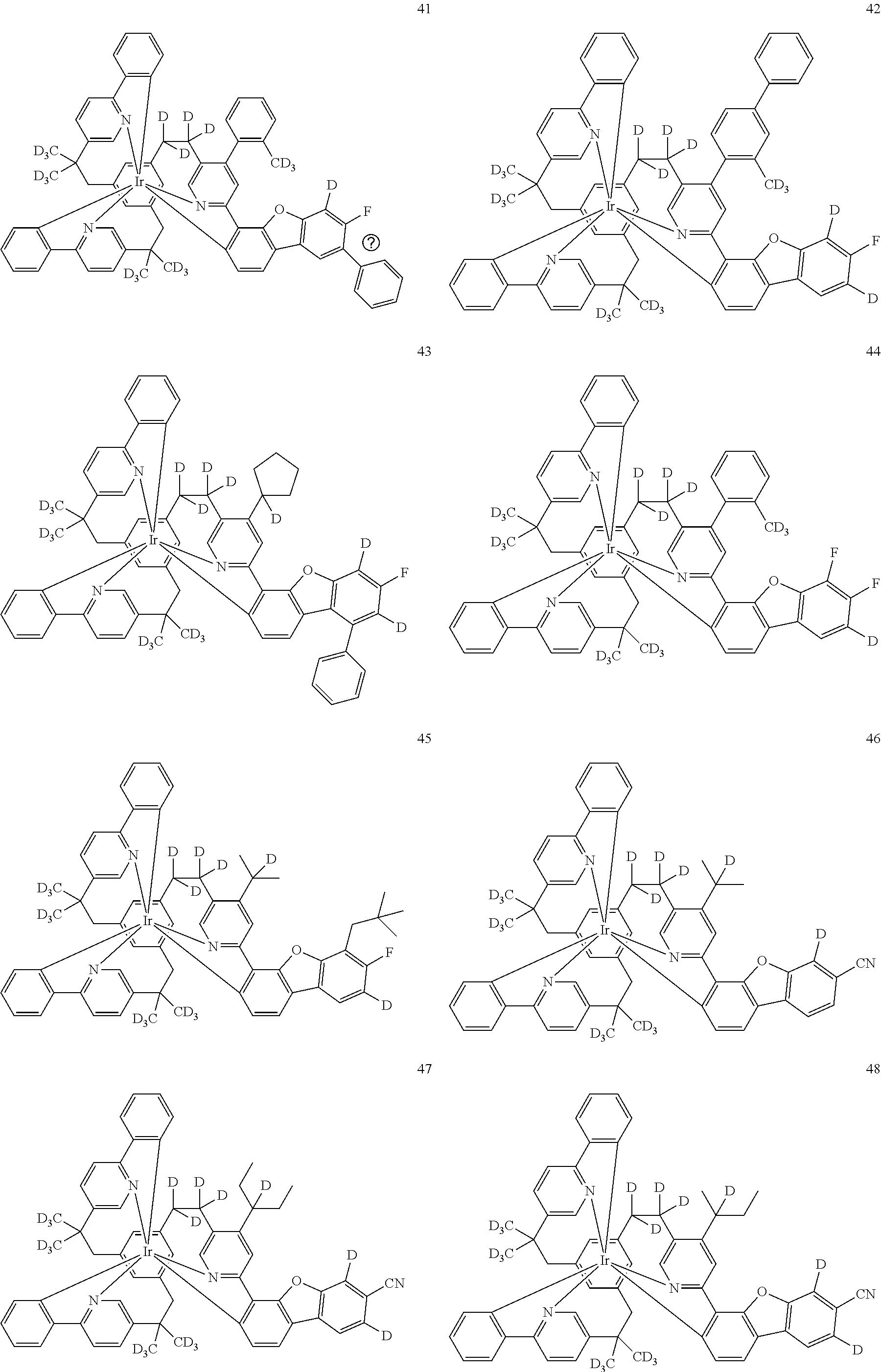

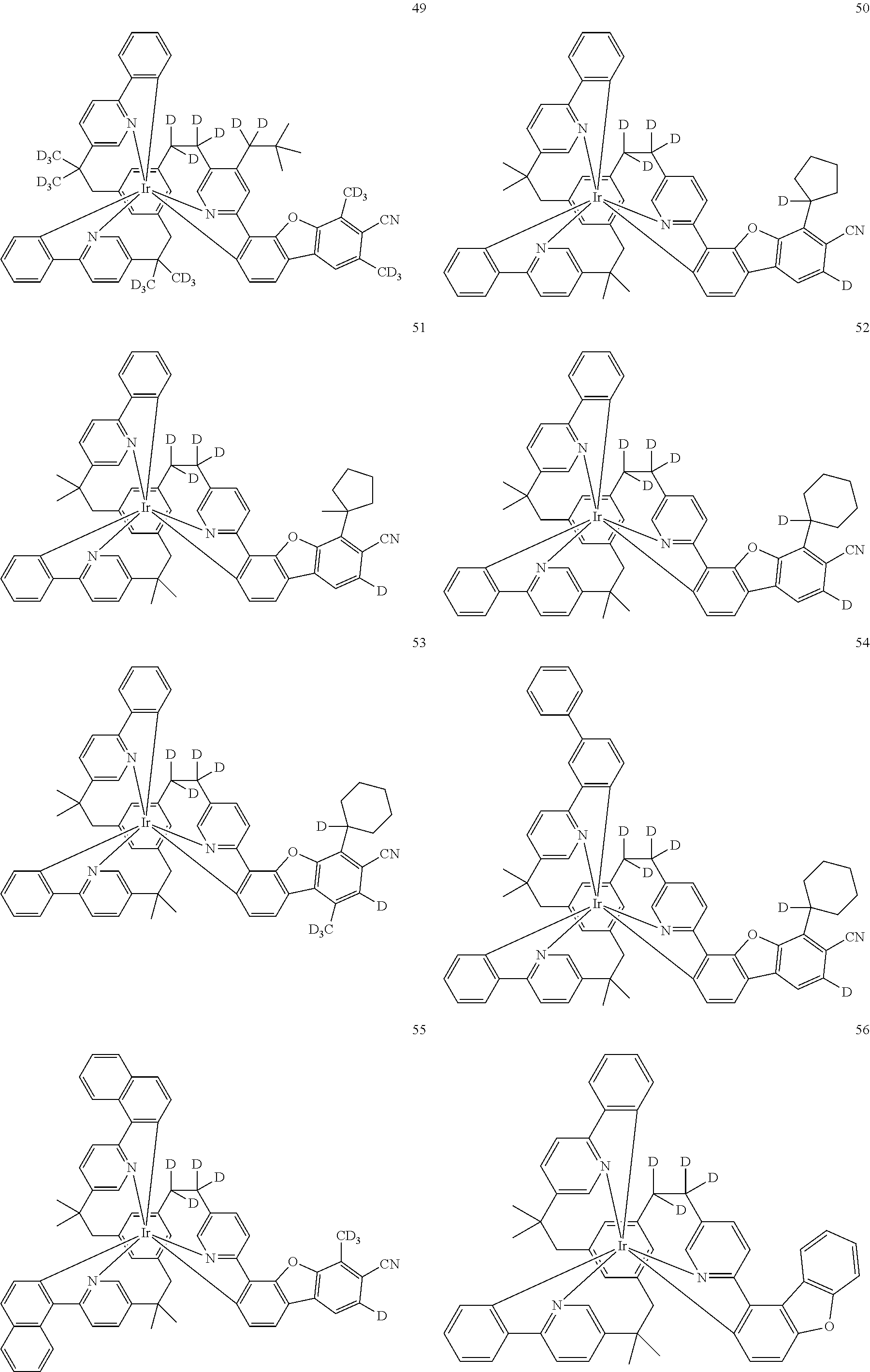

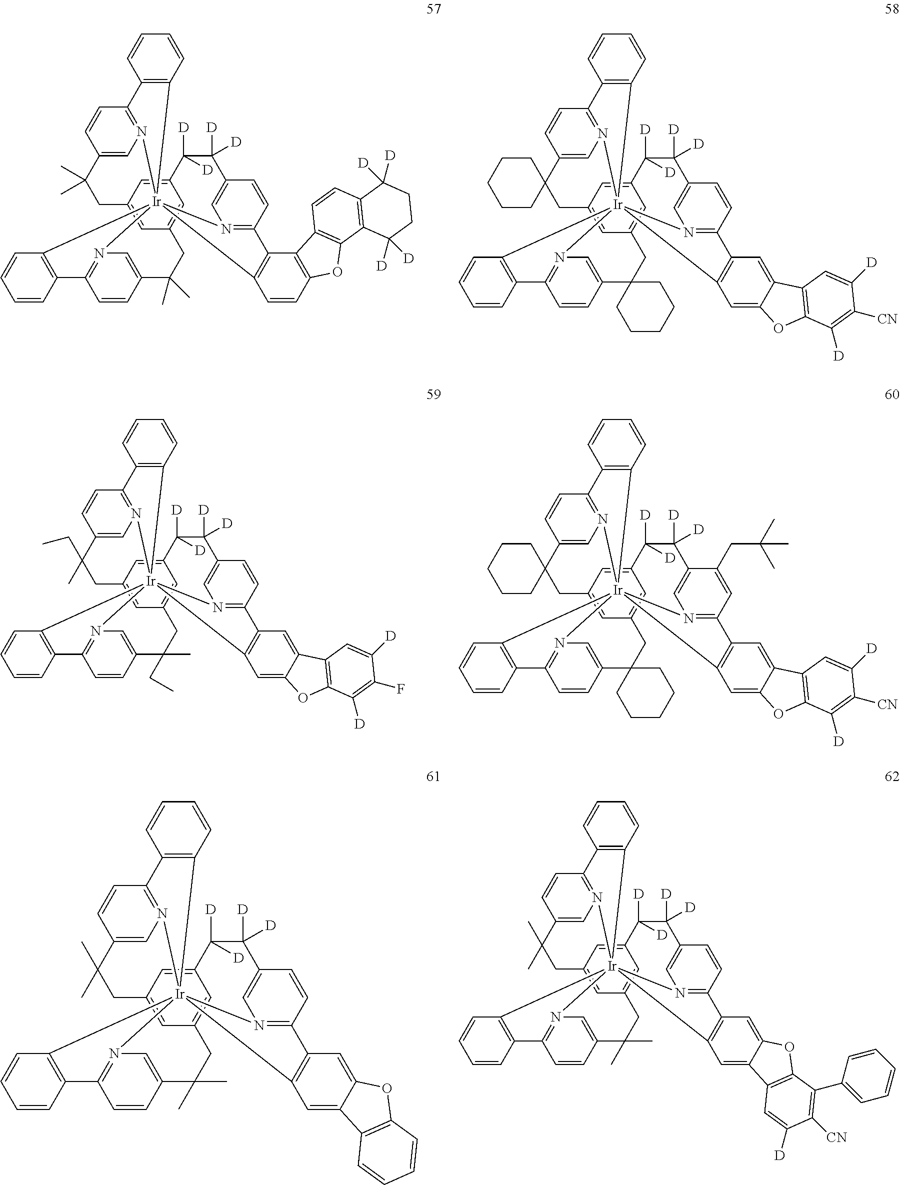

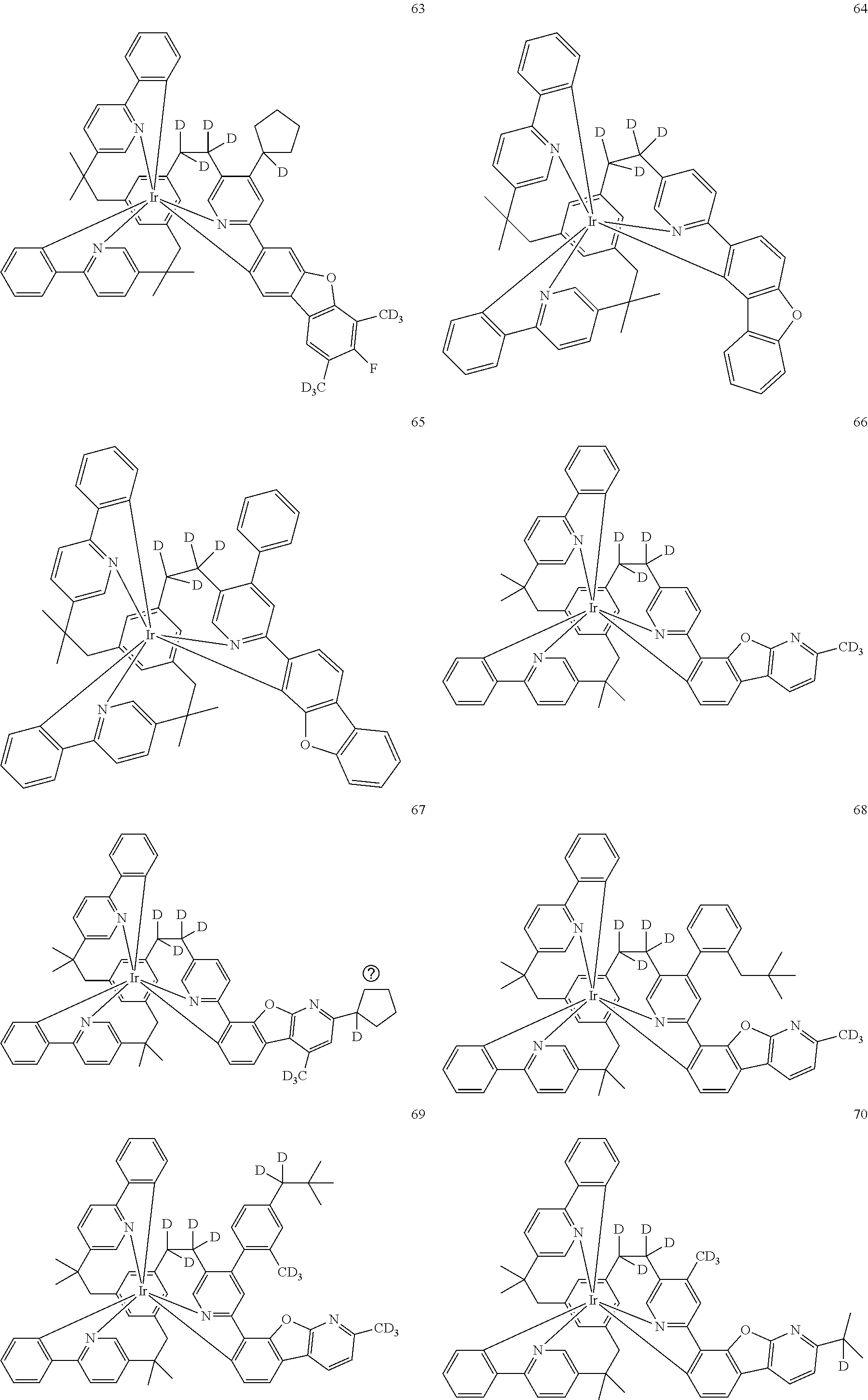

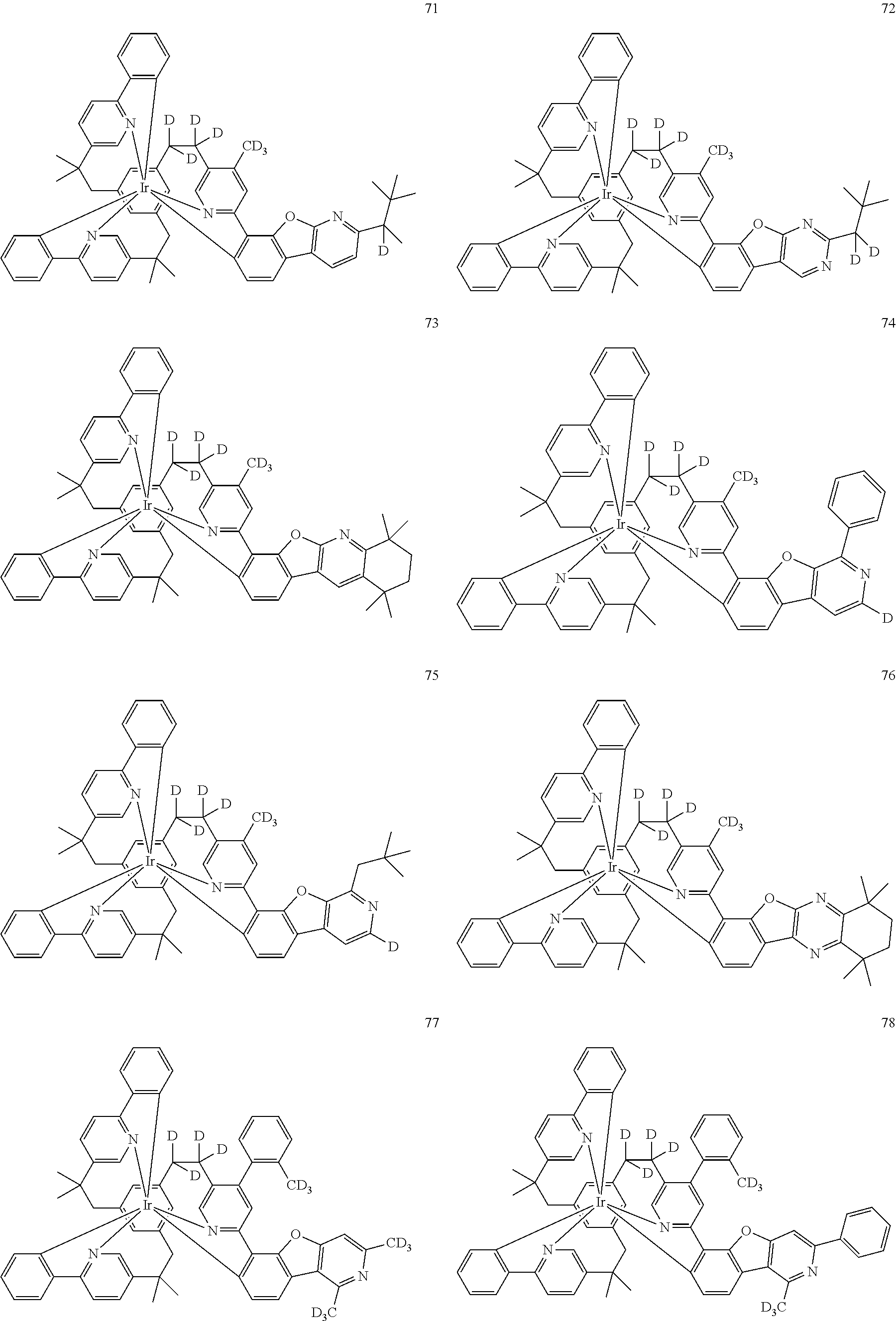

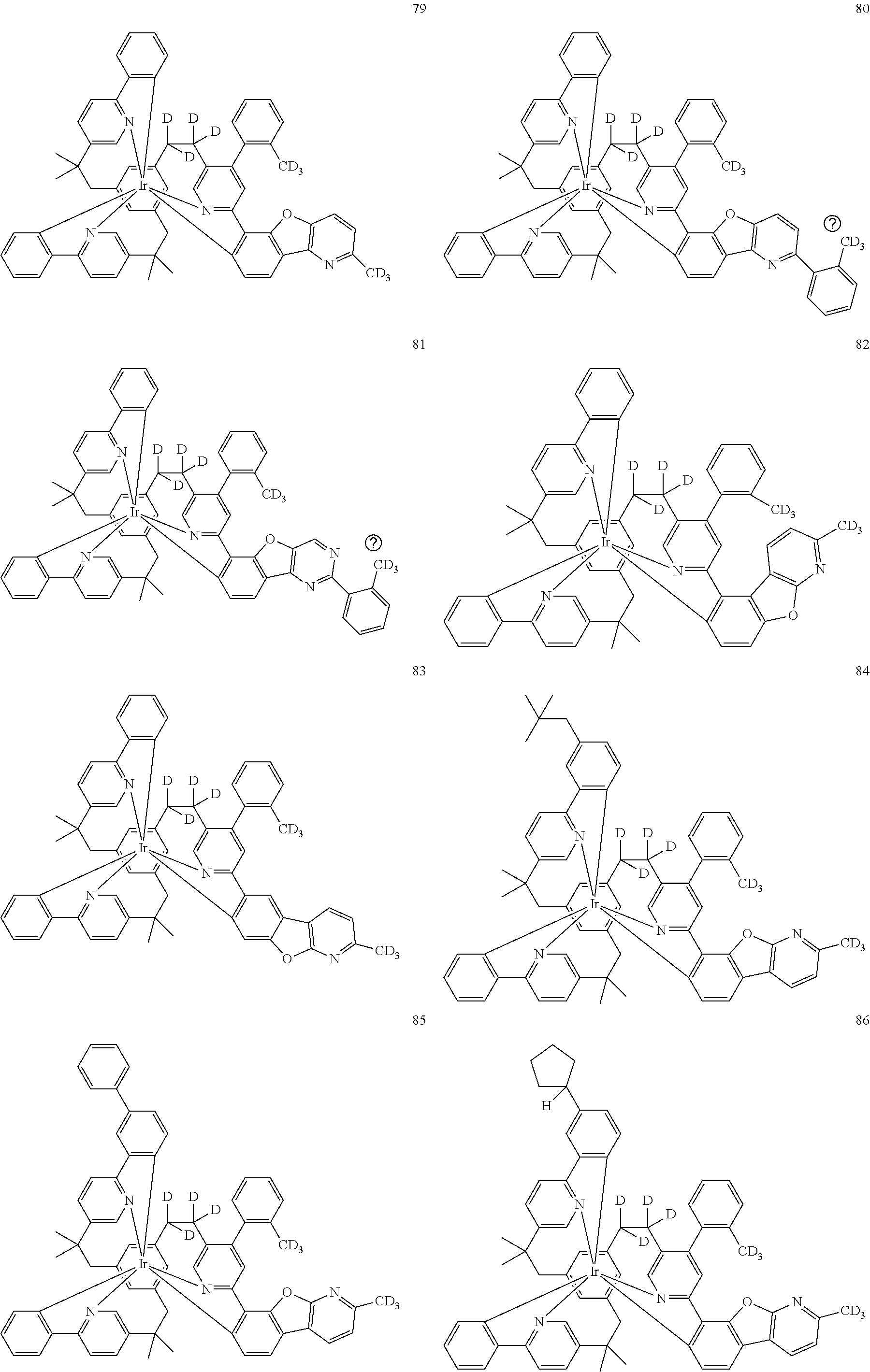

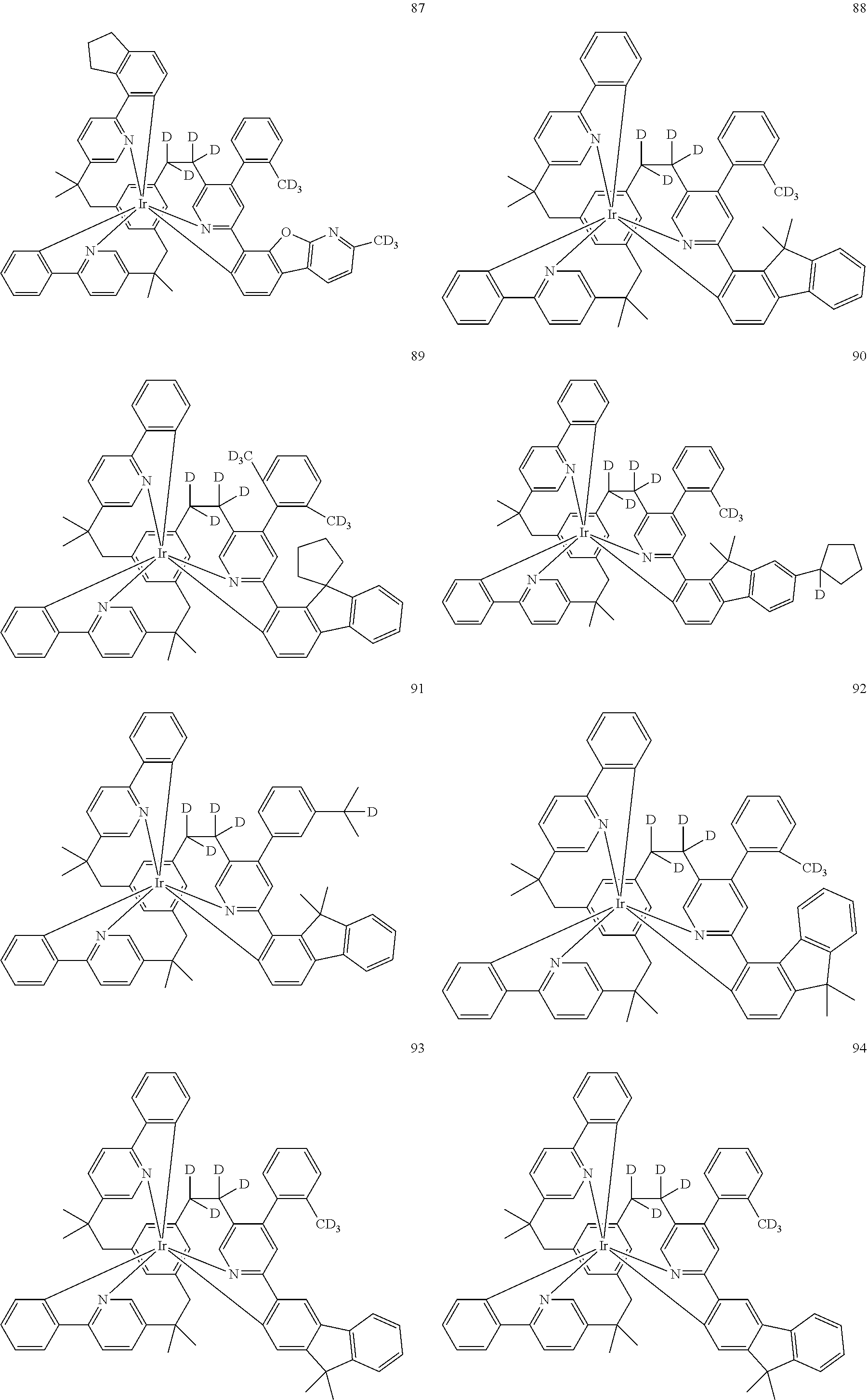

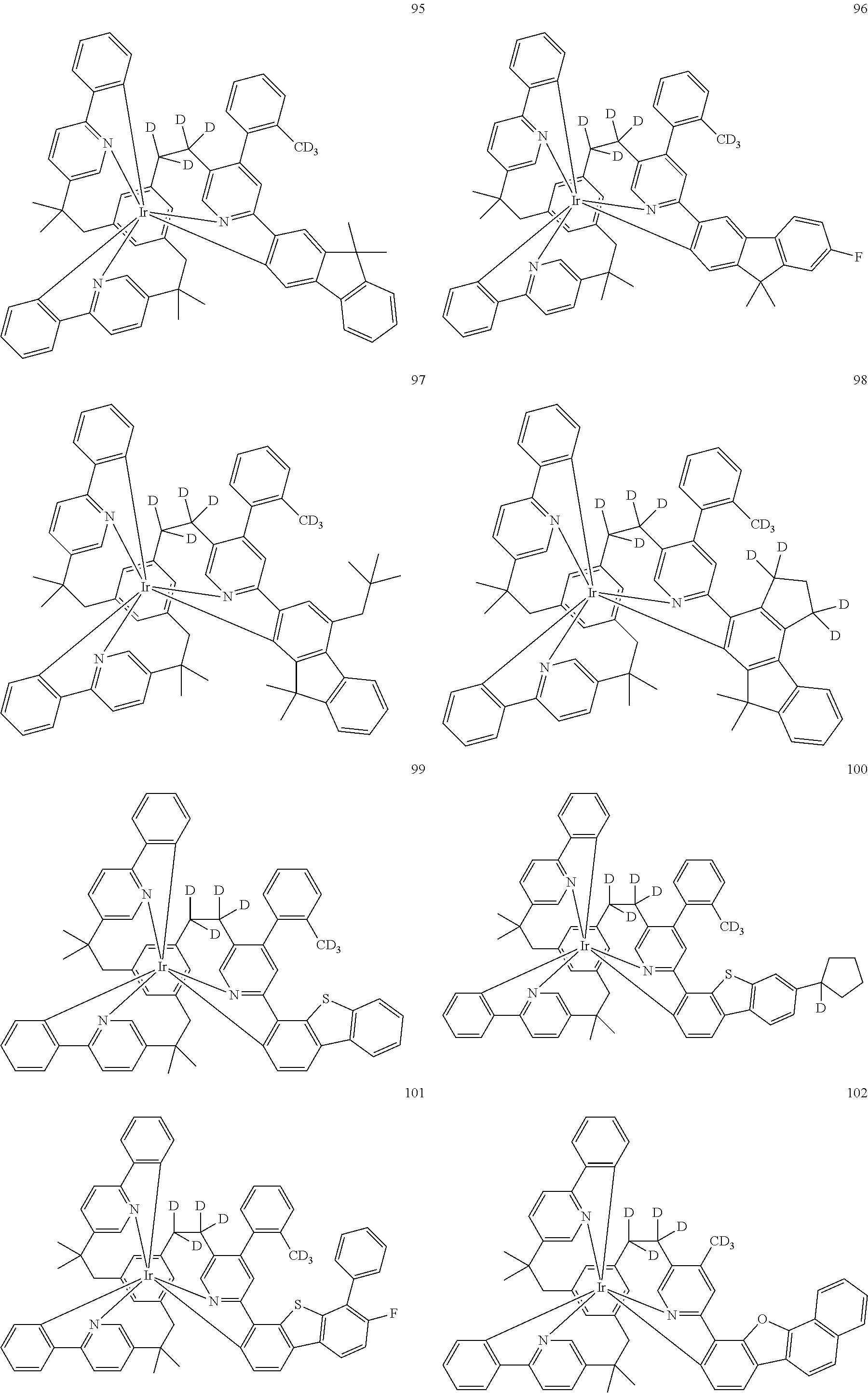

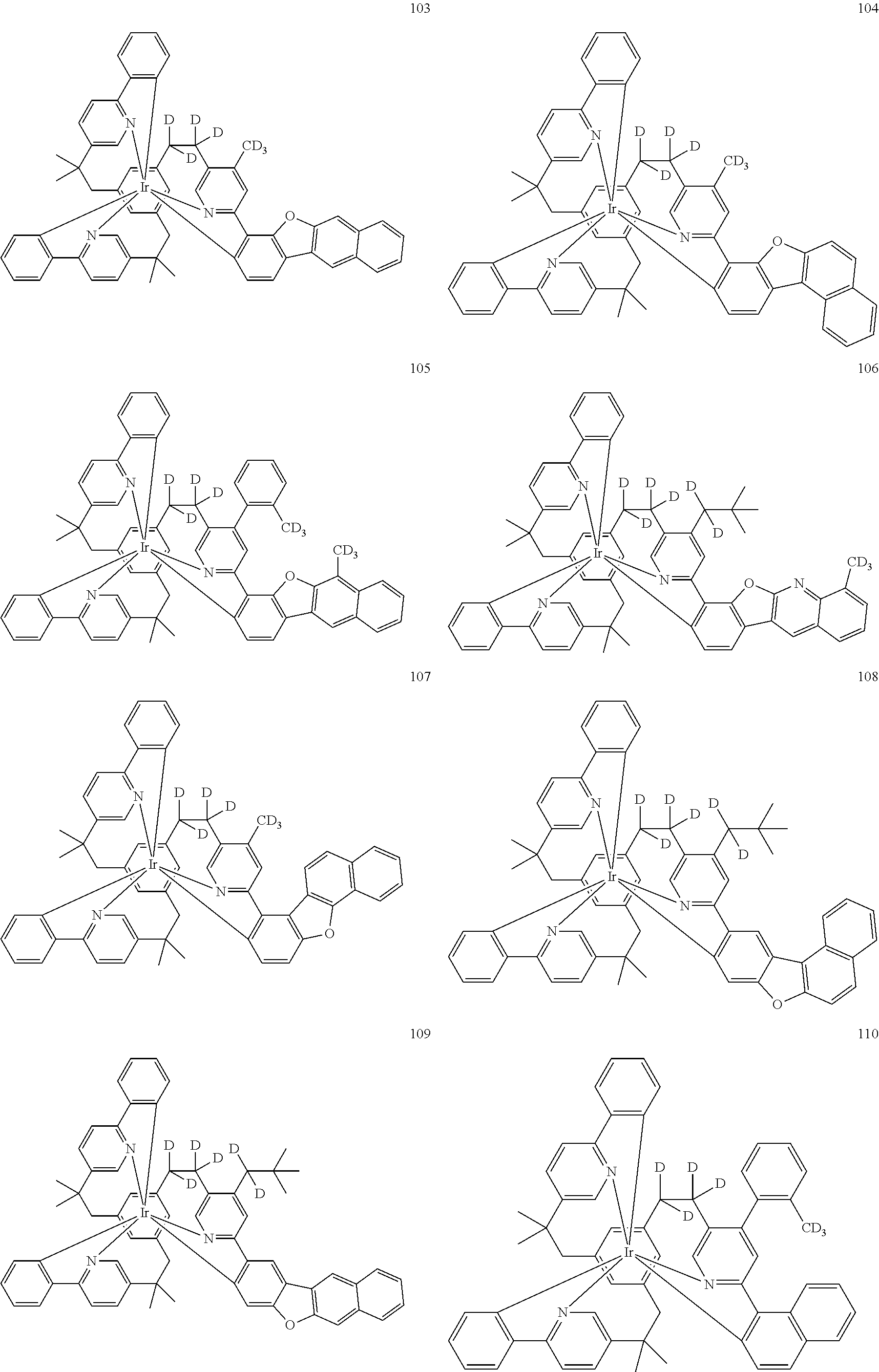

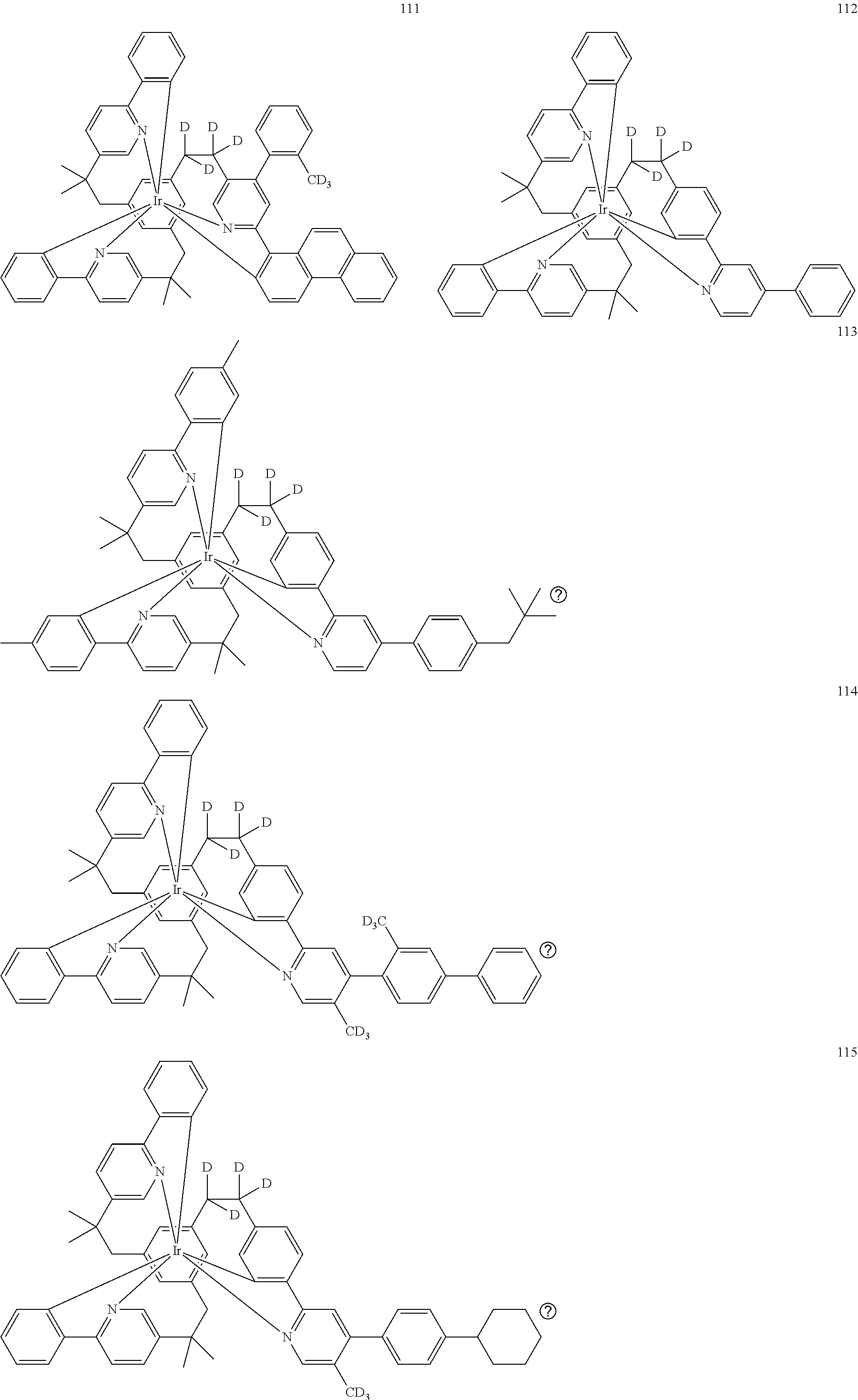

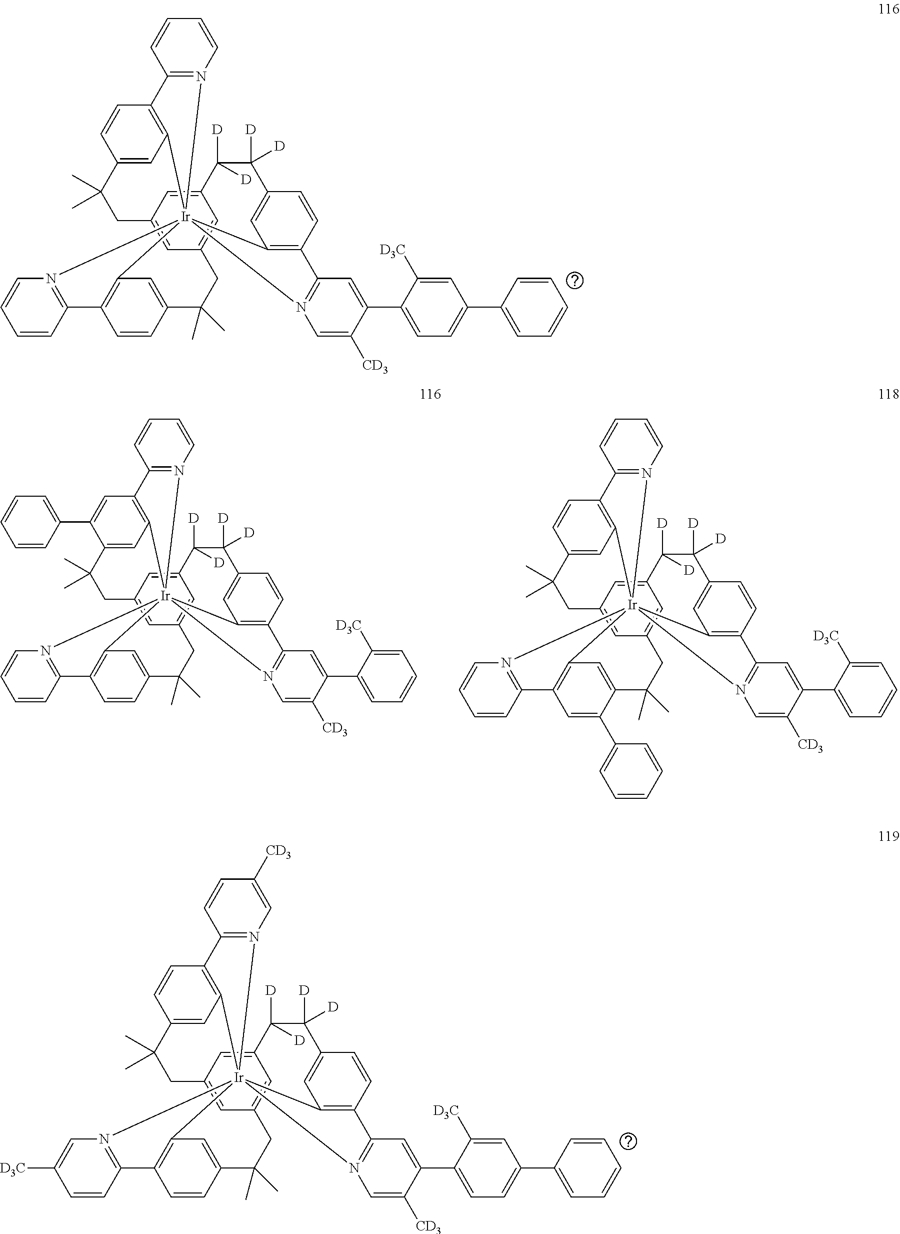

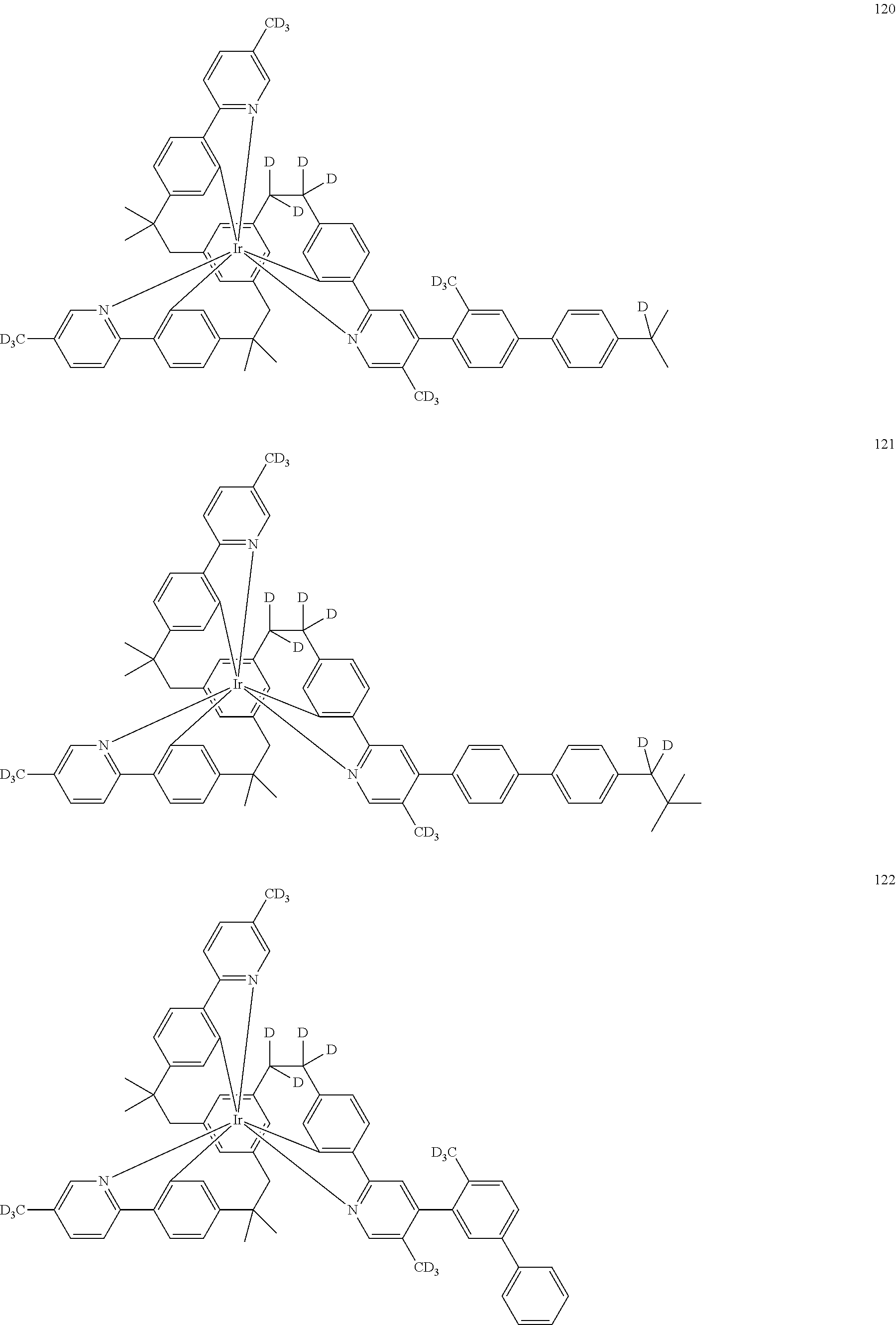

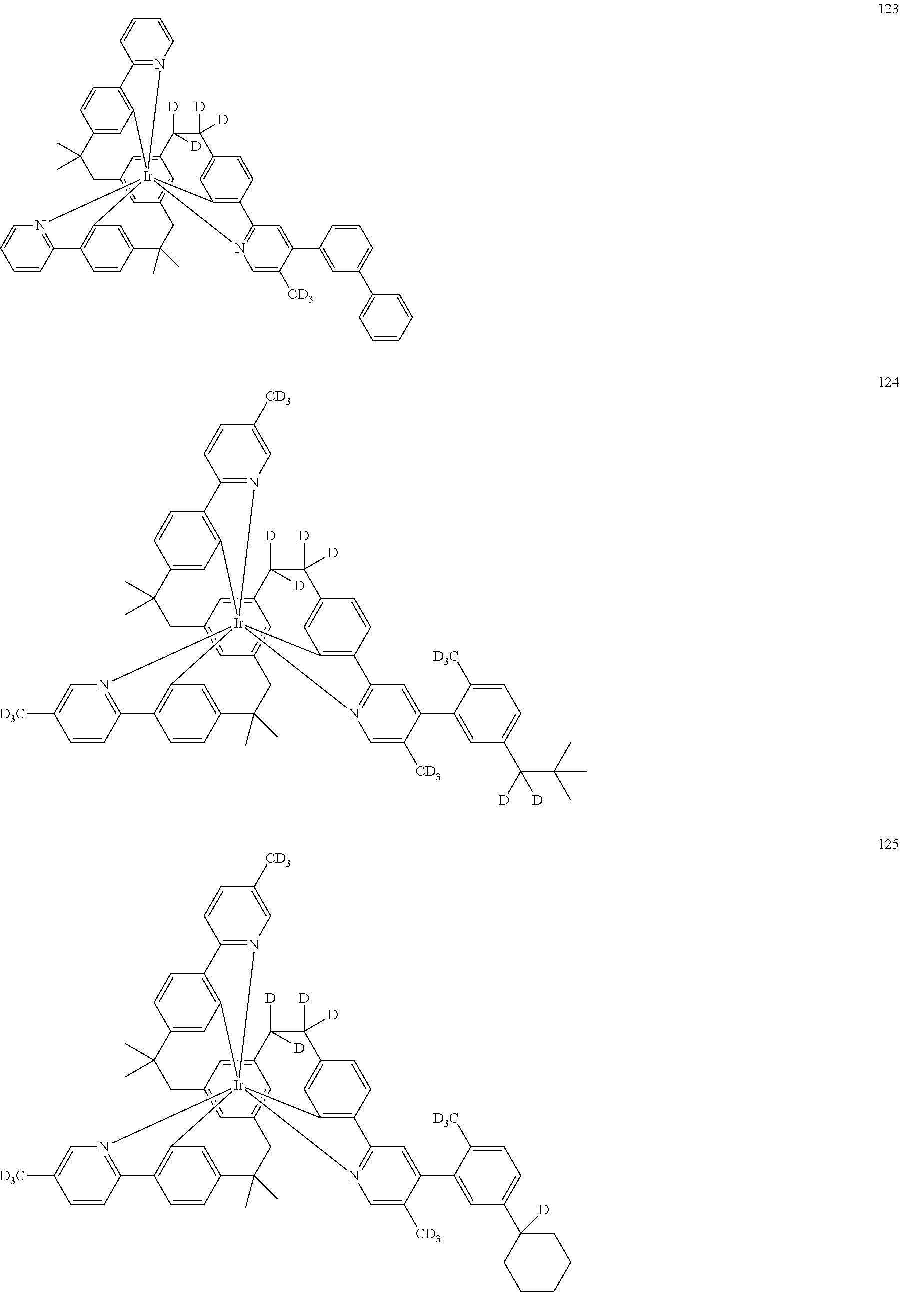

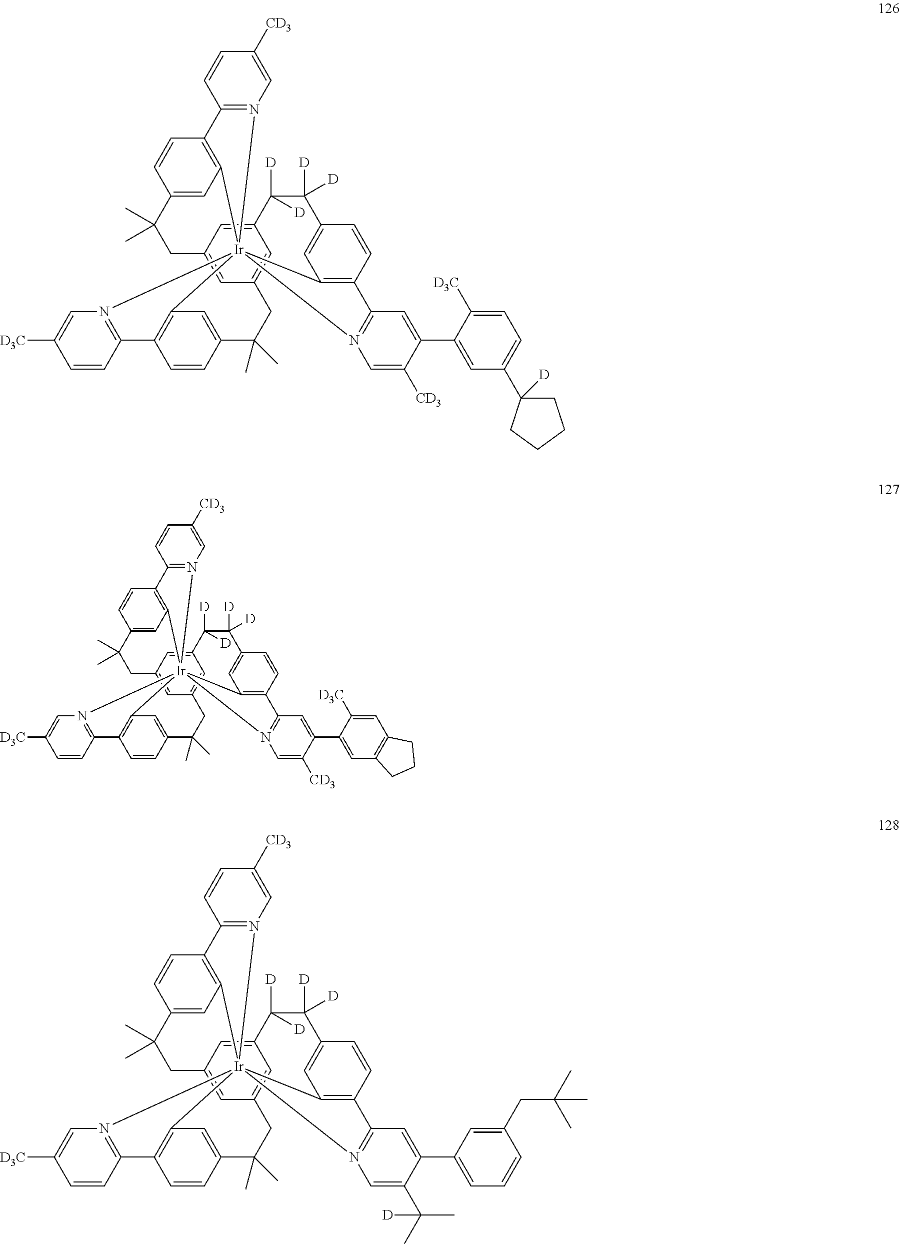

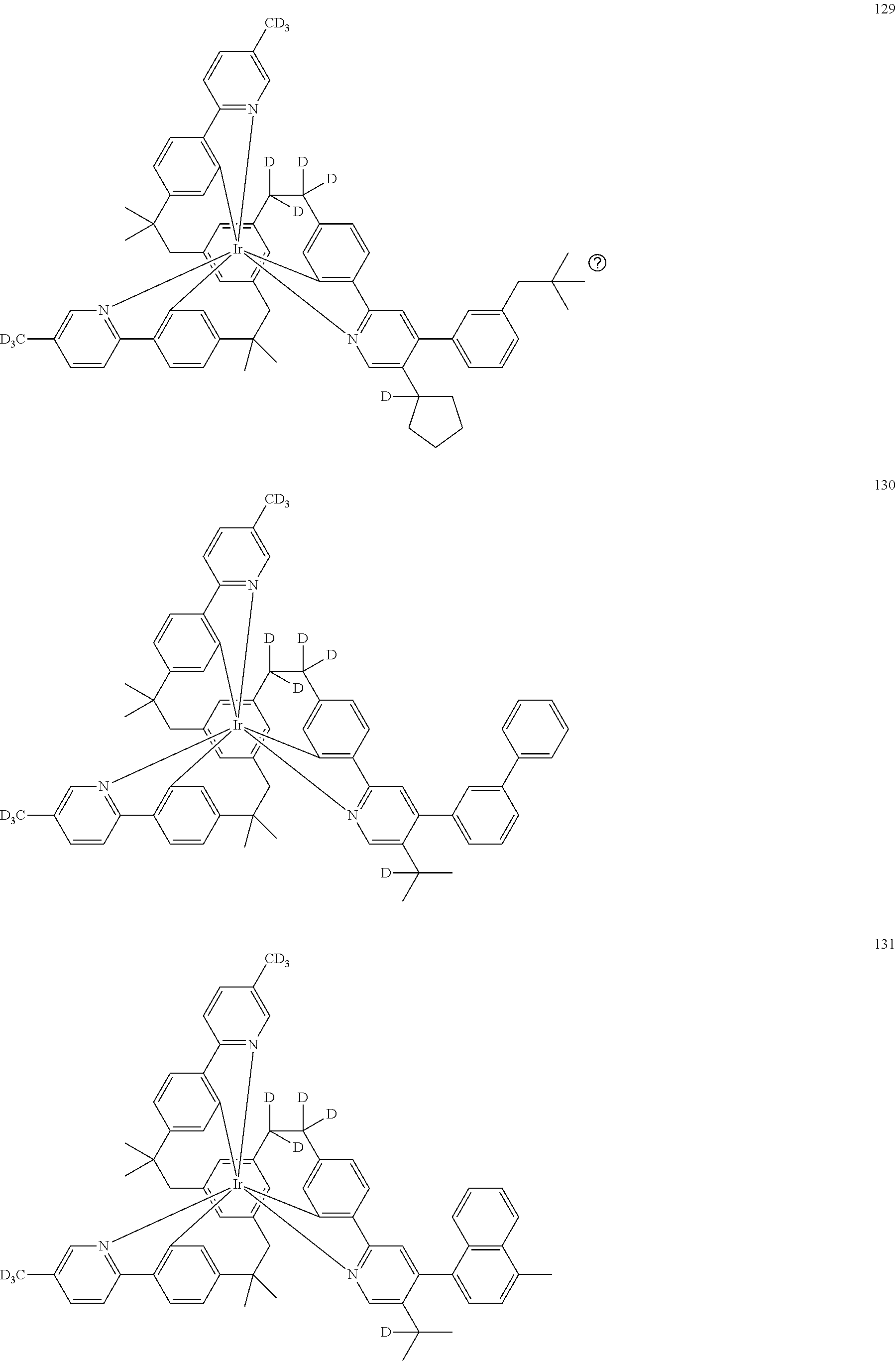

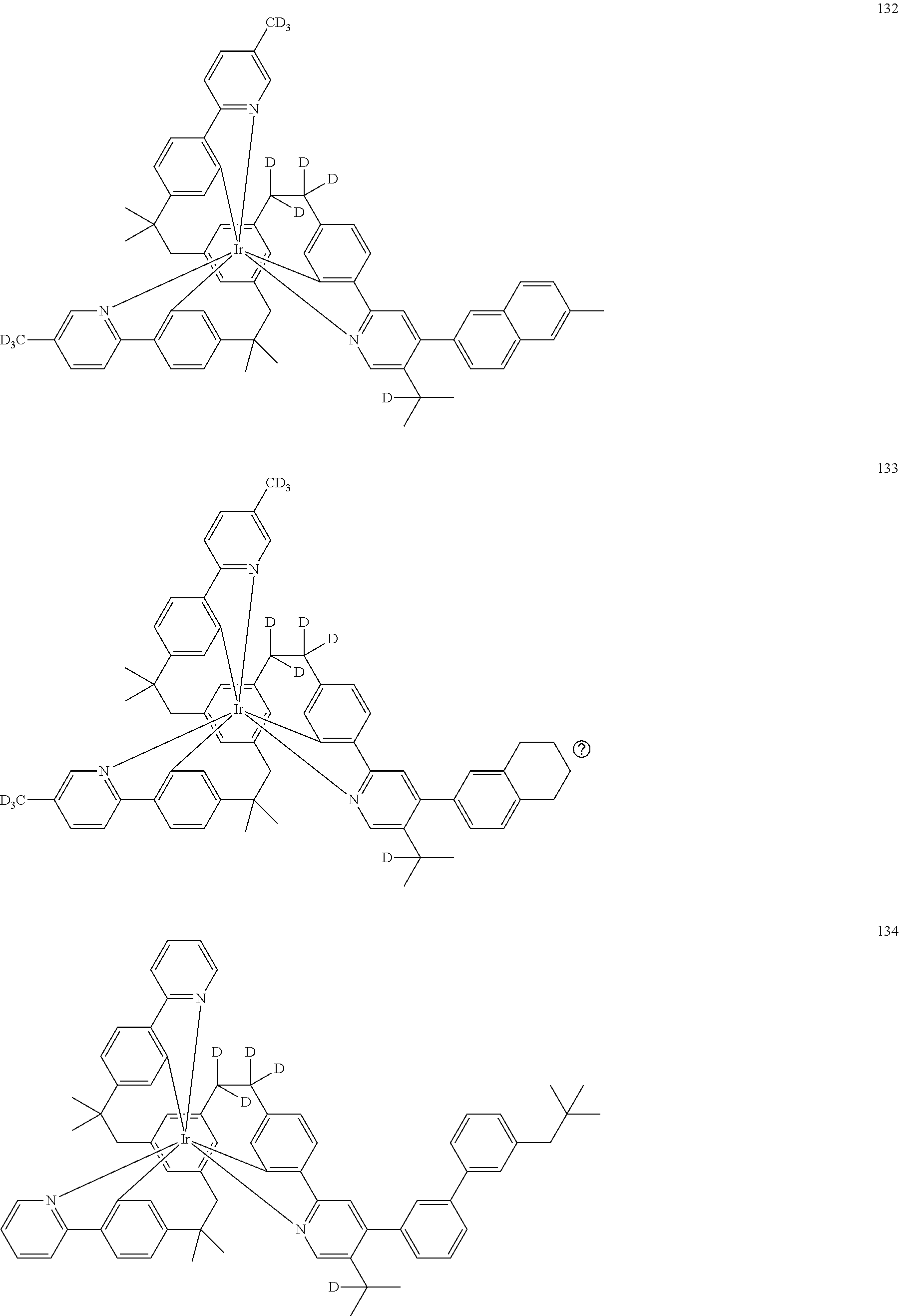

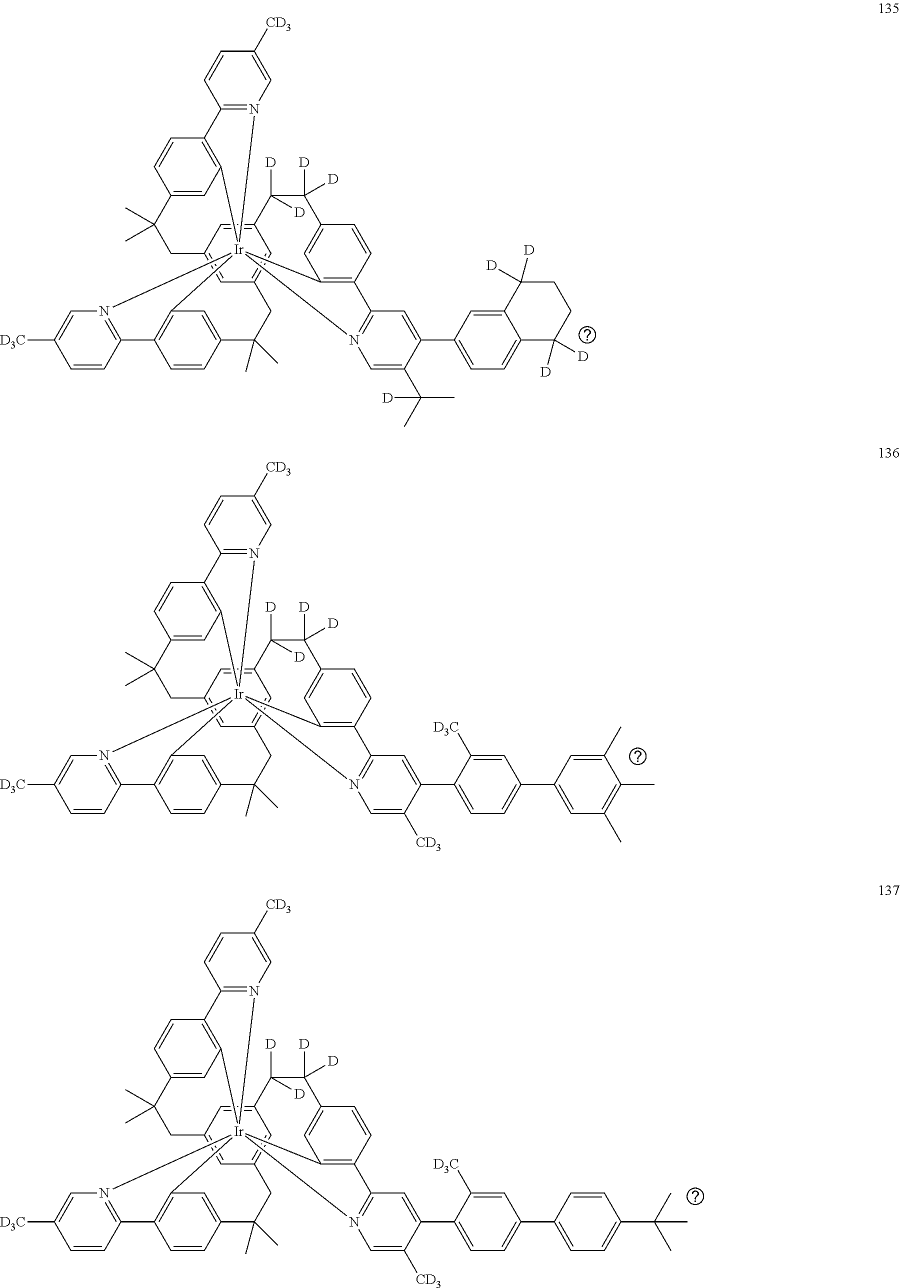

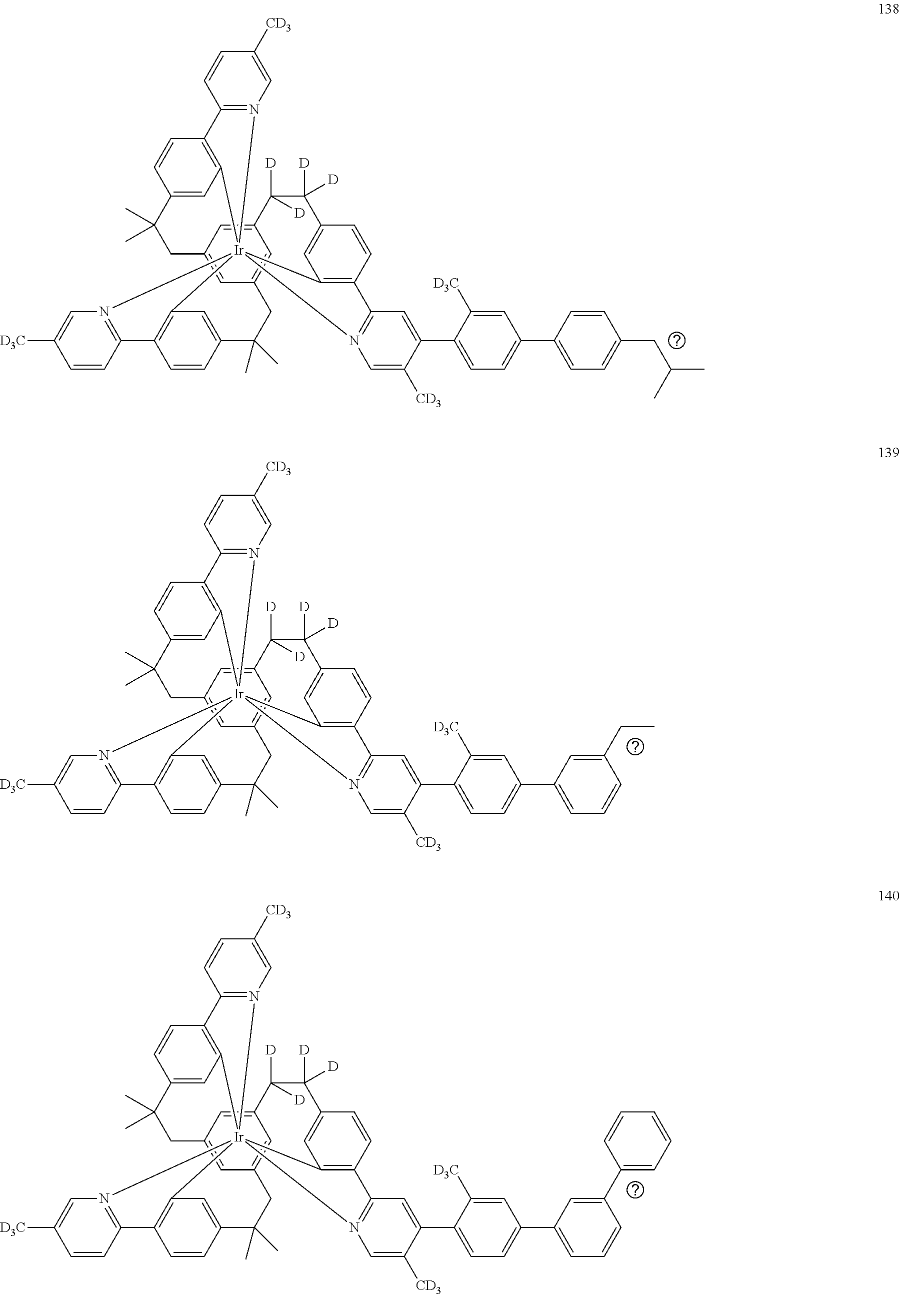

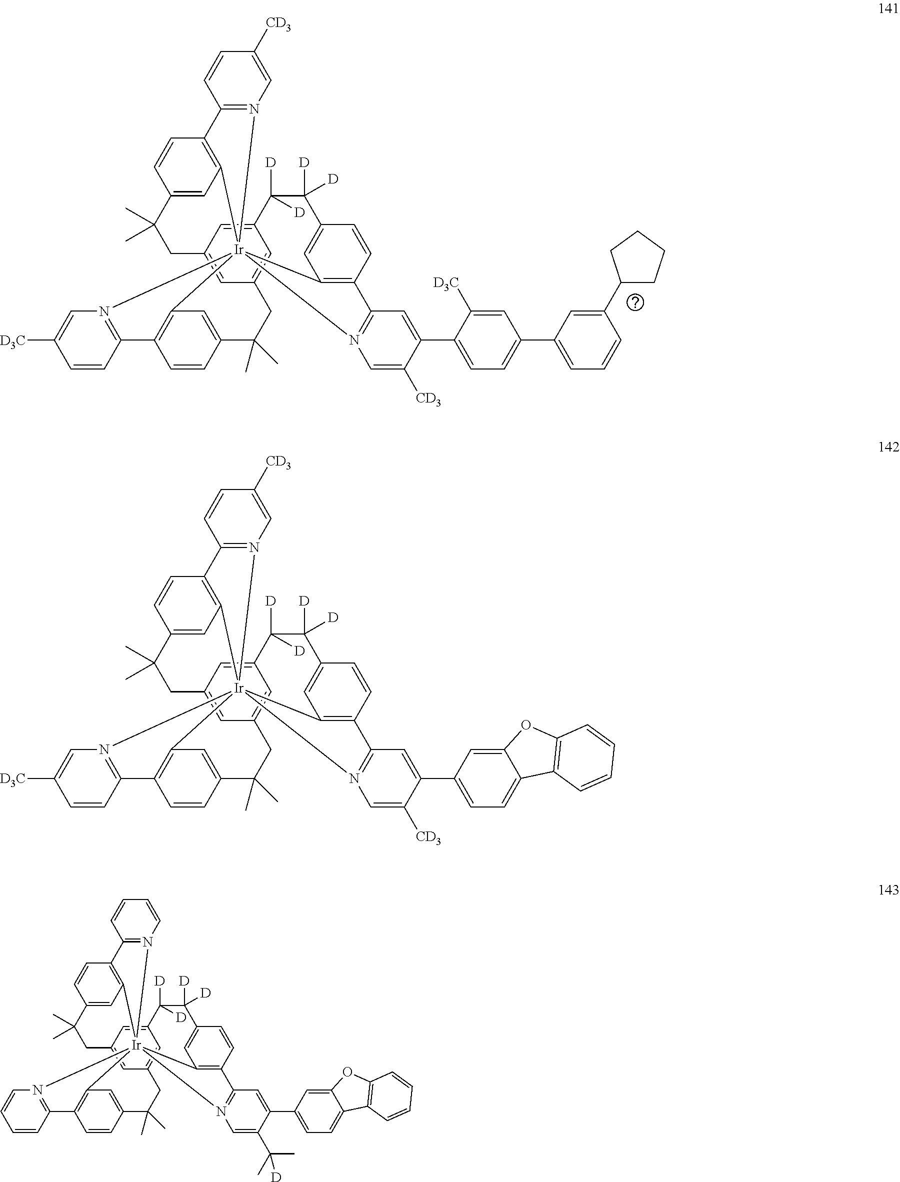

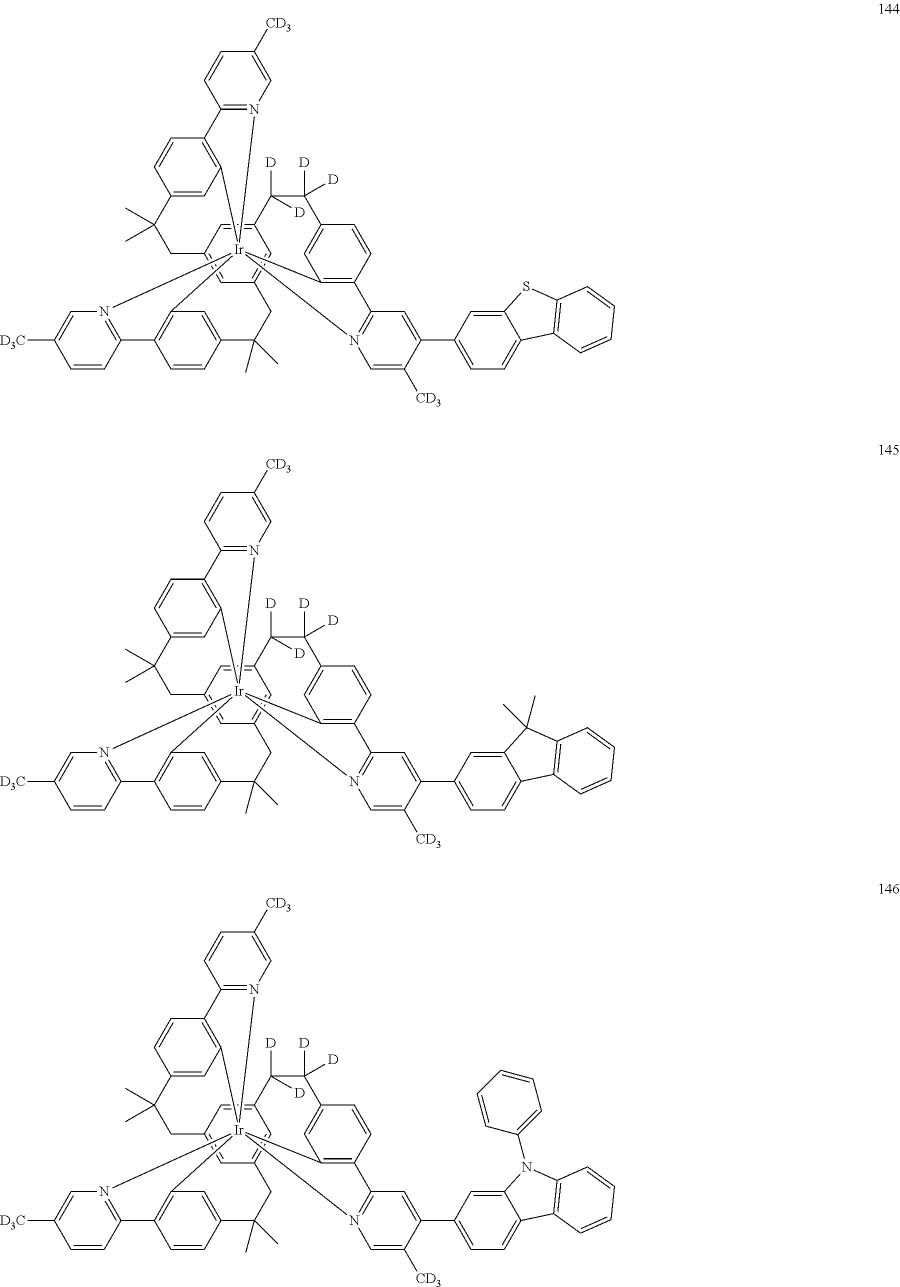

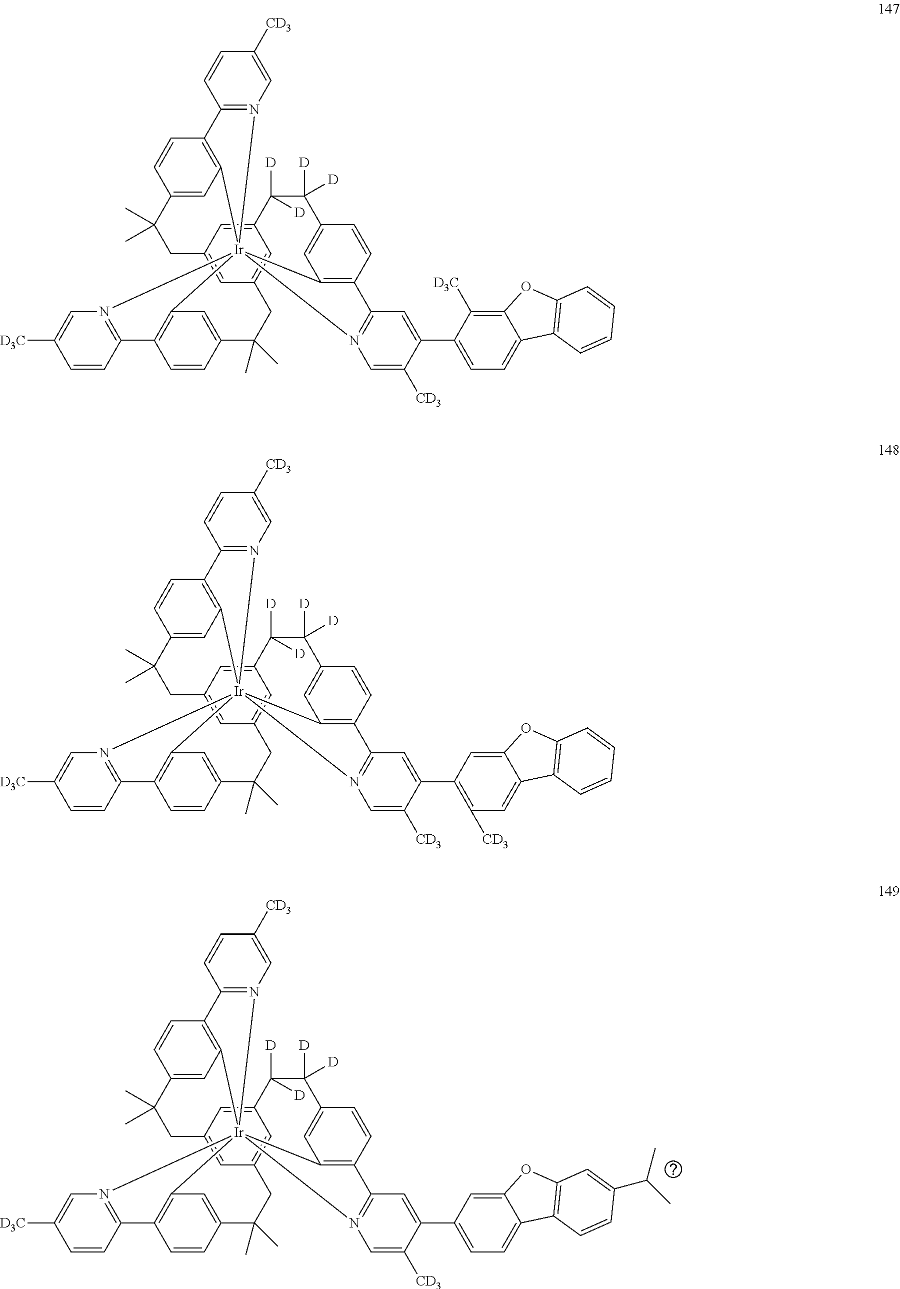

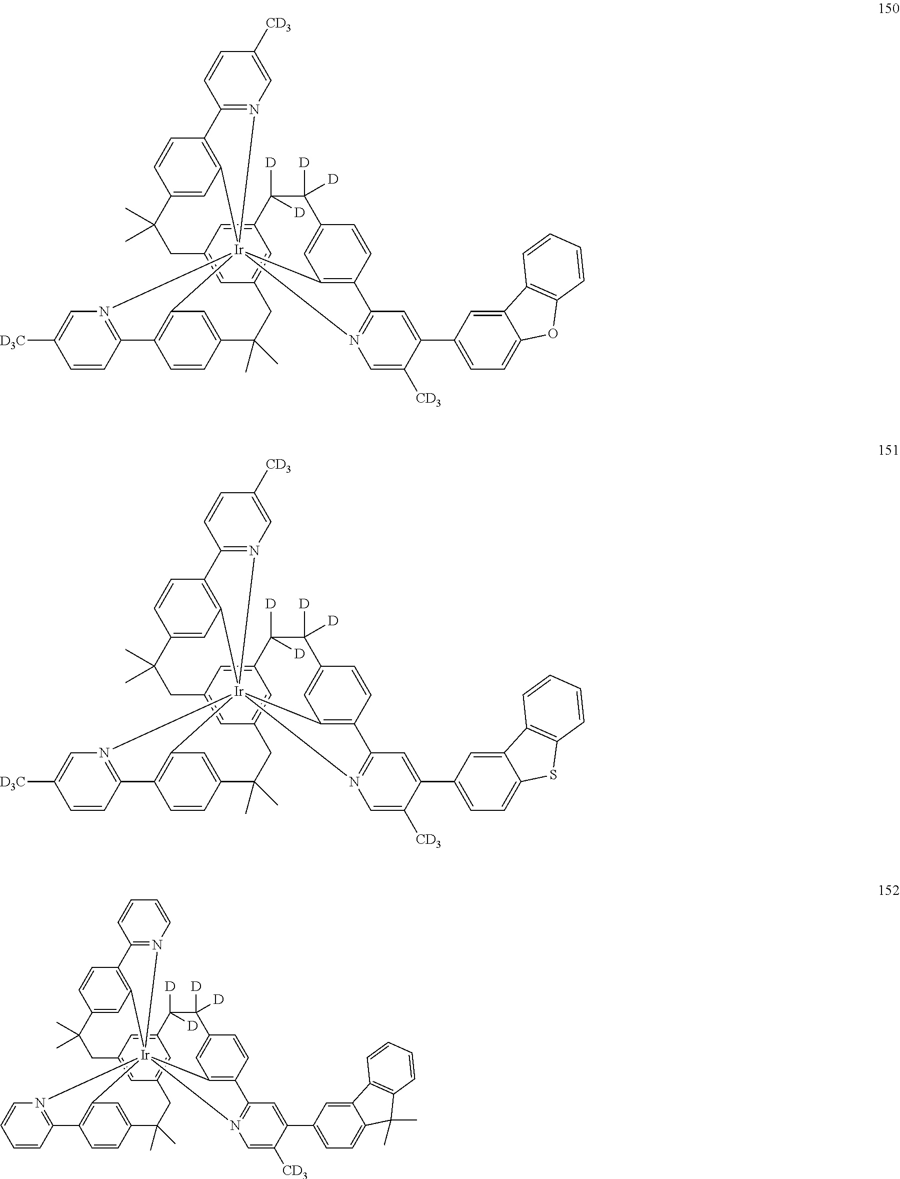

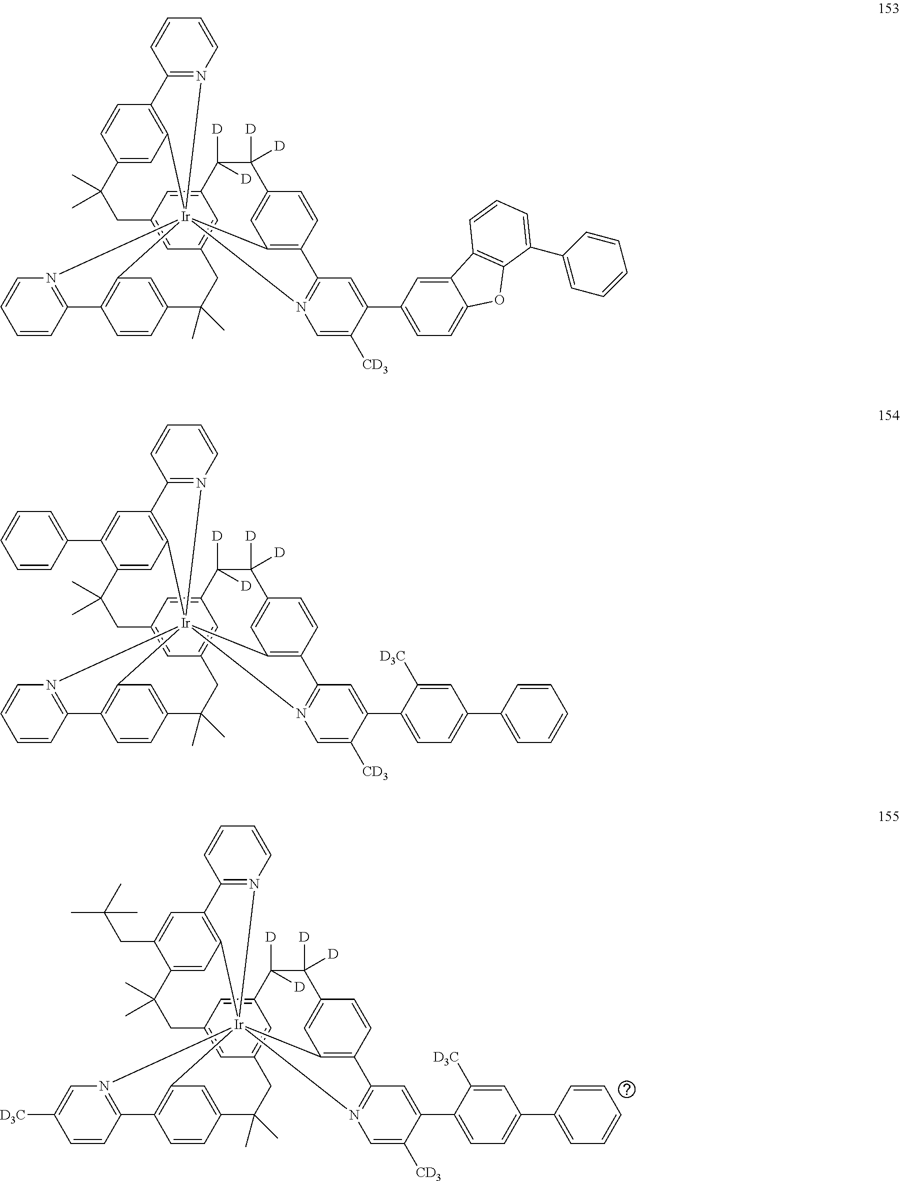

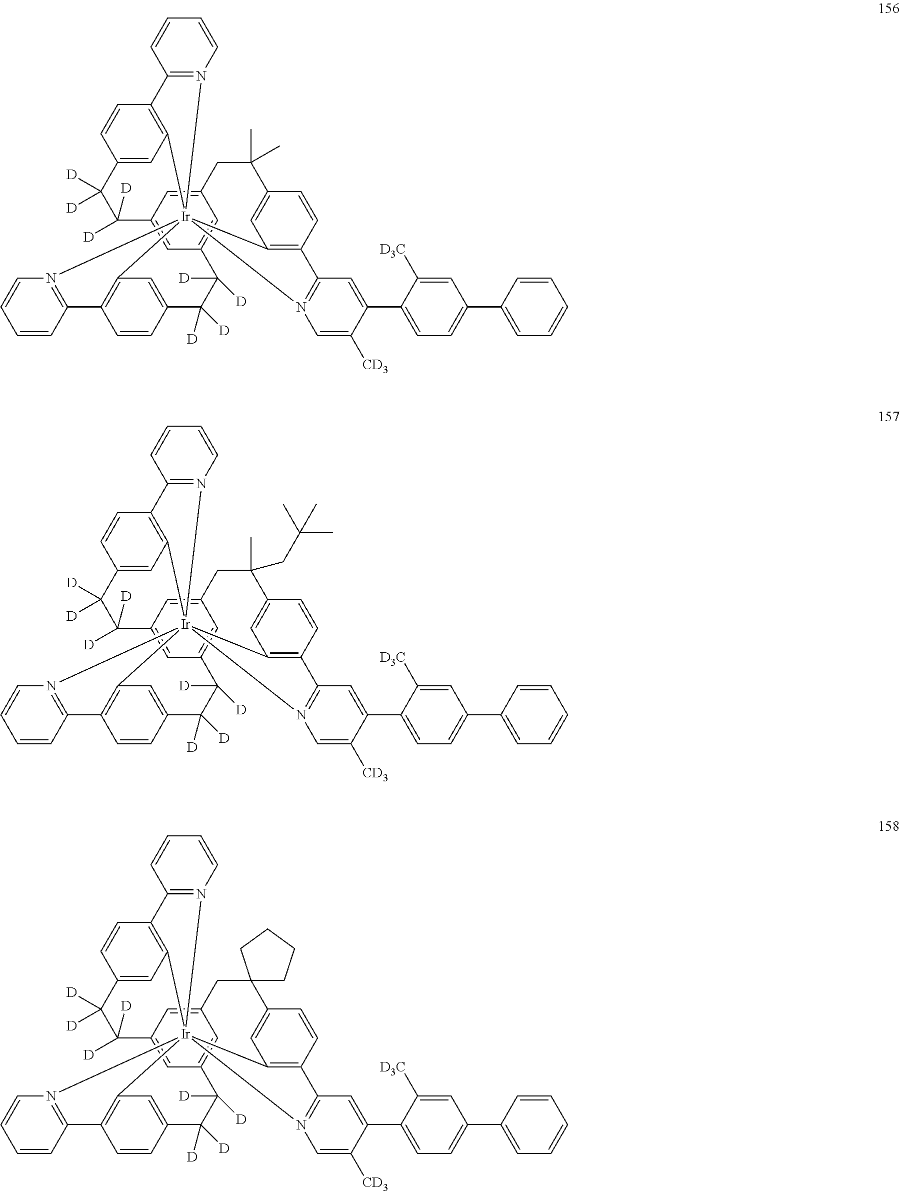

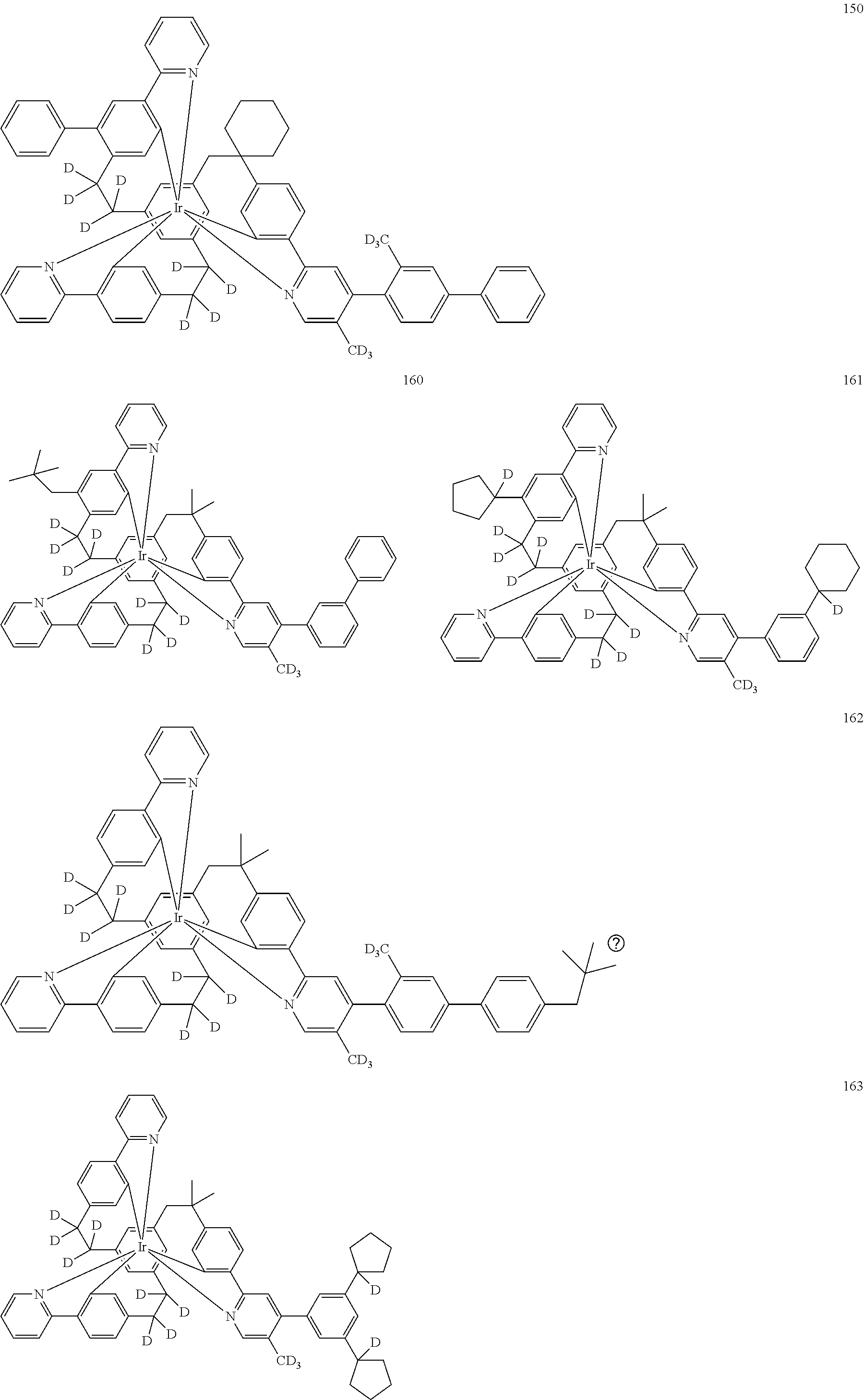

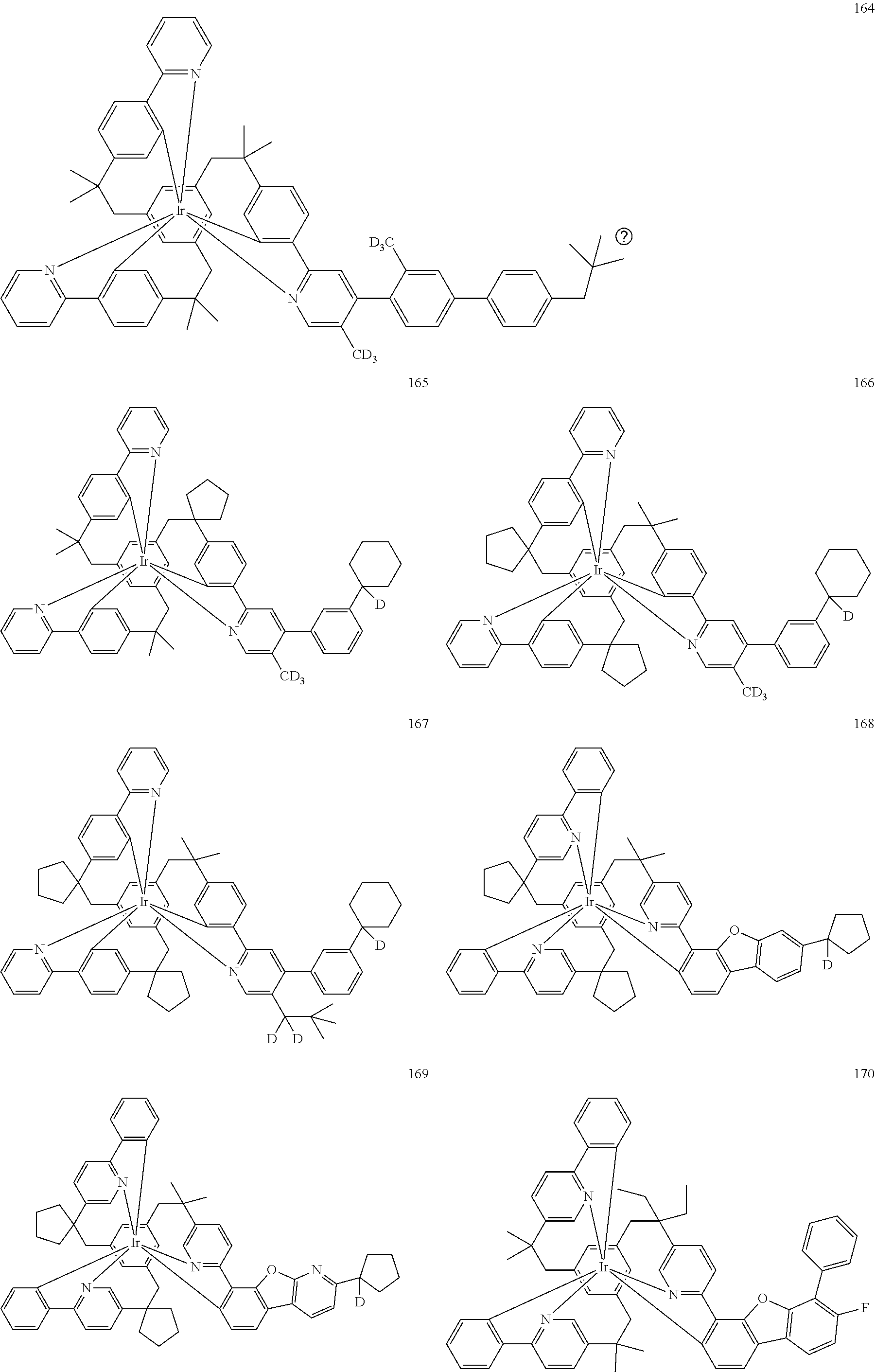

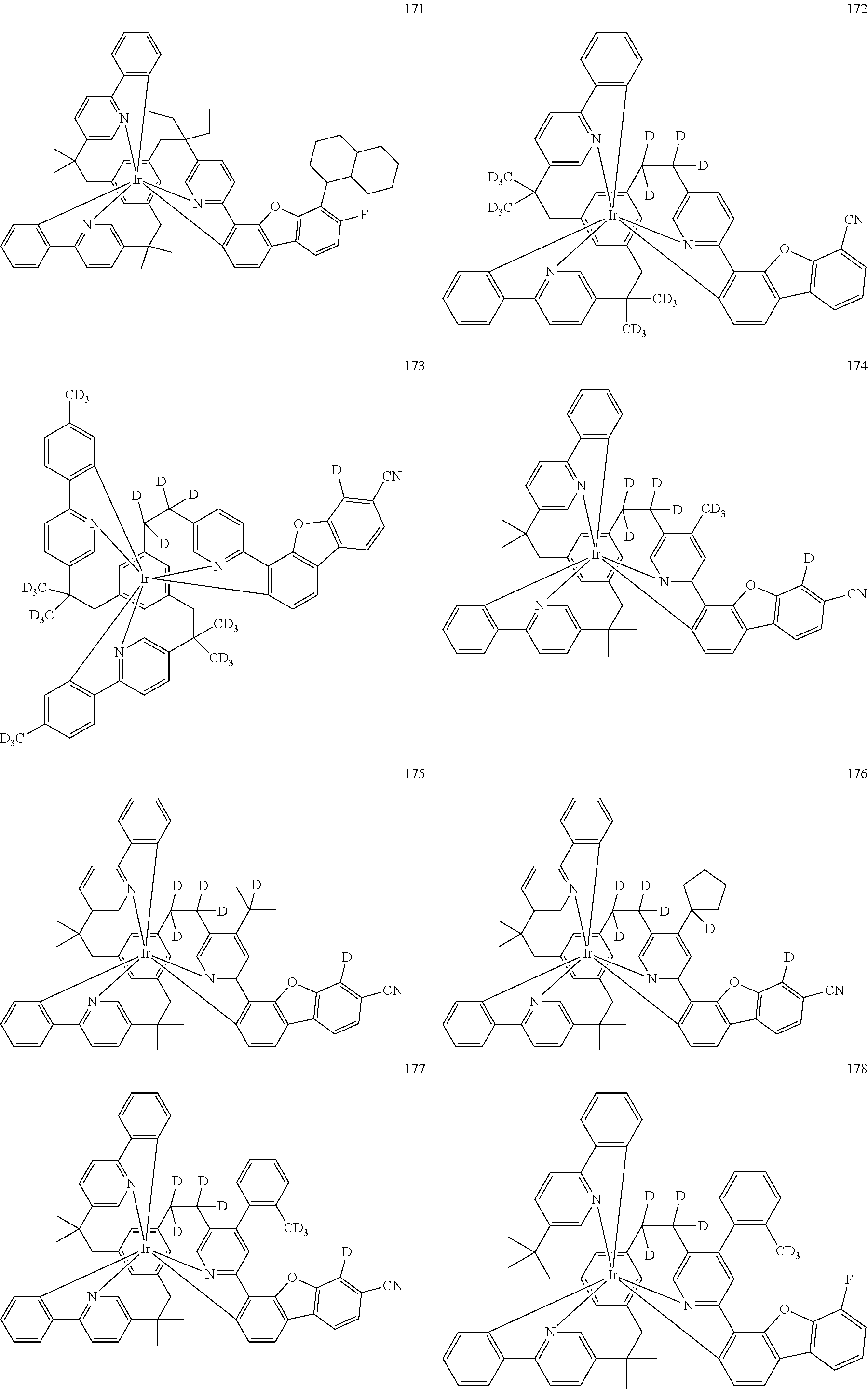

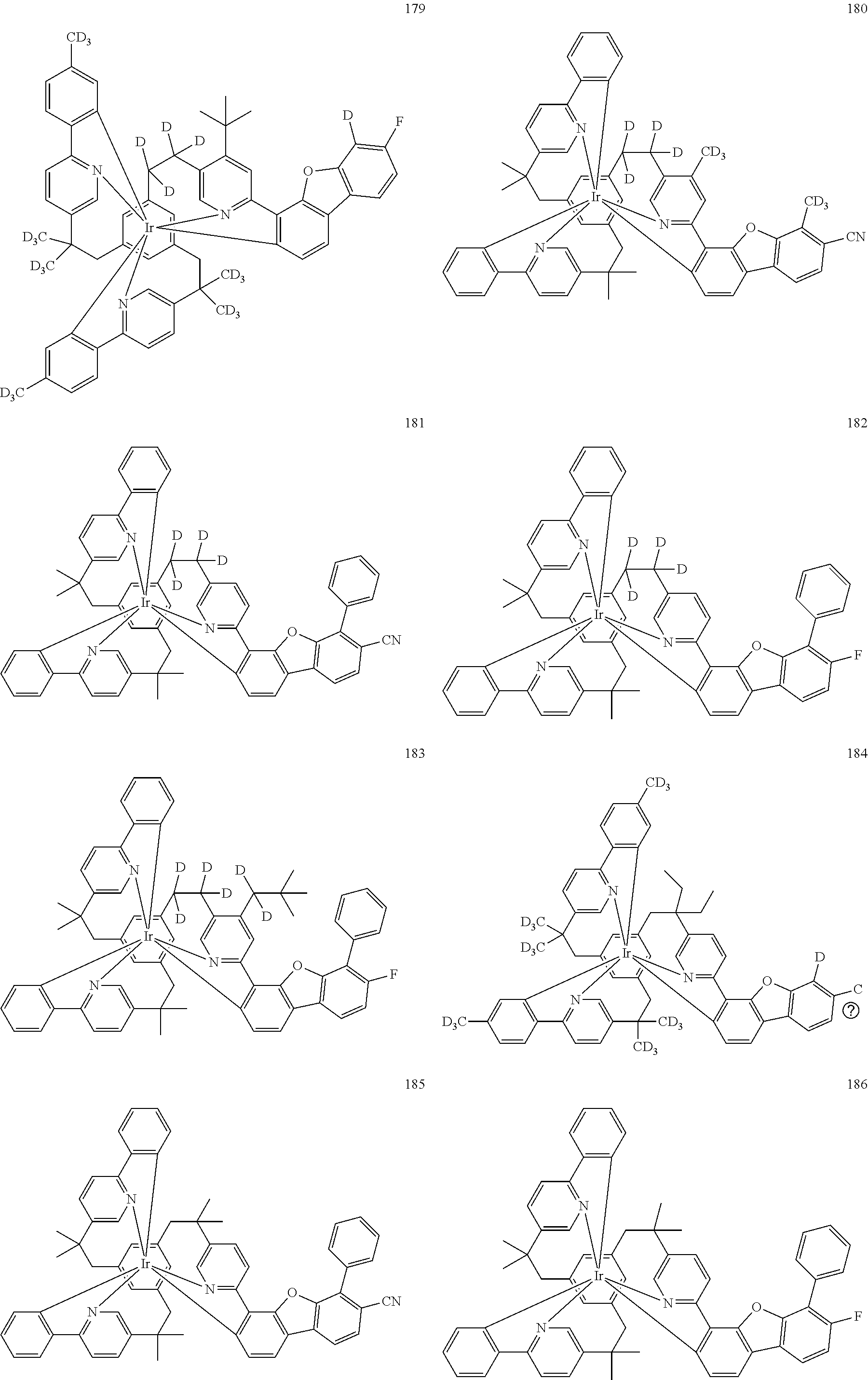

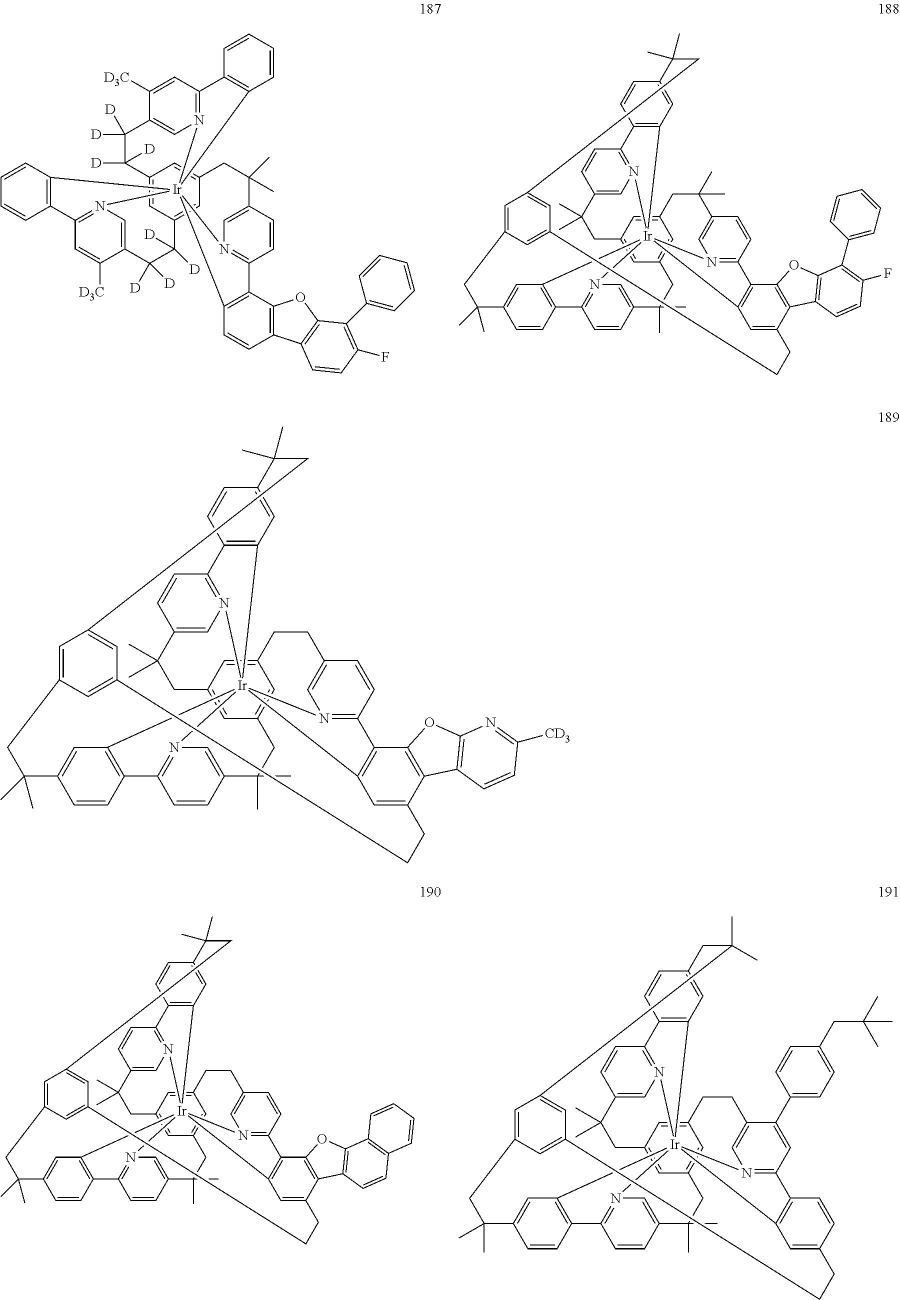

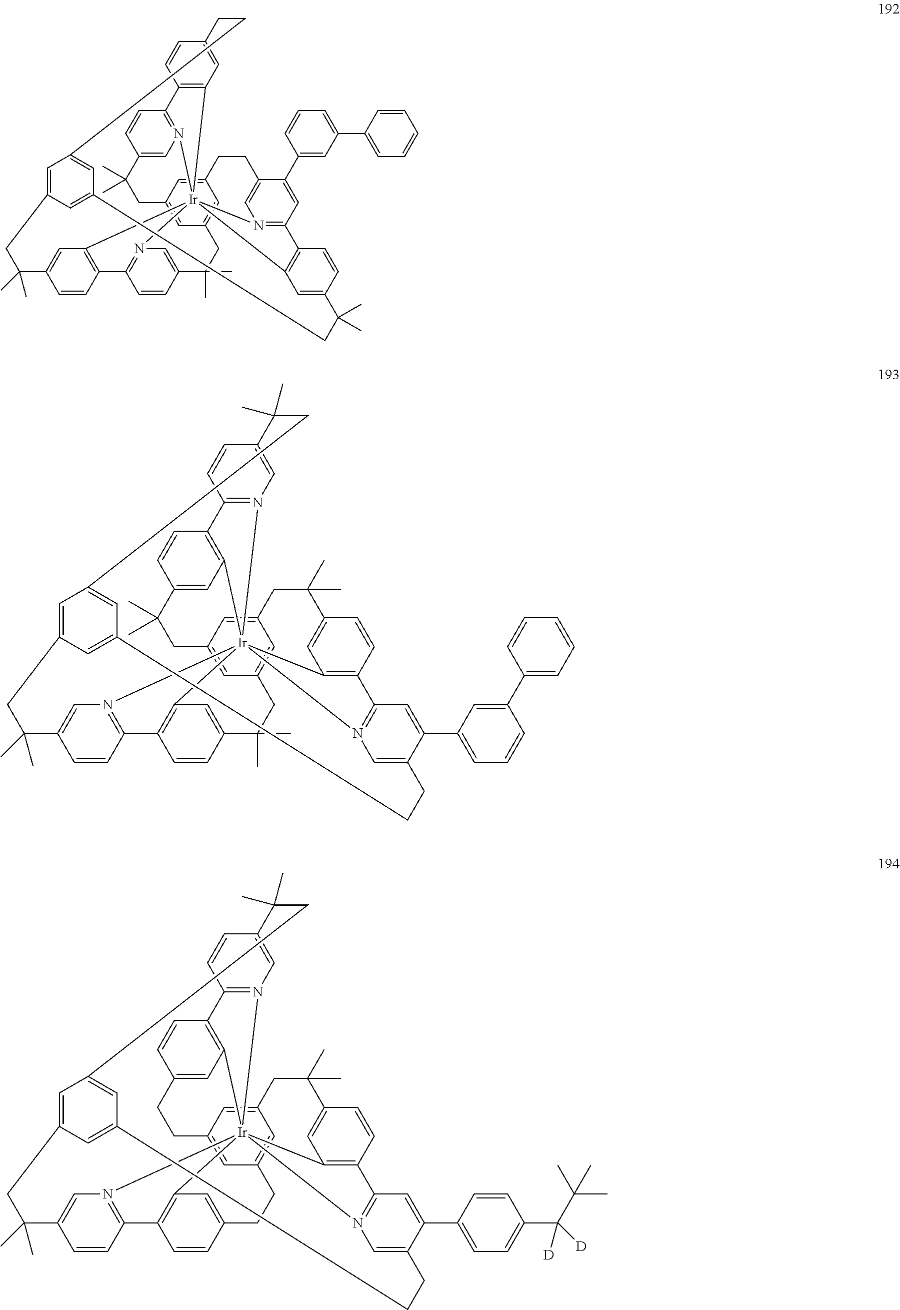

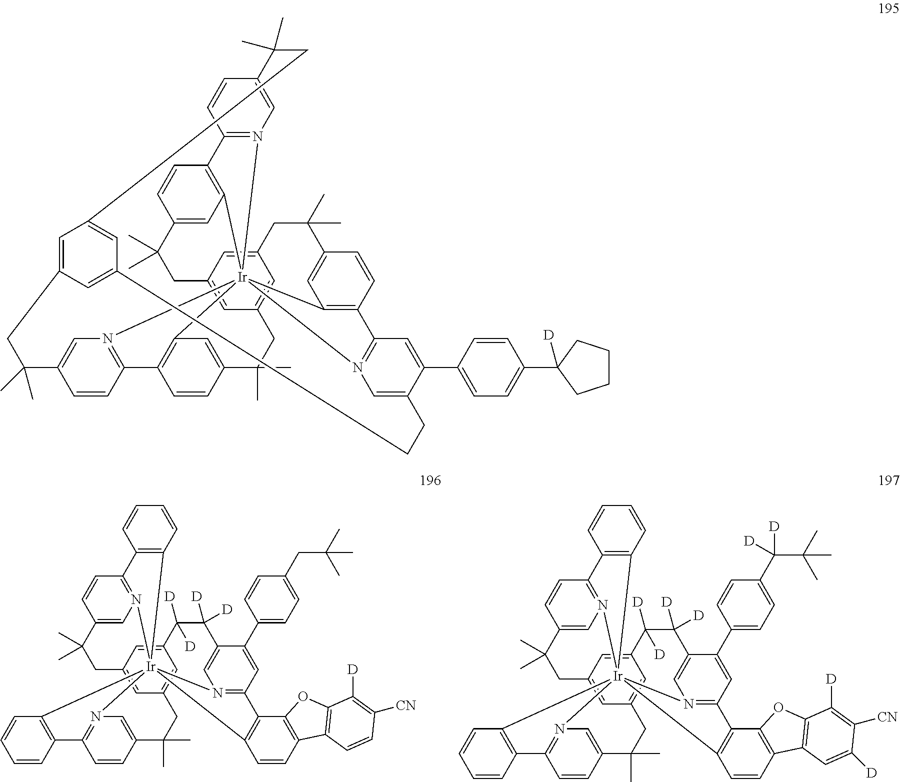

The ligands can be synthesized starting from the building blocks known from the literature. For the sake of clarity, the following description of the synthesis deliberately omits substituents on the phenyl or pyridine rings (Scheme 1 to 3).

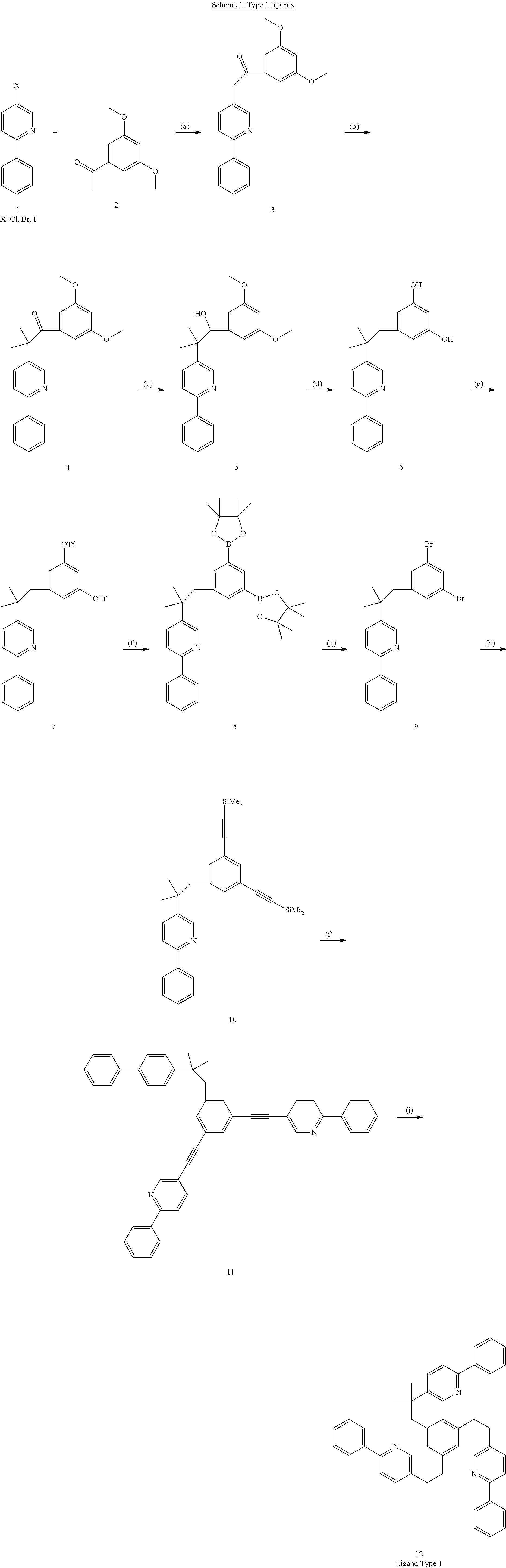

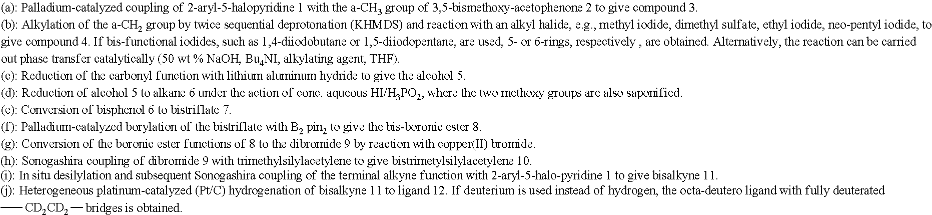

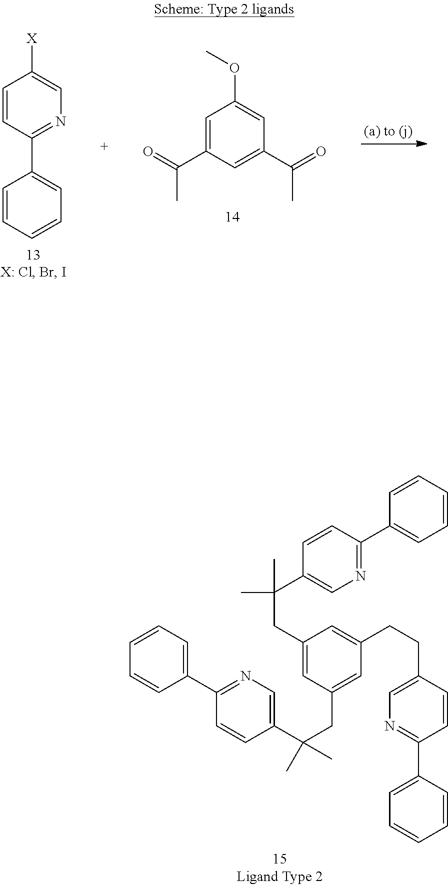

The synthesis of type 2 ligands is analogous to the synthesis of type 1 ligands (Scheme 1), with the use of diacetyl compound 14 instead of monoacetyl compound 1.

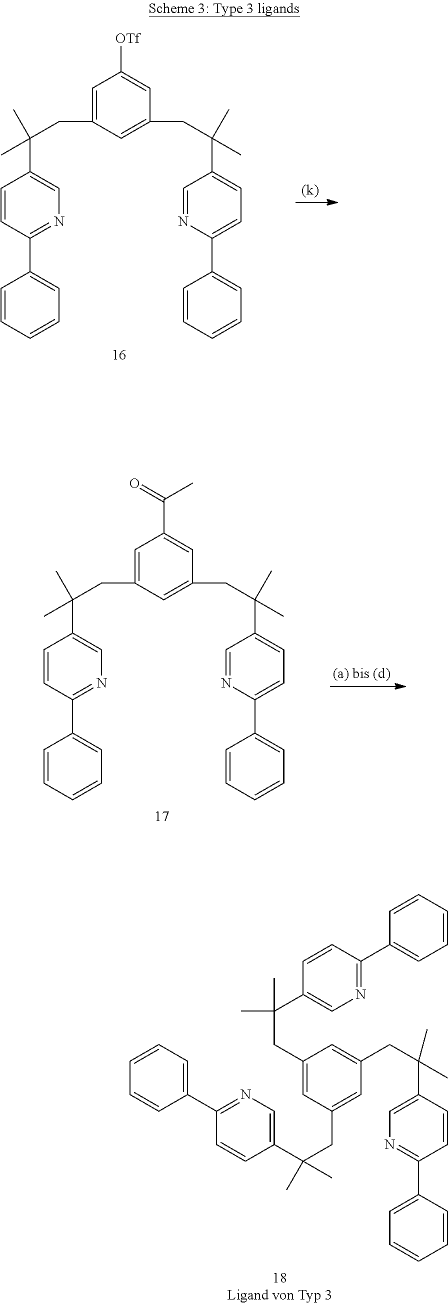 [SMILES: CC(C)(Cc1cc(CC(C)(C)c2ccc(-c3ccccc3)nc2)cc(OS(=O)(=O)C(F)(F)F)c1)c1ccc(-c2ccccc2)nc1 ; CC(=O)c1cc(CC(C)(C)c2ccc(-c3ccccc3)nc2)cc(CC(C)(C)c2ccc(-c3ccccc3)nc2)c1 ; CC(C)(Cc1cc(CC(C)(C)c2ccc(-c3ccccc3)nc2)cc(CC(C)(C)c2ccc(-c3ccccc3)nc2)c1)c1ccc(-c2ccccc2)nc1]

(k): Starting from compound 16, shown according to ligands of type 2 (Scheme 2), the triflate function is reacted in a Heck coupling with n-butyl vinyl ether, which after acid hydrolysis releases the acetyl function in compound 17. Further synthesis can be carried out analogously to steps (a) to (d) in the same way as for ligands of type 1 (Scheme 1).

If 1-halo-4-(2-pyridyl) aromatics are used in the above ligand syntheses, the type 1, type 2, and type 3 ligands are obtained in which the attachment of the bidentate partial ligands is via the aromatic and not via the pyridine. This is exemplified in Scheme 4 for type 1 ligands.

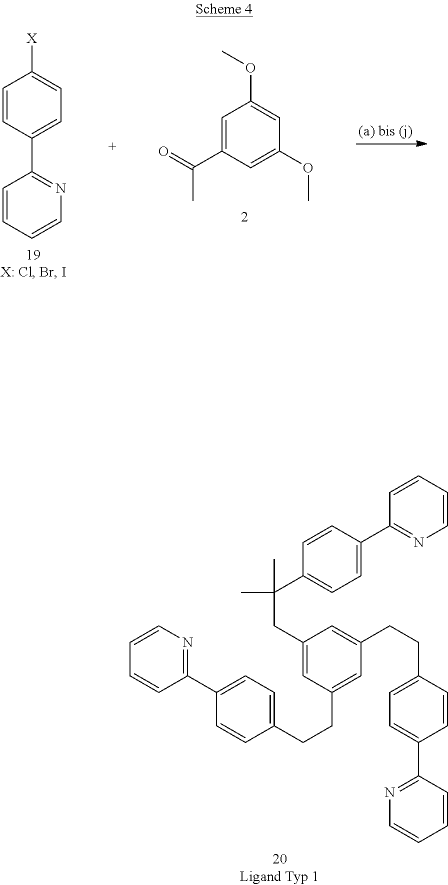

The synthesis of the iridium complexes of the invention can be carried out by reacting the type 1, type 2 and type 3 ligands with iridium compounds.

Therefore, a further object of the present invention is a process for preparing the compounds of the invention by reacting the corresponding free ligands with iridium alkoxides of formula (Ir-1), with iridium ketoketonates of formula (Ir-2), with iridium halides of formula (Ir-3) or with iridium carboxylates of formula (Ir-4),

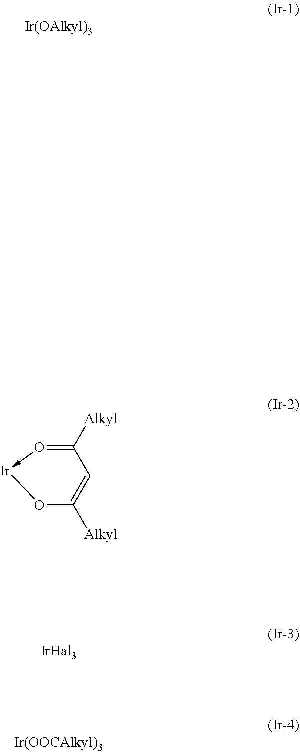

wherein R has the meanings given above, Hal=F, Cl, Br or I and the iridium reagents may also be present as the corresponding hydrates. In this context, alkyl preferably stands for an alkyl group having 1 to 4 carbon atoms.

Iridium compounds bearing alkoxide and/or halide and/or hydroxy as well as ketoketonate residues can also be used. These compounds may also be charged. Corresponding iridium compounds that are particularly suitable as reactants are disclosed in WO 2004/085449. Particularly suitable are [IrCl₂(acac)₂]⁻, for example Na[IrCl₂(acac)₂], metal complexes with acetylacetonate derivatives as ligands, for example Ir(acac)₃ or tris(2,2,6,6-tetramethylheptane-3,5-dionato)iridium, and IrCl₃·xH₂O, where x usually stands for a number between 2 and 4.

The synthesis of the complexes is preferably carried out as described in WO 2002/060910 and in WO 2004/085449. Synthesis in an organic acid or a mixture of an organic acid and an organic solvent, as described in WO 2021/013775, is also particularly suitable, with particularly suitable reaction media being, for example, acetic acid or a mixture of salicylic acid and an organic solvent, for example mesitylene. In this context, the synthesis can also be activated thermally, photochemically and/or by microwaves radiation. Furthermore, the synthesis can also be carried out in the autoclave at elevated pressure and/or temperature.

The reactions can be carried out without the addition of solvents or melting aids in a melt of the corresponding ligands to be o metallated. If necessary, solvents or melting aids can also be added. Suitable solvents are protic or aprotic solvents, such as aliphatic and/or aromatic alcohols (methanol, ethanol, iso-propanol, t-butanol, etc.), oligo- and polyalcohols (ethylene glycol, 1,2-propanediol, glycerol, etc.), alcohol ethers (ethoxyethanol, diethylene glycol, triethylene glycol, polyethylene glycol, etc.), ethers (di- and triethylene glycol dimethyl ether, diphenyl ether, etc.), aromatic, heteroaromatic and or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO), or sulfones (dimethyl sulfone, sulfolane, etc.). Suitable melting aids are compounds that are solid at room temperature but melt and dissolve the reactants when the reaction mixture is heated, resulting in a homogeneous melt. Particularly suitable are biphenyl, m-terphenyl, triphenylene, R- or S-binaphthol or also the corresponding racemate, 1,2-, 1,3-, 1,4-bis phenoxybenzene, triphenylphosphine oxide, 18-crown-6, phenol, 1-naphthol, hydroquinone, propofol, etc. The use of hydroquinone is particularly preferred.

As described above and in the example section, the synthesis of the fully or partially deuterated complexes is possible either by using the partially or fully deuterated ligand in the complexation reaction and/or by deuterating the complex after the complexation reaction.

By these methods, optionally followed by purification, such as recrystallization or sublimation, the compounds of the invention according to formula (1) can be obtained in high purity, preferably more than 99% (determined by ¹H-NMR and/or HPLC).

The metal complexes according to the invention are chiral structures. If, in addition, the ligand L is also chiral, the formation of diastereomers and several pairs of enantiomers is possible. The complexes according to the invention then comprise both the mixtures of the diastereomers and the corresponding racemates and the individual isolated diastereomers and enantiomers.

If ligands with two identical partial ligands are used in ortho-metallation, a racemic mixture of the C₁-symmetric complexes, i.e., the Δ and the Λ enantiomers, is usually obtained. These can be separated by common methods (chromatography on chiral materials/columns or racemate separation by crystallization) as shown in the following scheme, wherein for clarity the optional substituents are not shown:

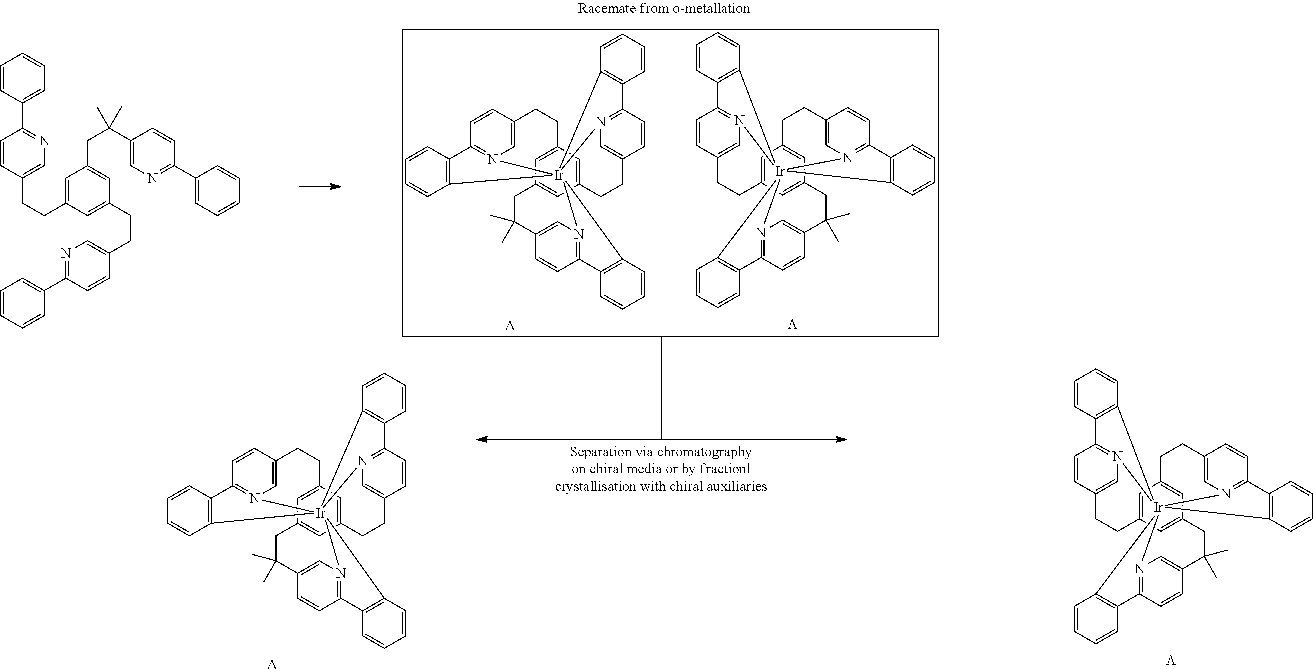

Racemate separation via fractional crystallization of diastereomeric salt pairs can be performed according to standard methods. For this purpose, it is useful to oxidize the neutral Ir(III) complexes (e.g., with peroxides, H O₂₂ or electrochemically), to add the salt of an enantiomerically pure, monoanionic base (chiral base) to the cationic Ir(IV) complexes thus produced, to separate the diasteromeric salts thus produced by fractionized crystallization, and then to convert them to the enantiomeric salts with the aid of a reduction agent (e.g., zinc, hydrazine hydrate, ascorbic acid, etc.). e.g. zinc, hydrazine hydrate, ascorbic acid, etc.) to the enantiomers pure neutral complex, as shown schematically below:

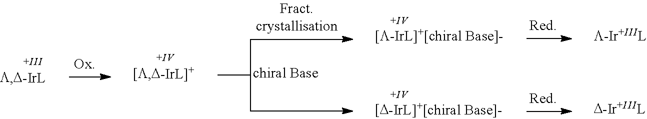

In addition, enantiomerically pure or enantiomerically enriched synthesis is possible by complexation in a chiral medium (e.g., R- or S-1,1-binaphthol).

If ligands with three different partial ligands are used in the complexation, a diastereomeric mixture of the complexes is usually obtained, which can be separated by common methods (chromatography, crystallization, etc.).

Enantiomerically pure C₁-symmetric complexes can also be specifically synthesized. For this purpose, an enantiomerically pure C₁-symmetric ligand is presented, complexed, the diastereomeric mixture obtained is separated and then the chiral group is cleaved off.

By these methods, optionally followed by purification, such as recrystallization or sublimation, the compounds of the invention according to formula (1) can be obtained in high purity, preferably more than 99% (determined by ¹H-NMR and/or HPLC).

The compounds according to the invention can also be made soluble by suitable substitution, for example by longer alkyl groups (about 4 to 20 C atoms), in particular branched alkyl groups, or optionally substituted aryl groups, for example xylyl, mesityl or branched terphenyl or quaterphenyl groups. In particular, the use of fused aliphatic groups, such as those represented by the formulae (44) to (50) disclosed above, also leads to a significant improvement in the solubility of the metal complexes. Such compounds are then soluble in common organic solvents such as, for example, toluene or xylene at room temperature in sufficient concentration to allow the complexes to be processed from solution. These soluble compounds are particularly suitable for processing from solution, for example by printing processes.

Formulations of the iridium complexes of the invention are required for processing the iridium complexes of the invention from liquid phase, for example by spin coating or by pressure processes. These formulations may be, for example, solutions, dispersions or emulsions. It may be preferred to use mixtures of two or more solvents for this purpose. Suitable and preferred solvents are, for example, toluene, anisole, o-, m- or p-xylene, methyl-benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethyl anisole, acetophenone, α-terpineol, benzothiazole, butyl benzoate, cumene, cyclohexanol, cyclohexanone, cyclohexylbenzene, decalin, dodecylbenzene, ethyl benzoate, indane, NMP, p-cymene, phenetol, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropyleneglycol dimethyl ether, tetraethyleneglycol dimethyl ether, 2-isopropylnaphthalene, pentylbenzene, hexyl benzene, heptylbenzene, octylbenzene, 1,1-bis(3,4-dimethylphenyl)ethane, hexamethylindane, 2-methylbiphenyl, 3-methylbiphenyl, 1-methylnaphthaline, 1-ethylnaphthalene, ethyl octanoate, sebacic acid diethyl ester, octyl octanoate, heptylbenzene, menthyl isovalerate, cyclohexyl hexanoate or mixtures of these solvents.

A further object of the present invention is therefore a formulation comprising at least one compound according to the invention and at least one further compound. The further compound may be, for example, a solvent, in particular one of the solvents mentioned above or a mixture of these solvents. However, the further compound may also be a further organic or inorganic compound that is also used in the electronic device, for example a matrix material. This further compound may also be polymeric.

The compound according to the invention can be used in the electronic device as an active component, preferably as an emitter in the emissive layer or as a hole or electron transport material in a hole or electron transporting layer, or as oxygen sensitizers or as a photoinitiator or photocatalyst. Thus, a further object of the present invention is the use wen of a compound according to the invention in an electronic device or as an oxygen sensitizer or as a photoinitiator or photo catalyst. Enantiomerically pure iridium complexes according to the invention are suitable as photocatalysts for chiral photoinduced syntheses.

Yet another object of the present invention is an electronic device containing at least one connection according to the invention.

An electronic device is understood to be a device which contains an anode, a cathode and at least one layer, this layer containing at least one organic or organometallic compound. The electronic device according to the invention thus contains an anode, cathode and at least one layer, which contains at least one iridium complex according to the invention. In this context, preferred electronic devices are selected from the group consisting of organic electroluminescence devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), where this includes both purely organic solar cells and dye-sensitized solar cells, organic optical detectors, organic photoreceptors, organic field quench devices (O-FQDs), light-emitting electrochemical cells (LECs), oxygen sensors or organic laser diodes (O-Lasers), containing in at least one layer at least one compound of the invention. Compounds that emit in the infrared are suitable for use in organic infrared electroluminescent devices and infrared sensors. Organic electroluminescent devices are particularly preferred. Active components are generally organic or inorganic materials that are introduced between the anode and cathode, for example charge injection, charge transport or charge blocking materials, but in particular emission materials and matrix materials. The compounds according to the invention show particularly good properties as emission materials in organic electroluminescent devices. A preferred embodiment of the invention is therefore organic electroluminescent devices. Furthermore, the compounds according to the invention can be used for the generation of singlet oxygen or in photocatalysis.

The organic electroluminescent device includes cathode, anode and at least one emitting layer. In addition to these layers, it may contain other layers, for example one or more hole injection layers, hole transport layers, hole blocking layers, electron transport layers, electron injection layers, exciton blocking layers, electron blocking layers, charge generation layers and/or organic or inorganic p/n transitions. In this context, it is possible that one or more hole transport layers are p-doped, for example with metal oxides, such as MoO₃ or WO₃, or with (per)fluorinated electron-poor aromatics or with electron-poor cyano-substituted heteroaromatics (e.g., according to JP 4747558, JP 2006-135145, US 2006/0289882, WO 2012/095143), or with quinoid systems (e.g. e.g. according to EP1336208) or with Lewis acids, or with boranes (e.g. according to US 2003/0006411, WO 2002/051850, WO 2015/049030) or with carboxylates of the elements of the 3rd, 4th or 5th main group (WO 2015/018539) and/or that one or more electron transport layers are n-doped.

Interlayers can also be inserted between two emitting layers that, for example, have an exciton-blocking function and/or control the charge balance in the electroluminescence before and/or generate charges (charge generation layer, e.g., in layer systems with multiple emitting layers, e.g., in white emitting OLED devices). It should be noted, however, that not necessarily each of these layers must be present.

The organic electroluminescence device may contain one emitting layer, or it may contain several emitting layers. If several emitting layers are present, these preferably have a total of several emission maxima between 380 nm and 750 nm, so that overall white emission results, i.e., different emitting compounds that can fluoresce or phosphoresce are used in the emitting layers. Particularly preferred are three-layer systems, wherein the three layers show blue, green and orange or red emission (for the principle structure see e.g., WO 2005/011013) or systems which have more than three emitting layers. It can also be a hybrid system, where one or more layers fluoresce, and one or more other layers phosphoresce. Tandem OLEDs are a preferred embodiment. White emitting organic electroluminescence in front of directions can be used for lighting applications or with color filters also for full color displays.

In a preferred embodiment of the invention, the organic electroluminescent device contains the iridium complex of the invention as an emitting compound in one or more emitting layers.

When the iridium complex according to the invention is used as an emitting compound in an emitting layer, it is preferably used in combination with one or more matrix materials. The mixture of the iridium complex according to the invention and the matrix material contains between 0.1 and 99 vol.-%, preferably between 1 and 90 vol.-%, particularly preferably between 3 and 40 vol.-%, especially between 5 and 15 vol. % of the iridium complex according to the invention relative to the total mixture of emitter and matrix material. Accordingly, the mixture contains between 99.9 and 1 vol. %, preferably between 99 and 10 vol. %, particularly preferably between 97 and 60 vol. %, especially between 95 and 85 vol. % of the matrix material relative to the total mixture of emitter and matrix material.

In general, all materials known in the prior art can be used as matrix material. Preferably, the triplet level of the matrix material is higher than the triplet level of the emitter.

Suitable matrix materials for the compounds according to the invention are ketones, phosphine oxides, sulfoxides and sulfones, e.g. according to WO 2004/013080, WO 2004/093207, WO 2006/005627 or WO 2010/006680, triarylamines, carbazole derivatives, e.g. E.g. CBP (N,N-biscarbazolylbiphenyl), m-CBP or carbazole derivatives disclosed in WO 2005/039246, US 2005/0069729, JP 2004/288381, EP 1205527, WO 2008/086851 or US 2009/0134784, biscarbazole derivatives, indolocarbazole derivatives, e.g. according to WO 2007/063754 or WO 2008/056746, indenocarbazole derivatives, e.g. according to WO 2010/136109 or WO 2011/000455, azacarbazoles, e.g. according to EP 1617710, EP 1617711, EP 1731584, JP 2005/347160, bipolar matrix materials, e.g. according to WO 2007/137725, silanes, e.g. according to WO 2005/111172, azaboroles or boronic esters, e.g. according to WO 2006/117052, diazasilol derivatives, e.g. according to WO 2010/054729, diazaphosphol derivatives, e.g. according to WO 2010/054730, triazine derivatives, e.g. according to WO 2010/015306, WO 2007/063754 or WO 2008/056746, zinc complexes, e.g. according to EP 652273 or WO 2009/062578, dibenzofuran derivatives, e.g. according to WO 2009/148015 or WO 2015/169412, or bridged carbazole derivatives, e.g. according to US 2009/0136779, WO 2010/050778, WO 2011/042107 or WO 2011/088877. For solution-processed OLEDs, polymers, e.g., according to WO 2012/008550 or WO 2012/048778, oligomers or dendrimers, e.g., according to Journal of Luminescence 183 (2017), 150-158, are also suitable as matrix materials.

It may also be preferred to use several different matrix materials as a mixture, in particular at least one electron-conducting matrix material and at least one hole-conducting matrix material. For example, a preferred combination is the use of an aromatic ketone, a triazine derivative or a phosphine oxide derivative with a triarylamine derivative or a carbazole derivative as a mixed matrix for the metal complex according to the invention. Equally preferred is the use of a mixture of a charge-transporting matrix material and an electrically inert matrix material (so-called “wide bandgap host”), which is not or not significantly involved in charge transport, as described, for example, in WO 2010/108579 or WO 2016/184540. Equally preferred is the use of two electron transporting matrix materials, for example triazine derivatives and lactam derivatives, as described e.g., in WO 2014/094964.

It is not difficult for the skilled person to draw on a variety of materials known in the prior art to select suitable materials for use in the layers of the organic electroluminescent device described above. In doing so, the person skilled in the art makes common considerations concerning the chemical and physical properties of the materials, since it is known to him that the materials in an organic electroluminescence device are interrelated. This concerns, for example, the energy positions of the orbitals (HOMO, LUMO) or the position of triplet and singlet energies, but also other material properties.

Preferred triazine or pyrimidine derivatives, which can be used as a mixture together with the compounds of the invention, are the compounds of the following formulae (eTMM-1) and (eTMM-2),

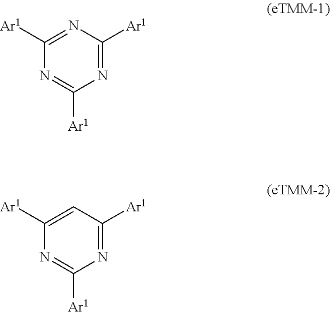

wherein each occurrence of Ar¹ may be the same or different and is an aromatic or heteroaromatic ring system having from 5 to 40 aromatic ring atoms, preferably having from 6 to 24 aromatic ring atoms, each of which may be substituted by one or more radicals R¹, wherein R¹ is as defined above.

Triazine derivatives (eTMM-1) are particularly preferred.

Examples of suitable electron-transporting compounds that can be used as matrix materials together with the compounds according to the invention are the compounds shown in the following table.

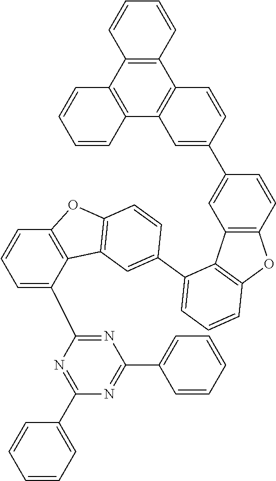 [SMILES: c1ccc(-c2nc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1]

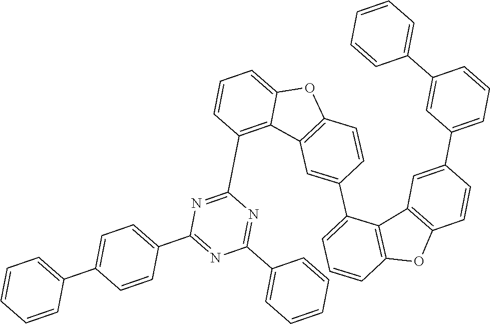 [SMILES: c1ccc(-c2ccc(-c3nc(-c4ccccc4)nc(-c4cccc5oc6ccc(-c7cccc8oc9ccc(-c%10cccc(-c%11ccccc%11)c%10)cc9c78)cc6c45)n3)cc2)cc1]

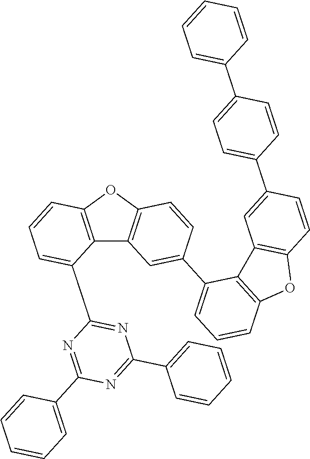 [SMILES: c1ccc(-c2ccc(-c3ccc4oc5cccc(-c6ccc7oc8cccc(-c9nc(-c%10ccccc%10)nc(-c%10ccccc%10)n9)c8c7c6)c5c4c3)cc2)cc1]

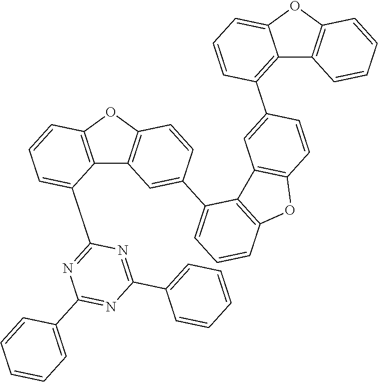 [SMILES: c1ccc(-c2nc(-c3ccccc3)nc(-c3cccc4oc5ccc(-c6cccc7oc8ccc(-c9cccc%10oc%11ccccc%11c9%10)cc8c67)cc5c34)n2)cc1]

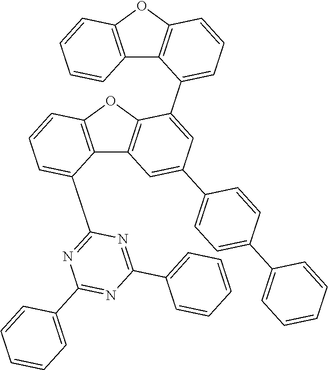 [SMILES: c1ccc(-c2ccc(-c3cc(-c4cccc5oc6ccccc6c45)c4oc5cccc(-c6nc(-c7ccccc7)nc(-c7ccccc7)n6)c5c4c3)cc2)cc1]

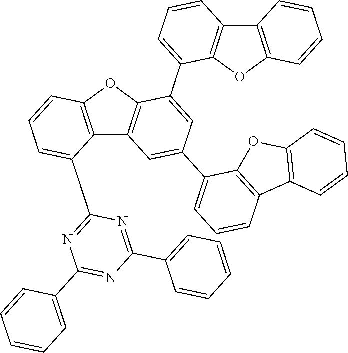 [SMILES: c1ccc(-c2nc(-c3ccccc3)nc(-c3cccc4oc5c(-c6cccc7c6oc6ccccc67)cc(-c6cccc7c6oc6ccccc67)cc5c34)n2)cc1]

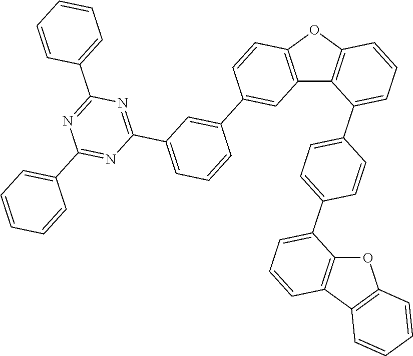 [SMILES: c1ccc(-c2nc(-c3ccccc3)nc(-c3cccc(-c4ccc5oc6cccc(-c7ccc(-c8cccc9c8oc8ccccc89)cc7)c6c5c4)c3)n2)cc1]

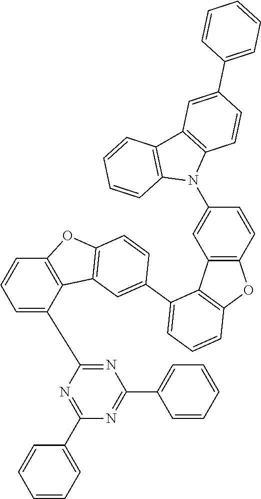 [SMILES: c1ccc(-c2ccc3c(c2)c2ccccc2n3-c2ccc3oc4cccc(-c5ccc6oc7cccc(-c8nc(-c9ccccc9)nc(-c9ccccc9)n8)c7c6c5)c4c3c2)cc1]

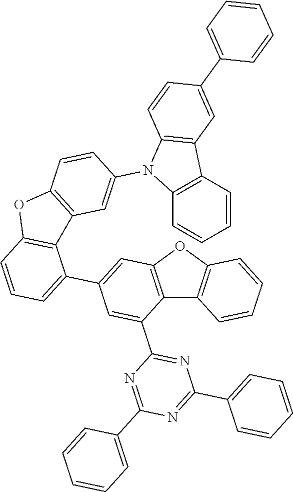 [SMILES: c1ccc(-c2ccc3c(c2)c2ccccc2n3-c2ccc3oc4cccc(-c5cc(-c6nc(-c7ccccc7)nc(-c7ccccc7)n6)c6c(c5)oc5ccccc56)c4c3c2)cc1]

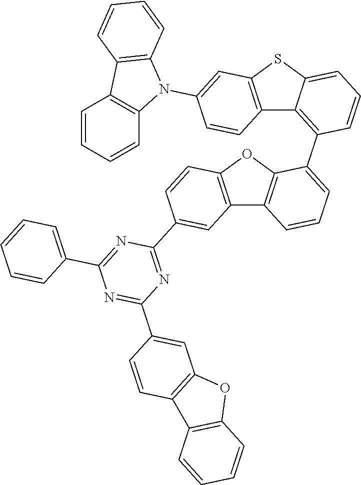 [SMILES: c1ccc(-c2nc(-c3ccc4c(c3)oc3ccccc34)nc(-c3ccc4oc5c(-c6cccc7sc8cc(-n9c%10ccccc%10c%10ccccc%109)ccc8c67)cccc5c4c3)n2)cc1]

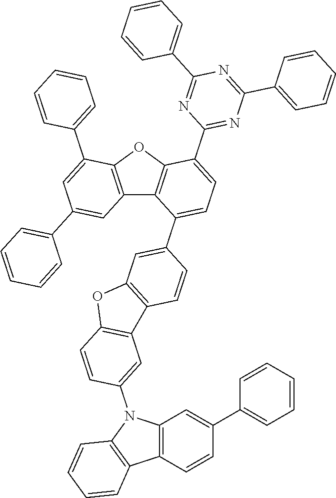 [SMILES: c1ccc(-c2cc(-c3ccccc3)c3oc4c(-c5nc(-c6ccccc6)nc(-c6ccccc6)n5)ccc(-c5ccc6c(c5)oc5ccc(-n7c8ccccc8c8ccc(-c9ccccc9)cc87)cc56)c4c3c2)cc1]

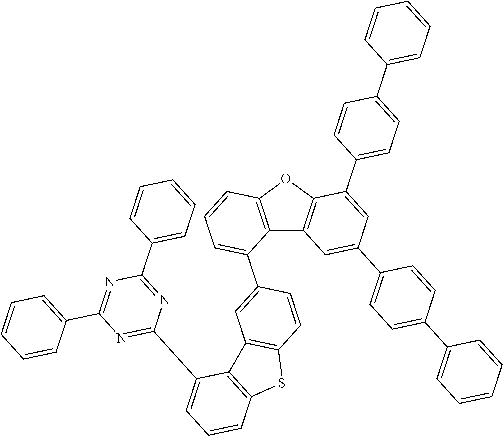 [SMILES: c1ccc(-c2ccc(-c3cc(-c4ccc(-c5ccccc5)cc4)c4oc5cccc(-c6ccc7sc8cccc(-c9nc(-c%10ccccc%10)nc(-c%10ccccc%10)n9)c8c7c6)c5c4c3)cc2)cc1]

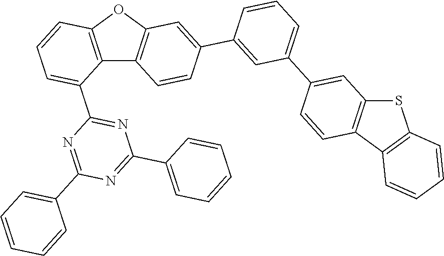 [SMILES: c1ccc(-c2nc(-c3ccccc3)nc(-c3cccc4oc5cc(-c6cccc(-c7ccc8c(c7)sc7ccccc78)c6)ccc5c34)n2)cc1]

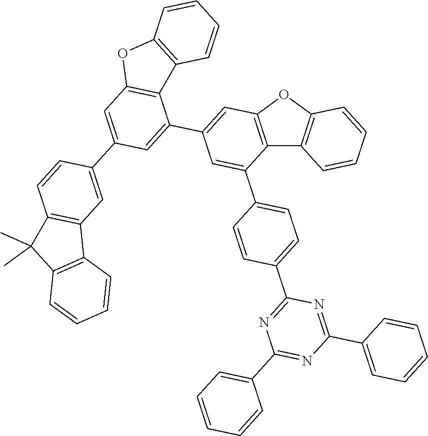 [SMILES: CC1(C)c2ccccc2-c2cc(-c3cc(-c4cc(-c5ccc(-c6nc(-c7ccccc7)nc(-c7ccccc7)n6)cc5)c5c(c4)oc4ccccc45)c4c(c3)oc3ccccc34)ccc21]

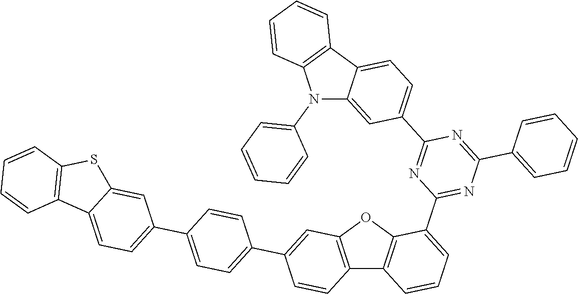 [SMILES: c1ccc(-c2nc(-c3ccc4c5ccccc5n(-c5ccccc5)c4c3)nc(-c3cccc4c3oc3cc(-c5ccc(-c6ccc7c(c6)sc6ccccc67)cc5)ccc34)n2)cc1]

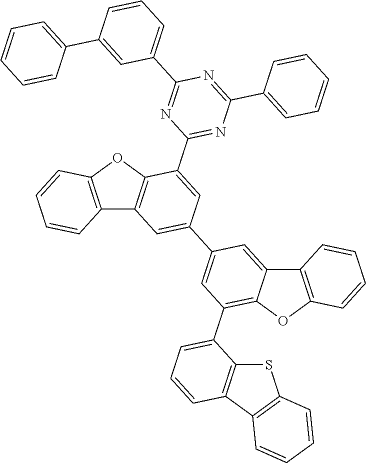 [SMILES: c1ccc(-c2cccc(-c3nc(-c4ccccc4)nc(-c4cc(-c5cc(-c6cccc7c6sc6ccccc67)c6oc7ccccc7c6c5)cc5c4oc4ccccc45)n3)c2)cc1]

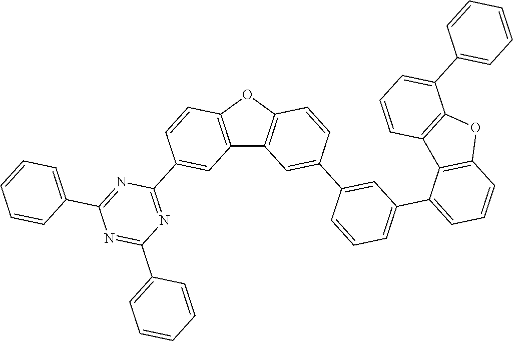 [SMILES: c1ccc(-c2nc(-c3ccccc3)nc(-c3ccc4oc5ccc(-c6cccc(-c7cccc8oc9c(-c%10ccccc%10)cccc9c78)c6)cc5c4c3)n2)cc1]

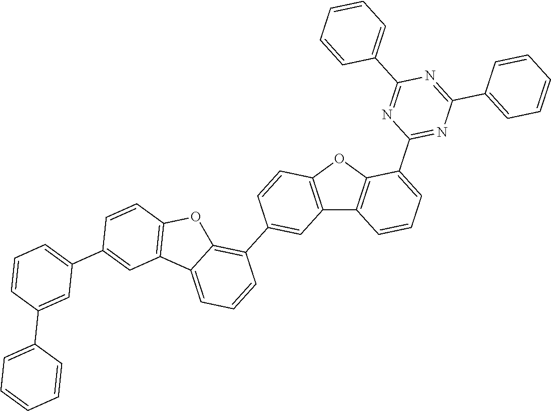 [SMILES: c1ccc(-c2cccc(-c3ccc4oc5c(-c6ccc7oc8c(-c9nc(-c%10ccccc%10)nc(-c%10ccccc%10)n9)cccc8c7c6)cccc5c4c3)c2)cc1]

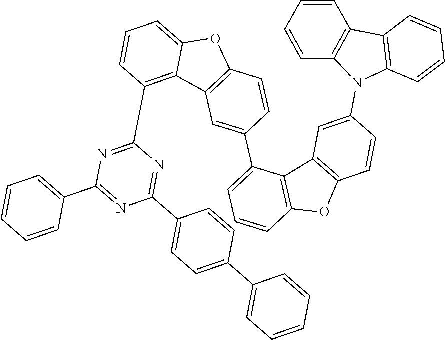 [SMILES: c1ccc(-c2ccc(-c3nc(-c4ccccc4)nc(-c4cccc5oc6ccc(-c7cccc8oc9ccc(-n%10c%11ccccc%11c%11ccccc%11%10)cc9c78)cc6c45)n3)cc2)cc1]

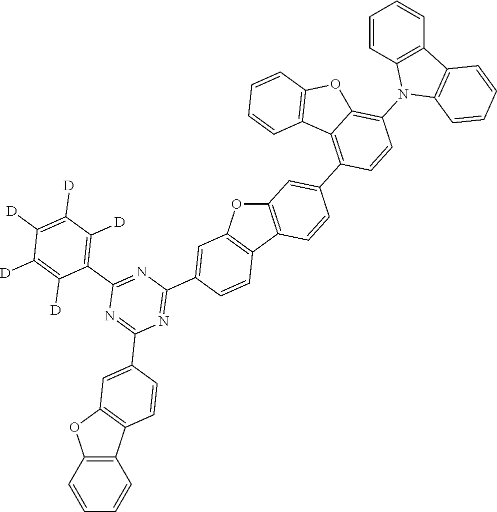 [SMILES: [2H]c1c([2H])c([2H])c(-c2nc(-c3ccc4c(c3)oc3ccccc34)nc(-c3ccc4c(c3)oc3cc(-c5ccc(-n6c7ccccc7c7ccccc76)c6oc7ccccc7c56)ccc34)n2)c([2H])c1[2H]]

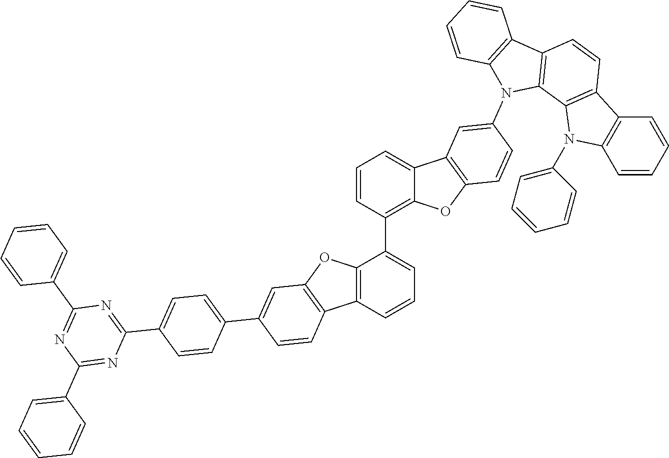 [SMILES: c1ccc(-c2nc(-c3ccccc3)nc(-c3ccc(-c4ccc5c(c4)oc4c(-c6cccc7c6oc6ccc(-n8c9ccccc9c9ccc%10c%11ccccc%11n(-c%11ccccc%11)c%10c98)cc67)cccc45)cc3)n2)cc1]

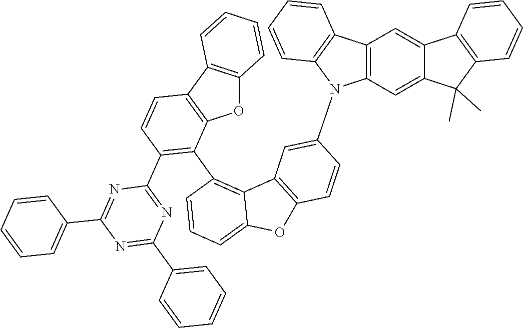 [SMILES: CC1(C)c2ccccc2-c2cc3c4ccccc4n(-c4ccc5oc6cccc(-c7c(-c8nc(-c9ccccc9)nc(-c9ccccc9)n8)ccc8c7oc7ccccc78)c6c5c4)c3cc21]

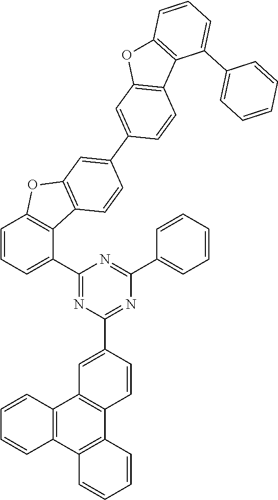 [SMILES: c1ccc(-c2nc(-c3ccc4c5ccccc5c5ccccc5c4c3)nc(-c3cccc4oc5cc(-c6ccc7c(c6)oc6cccc(-c8ccccc8)c67)ccc5c34)n2)cc1]

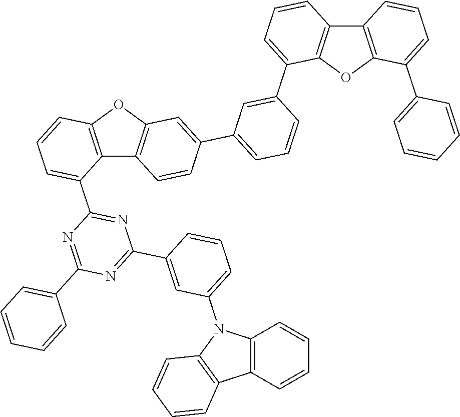 [SMILES: c1ccc(-c2nc(-c3cccc(-n4c5ccccc5c5ccccc54)c3)nc(-c3cccc4oc5cc(-c6cccc(-c7cccc8c7oc7c(-c9ccccc9)cccc78)c6)ccc5c34)n2)cc1]

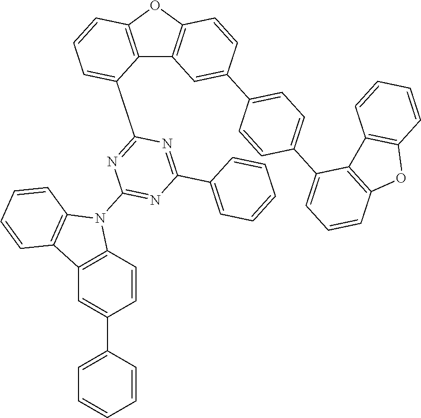 [SMILES: c1ccc(-c2ccc3c(c2)c2ccccc2n3-c2nc(-c3ccccc3)nc(-c3cccc4oc5ccc(-c6ccc(-c7cccc8oc9ccccc9c78)cc6)cc5c34)n2)cc1]

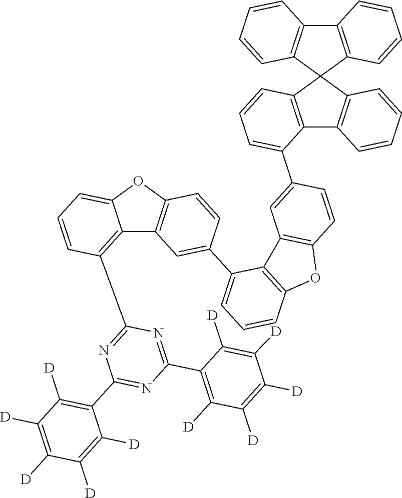 [SMILES: [2H]c1c([2H])c([2H])c(-c2nc(-c3c([2H])c([2H])c([2H])c([2H])c3[2H])nc(-c3cccc4oc5ccc(-c6cccc7oc8ccc(-c9cccc%10c9-c9ccccc9C%109c%10ccccc%10-c%10ccccc%109)cc8c67)cc5c34)n2)c([2H])c1[2H]]

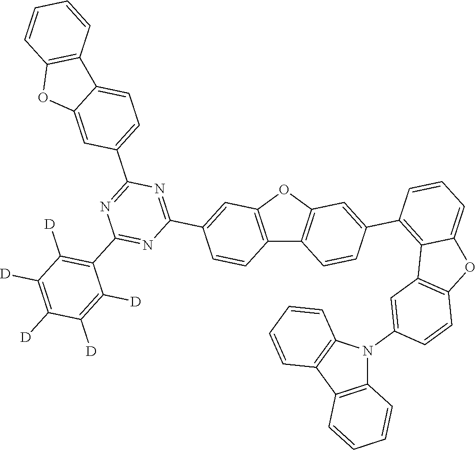 [SMILES: [2H]c1c([2H])c([2H])c(-c2nc(-c3ccc4c(c3)oc3ccccc34)nc(-c3ccc4c(c3)oc3cc(-c5cccc6oc7ccc(-n8c9ccccc9c9ccccc98)cc7c56)ccc34)n2)c([2H])c1[2H]]

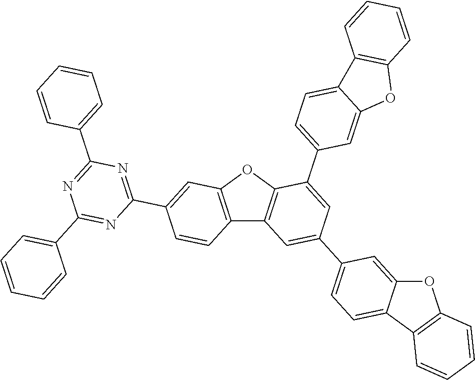 [SMILES: c1ccc(-c2nc(-c3ccccc3)nc(-c3ccc4c(c3)oc3c(-c5ccc6c(c5)oc5ccccc56)cc(-c5ccc6c(c5)oc5ccccc56)cc34)n2)cc1]

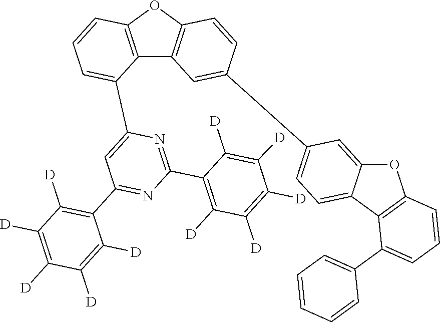 [SMILES: [2H]c1c([2H])c([2H])c(-c2cc(-c3cccc4oc5ccc(-c6ccc7c(c6)oc6cccc(-c8ccccc8)c67)cc5c34)nc(-c3c([2H])c([2H])c([2H])c([2H])c3[2H])n2)c([2H])c1[2H]]

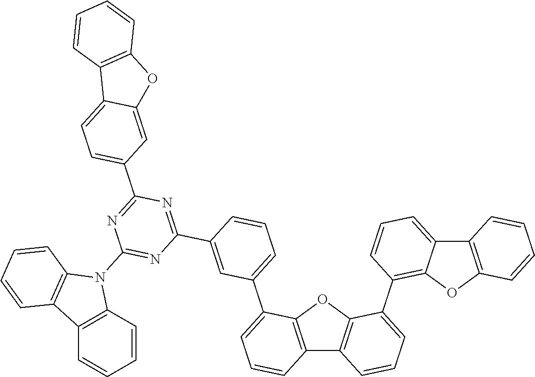 [SMILES: c1cc(-c2nc(-c3ccc4c(c3)oc3ccccc34)nc(-n3c4ccccc4c4ccccc43)n2)cc(-c2cccc3c2oc2c(-c4cccc5c4oc4ccccc45)cccc23)c1]

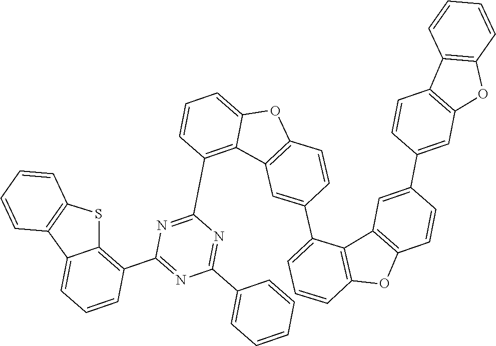 [SMILES: c1ccc(-c2nc(-c3cccc4c3sc3ccccc34)nc(-c3cccc4oc5ccc(-c6cccc7oc8ccc(-c9ccc%10c(c9)oc9ccccc9%10)cc8c67)cc5c34)n2)cc1]

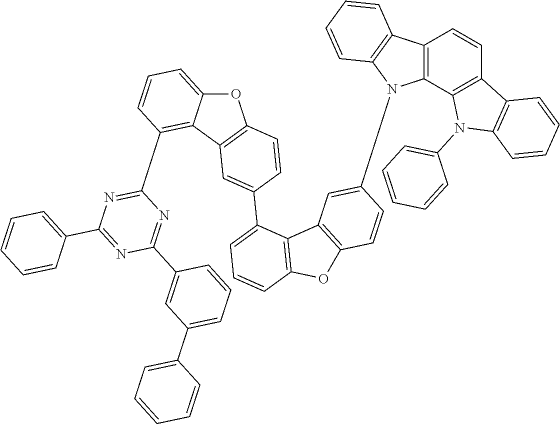 [SMILES: c1ccc(-c2cccc(-c3nc(-c4ccccc4)nc(-c4cccc5oc6ccc(-c7cccc8oc9ccc(-n%10c%11ccccc%11c%11ccc%12c%13ccccc%13n(-c%13ccccc%13)c%12c%11%10)cc9c78)cc6c45)n3)c2)cc1]

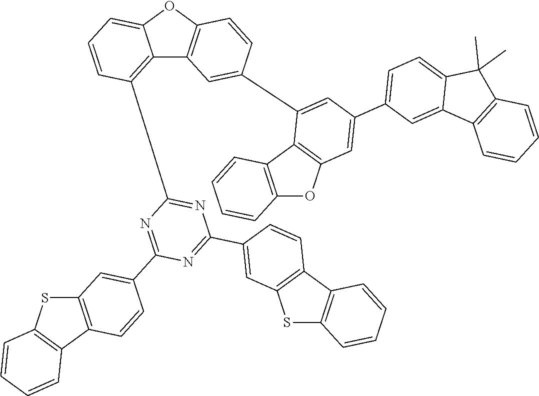 [SMILES: CC1(C)c2ccccc2-c2cc(-c3cc(-c4ccc5oc6cccc(-c7nc(-c8ccc9c(c8)sc8ccccc89)nc(-c8ccc9c(c8)sc8ccccc89)n7)c6c5c4)c4c(c3)oc3ccccc34)ccc21]

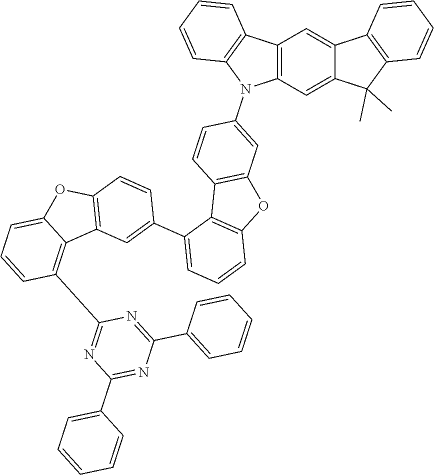 [SMILES: CC1(C)c2ccccc2-c2cc3c4ccccc4n(-c4ccc5c(c4)oc4cccc(-c6ccc7oc8cccc(-c9nc(-c%10ccccc%10)nc(-c%10ccccc%10)n9)c8c7c6)c45)c3cc21]

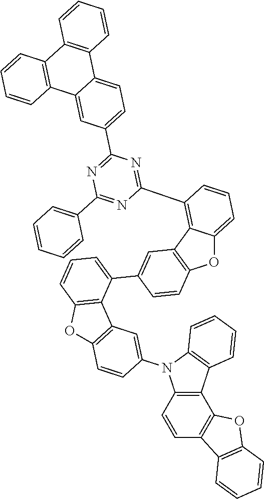 [SMILES: c1ccc(-c2nc(-c3ccc4c5ccccc5c5ccccc5c4c3)nc(-c3cccc4oc5ccc(-c6cccc7oc8ccc(-n9c%10ccccc%10c%10c%11oc%12ccccc%12c%11ccc%109)cc8c67)cc5c34)n2)cc1]

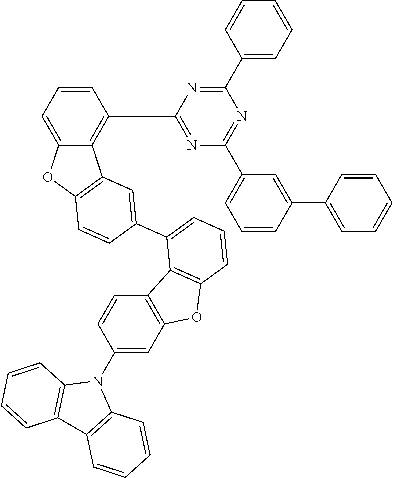 [SMILES: c1ccc(-c2cccc(-c3nc(-c4ccccc4)nc(-c4cccc5oc6ccc(-c7cccc8oc9cc(-n%10c%11ccccc%11c%11ccccc%11%10)ccc9c78)cc6c45)n3)c2)cc1]

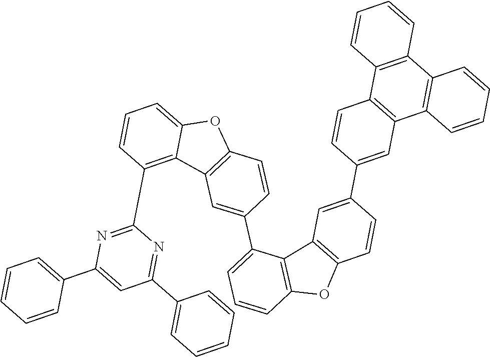 [SMILES: c1ccc(-c2cc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1]

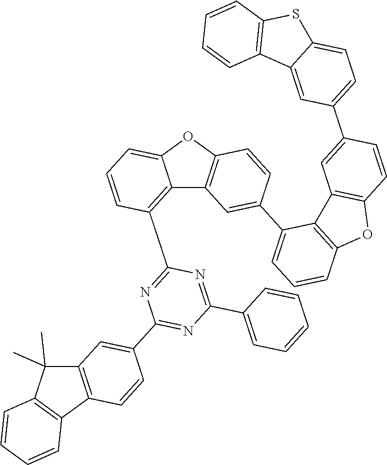 [SMILES: CC1(C)c2ccccc2-c2ccc(-c3nc(-c4ccccc4)nc(-c4cccc5oc6ccc(-c7cccc8oc9ccc(-c%10ccc%11sc%12ccccc%12c%11c%10)cc9c78)cc6c45)n3)cc21]

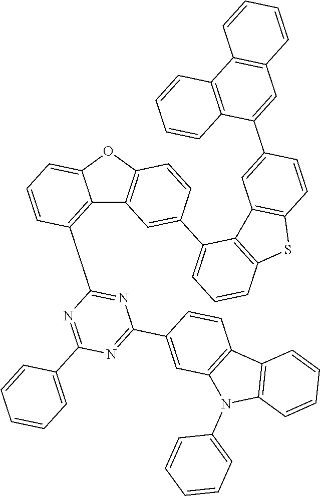 [SMILES: c1ccc(-c2nc(-c3ccc4c5ccccc5n(-c5ccccc5)c4c3)nc(-c3cccc4oc5ccc(-c6cccc7sc8ccc(-c9cc%10ccccc%10c%10ccccc9%10)cc8c67)cc5c34)n2)cc1]

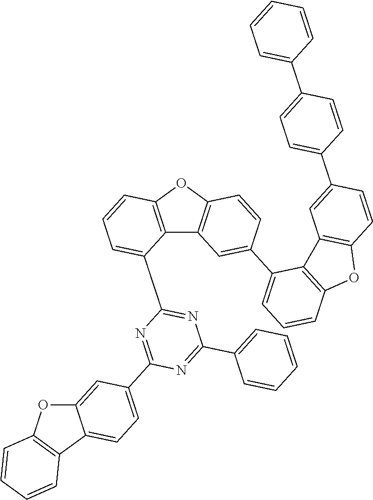 [SMILES: c1ccc(-c2ccc(-c3ccc4oc5cccc(-c6ccc7oc8cccc(-c9nc(-c%10ccccc%10)nc(-c%10ccc%11c(c%10)oc%10ccccc%10%11)n9)c8c7c6)c5c4c3)cc2)cc1]

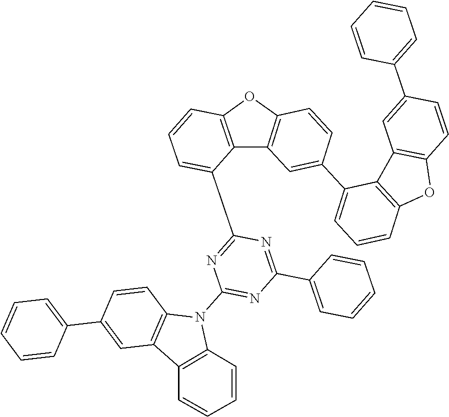 [SMILES: c1ccc(-c2ccc3oc4cccc(-c5ccc6oc7cccc(-c8nc(-c9ccccc9)nc(-n9c%10ccccc%10c%10cc(-c%11ccccc%11)ccc%109)n8)c7c6c5)c4c3c2)cc1]

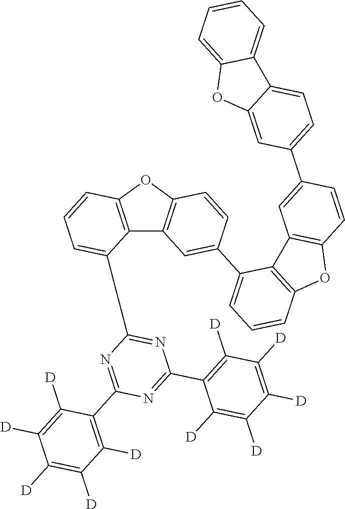 [SMILES: [2H]c1c([2H])c([2H])c(-c2nc(-c3c([2H])c([2H])c([2H])c([2H])c3[2H])nc(-c3cccc4oc5ccc(-c6cccc7oc8ccc(-c9ccc%10c(c9)oc9ccccc9%10)cc8c67)cc5c34)n2)c([2H])c1[2H]]

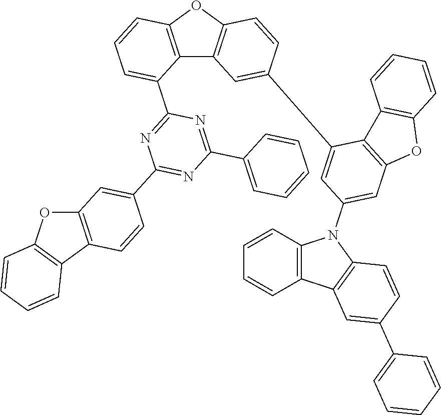 [SMILES: c1ccc(-c2ccc3c(c2)c2ccccc2n3-c2cc(-c3ccc4oc5cccc(-c6nc(-c7ccccc7)nc(-c7ccc8c(c7)oc7ccccc78)n6)c5c4c3)c3c(c2)oc2ccccc23)cc1]

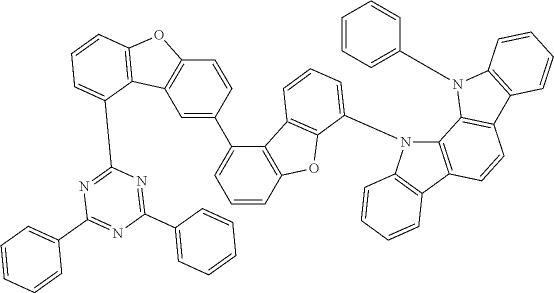 [SMILES: c1ccc(-c2nc(-c3ccccc3)nc(-c3cccc4oc5ccc(-c6cccc7oc8c(-n9c%10ccccc%10c%10ccc%11c%12ccccc%12n(-c%12ccccc%12)c%11c%109)cccc8c67)cc5c34)n2)cc1]

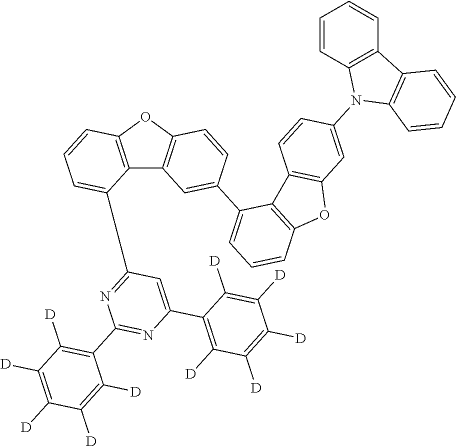 [SMILES: [2H]c1c([2H])c([2H])c(-c2cc(-c3cccc4oc5ccc(-c6cccc7oc8cc(-n9c%10ccccc%10c%10ccccc%109)ccc8c67)cc5c34)nc(-c3c([2H])c([2H])c([2H])c([2H])c3[2H])n2)c([2H])c1[2H]]

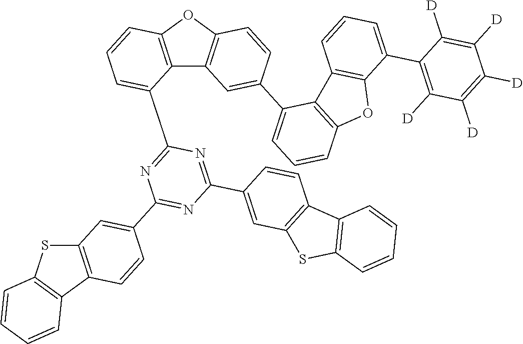 [SMILES: [2H]c1c([2H])c([2H])c(-c2cccc3c2oc2cccc(-c4ccc5oc6cccc(-c7nc(-c8ccc9c(c8)sc8ccccc89)nc(-c8ccc9c(c8)sc8ccccc89)n7)c6c5c4)c23)c([2H])c1[2H]]

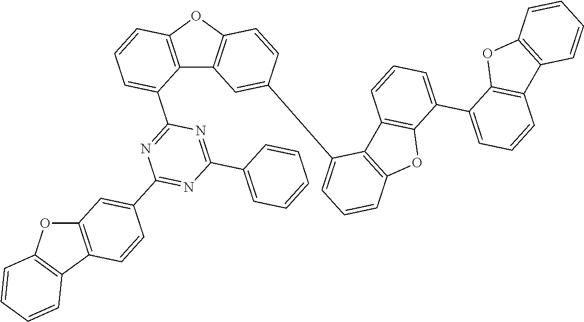 [SMILES: c1ccc(-c2nc(-c3ccc4c(c3)oc3ccccc34)nc(-c3cccc4oc5ccc(-c6cccc7oc8c(-c9cccc%10c9oc9ccccc9%10)cccc8c67)cc5c34)n2)cc1]

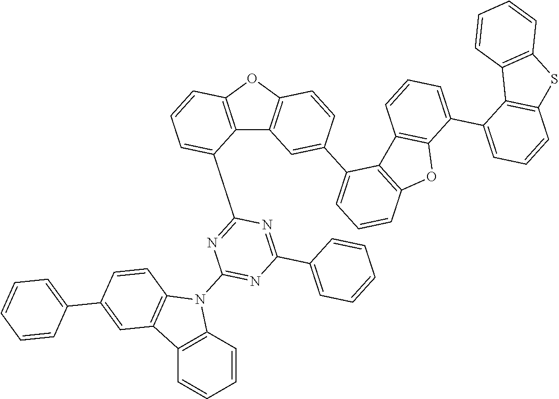 [SMILES: c1ccc(-c2ccc3c(c2)c2ccccc2n3-c2nc(-c3ccccc3)nc(-c3cccc4oc5ccc(-c6cccc7oc8c(-c9cccc%10sc%11ccccc%11c9%10)cccc8c67)cc5c34)n2)cc1]

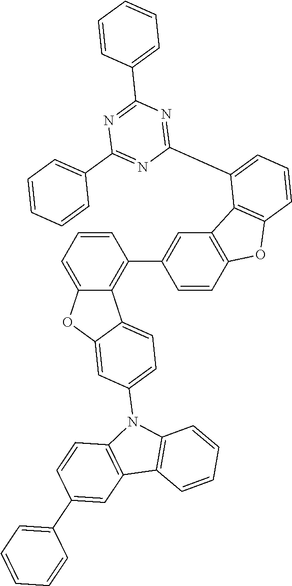 [SMILES: c1ccc(-c2ccc3c(c2)c2ccccc2n3-c2ccc3c(c2)oc2cccc(-c4ccc5oc6cccc(-c7nc(-c8ccccc8)nc(-c8ccccc8)n7)c6c5c4)c23)cc1]

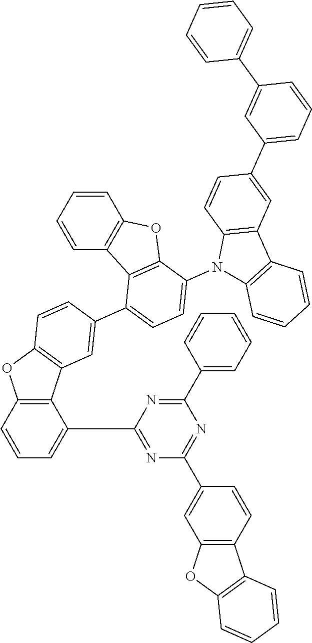 [SMILES: c1ccc(-c2cccc(-c3ccc4c(c3)c3ccccc3n4-c3ccc(-c4ccc5oc6cccc(-c7nc(-c8ccccc8)nc(-c8ccc9c(c8)oc8ccccc89)n7)c6c5c4)c4c3oc3ccccc34)c2)cc1]

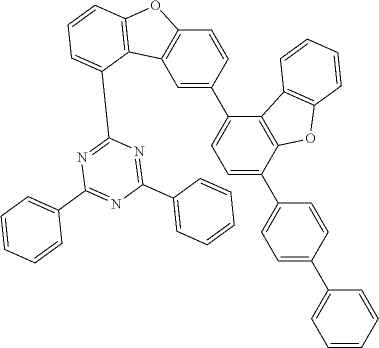 [SMILES: c1ccc(-c2ccc(-c3ccc(-c4ccc5oc6cccc(-c7nc(-c8ccccc8)nc(-c8ccccc8)n7)c6c5c4)c4c3oc3ccccc34)cc2)cc1]

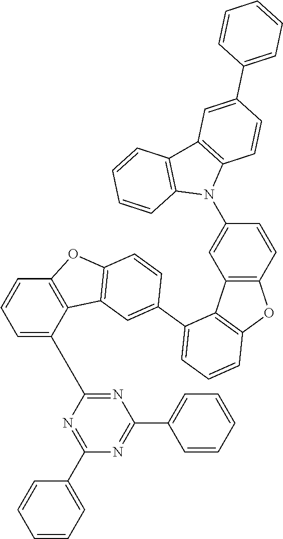 [SMILES: c1ccc(-c2ccc3c(c2)c2ccccc2n3-c2ccc3oc4cccc(-c5ccc6oc7cccc(-c8nc(-c9ccccc9)nc(-c9ccccc9)n8)c7c6c5)c4c3c2)cc1]

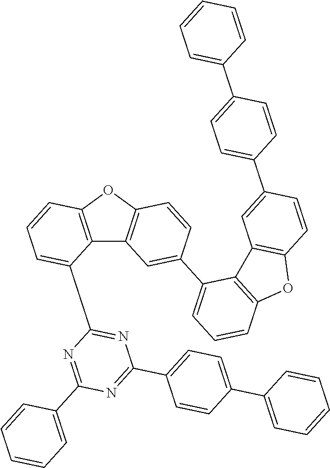 [SMILES: c1ccc(-c2ccc(-c3ccc4oc5cccc(-c6ccc7oc8cccc(-c9nc(-c%10ccccc%10)nc(-c%10ccc(-c%11ccccc%11)cc%10)n9)c8c7c6)c5c4c3)cc2)cc1]

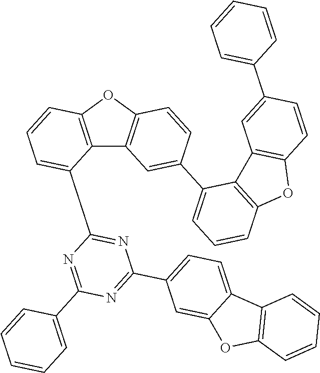 [SMILES: c1ccc(-c2ccc3oc4cccc(-c5ccc6oc7cccc(-c8nc(-c9ccccc9)nc(-c9ccc%10c(c9)oc9ccccc9%10)n8)c7c6c5)c4c3c2)cc1]

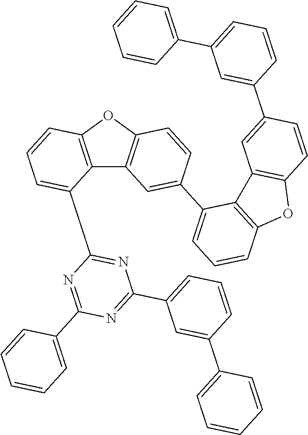 [SMILES: c1ccc(-c2cccc(-c3ccc4oc5cccc(-c6ccc7oc8cccc(-c9nc(-c%10ccccc%10)nc(-c%10cccc(-c%11ccccc%11)c%10)n9)c8c7c6)c5c4c3)c2)cc1]

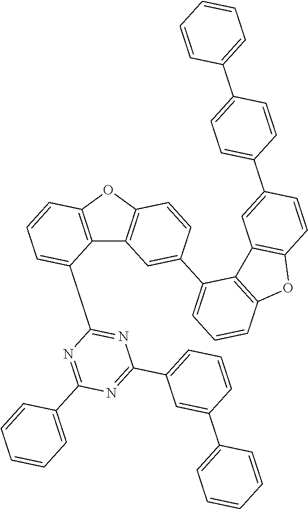 [SMILES: c1ccc(-c2ccc(-c3ccc4oc5cccc(-c6ccc7oc8cccc(-c9nc(-c%10ccccc%10)nc(-c%10cccc(-c%11ccccc%11)c%10)n9)c8c7c6)c5c4c3)cc2)cc1]

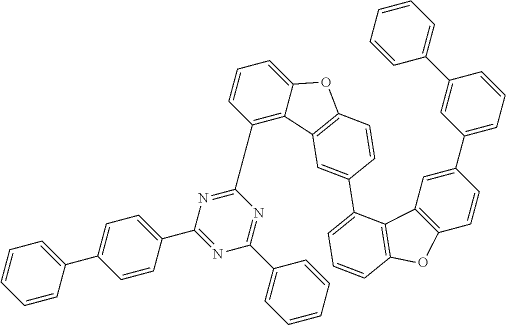 [SMILES: c1ccc(-c2ccc(-c3nc(-c4ccccc4)nc(-c4cccc5oc6ccc(-c7cccc8oc9ccc(-c%10cccc(-c%11ccccc%11)c%10)cc9c78)cc6c45)n3)cc2)cc1]

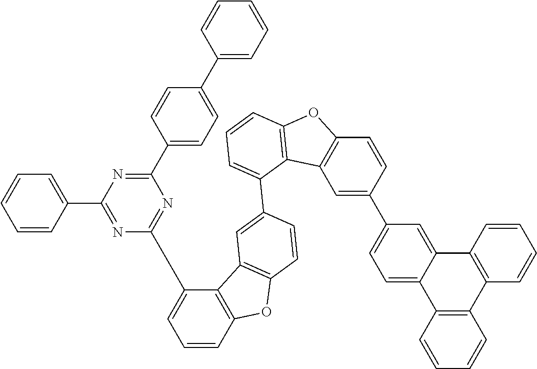 [SMILES: c1ccc(-c2ccc(-c3nc(-c4ccccc4)nc(-c4cccc5oc6ccc(-c7cccc8oc9ccc(-c%10ccc%11c%12ccccc%12c%12ccccc%12c%11c%10)cc9c78)cc6c45)n3)cc2)cc1]

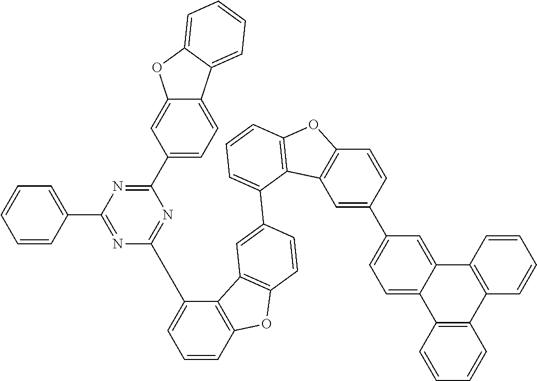 [SMILES: c1ccc(-c2nc(-c3ccc4c(c3)oc3ccccc34)nc(-c3cccc4oc5ccc(-c6cccc7oc8ccc(-c9ccc%10c%11ccccc%11c%11ccccc%11c%10c9)cc8c67)cc5c34)n2)cc1]

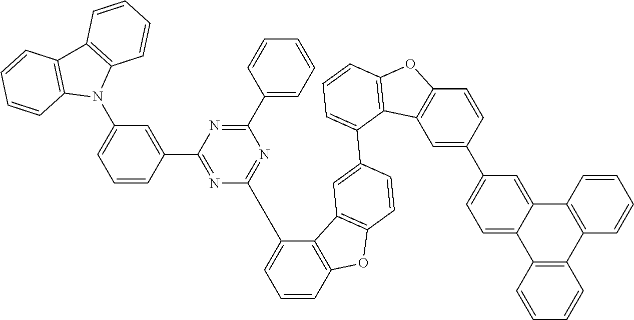 [SMILES: c1ccc(-c2nc(-c3cccc(-n4c5ccccc5c5ccccc54)c3)nc(-c3cccc4oc5ccc(-c6cccc7oc8ccc(-c9ccc%10c%11ccccc%11c%11ccccc%11c%10c9)cc8c67)cc5c34)n2)cc1]

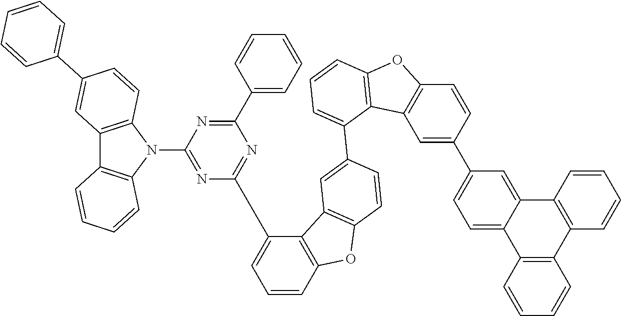 [SMILES: c1ccc(-c2ccc3c(c2)c2ccccc2n3-c2nc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1]

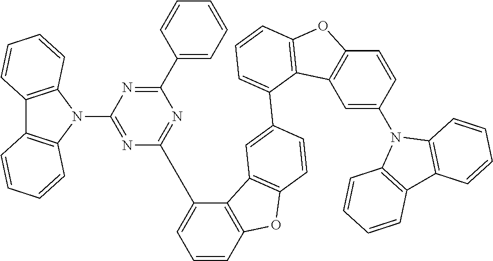 [SMILES: c1ccc(-c2nc(-c3cccc4oc5ccc(-c6cccc7oc8ccc(-n9c%10ccccc%10c%10ccccc%109)cc8c67)cc5c34)nc(-n3c4ccccc4c4ccccc43)n2)cc1]

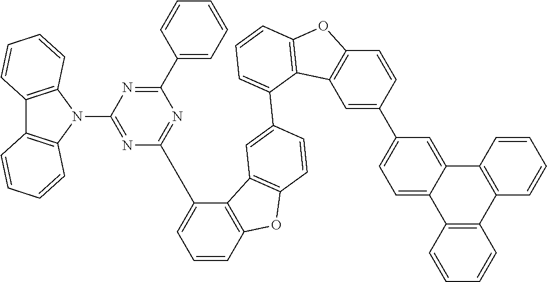 [SMILES: c1ccc(-c2nc(-c3cccc4oc5ccc(-c6cccc7oc8ccc(-c9ccc%10c%11ccccc%11c%11ccccc%11c%10c9)cc8c67)cc5c34)nc(-n3c4ccccc4c4ccccc43)n2)cc1]

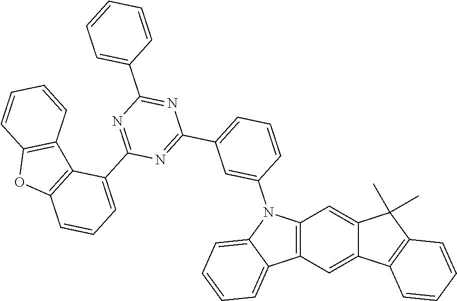 [SMILES: CC1(C)c2ccccc2-c2cc3c4ccccc4n(-c4cccc(-c5nc(-c6ccccc6)nc(-c6cccc7oc8ccccc8c67)n5)c4)c3cc21]

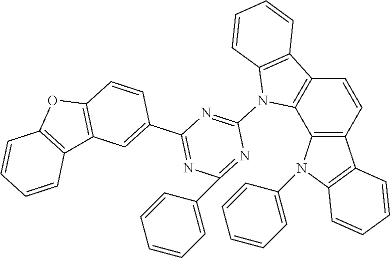 [SMILES: c1ccc(-c2nc(-c3ccc4oc5ccccc5c4c3)nc(-n3c4ccccc4c4ccc5c6ccccc6n(-c6ccccc6)c5c43)n2)cc1]

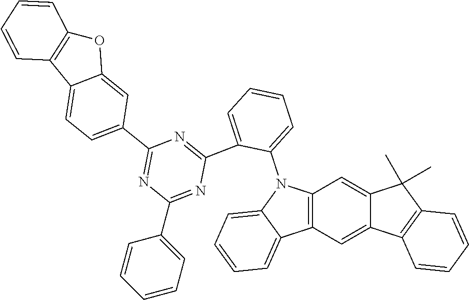 [SMILES: CC1(C)c2ccccc2-c2cc3c4ccccc4n(-c4ccccc4-c4nc(-c5ccccc5)nc(-c5ccc6c(c5)oc5ccccc56)n4)c3cc21]

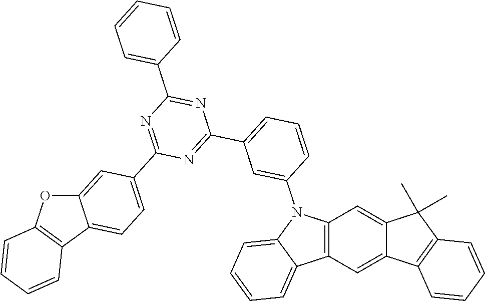 [SMILES: CC1(C)c2ccccc2-c2cc3c4ccccc4n(-c4cccc(-c5nc(-c6ccccc6)nc(-c6ccc7c(c6)oc6ccccc67)n5)c4)c3cc21]

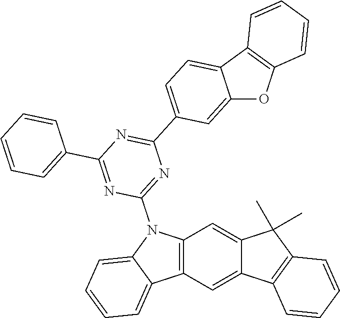 [SMILES: CC1(C)c2ccccc2-c2cc3c4ccccc4n(-c4nc(-c5ccccc5)nc(-c5ccc6c(c5)oc5ccccc56)n4)c3cc21]

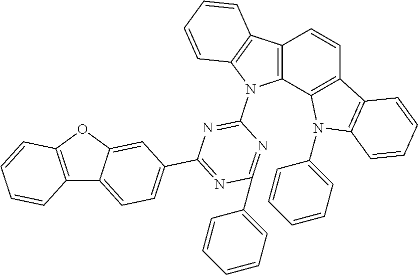 [SMILES: c1ccc(-c2nc(-c3ccc4c(c3)oc3ccccc34)nc(-n3c4ccccc4c4ccc5c6ccccc6n(-c6ccccc6)c5c43)n2)cc1]

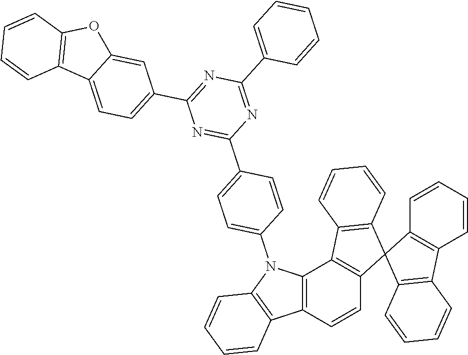 [SMILES: c1ccc(-c2nc(-c3ccc(-n4c5ccccc5c5ccc6c(c54)-c4ccccc4C64c5ccccc5-c5ccccc54)cc3)nc(-c3ccc4c(c3)oc3ccccc34)n2)cc1]

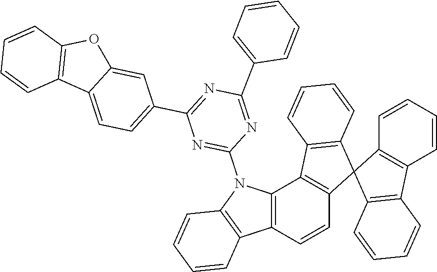 [SMILES: c1ccc(-c2nc(-c3ccc4c(c3)oc3ccccc34)nc(-n3c4ccccc4c4ccc5c(c43)-c3ccccc3C53c4ccccc4-c4ccccc43)n2)cc1]

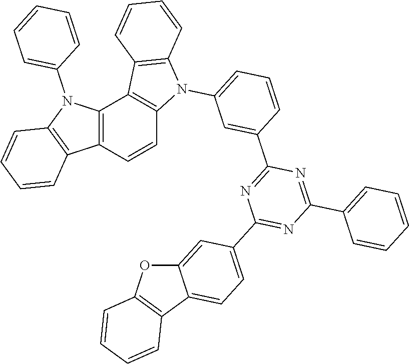 [SMILES: c1ccc(-c2nc(-c3cccc(-n4c5ccccc5c5c4ccc4c6ccccc6n(-c6ccccc6)c45)c3)nc(-c3ccc4c(c3)oc3ccccc34)n2)cc1]

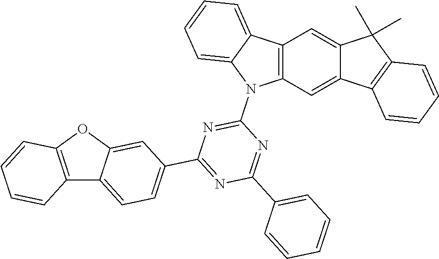 [SMILES: CC1(C)c2ccccc2-c2cc3c(cc21)c1ccccc1n3-c1nc(-c2ccccc2)nc(-c2ccc3c(c2)oc2ccccc23)n1]

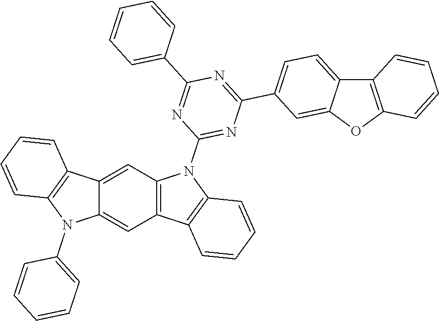 [SMILES: c1ccc(-c2nc(-c3ccc4c(c3)oc3ccccc34)nc(-n3c4ccccc4c4cc5c(cc43)c3ccccc3n5-c3ccccc3)n2)cc1]

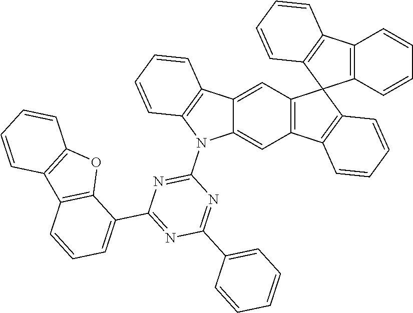 [SMILES: c1ccc(-c2nc(-c3cccc4c3oc3ccccc34)nc(-n3c4ccccc4c4cc5c(cc43)-c3ccccc3C53c4ccccc4-c4ccccc43)n2)cc1]

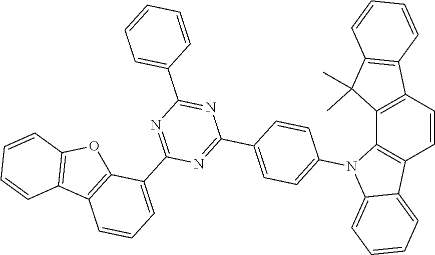 [SMILES: CC1(C)c2ccccc2-c2ccc3c4ccccc4n(-c4ccc(-c5nc(-c6ccccc6)nc(-c6cccc7c6oc6ccccc67)n5)cc4)c3c21]

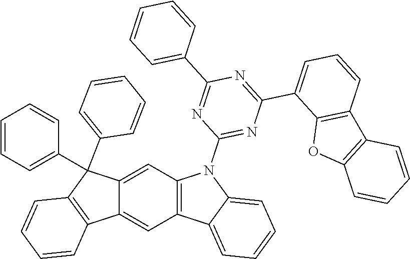 [SMILES: c1ccc(-c2nc(-c3cccc4c3oc3ccccc34)nc(-n3c4ccccc4c4cc5c(cc43)C(c3ccccc3)(c3ccccc3)c3ccccc3-5)n2)cc1]

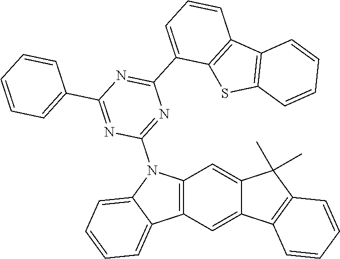 [SMILES: CC1(C)c2ccccc2-c2cc3c4ccccc4n(-c4nc(-c5ccccc5)nc(-c5cccc6c5sc5ccccc56)n4)c3cc21]

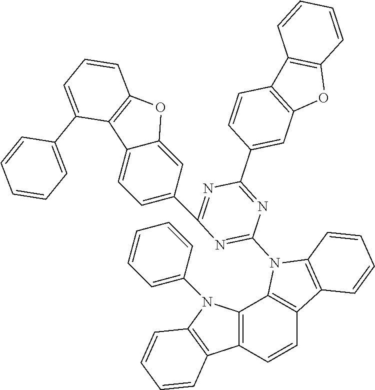 [SMILES: c1ccc(-c2cccc3oc4cc(-c5nc(-c6ccc7c(c6)oc6ccccc67)nc(-n6c7ccccc7c7ccc8c9ccccc9n(-c9ccccc9)c8c76)n5)ccc4c23)cc1]

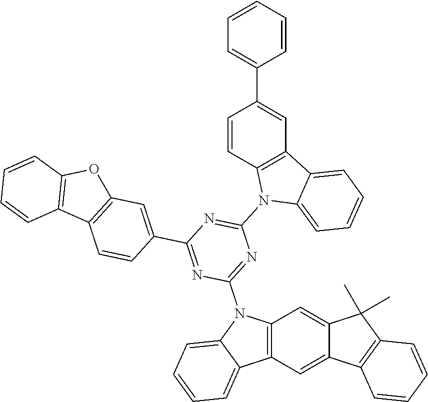 [SMILES: CC1(C)c2ccccc2-c2cc3c4ccccc4n(-c4nc(-c5ccc6c(c5)oc5ccccc56)nc(-n5c6ccccc6c6cc(-c7ccccc7)ccc65)n4)c3cc21]

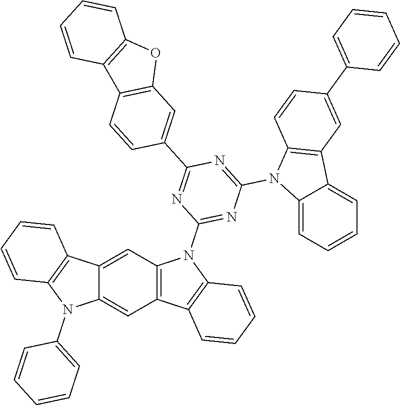 [SMILES: c1ccc(-c2ccc3c(c2)c2ccccc2n3-c2nc(-c3ccc4c(c3)oc3ccccc34)nc(-n3c4ccccc4c4cc5c(cc43)c3ccccc3n5-c3ccccc3)n2)cc1]

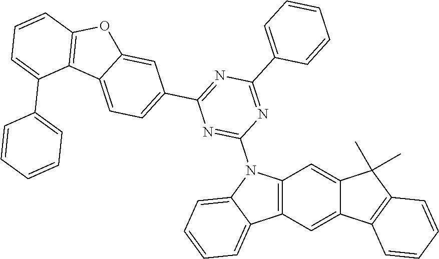 [SMILES: CC1(C)c2ccccc2-c2cc3c4ccccc4n(-c4nc(-c5ccccc5)nc(-c5ccc6c(c5)oc5cccc(-c7ccccc7)c56)n4)c3cc21]

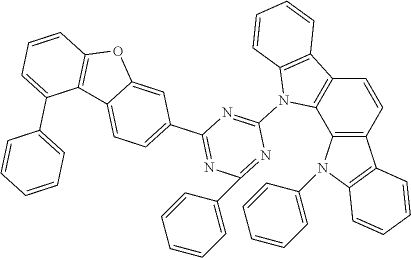 [SMILES: c1ccc(-c2nc(-c3ccc4c(c3)oc3cccc(-c5ccccc5)c34)nc(-n3c4ccccc4c4ccc5c6ccccc6n(-c6ccccc6)c5c43)n2)cc1]

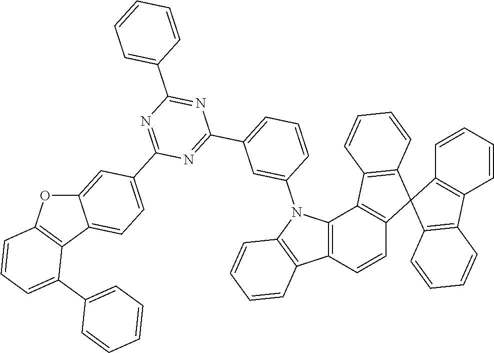 [SMILES: c1ccc(-c2nc(-c3cccc(-n4c5ccccc5c5ccc6c(c54)-c4ccccc4C64c5ccccc5-c5ccccc54)c3)nc(-c3ccc4c(c3)oc3cccc(-c5ccccc5)c34)n2)cc1]

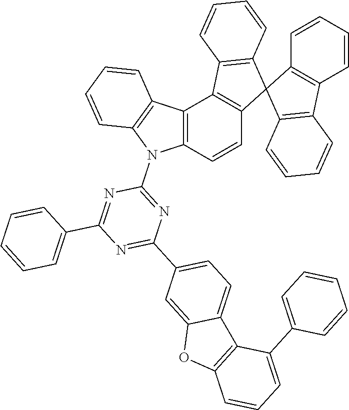 [SMILES: c1ccc(-c2nc(-c3ccc4c(c3)oc3cccc(-c5ccccc5)c34)nc(-n3c4ccccc4c4c5c(ccc43)C3(c4ccccc4-c4ccccc43)c3ccccc3-5)n2)cc1]

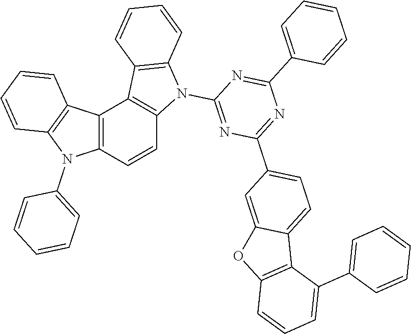 [SMILES: c1ccc(-c2nc(-c3ccc4c(c3)oc3cccc(-c5ccccc5)c34)nc(-n3c4ccccc4c4c5c6ccccc6n(-c6ccccc6)c5ccc43)n2)cc1]

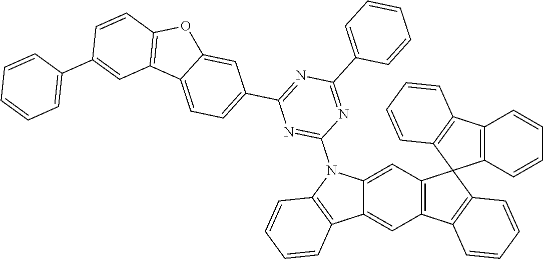 [SMILES: c1ccc(-c2ccc3oc4cc(-c5nc(-c6ccccc6)nc(-n6c7ccccc7c7cc8c(cc76)C6(c7ccccc7-c7ccccc76)c6ccccc6-8)n5)ccc4c3c2)cc1]

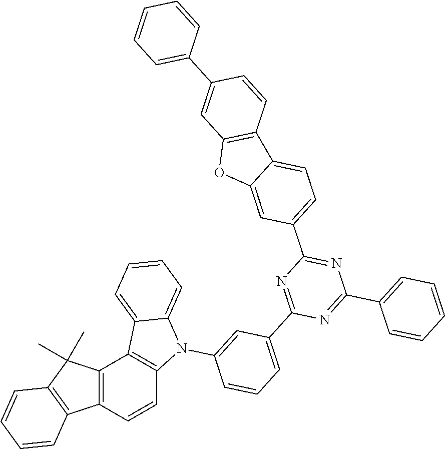 [SMILES: CC1(C)c2ccccc2-c2ccc3c(c21)c1ccccc1n3-c1cccc(-c2nc(-c3ccccc3)nc(-c3ccc4c(c3)oc3cc(-c5ccccc5)ccc34)n2)c1]

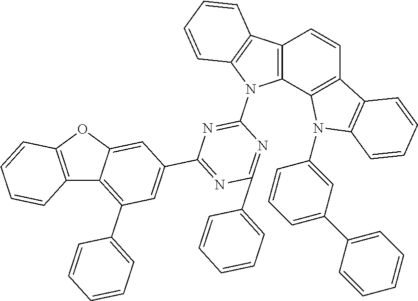 [SMILES: c1ccc(-c2cccc(-n3c4ccccc4c4ccc5c6ccccc6n(-c6nc(-c7ccccc7)nc(-c7cc(-c8ccccc8)c8c(c7)oc7ccccc78)n6)c5c43)c2)cc1]

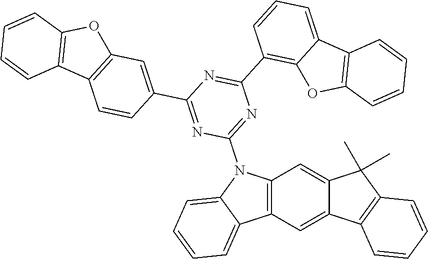 [SMILES: CC1(C)c2ccccc2-c2cc3c4ccccc4n(-c4nc(-c5ccc6c(c5)oc5ccccc56)nc(-c5cccc6c5oc5ccccc56)n4)c3cc21]

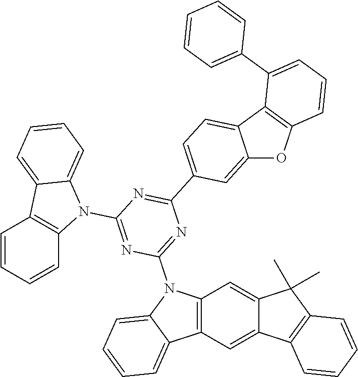 [SMILES: CC1(C)c2ccccc2-c2cc3c4ccccc4n(-c4nc(-c5ccc6c(c5)oc5cccc(-c7ccccc7)c56)nc(-n5c6ccccc6c6ccccc65)n4)c3cc21]

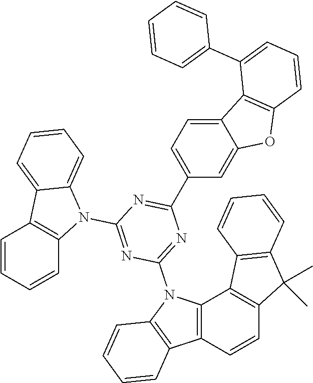 [SMILES: CC1(C)c2ccccc2-c2c1ccc1c3ccccc3n(-c3nc(-c4ccc5c(c4)oc4cccc(-c6ccccc6)c45)nc(-n4c5ccccc5c5ccccc54)n3)c21]

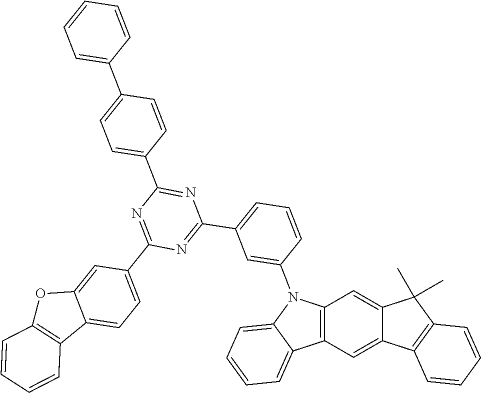 [SMILES: CC1(C)c2ccccc2-c2cc3c4ccccc4n(-c4cccc(-c5nc(-c6ccc(-c7ccccc7)cc6)nc(-c6ccc7c(c6)oc6ccccc67)n5)c4)c3cc21]

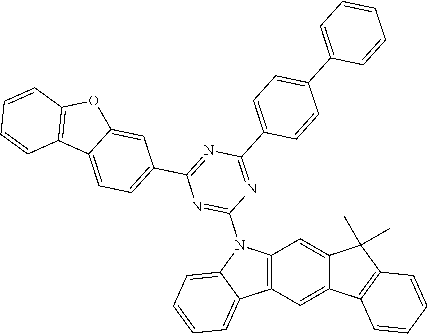 [SMILES: CC1(C)c2ccccc2-c2cc3c4ccccc4n(-c4nc(-c5ccc(-c6ccccc6)cc5)nc(-c5ccc6c(c5)oc5ccccc56)n4)c3cc21]

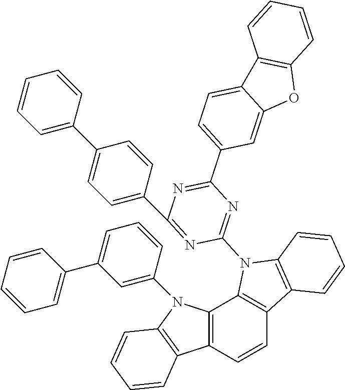 [SMILES: c1ccc(-c2ccc(-c3nc(-c4ccc5c(c4)oc4ccccc45)nc(-n4c5ccccc5c5ccc6c7ccccc7n(-c7cccc(-c8ccccc8)c7)c6c54)n3)cc2)cc1]

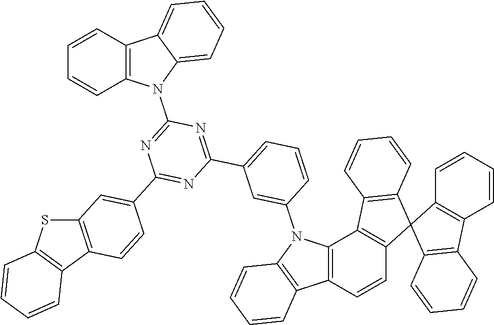 [SMILES: c1cc(-c2nc(-c3ccc4c(c3)sc3ccccc34)nc(-n3c4ccccc4c4ccccc43)n2)cc(-n2c3ccccc3c3ccc4c(c32)-c2ccccc2C42c3ccccc3-c3ccccc32)c1]

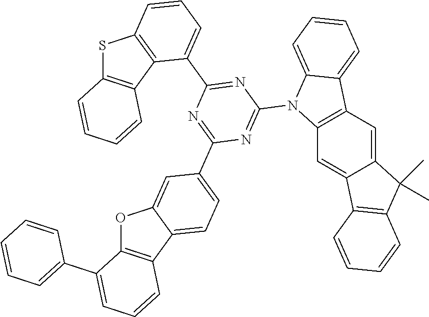 [SMILES: CC1(C)c2ccccc2-c2cc3c(cc21)c1ccccc1n3-c1nc(-c2ccc3c(c2)oc2c(-c4ccccc4)cccc23)nc(-c2cccc3sc4ccccc4c23)n1]

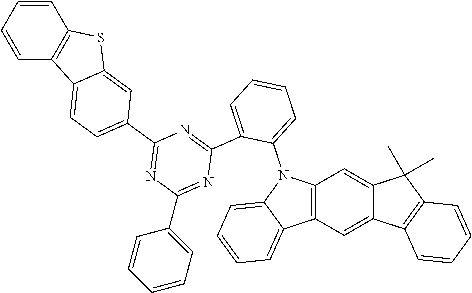 [SMILES: CC1(C)c2ccccc2-c2cc3c4ccccc4n(-c4ccccc4-c4nc(-c5ccccc5)nc(-c5ccc6c(c5)sc5ccccc56)n4)c3cc21]

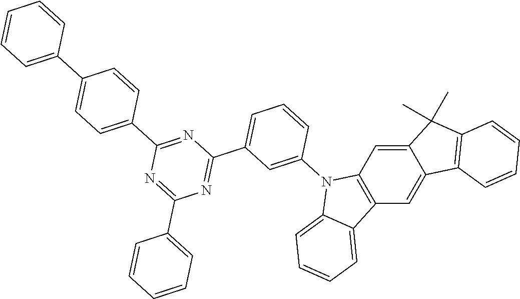 [SMILES: CC1(C)c2ccccc2-c2cc3c4ccccc4n(-c4cccc(-c5nc(-c6ccccc6)nc(-c6ccc(-c7ccccc7)cc6)n5)c4)c3cc21]

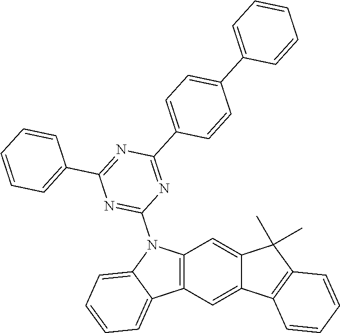 [SMILES: CC1(C)c2ccccc2-c2cc3c4ccccc4n(-c4nc(-c5ccccc5)nc(-c5ccc(-c6ccccc6)cc5)n4)c3cc21]

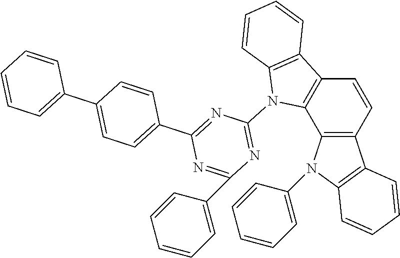 [SMILES: c1ccc(-c2ccc(-c3nc(-c4ccccc4)nc(-n4c5ccccc5c5ccc6c7ccccc7n(-c7ccccc7)c6c54)n3)cc2)cc1]

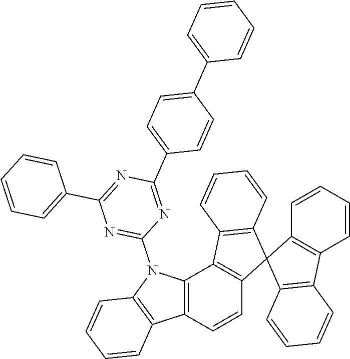 [SMILES: c1ccc(-c2ccc(-c3nc(-c4ccccc4)nc(-n4c5ccccc5c5ccc6c(c54)-c4ccccc4C64c5ccccc5-c5ccccc54)n3)cc2)cc1]

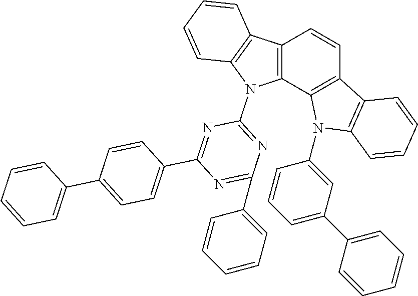 [SMILES: c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1]

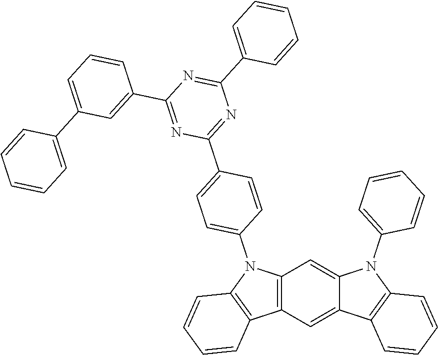 [SMILES: c1ccc(-c2cccc(-c3nc(-c4ccccc4)nc(-c4ccc(-n5c6ccccc6c6cc7c8ccccc8n(-c8ccccc8)c7cc65)cc4)n3)c2)cc1]

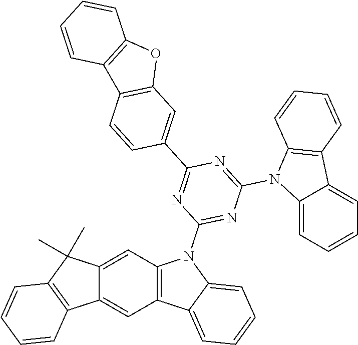 [SMILES: CC1(C)c2ccccc2-c2cc3c4ccccc4n(-c4nc(-c5ccc6c(c5)oc5ccccc56)nc(-n5c6ccccc6c6ccccc65)n4)c3cc21]

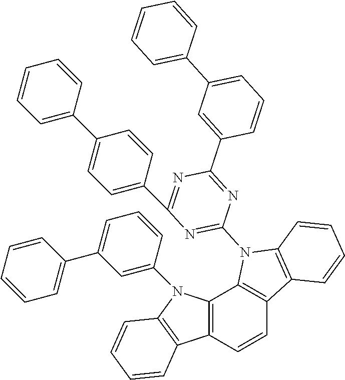 [SMILES: c1ccc(-c2ccc(-c3nc(-c4cccc(-c5ccccc5)c4)nc(-n4c5ccccc5c5ccc6c7ccccc7n(-c7cccc(-c8ccccc8)c7)c6c54)n3)cc2)cc1]

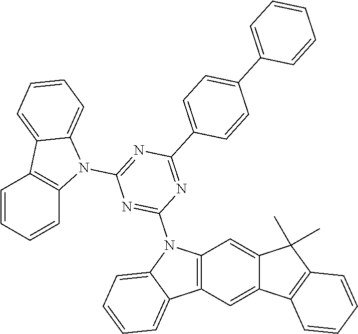 [SMILES: CC1(C)c2ccccc2-c2cc3c4ccccc4n(-c4nc(-c5ccc(-c6ccccc6)cc5)nc(-n5c6ccccc6c6ccccc65)n4)c3cc21]

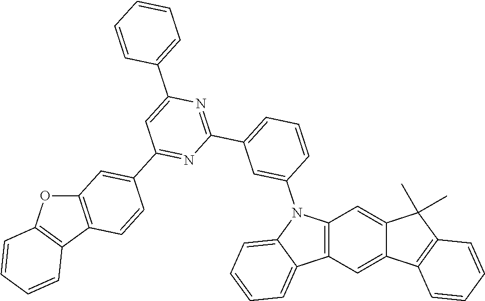 [SMILES: CC1(C)c2ccccc2-c2cc3c4ccccc4n(-c4cccc(-c5nc(-c6ccccc6)cc(-c6ccc7c(c6)oc6ccccc67)n5)c4)c3cc21]

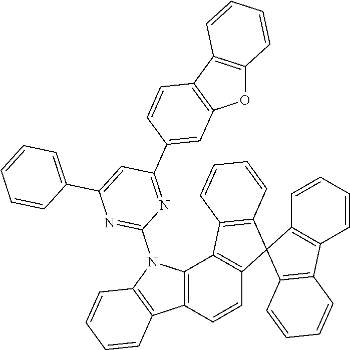 [SMILES: c1ccc(-c2cc(-c3ccc4c(c3)oc3ccccc34)nc(-n3c4ccccc4c4ccc5c(c43)-c3ccccc3C53c4ccccc4-c4ccccc43)n2)cc1]

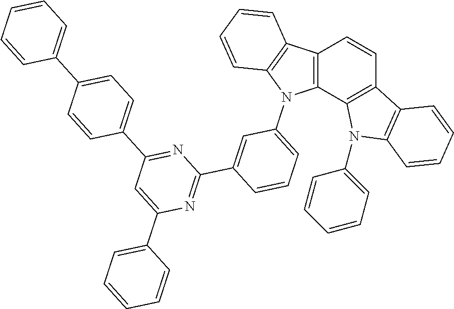 [SMILES: c1ccc(-c2ccc(-c3cc(-c4ccccc4)nc(-c4cccc(-n5c6ccccc6c6ccc7c8ccccc8n(-c8ccccc8)c7c65)c4)n3)cc2)cc1]

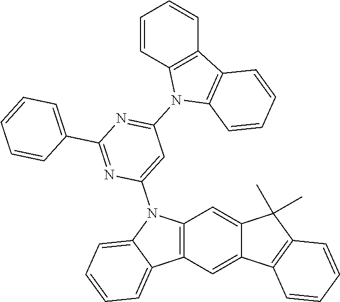 [SMILES: CC1(C)c2ccccc2-c2cc3c4ccccc4n(-c4cc(-n5c6ccccc6c6ccccc65)nc(-c5ccccc5)n4)c3cc21]

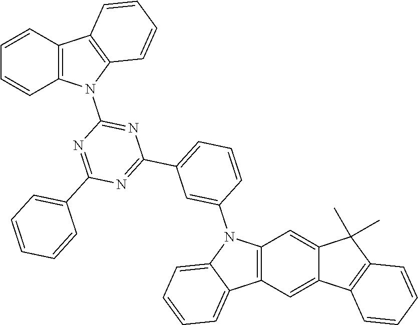 [SMILES: CC1(C)c2ccccc2-c2cc3c4ccccc4n(-c4cccc(-c5nc(-c6ccccc6)nc(-n6c7ccccc7c7ccccc76)n5)c4)c3cc21]

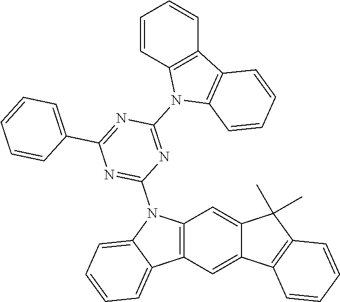 [SMILES: CC1(C)c2ccccc2-c2cc3c4ccccc4n(-c4nc(-c5ccccc5)nc(-n5c6ccccc6c6ccccc65)n4)c3cc21]

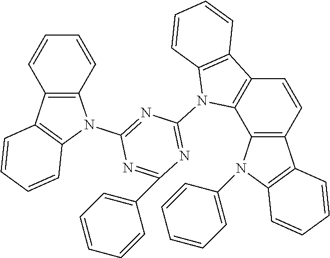 [SMILES: c1ccc(-c2nc(-n3c4ccccc4c4ccccc43)nc(-n3c4ccccc4c4ccc5c6ccccc6n(-c6ccccc6)c5c43)n2)cc1]

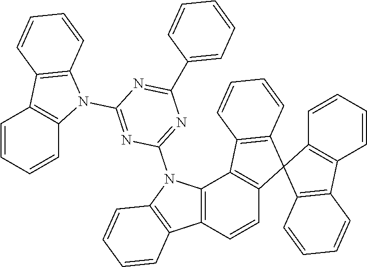 [SMILES: c1ccc(-c2nc(-n3c4ccccc4c4ccccc43)nc(-n3c4ccccc4c4ccc5c(c43)-c3ccccc3C53c4ccccc4-c4ccccc43)n2)cc1]

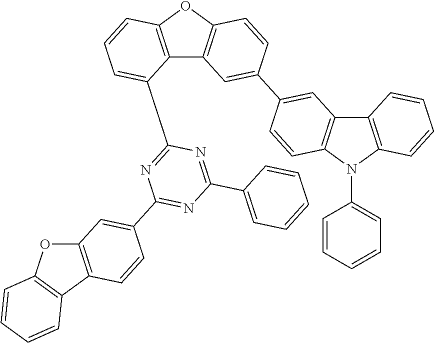 [SMILES: c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1]

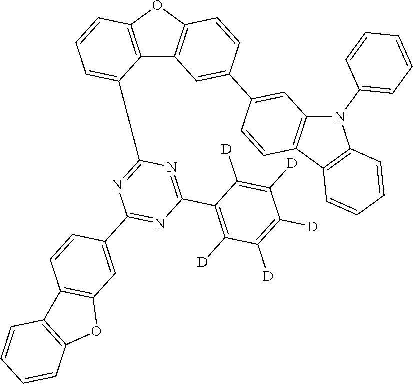 [SMILES: [2H]c1c([2H])c([2H])c(-c2nc(-c3ccc4c(c3)oc3ccccc34)nc(-c3cccc4oc5ccc(-c6ccc7c8ccccc8n(-c8ccccc8)c7c6)cc5c34)n2)c([2H])c1[2H]]

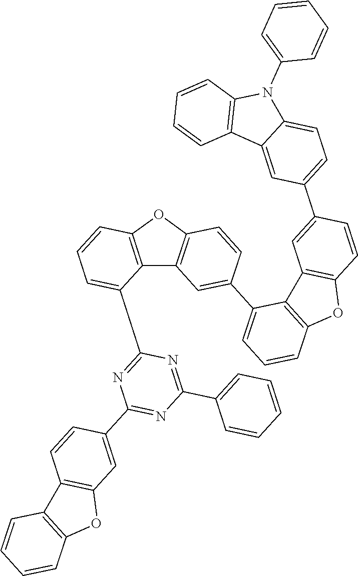 [SMILES: c1ccc(-c2nc(-c3ccc4c(c3)oc3ccccc34)nc(-c3cccc4oc5ccc(-c6cccc7oc8ccc(-c9ccc%10c(c9)c9ccccc9n%10-c9ccccc9)cc8c67)cc5c34)n2)cc1]

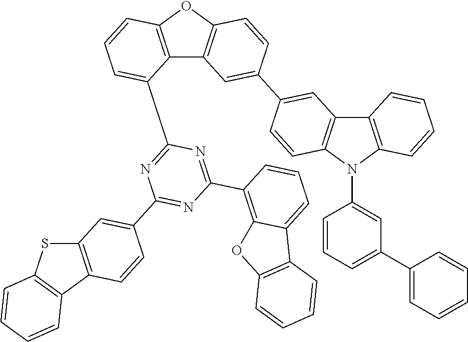 [SMILES: c1ccc(-c2cccc(-n3c4ccccc4c4cc(-c5ccc6oc7cccc(-c8nc(-c9ccc%10c(c9)sc9ccccc9%10)nc(-c9cccc%10c9oc9ccccc9%10)n8)c7c6c5)ccc43)c2)cc1]

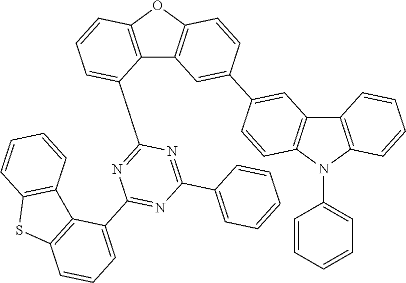 [SMILES: c1ccc(-c2nc(-c3cccc4oc5ccc(-c6ccc7c(c6)c6ccccc6n7-c6ccccc6)cc5c34)nc(-c3cccc4sc5ccccc5c34)n2)cc1]

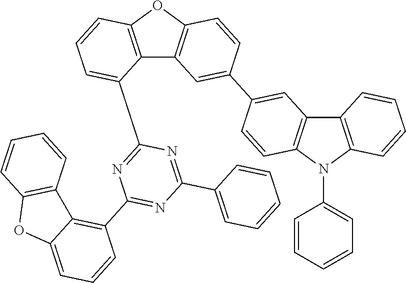 [SMILES: c1ccc(-c2nc(-c3cccc4oc5ccccc5c34)nc(-c3cccc4oc5ccc(-c6ccc7c(c6)c6ccccc6n7-c6ccccc6)cc5c34)n2)cc1]

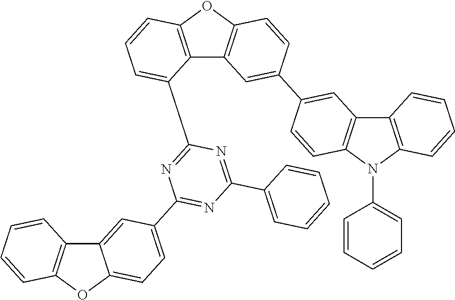 [SMILES: c1ccc(-c2nc(-c3ccc4oc5ccccc5c4c3)nc(-c3cccc4oc5ccc(-c6ccc7c(c6)c6ccccc6n7-c6ccccc6)cc5c34)n2)cc1]

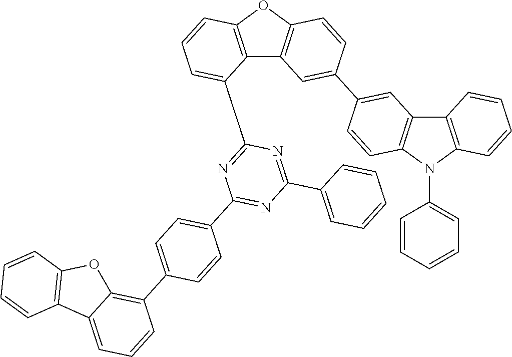 [SMILES: c1ccc(-c2nc(-c3ccc(-c4cccc5c4oc4ccccc45)cc3)nc(-c3cccc4oc5ccc(-c6ccc7c(c6)c6ccccc6n7-c6ccccc6)cc5c34)n2)cc1]

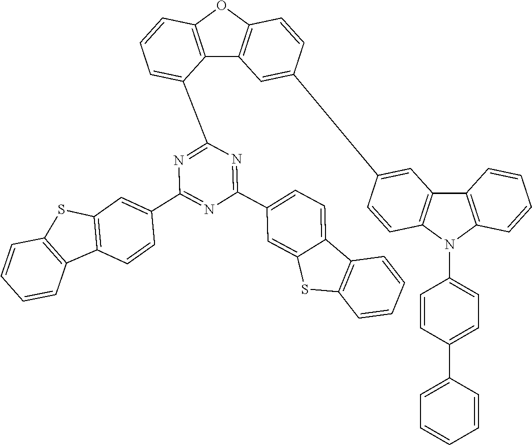 [SMILES: c1ccc(-c2ccc(-n3c4ccccc4c4cc(-c5ccc6oc7cccc(-c8nc(-c9ccc%10c(c9)sc9ccccc9%10)nc(-c9ccc%10c(c9)sc9ccccc9%10)n8)c7c6c5)ccc43)cc2)cc1]

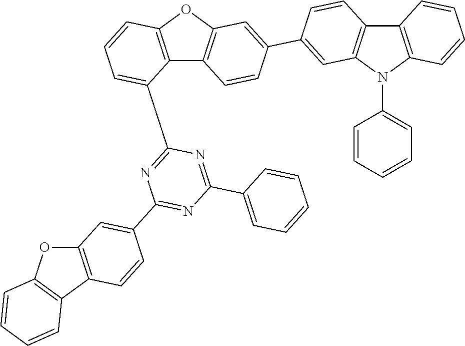 [SMILES: c1ccc(-c2nc(-c3ccc4c(c3)oc3ccccc34)nc(-c3cccc4oc5cc(-c6ccc7c8ccccc8n(-c8ccccc8)c7c6)ccc5c34)n2)cc1]

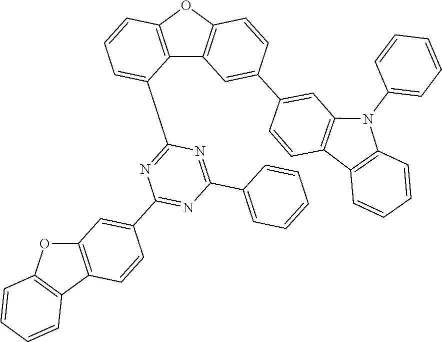 [SMILES: c1ccc(-c2nc(-c3ccc4c(c3)oc3ccccc34)nc(-c3cccc4oc5ccc(-c6ccc7c8ccccc8n(-c8ccccc8)c7c6)cc5c34)n2)cc1]

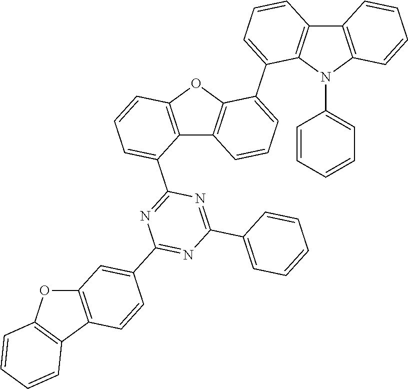 [SMILES: c1ccc(-c2nc(-c3ccc4c(c3)oc3ccccc34)nc(-c3cccc4oc5c(-c6cccc7c8ccccc8n(-c8ccccc8)c67)cccc5c34)n2)cc1]

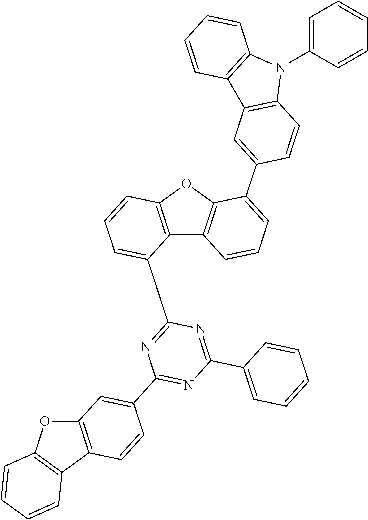 [SMILES: c1ccc(-c2nc(-c3ccc4c(c3)oc3ccccc34)nc(-c3cccc4oc5c(-c6ccc7c(c6)c6ccccc6n7-c6ccccc6)cccc5c34)n2)cc1]

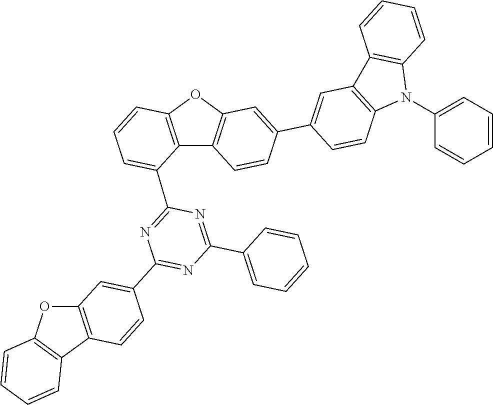 [SMILES: c1ccc(-c2nc(-c3ccc4c(c3)oc3ccccc34)nc(-c3cccc4oc5cc(-c6ccc7c(c6)c6ccccc6n7-c6ccccc6)ccc5c34)n2)cc1]

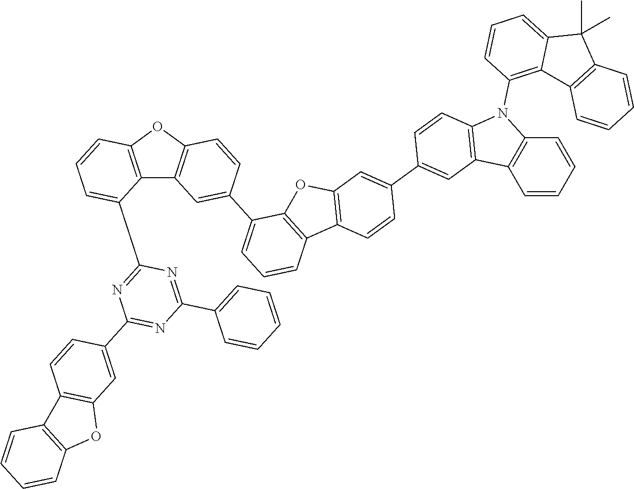 [SMILES: CC1(C)c2ccccc2-c2c(-n3c4ccccc4c4cc(-c5ccc6c(c5)oc5c(-c7ccc8oc9cccc(-c%10nc(-c%11ccccc%11)nc(-c%11ccc%12c(c%11)oc%11ccccc%11%12)n%10)c9c8c7)cccc56)ccc43)cccc21]

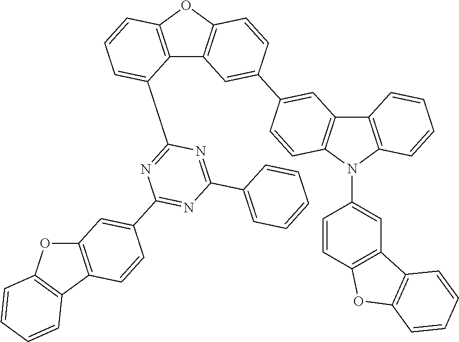 [SMILES: c1ccc(-c2nc(-c3ccc4c(c3)oc3ccccc34)nc(-c3cccc4oc5ccc(-c6ccc7c(c6)c6ccccc6n7-c6ccc7oc8ccccc8c7c6)cc5c34)n2)cc1]

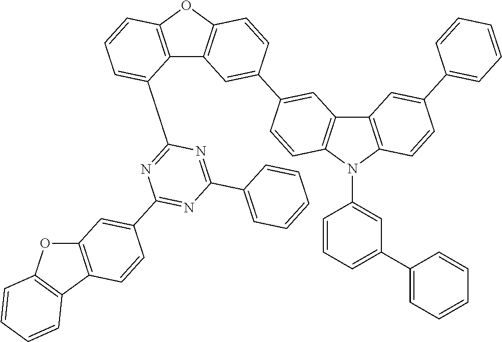 [SMILES: c1ccc(-c2cccc(-n3c4ccc(-c5ccccc5)cc4c4cc(-c5ccc6oc7cccc(-c8nc(-c9ccccc9)nc(-c9ccc%10c(c9)oc9ccccc9%10)n8)c7c6c5)ccc43)c2)cc1]

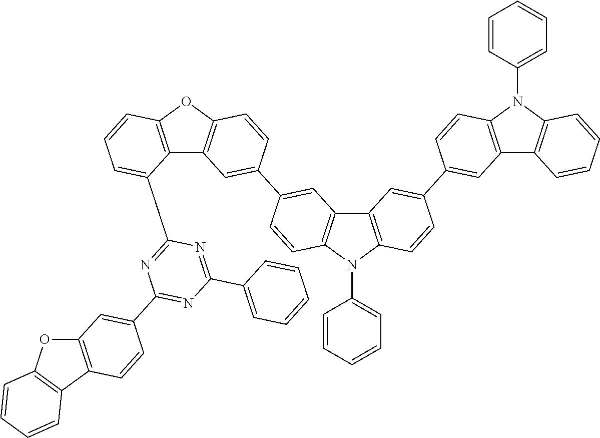 [SMILES: c1ccc(-c2nc(-c3ccc4c(c3)oc3ccccc34)nc(-c3cccc4oc5ccc(-c6ccc7c(c6)c6cc(-c8ccc9c(c8)c8ccccc8n9-c8ccccc8)ccc6n7-c6ccccc6)cc5c34)n2)cc1]

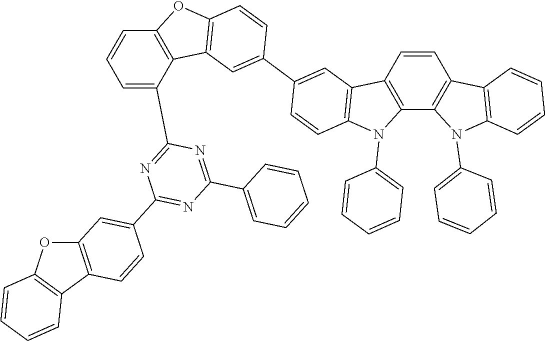 [SMILES: c1ccc(-c2nc(-c3ccc4c(c3)oc3ccccc34)nc(-c3cccc4oc5ccc(-c6ccc7c(c6)c6ccc8c9ccccc9n(-c9ccccc9)c8c6n7-c6ccccc6)cc5c34)n2)cc1]

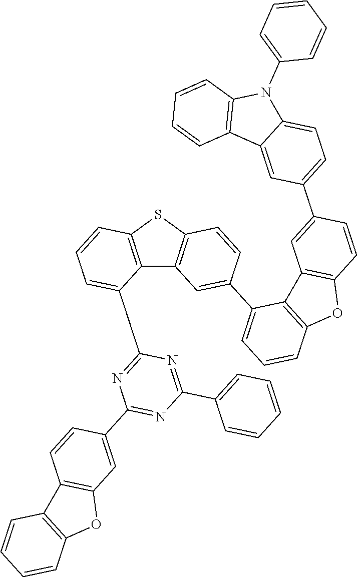 [SMILES: c1ccc(-c2nc(-c3ccc4c(c3)oc3ccccc34)nc(-c3cccc4sc5ccc(-c6cccc7oc8ccc(-c9ccc%10c(c9)c9ccccc9n%10-c9ccccc9)cc8c67)cc5c34)n2)cc1]

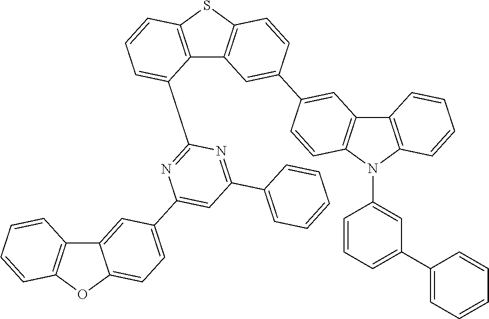 [SMILES: c1ccc(-c2cccc(-n3c4ccccc4c4cc(-c5ccc6sc7cccc(-c8nc(-c9ccccc9)cc(-c9ccc%10oc%11ccccc%11c%10c9)n8)c7c6c5)ccc43)c2)cc1]

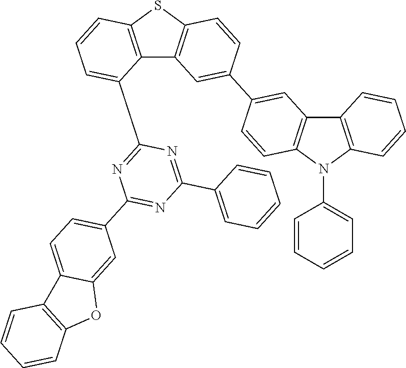 [SMILES: c1ccc(-c2nc(-c3ccc4c(c3)oc3ccccc34)nc(-c3cccc4sc5ccc(-c6ccc7c(c6)c6ccccc6n7-c6ccccc6)cc5c34)n2)cc1]

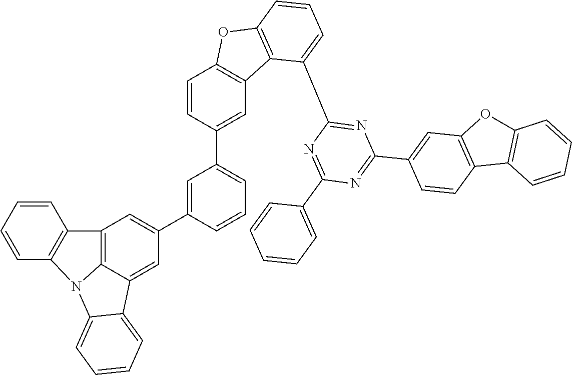 [SMILES: c1ccc(-c2nc(-c3ccc4c(c3)oc3ccccc34)nc(-c3cccc4oc5ccc(-c6cccc(-c7cc8c9ccccc9n9c%10ccccc%10c(c7)c89)c6)cc5c34)n2)cc1]

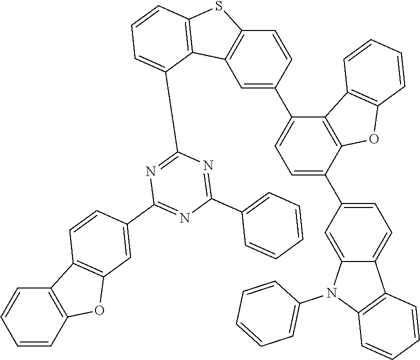 [SMILES: c1ccc(-c2nc(-c3ccc4c(c3)oc3ccccc34)nc(-c3cccc4sc5ccc(-c6ccc(-c7ccc8c9ccccc9n(-c9ccccc9)c8c7)c7oc8ccccc8c67)cc5c34)n2)cc1]

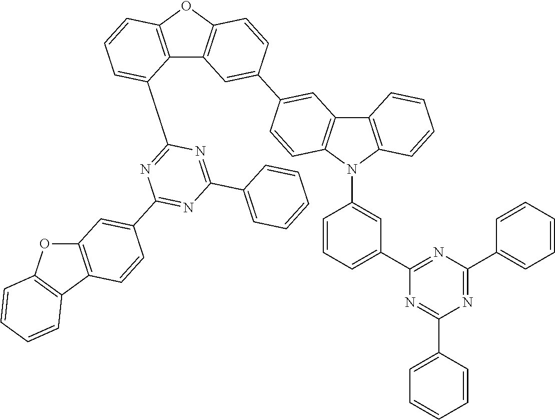 [SMILES: c1ccc(-c2nc(-c3ccccc3)nc(-c3cccc(-n4c5ccccc5c5cc(-c6ccc7oc8cccc(-c9nc(-c%10ccccc%10)nc(-c%10ccc%11c(c%10)oc%10ccccc%10%11)n9)c8c7c6)ccc54)c3)n2)cc1]

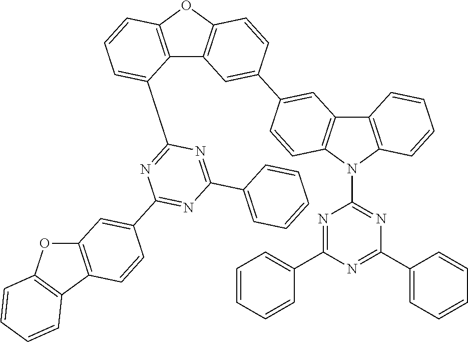 [SMILES: c1ccc(-c2nc(-c3ccc4c(c3)oc3ccccc34)nc(-c3cccc4oc5ccc(-c6ccc7c(c6)c6ccccc6n7-c6nc(-c7ccccc7)nc(-c7ccccc7)n6)cc5c34)n2)cc1]

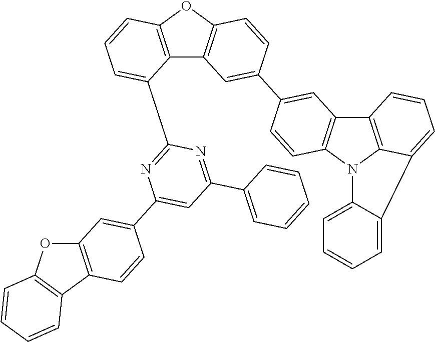 [SMILES: c1ccc(-c2cc(-c3ccc4c(c3)oc3ccccc34)nc(-c3cccc4oc5ccc(-c6ccc7c(c6)c6cccc8c9ccccc9n7c86)cc5c34)n2)cc1]

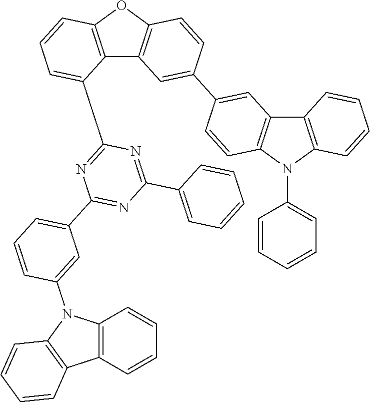 [SMILES: c1ccc(-c2nc(-c3cccc(-n4c5ccccc5c5ccccc54)c3)nc(-c3cccc4oc5ccc(-c6ccc7c(c6)c6ccccc6n7-c6ccccc6)cc5c34)n2)cc1]

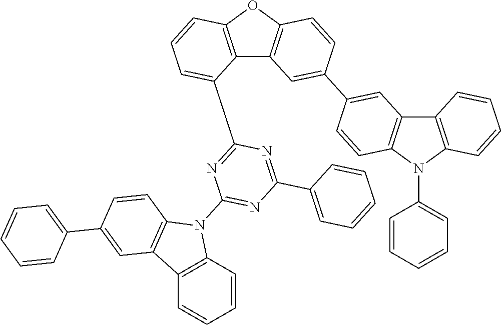 [SMILES: c1ccc(-c2ccc3c(c2)c2ccccc2n3-c2nc(-c3ccccc3)nc(-c3cccc4oc5ccc(-c6ccc7c(c6)c6ccccc6n7-c6ccccc6)cc5c34)n2)cc1]

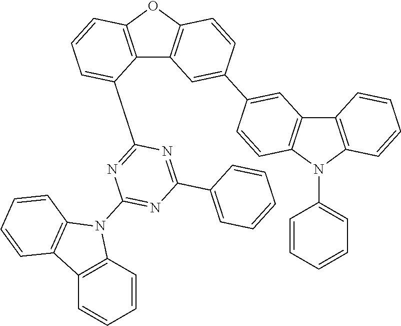 [SMILES: c1ccc(-c2nc(-c3cccc4oc5ccc(-c6ccc7c(c6)c6ccccc6n7-c6ccccc6)cc5c34)nc(-n3c4ccccc4c4ccccc43)n2)cc1]

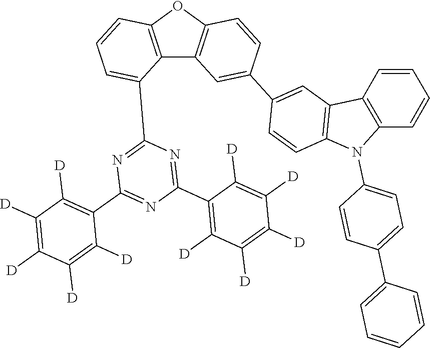 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc(-c7ccccc7)cc6)cc5c34)n2)c([2H])c1[2H]]

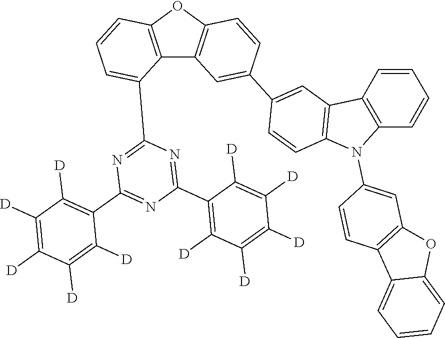 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc7c(c6)oc6ccccc67)cc5c34)n2)c([2H])c1[2H]]

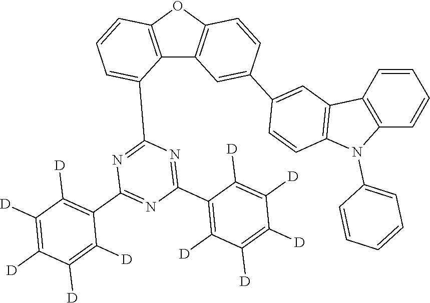 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccccc6)cc5c34)n2)c([2H])c1[2H]]

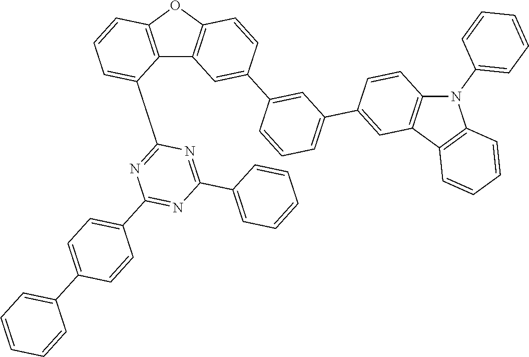 [SMILES: c1ccc(-c2ccc(-c3nc(-c4ccccc4)nc(-c4cccc5oc6ccc(-c7cccc(-c8ccc9c(c8)c8ccccc8n9-c8ccccc8)c7)cc6c45)n3)cc2)cc1]

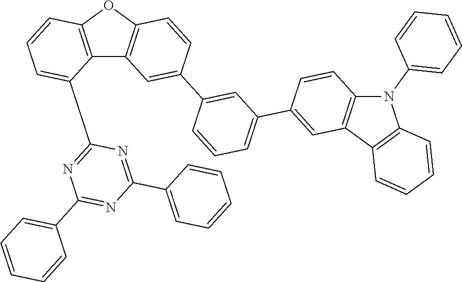 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

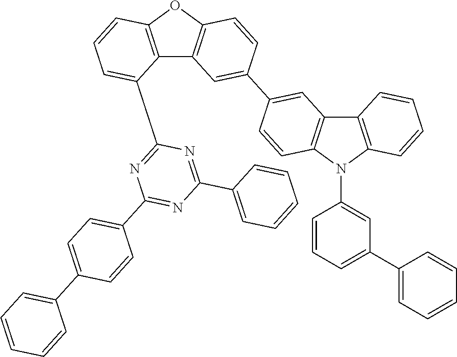 [SMILES: c1ccc(-c2ccc(-c3nc(-c4ccccc4)nc(-c4cccc5oc6ccc(-c7ccc8c(c7)c7ccccc7n8-c7cccc(-c8ccccc8)c7)cc6c45)n3)cc2)cc1]

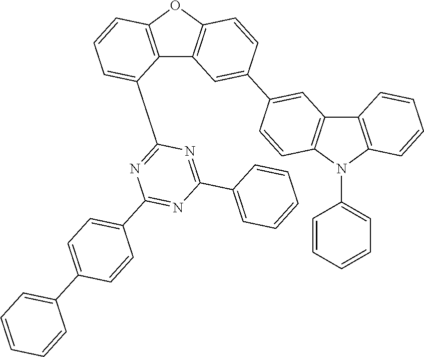 [SMILES: c1ccc(-c2ccc(-c3nc(-c4ccccc4)nc(-c4cccc5oc6ccc(-c7ccc8c(c7)c7ccccc7n8-c7ccccc7)cc6c45)n3)cc2)cc1]

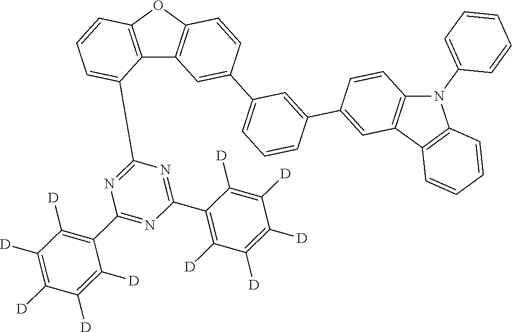 [SMILES: [2H]c1c([2H])c([2H])c(-c2nc(-c3c([2H])c([2H])c([2H])c([2H])c3[2H])nc(-c3cccc4oc5ccc(-c6cccc(-c7ccc8c(c7)c7ccccc7n8-c7ccccc7)c6)cc5c34)n2)c([2H])c1[2H]]

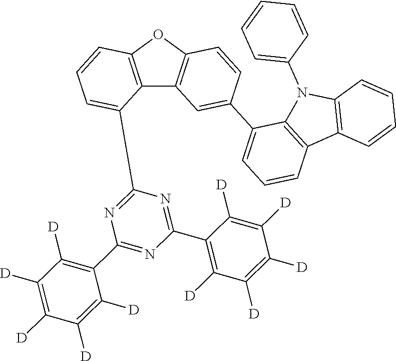 [SMILES: [2H]c1c([2H])c([2H])c(-c2nc(-c3c([2H])c([2H])c([2H])c([2H])c3[2H])nc(-c3cccc4oc5ccc(-c6cccc7c8ccccc8n(-c8ccccc8)c67)cc5c34)n2)c([2H])c1[2H]]

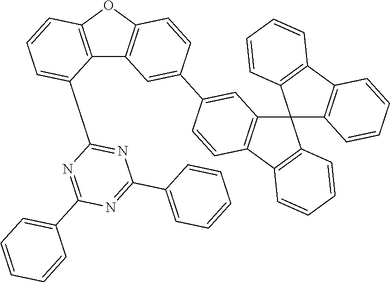 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1]

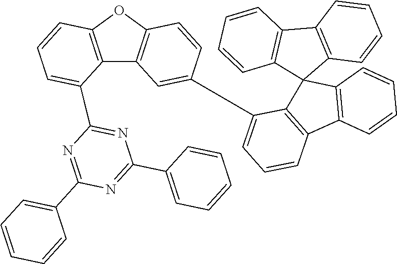 [SMILES: c1ccc(-c2nc(-c3ccccc3)nc(-c3cccc4oc5ccc(-c6cccc7c6C6(c8ccccc8-c8ccccc86)c6ccccc6-7)cc5c34)n2)cc1]

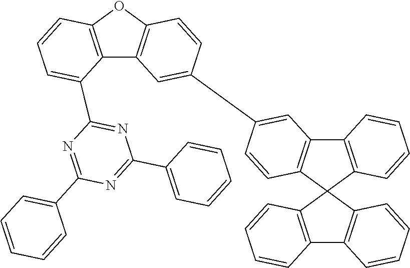 [SMILES: c1ccc(-c2nc(-c3ccccc3)nc(-c3cccc4oc5ccc(-c6ccc7c(c6)-c6ccccc6C76c7ccccc7-c7ccccc76)cc5c34)n2)cc1]

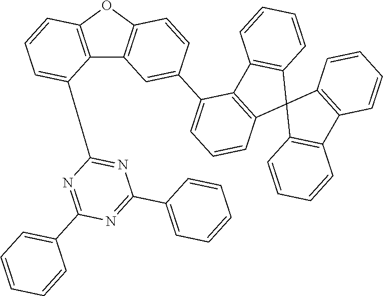 [SMILES: c1ccc(-c2nc(-c3ccccc3)nc(-c3cccc4oc5ccc(-c6cccc7c6-c6ccccc6C76c7ccccc7-c7ccccc76)cc5c34)n2)cc1]

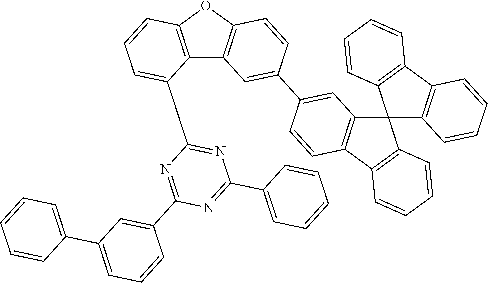 [SMILES: c1ccc(-c2cccc(-c3nc(-c4ccccc4)nc(-c4cccc5oc6ccc(-c7ccc8c(c7)C7(c9ccccc9-c9ccccc97)c7ccccc7-8)cc6c45)n3)c2)cc1]

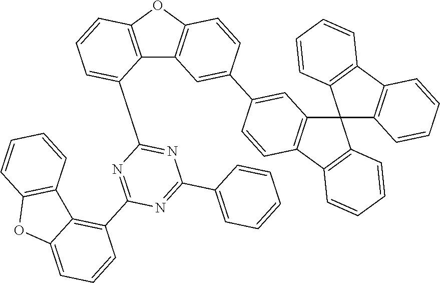 [SMILES: c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1]

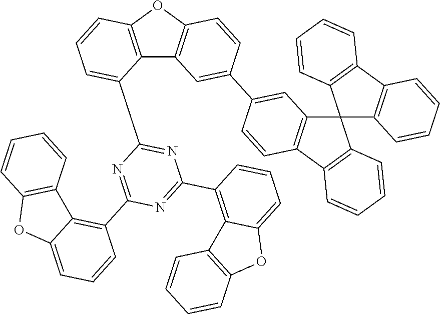 [SMILES: c1ccc2c(c1)-c1ccccc1C21c2ccccc2-c2ccc(-c3ccc4oc5cccc(-c6nc(-c7cccc8oc9ccccc9c78)nc(-c7cccc8oc9ccccc9c78)n6)c5c4c3)cc21]

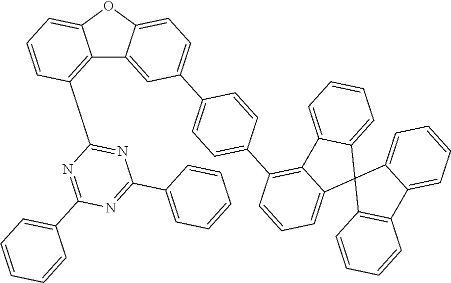 [SMILES: c1ccc(-c2nc(-c3ccccc3)nc(-c3cccc4oc5ccc(-c6ccc(-c7cccc8c7-c7ccccc7C87c8ccccc8-c8ccccc87)cc6)cc5c34)n2)cc1]

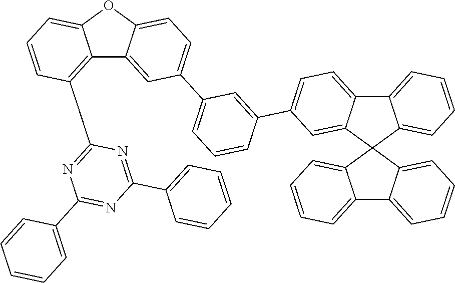 [SMILES: c1ccc(-c2nc(-c3ccccc3)nc(-c3cccc4oc5ccc(-c6cccc(-c7ccc8c(c7)C7(c9ccccc9-c9ccccc97)c7ccccc7-8)c6)cc5c34)n2)cc1]

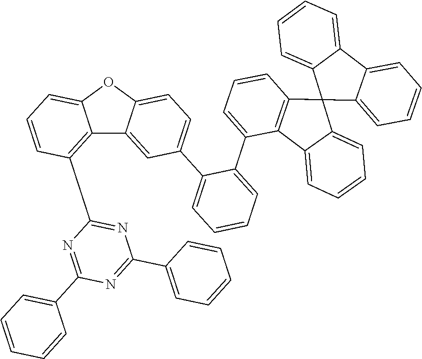 [SMILES: c1ccc(-c2nc(-c3ccccc3)nc(-c3cccc4oc5ccc(-c6ccccc6-c6cccc7c6-c6ccccc6C76c7ccccc7-c7ccccc76)cc5c34)n2)cc1]

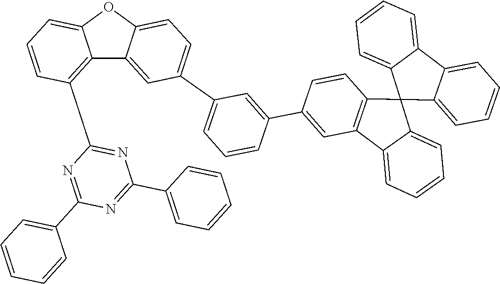 [SMILES: c1ccc(-c2nc(-c3ccccc3)nc(-c3cccc4oc5ccc(-c6cccc(-c7ccc8c(c7)-c7ccccc7C87c8ccccc8-c8ccccc87)c6)cc5c34)n2)cc1]

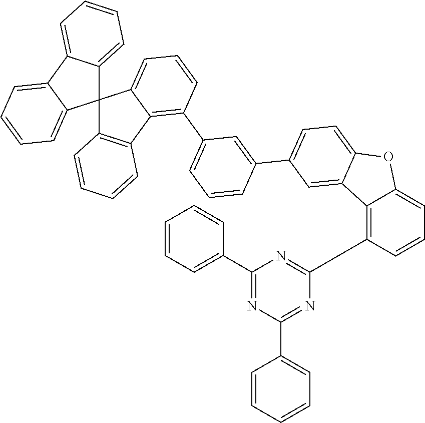 [SMILES: c1ccc(-c2nc(-c3ccccc3)nc(-c3cccc4oc5ccc(-c6cccc(-c7cccc8c7-c7ccccc7C87c8ccccc8-c8ccccc87)c6)cc5c34)n2)cc1]

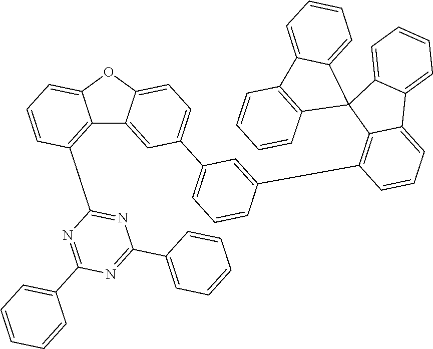 [SMILES: c1ccc(-c2nc(-c3ccccc3)nc(-c3cccc4oc5ccc(-c6cccc(-c7cccc8c7C7(c9ccccc9-c9ccccc97)c7ccccc7-8)c6)cc5c34)n2)cc1]

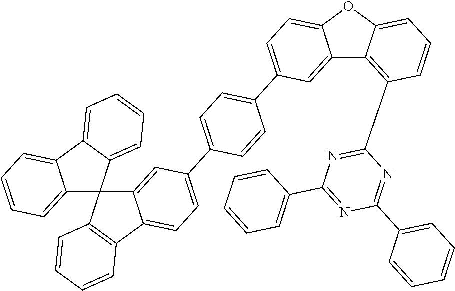 [SMILES: c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1]

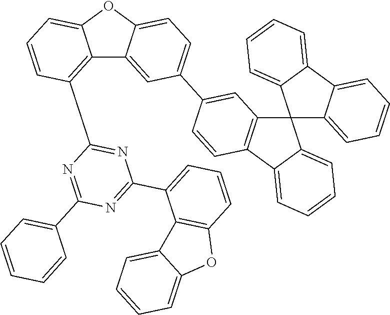 [SMILES: c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1]

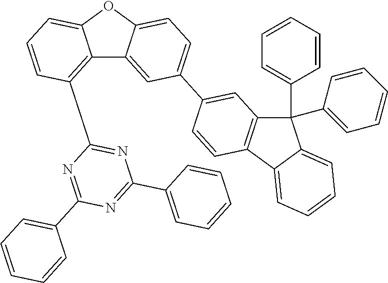 [SMILES: c1ccc(-c2nc(-c3ccccc3)nc(-c3cccc4oc5ccc(-c6ccc7c(c6)C(c6ccccc6)(c6ccccc6)c6ccccc6-7)cc5c34)n2)cc1]

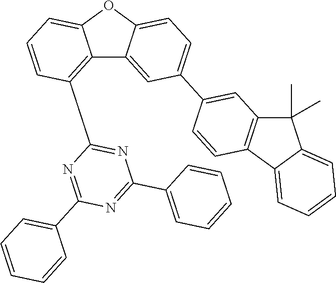 [SMILES: CC1(C)c2ccccc2-c2ccc(-c3ccc4oc5cccc(-c6nc(-c7ccccc7)nc(-c7ccccc7)n6)c5c4c3)cc21]

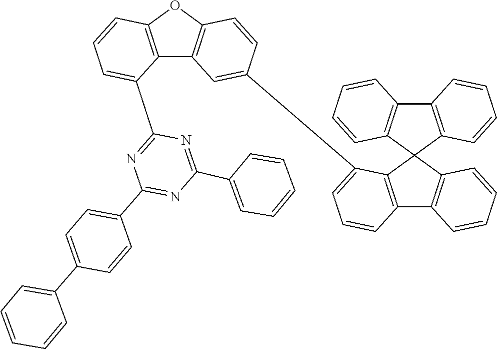 [SMILES: c1ccc(-c2ccc(-c3nc(-c4ccccc4)nc(-c4cccc5oc6ccc(-c7cccc8c7C7(c9ccccc9-c9ccccc97)c7ccccc7-8)cc6c45)n3)cc2)cc1]

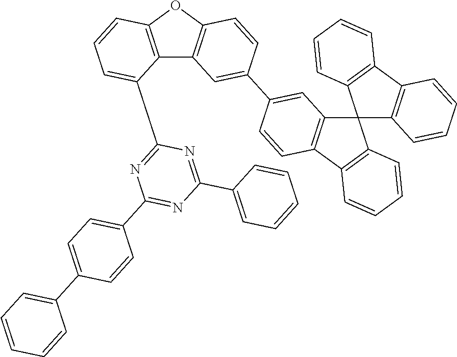 [SMILES: c1ccc(-c2ccc(-c3nc(-c4ccccc4)nc(-c4cccc5oc6ccc(-c7ccc8c(c7)C7(c9ccccc9-c9ccccc97)c7ccccc7-8)cc6c45)n3)cc2)cc1]

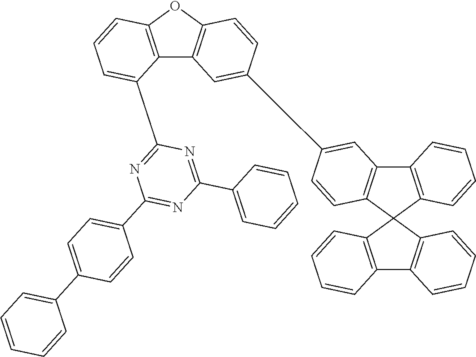 [SMILES: c1ccc(-c2ccc(-c3nc(-c4ccccc4)nc(-c4cccc5oc6ccc(-c7ccc8c(c7)-c7ccccc7C87c8ccccc8-c8ccccc87)cc6c45)n3)cc2)cc1]

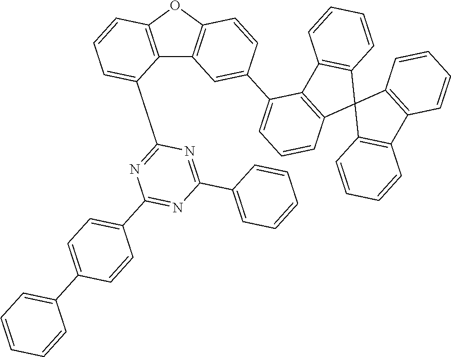 [SMILES: c1ccc(-c2ccc(-c3nc(-c4ccccc4)nc(-c4cccc5oc6ccc(-c7cccc8c7-c7ccccc7C87c8ccccc8-c8ccccc87)cc6c45)n3)cc2)cc1]

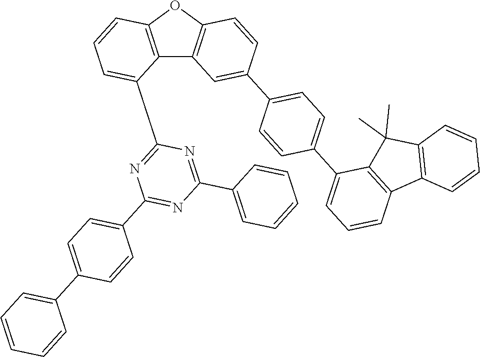 [SMILES: CC1(C)c2ccccc2-c2cccc(-c3ccc(-c4ccc5oc6cccc(-c7nc(-c8ccccc8)nc(-c8ccc(-c9ccccc9)cc8)n7)c6c5c4)cc3)c21]

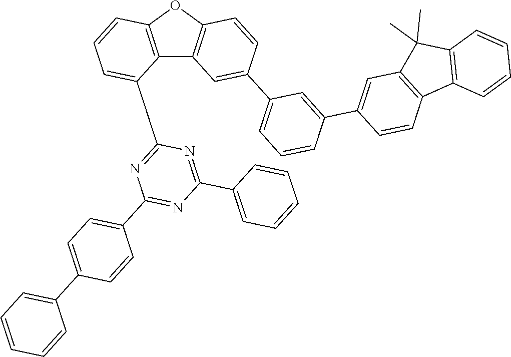 [SMILES: CC1(C)c2ccccc2-c2ccc(-c3cccc(-c4ccc5oc6cccc(-c7nc(-c8ccccc8)nc(-c8ccc(-c9ccccc9)cc8)n7)c6c5c4)c3)cc21]

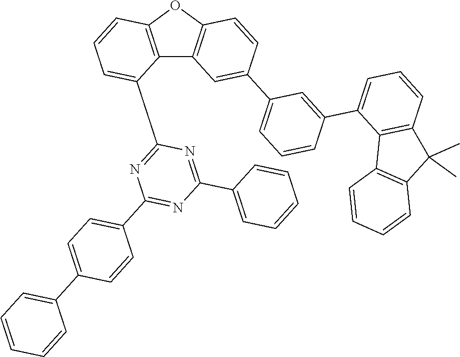 [SMILES: CC1(C)c2ccccc2-c2c(-c3cccc(-c4ccc5oc6cccc(-c7nc(-c8ccccc8)nc(-c8ccc(-c9ccccc9)cc8)n7)c6c5c4)c3)cccc21]

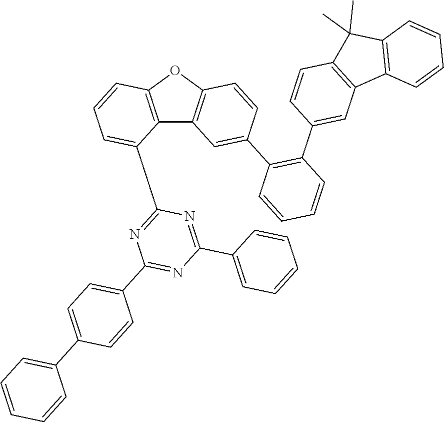 [SMILES: CC1(C)c2ccccc2-c2cc(-c3ccccc3-c3ccc4oc5cccc(-c6nc(-c7ccccc7)nc(-c7ccc(-c8ccccc8)cc7)n6)c5c4c3)ccc21]

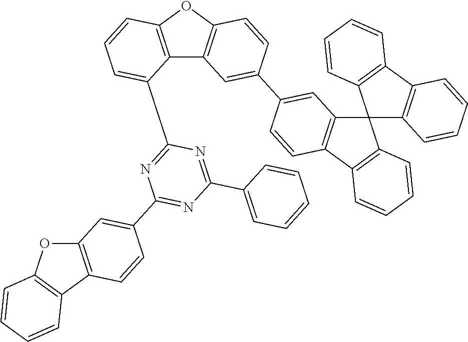 [SMILES: c1ccc(-c2nc(-c3ccc4c(c3)oc3ccccc34)nc(-c3cccc4oc5ccc(-c6ccc7c(c6)C6(c8ccccc8-c8ccccc86)c6ccccc6-7)cc5c34)n2)cc1]

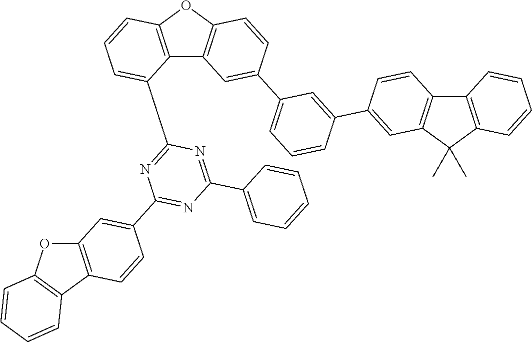 [SMILES: CC1(C)c2ccccc2-c2ccc(-c3cccc(-c4ccc5oc6cccc(-c7nc(-c8ccccc8)nc(-c8ccc9c(c8)oc8ccccc89)n7)c6c5c4)c3)cc21]

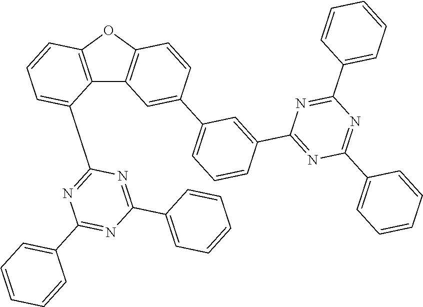 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

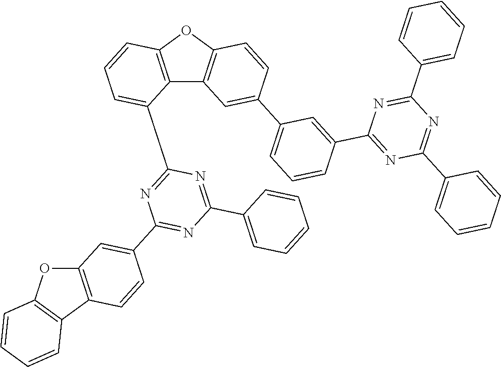 [SMILES: c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1]

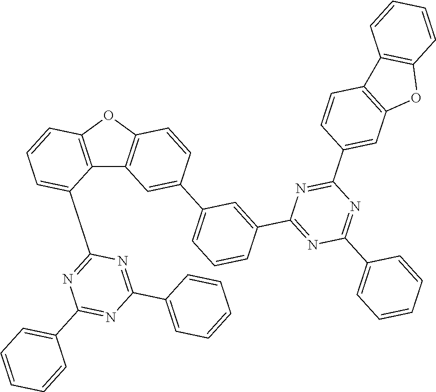 [SMILES: c1ccc(-c2nc(-c3cccc(-c4ccc5oc6cccc(-c7nc(-c8ccccc8)nc(-c8ccccc8)n7)c6c5c4)c3)nc(-c3ccc4c(c3)oc3ccccc34)n2)cc1]

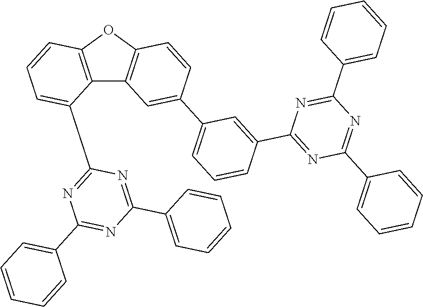 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

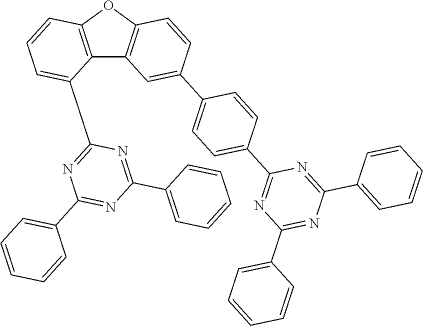 [SMILES: c1ccc(-c2nc(-c3ccccc3)nc(-c3ccc(-c4ccc5oc6cccc(-c7nc(-c8ccccc8)nc(-c8ccccc8)n7)c6c5c4)cc3)n2)cc1]

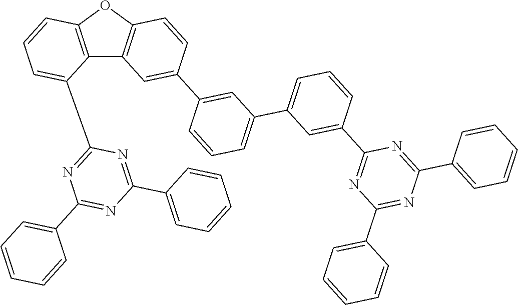 [SMILES: c1ccc(-c2nc(-c3ccccc3)nc(-c3cccc(-c4cccc(-c5ccc6oc7cccc(-c8nc(-c9ccccc9)nc(-c9ccccc9)n8)c7c6c5)c4)c3)n2)cc1]

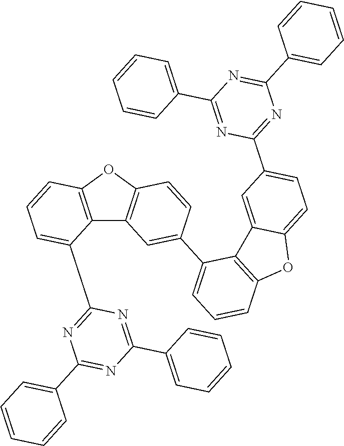 [SMILES: c1ccc(-c2nc(-c3ccccc3)nc(-c3ccc4oc5cccc(-c6ccc7oc8cccc(-c9nc(-c%10ccccc%10)nc(-c%10ccccc%10)n9)c8c7c6)c5c4c3)n2)cc1]

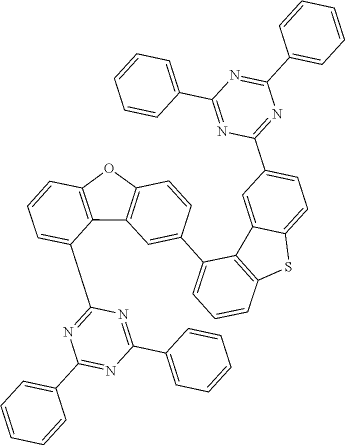 [SMILES: c1ccc(-c2nc(-c3ccccc3)nc(-c3ccc4sc5cccc(-c6ccc7oc8cccc(-c9nc(-c%10ccccc%10)nc(-c%10ccccc%10)n9)c8c7c6)c5c4c3)n2)cc1]

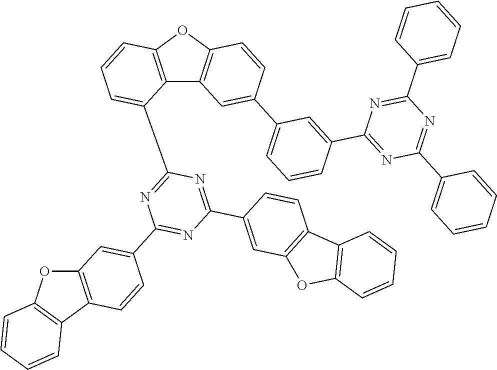 [SMILES: c1ccc(-c2nc(-c3ccccc3)nc(-c3cccc(-c4ccc5oc6cccc(-c7nc(-c8ccc9c(c8)oc8ccccc89)nc(-c8ccc9c(c8)oc8ccccc89)n7)c6c5c4)c3)n2)cc1]

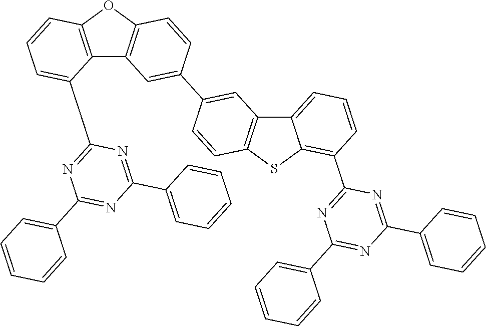 [SMILES: c1ccc(-c2nc(-c3ccccc3)nc(-c3cccc4c3sc3ccc(-c5ccc6oc7cccc(-c8nc(-c9ccccc9)nc(-c9ccccc9)n8)c7c6c5)cc34)n2)cc1]

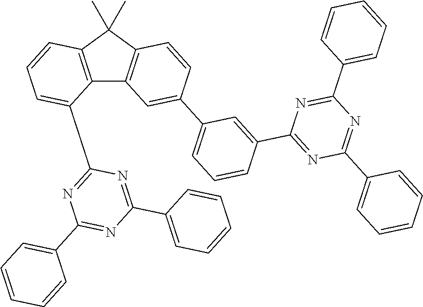 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21]

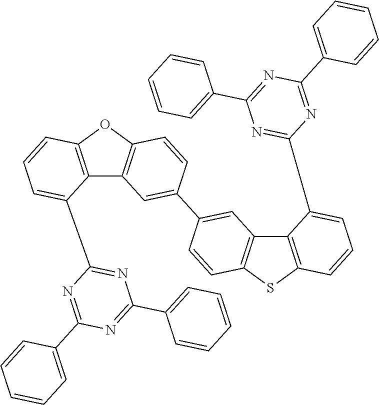 [SMILES: c1ccc(-c2nc(-c3ccccc3)nc(-c3cccc4oc5ccc(-c6ccc7sc8cccc(-c9nc(-c%10ccccc%10)nc(-c%10ccccc%10)n9)c8c7c6)cc5c34)n2)cc1]

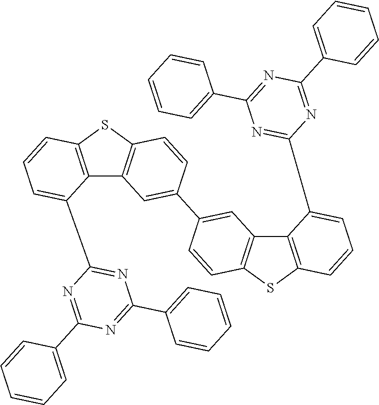 [SMILES: c1ccc(-c2nc(-c3ccccc3)nc(-c3cccc4sc5ccc(-c6ccc7sc8cccc(-c9nc(-c%10ccccc%10)nc(-c%10ccccc%10)n9)c8c7c6)cc5c34)n2)cc1]

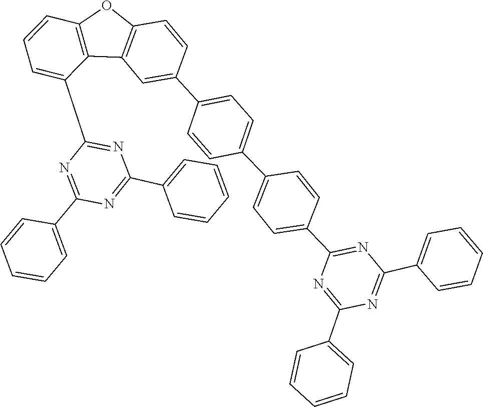 [SMILES: c1ccc(-c2nc(-c3ccccc3)nc(-c3ccc(-c4ccc(-c5ccc6oc7cccc(-c8nc(-c9ccccc9)nc(-c9ccccc9)n8)c7c6c5)cc4)cc3)n2)cc1]

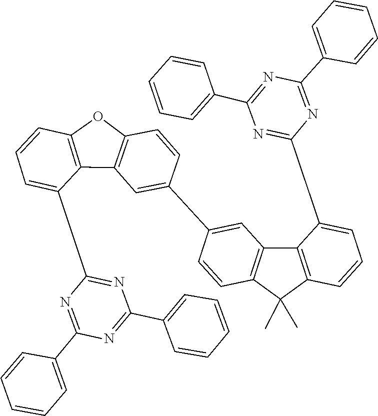 [SMILES: CC1(C)c2ccc(-c3ccc4oc5cccc(-c6nc(-c7ccccc7)nc(-c7ccccc7)n6)c5c4c3)cc2-c2c(-c3nc(-c4ccccc4)nc(-c4ccccc4)n3)cccc21]

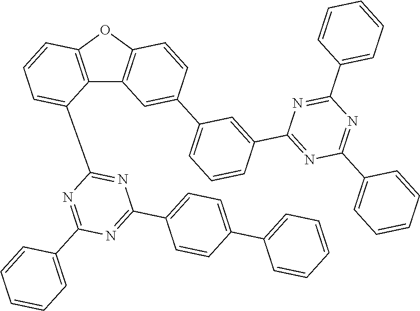 [SMILES: c1ccc(-c2ccc(-c3nc(-c4ccccc4)nc(-c4cccc5oc6ccc(-c7cccc(-c8nc(-c9ccccc9)nc(-c9ccccc9)n8)c7)cc6c45)n3)cc2)cc1]

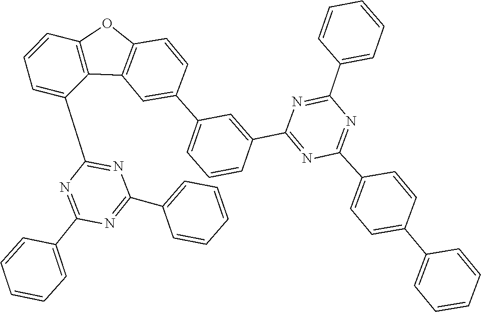 [SMILES: c1ccc(-c2ccc(-c3nc(-c4ccccc4)nc(-c4cccc(-c5ccc6oc7cccc(-c8nc(-c9ccccc9)nc(-c9ccccc9)n8)c7c6c5)c4)n3)cc2)cc1]

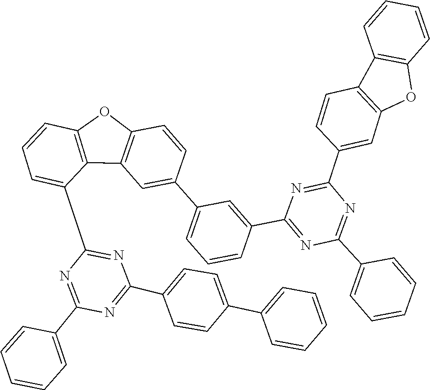 [SMILES: c1ccc(-c2ccc(-c3nc(-c4ccccc4)nc(-c4cccc5oc6ccc(-c7cccc(-c8nc(-c9ccccc9)nc(-c9ccc%10c(c9)oc9ccccc9%10)n8)c7)cc6c45)n3)cc2)cc1]

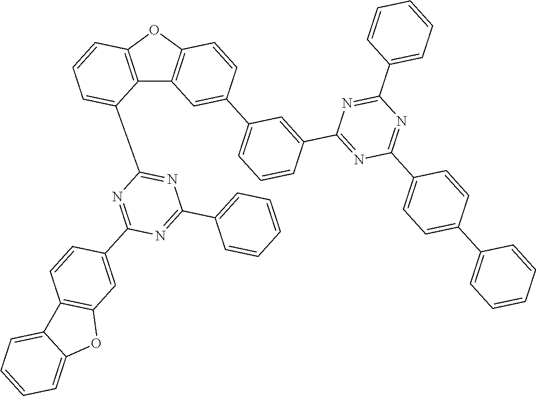 [SMILES: c1ccc(-c2ccc(-c3nc(-c4ccccc4)nc(-c4cccc(-c5ccc6oc7cccc(-c8nc(-c9ccccc9)nc(-c9ccc%10c(c9)oc9ccccc9%10)n8)c7c6c5)c4)n3)cc2)cc1]

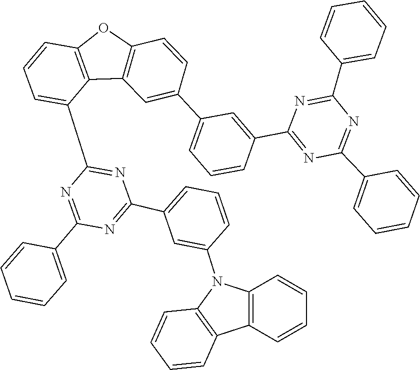 [SMILES: c1ccc(-c2nc(-c3ccccc3)nc(-c3cccc(-c4ccc5oc6cccc(-c7nc(-c8ccccc8)nc(-c8cccc(-n9c%10ccccc%10c%10ccccc%109)c8)n7)c6c5c4)c3)n2)cc1]

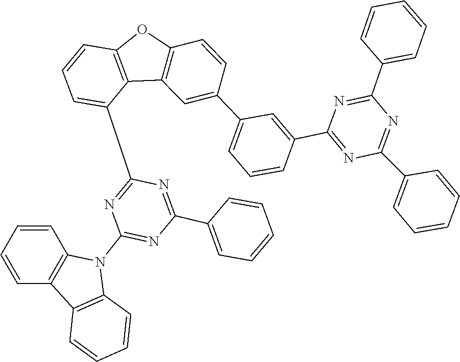 [SMILES: c1ccc(-c2nc(-c3ccccc3)nc(-c3cccc(-c4ccc5oc6cccc(-c7nc(-c8ccccc8)nc(-n8c9ccccc9c9ccccc98)n7)c6c5c4)c3)n2)cc1]

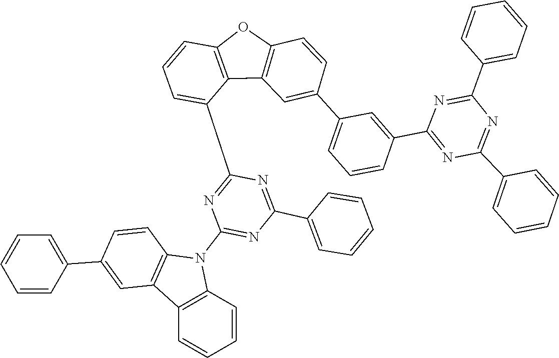 [SMILES: c1ccc(-c2ccc3c(c2)c2ccccc2n3-c2nc(-c3ccccc3)nc(-c3cccc4oc5ccc(-c6cccc(-c7nc(-c8ccccc8)nc(-c8ccccc8)n7)c6)cc5c34)n2)cc1]

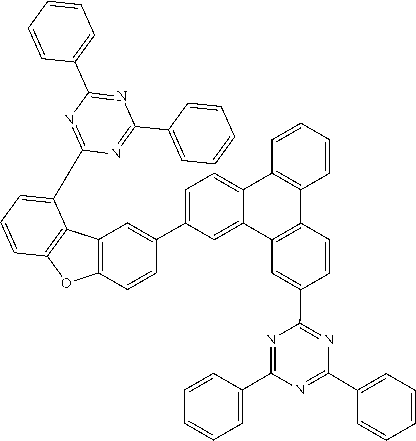 [SMILES: c1ccc(-c2nc(-c3ccccc3)nc(-c3ccc4c5ccccc5c5ccc(-c6ccc7oc8cccc(-c9nc(-c%10ccccc%10)nc(-c%10ccccc%10)n9)c8c7c6)cc5c4c3)n2)cc1]

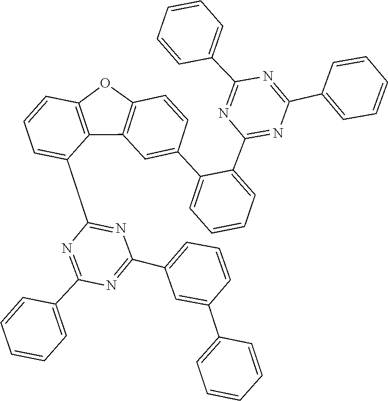 [SMILES: c1ccc(-c2cccc(-c3nc(-c4ccccc4)nc(-c4cccc5oc6ccc(-c7ccccc7-c7nc(-c8ccccc8)nc(-c8ccccc8)n7)cc6c45)n3)c2)cc1]

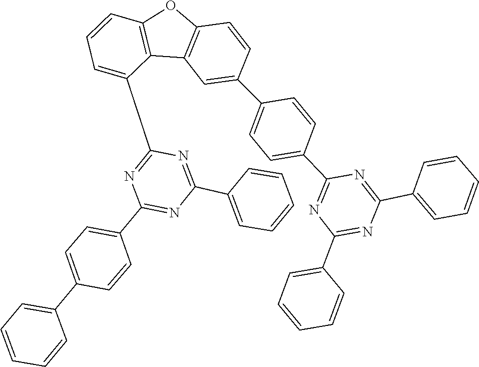 [SMILES: c1ccc(-c2ccc(-c3nc(-c4ccccc4)nc(-c4cccc5oc6ccc(-c7ccc(-c8nc(-c9ccccc9)nc(-c9ccccc9)n8)cc7)cc6c45)n3)cc2)cc1]

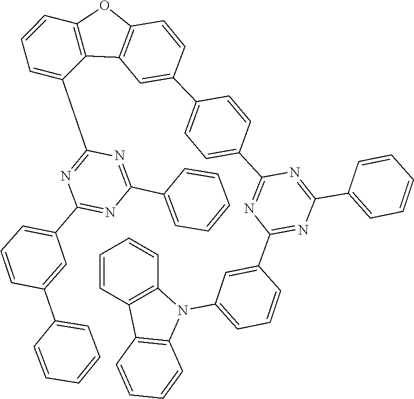 [SMILES: c1ccc(-c2cccc(-c3nc(-c4ccccc4)nc(-c4cccc5oc6ccc(-c7ccc(-c8nc(-c9ccccc9)nc(-c9cccc(-n%10c%11ccccc%11c%11ccccc%11%10)c9)n8)cc7)cc6c45)n3)c2)cc1]

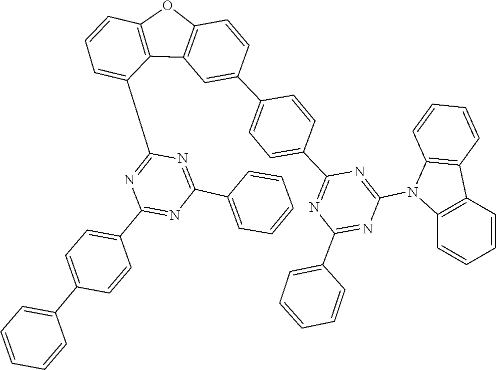 [SMILES: c1ccc(-c2ccc(-c3nc(-c4ccccc4)nc(-c4cccc5oc6ccc(-c7ccc(-c8nc(-c9ccccc9)nc(-n9c%10ccccc%10c%10ccccc%109)n8)cc7)cc6c45)n3)cc2)cc1]

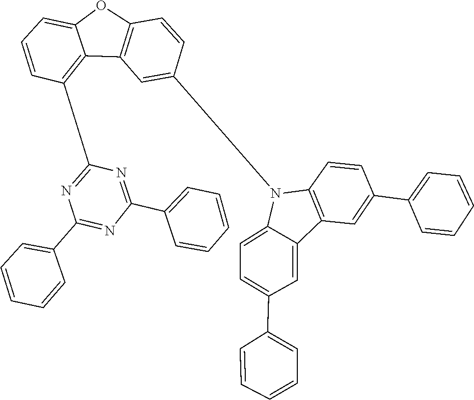 [SMILES: c1ccc(-c2ccc3c(c2)c2cc(-c4ccccc4)ccc2n3-c2ccc3oc4cccc(-c5nc(-c6ccccc6)nc(-c6ccccc6)n5)c4c3c2)cc1]

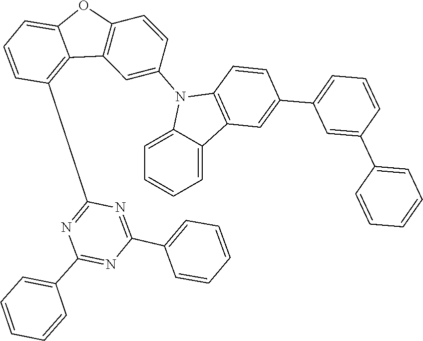 [SMILES: c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1]

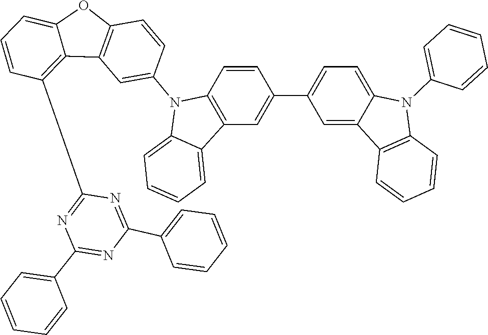 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1]

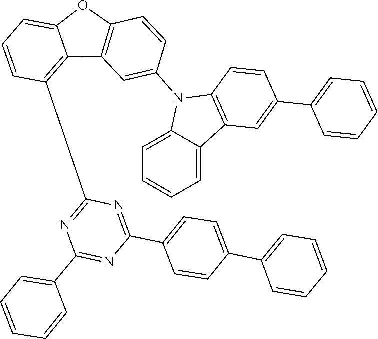 [SMILES: c1ccc(-c2ccc(-c3nc(-c4ccccc4)nc(-c4cccc5oc6ccc(-n7c8ccccc8c8cc(-c9ccccc9)ccc87)cc6c45)n3)cc2)cc1]

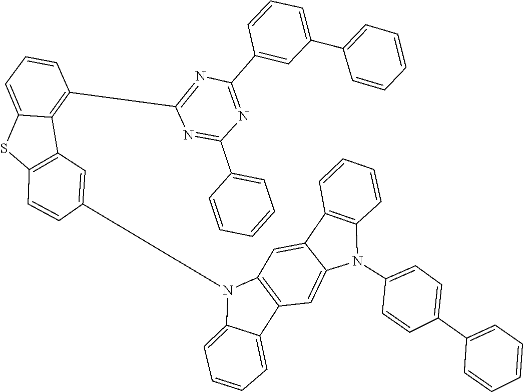 [SMILES: c1ccc(-c2ccc(-n3c4ccccc4c4cc5c(cc43)c3ccccc3n5-c3ccc4sc5cccc(-c6nc(-c7ccccc7)nc(-c7cccc(-c8ccccc8)c7)n6)c5c4c3)cc2)cc1]

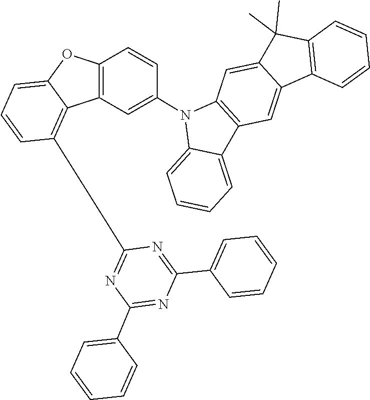 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21]

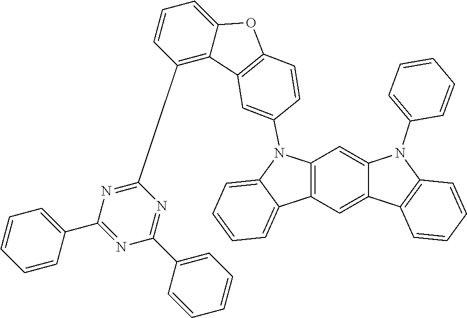 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1]

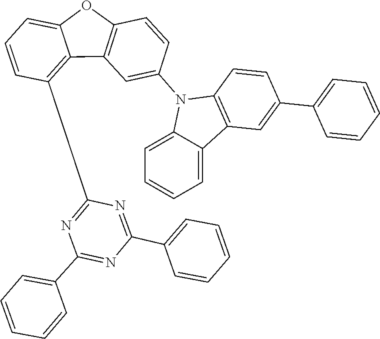 [SMILES: c1ccc(-c2ccc3c(c2)c2ccccc2n3-c2ccc3oc4cccc(-c5nc(-c6ccccc6)nc(-c6ccccc6)n5)c4c3c2)cc1]

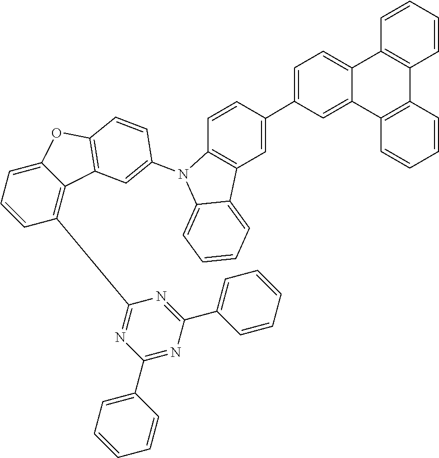 [SMILES: c1ccc(-c2nc(-c3ccccc3)nc(-c3cccc4oc5ccc(-n6c7ccccc7c7cc(-c8ccc9c%10ccccc%10c%10ccccc%10c9c8)ccc76)cc5c34)n2)cc1]

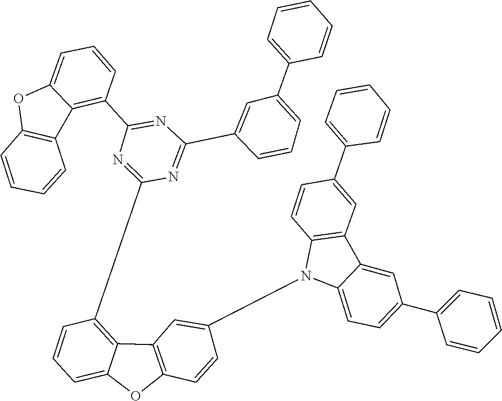 [SMILES: c1ccc(-c2cccc(-c3nc(-c4cccc5oc6ccccc6c45)nc(-c4cccc5oc6ccc(-n7c8ccc(-c9ccccc9)cc8c8cc(-c9ccccc9)ccc87)cc6c45)n3)c2)cc1]

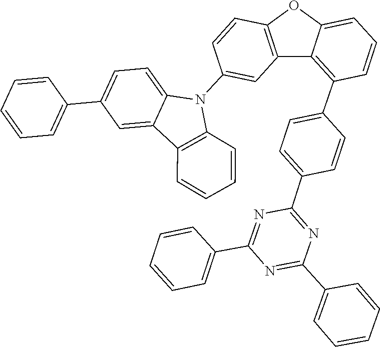 [SMILES: c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1]

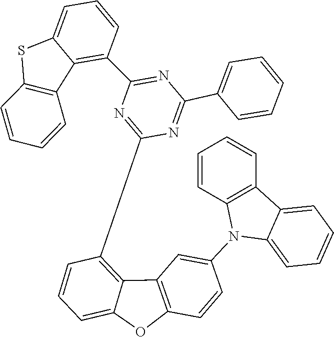 [SMILES: c1ccc(-c2nc(-c3cccc4oc5ccc(-n6c7ccccc7c7ccccc76)cc5c34)nc(-c3cccc4sc5ccccc5c34)n2)cc1]

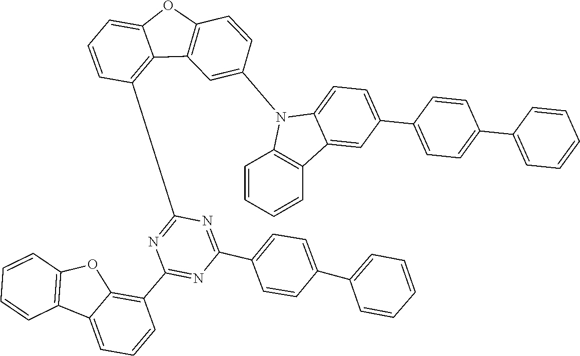 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8c7oc7ccccc78)n6)c5c4c3)cc2)cc1]

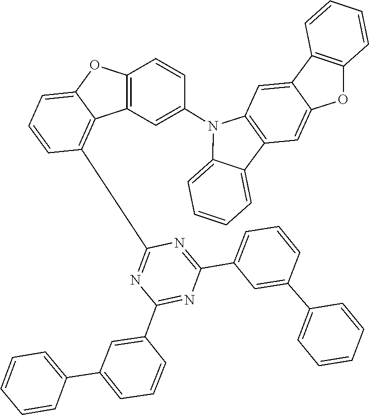 [SMILES: c1ccc(-c2cccc(-c3nc(-c4cccc(-c5ccccc5)c4)nc(-c4cccc5oc6ccc(-n7c8ccccc8c8cc9oc%10ccccc%10c9cc87)cc6c45)n3)c2)cc1]

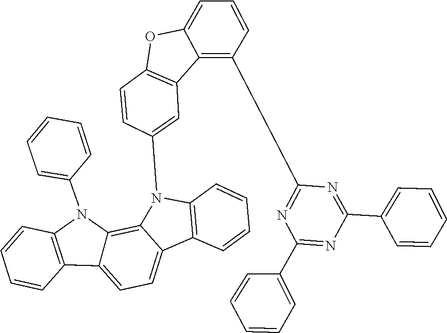 [SMILES: c1ccc(-c2nc(-c3ccccc3)nc(-c3cccc4oc5ccc(-n6c7ccccc7c7ccc8c9ccccc9n(-c9ccccc9)c8c76)cc5c34)n2)cc1]

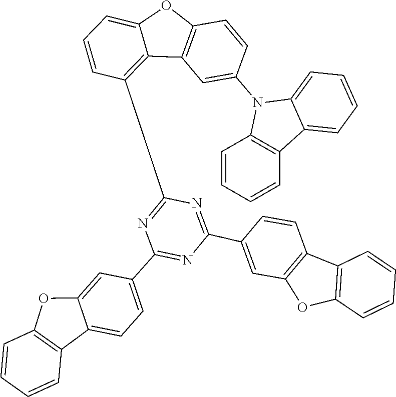 [SMILES: c1ccc2c(c1)oc1cc(-c3nc(-c4ccc5c(c4)oc4ccccc45)nc(-c4cccc5oc6ccc(-n7c8ccccc8c8ccccc87)cc6c45)n3)ccc12]

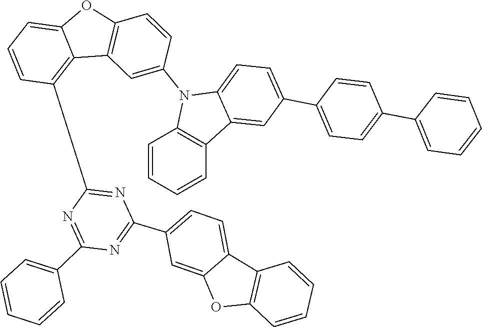 [SMILES: c1ccc(-c2ccc(-c3ccc4c(c3)c3ccccc3n4-c3ccc4oc5cccc(-c6nc(-c7ccccc7)nc(-c7ccc8c(c7)oc7ccccc78)n6)c5c4c3)cc2)cc1]

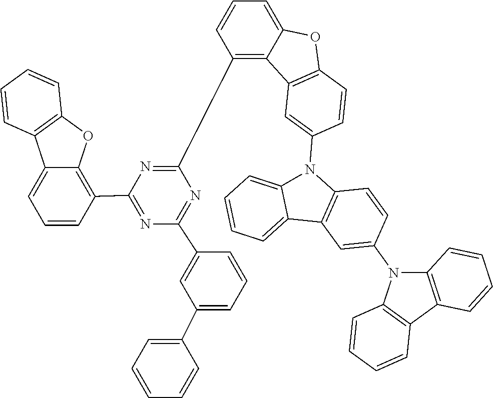 [SMILES: c1ccc(-c2cccc(-c3nc(-c4cccc5c4oc4ccccc45)nc(-c4cccc5oc6ccc(-n7c8ccccc8c8cc(-n9c%10ccccc%10c%10ccccc%109)ccc87)cc6c45)n3)c2)cc1]

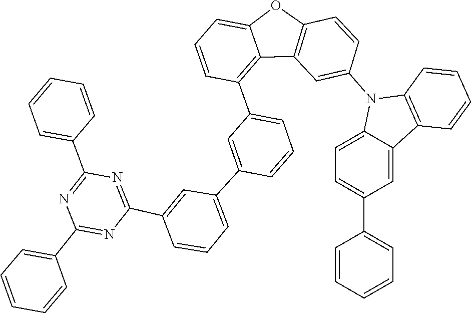 [SMILES: c1ccc(-c2ccc3c(c2)c2ccccc2n3-c2ccc3oc4cccc(-c5cccc(-c6cccc(-c7nc(-c8ccccc8)nc(-c8ccccc8)n7)c6)c5)c4c3c2)cc1]

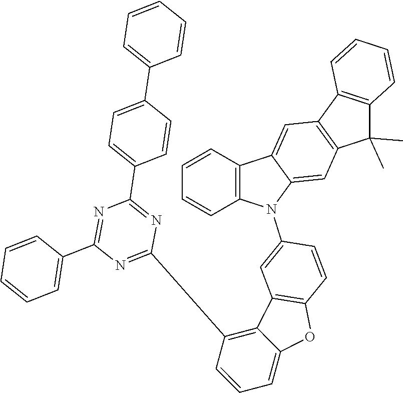 [SMILES: CC1(C)c2ccccc2-c2cc3c4ccccc4n(-c4ccc5oc6cccc(-c7nc(-c8ccccc8)nc(-c8ccc(-c9ccccc9)cc8)n7)c6c5c4)c3cc21]

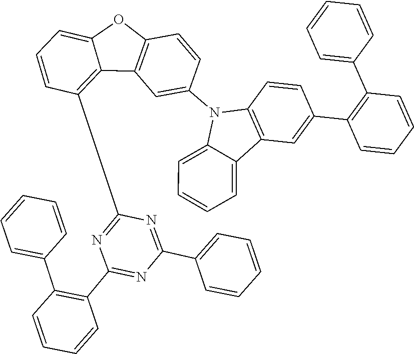 [SMILES: c1ccc(-c2nc(-c3ccccc3-c3ccccc3)nc(-c3cccc4oc5ccc(-n6c7ccccc7c7cc(-c8ccccc8-c8ccccc8)ccc76)cc5c34)n2)cc1]

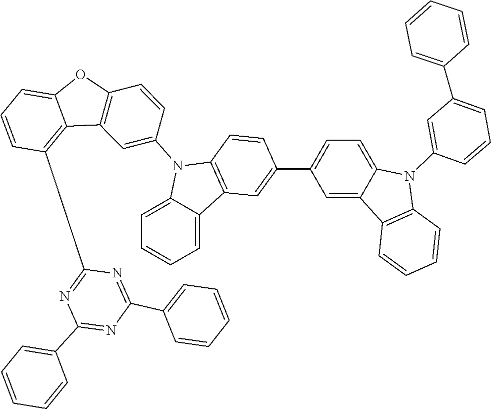 [SMILES: c1ccc(-c2cccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)c2)cc1]

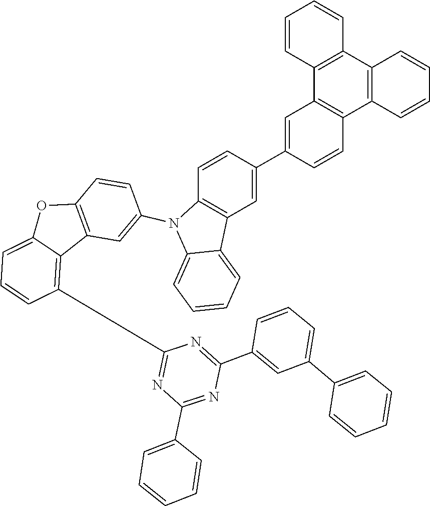 [SMILES: c1ccc(-c2cccc(-c3nc(-c4ccccc4)nc(-c4cccc5oc6ccc(-n7c8ccccc8c8cc(-c9ccc%10c%11ccccc%11c%11ccccc%11c%10c9)ccc87)cc6c45)n3)c2)cc1]

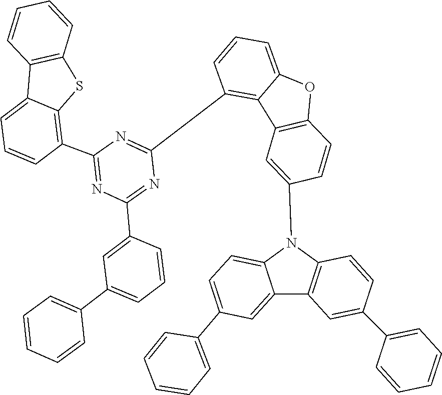 [SMILES: c1ccc(-c2cccc(-c3nc(-c4cccc5c4sc4ccccc45)nc(-c4cccc5oc6ccc(-n7c8ccc(-c9ccccc9)cc8c8cc(-c9ccccc9)ccc87)cc6c45)n3)c2)cc1]

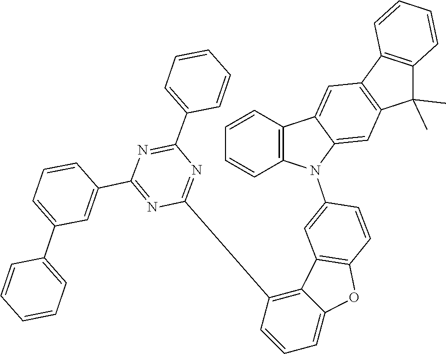 [SMILES: CC1(C)c2ccccc2-c2cc3c4ccccc4n(-c4ccc5oc6cccc(-c7nc(-c8ccccc8)nc(-c8cccc(-c9ccccc9)c8)n7)c6c5c4)c3cc21]

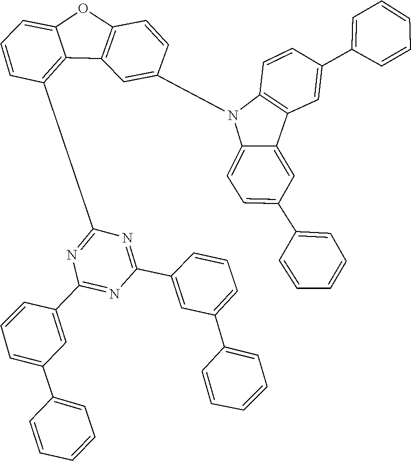 [SMILES: c1ccc(-c2cccc(-c3nc(-c4cccc(-c5ccccc5)c4)nc(-c4cccc5oc6ccc(-n7c8ccc(-c9ccccc9)cc8c8cc(-c9ccccc9)ccc87)cc6c45)n3)c2)cc1]

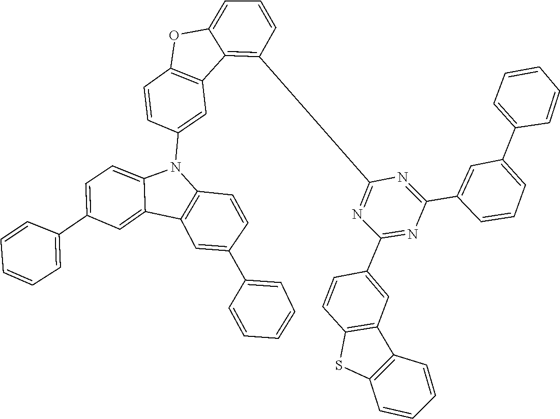 [SMILES: c1ccc(-c2cccc(-c3nc(-c4ccc5sc6ccccc6c5c4)nc(-c4cccc5oc6ccc(-n7c8ccc(-c9ccccc9)cc8c8cc(-c9ccccc9)ccc87)cc6c45)n3)c2)cc1]

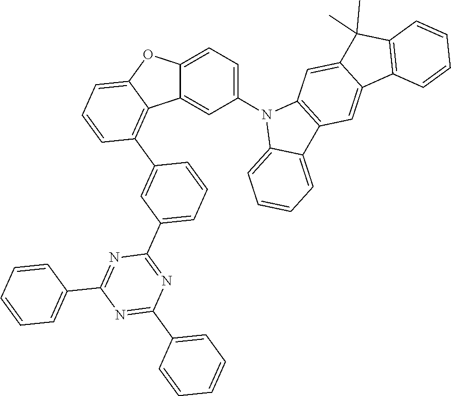 [SMILES: CC1(C)c2ccccc2-c2cc3c4ccccc4n(-c4ccc5oc6cccc(-c7cccc(-c8nc(-c9ccccc9)nc(-c9ccccc9)n8)c7)c6c5c4)c3cc21]

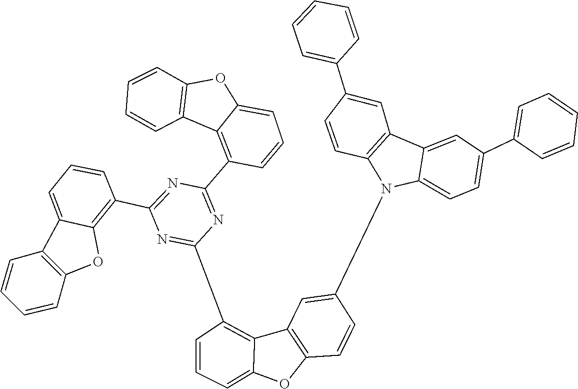 [SMILES: c1ccc(-c2ccc3c(c2)c2cc(-c4ccccc4)ccc2n3-c2ccc3oc4cccc(-c5nc(-c6cccc7c6oc6ccccc67)nc(-c6cccc7oc8ccccc8c67)n5)c4c3c2)cc1]

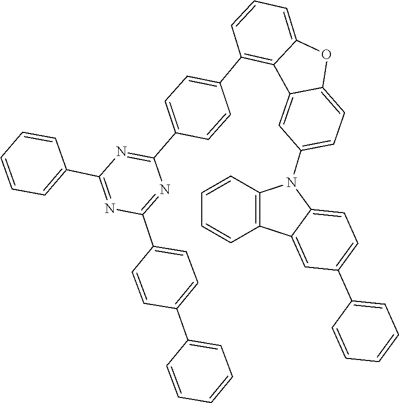 [SMILES: c1ccc(-c2ccc(-c3nc(-c4ccccc4)nc(-c4ccc(-c5cccc6oc7ccc(-n8c9ccccc9c9cc(-c%10ccccc%10)ccc98)cc7c56)cc4)n3)cc2)cc1]

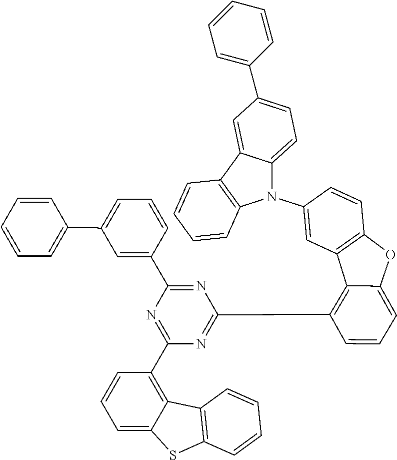 [SMILES: c1ccc(-c2cccc(-c3nc(-c4cccc5oc6ccc(-n7c8ccccc8c8cc(-c9ccccc9)ccc87)cc6c45)nc(-c4cccc5sc6ccccc6c45)n3)c2)cc1]

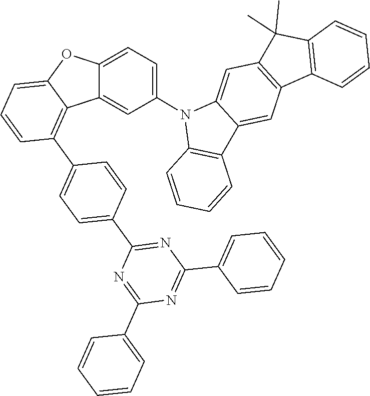 [SMILES: CC1(C)c2ccccc2-c2cc3c4ccccc4n(-c4ccc5oc6cccc(-c7ccc(-c8nc(-c9ccccc9)nc(-c9ccccc9)n8)cc7)c6c5c4)c3cc21]

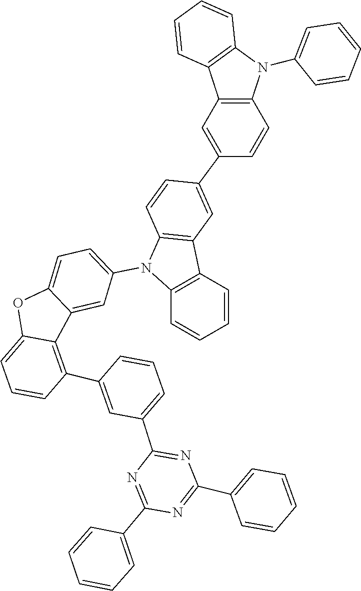 [SMILES: c1ccc(-c2nc(-c3ccccc3)nc(-c3cccc(-c4cccc5oc6ccc(-n7c8ccccc8c8cc(-c9ccc%10c(c9)c9ccccc9n%10-c9ccccc9)ccc87)cc6c45)c3)n2)cc1]

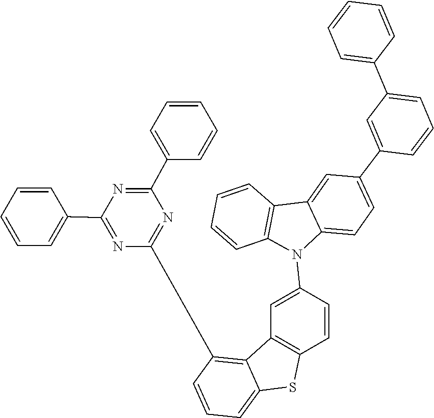 [SMILES: c1ccc(-c2cccc(-c3ccc4c(c3)c3ccccc3n4-c3ccc4sc5cccc(-c6nc(-c7ccccc7)nc(-c7ccccc7)n6)c5c4c3)c2)cc1]

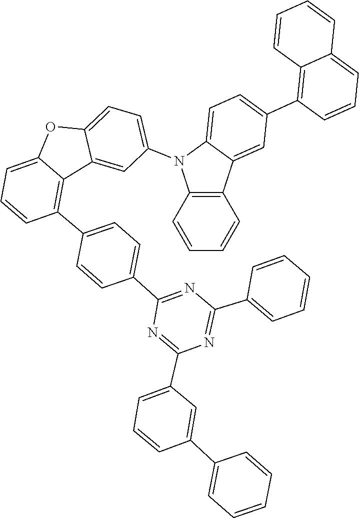 [SMILES: c1ccc(-c2cccc(-c3nc(-c4ccccc4)nc(-c4ccc(-c5cccc6oc7ccc(-n8c9ccccc9c9cc(-c%10cccc%11ccccc%10%11)ccc98)cc7c56)cc4)n3)c2)cc1]

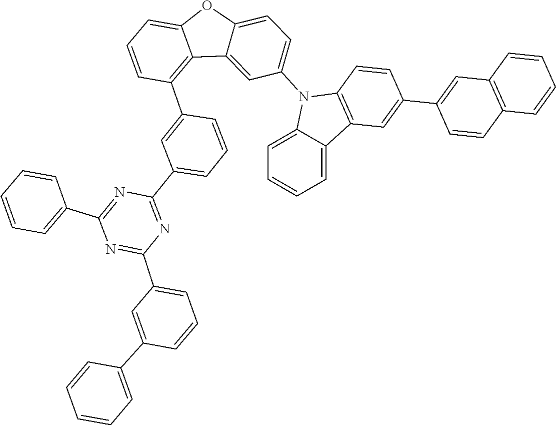 [SMILES: c1ccc(-c2cccc(-c3nc(-c4ccccc4)nc(-c4cccc(-c5cccc6oc7ccc(-n8c9ccccc9c9cc(-c%10ccc%11ccccc%11c%10)ccc98)cc7c56)c4)n3)c2)cc1]

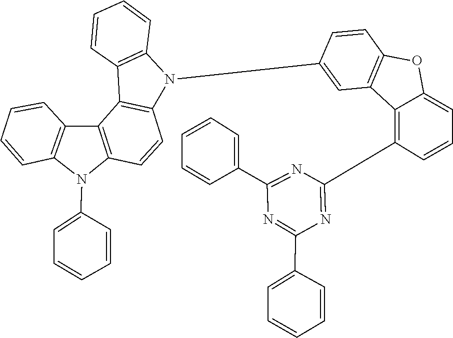 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1]

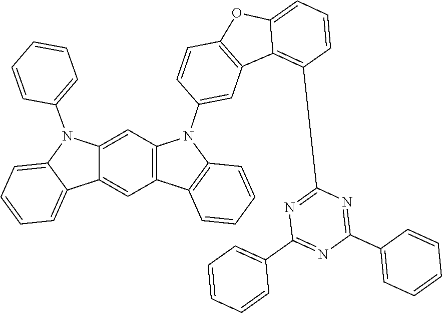 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1]

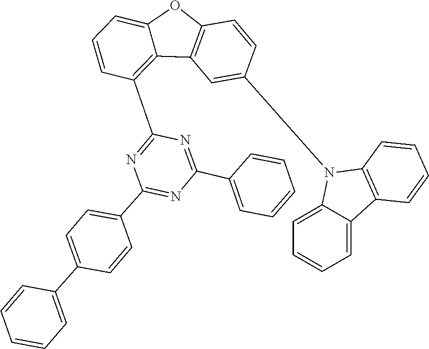 [SMILES: c1ccc(-c2ccc(-c3nc(-c4ccccc4)nc(-c4cccc5oc6ccc(-n7c8ccccc8c8ccccc87)cc6c45)n3)cc2)cc1]

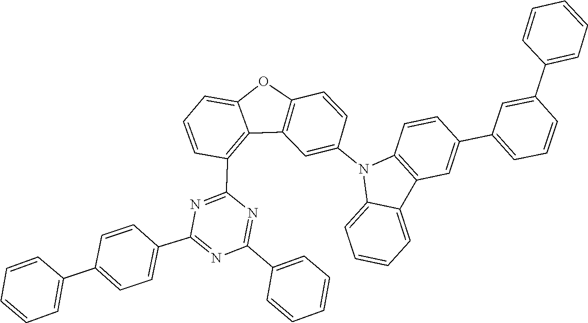 [SMILES: c1ccc(-c2ccc(-c3nc(-c4ccccc4)nc(-c4cccc5oc6ccc(-n7c8ccccc8c8cc(-c9cccc(-c%10ccccc%10)c9)ccc87)cc6c45)n3)cc2)cc1]

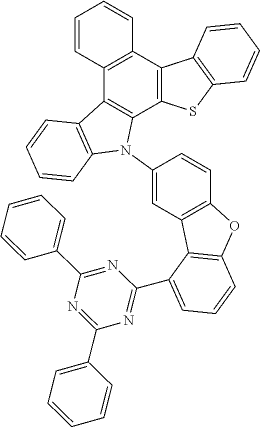 [SMILES: c1ccc(-c2nc(-c3ccccc3)nc(-c3cccc4oc5ccc(-n6c7ccccc7c7c8ccccc8c8c9ccccc9sc8c76)cc5c34)n2)cc1]

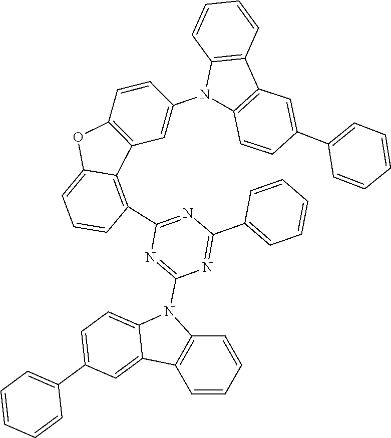 [SMILES: c1ccc(-c2ccc3c(c2)c2ccccc2n3-c2ccc3oc4cccc(-c5nc(-c6ccccc6)nc(-n6c7ccccc7c7cc(-c8ccccc8)ccc76)n5)c4c3c2)cc1]

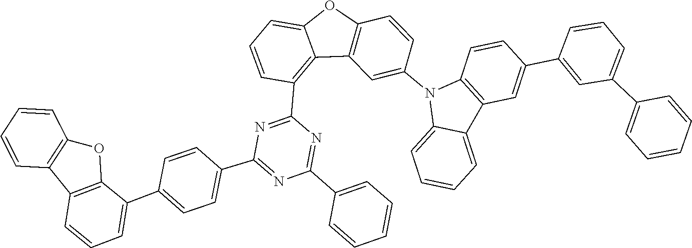 [SMILES: c1ccc(-c2cccc(-c3ccc4c(c3)c3ccccc3n4-c3ccc4oc5cccc(-c6nc(-c7ccccc7)nc(-c7ccc(-c8cccc9c8oc8ccccc89)cc7)n6)c5c4c3)c2)cc1]

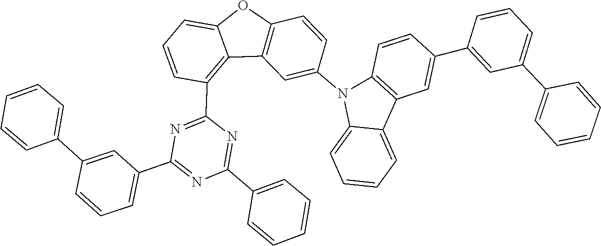 [SMILES: c1ccc(-c2cccc(-c3ccc4c(c3)c3ccccc3n4-c3ccc4oc5cccc(-c6nc(-c7ccccc7)nc(-c7cccc(-c8ccccc8)c7)n6)c5c4c3)c2)cc1]

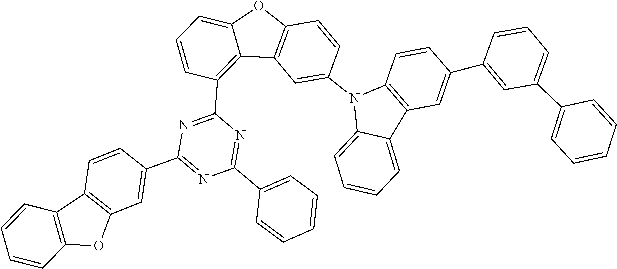 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1]

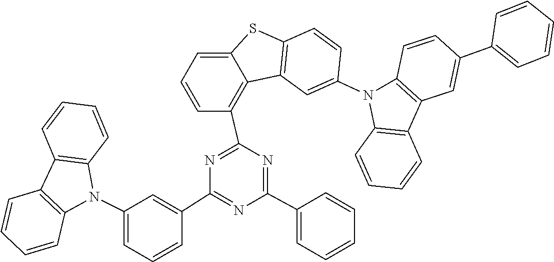 [SMILES: c1ccc(-c2ccc3c(c2)c2ccccc2n3-c2ccc3sc4cccc(-c5nc(-c6ccccc6)nc(-c6cccc(-n7c8ccccc8c8ccccc87)c6)n5)c4c3c2)cc1]

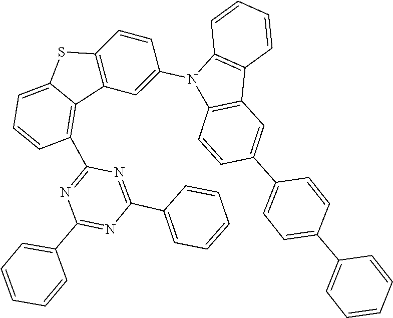 [SMILES: c1ccc(-c2ccc(-c3ccc4c(c3)c3ccccc3n4-c3ccc4sc5cccc(-c6nc(-c7ccccc7)nc(-c7ccccc7)n6)c5c4c3)cc2)cc1]

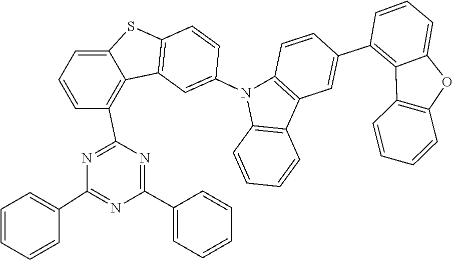 [SMILES: c1ccc(-c2nc(-c3ccccc3)nc(-c3cccc4sc5ccc(-n6c7ccccc7c7cc(-c8cccc9oc%10ccccc%10c89)ccc76)cc5c34)n2)cc1]

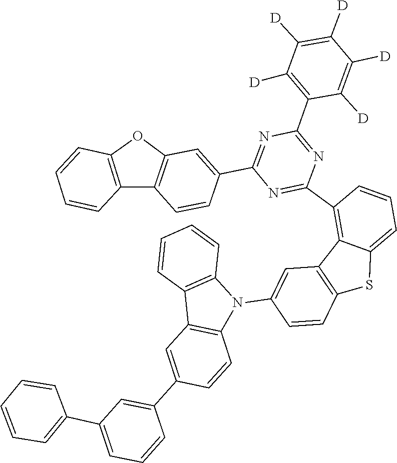 [SMILES: [2H]c1c([2H])c([2H])c(-c2nc(-c3ccc4c(c3)oc3ccccc34)nc(-c3cccc4sc5ccc(-n6c7ccccc7c7cc(-c8cccc(-c9ccccc9)c8)ccc76)cc5c34)n2)c([2H])c1[2H]]

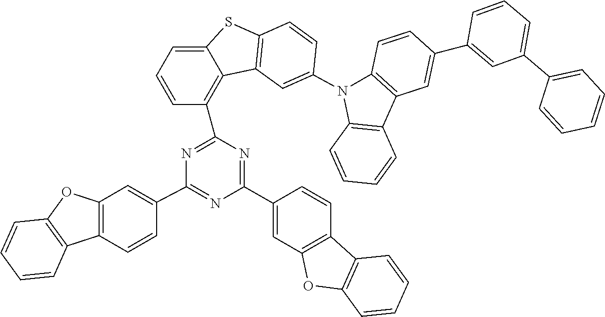 [SMILES: c1ccc(-c2cccc(-c3ccc4c(c3)c3ccccc3n4-c3ccc4sc5cccc(-c6nc(-c7ccc8c(c7)oc7ccccc78)nc(-c7ccc8c(c7)oc7ccccc78)n6)c5c4c3)c2)cc1]

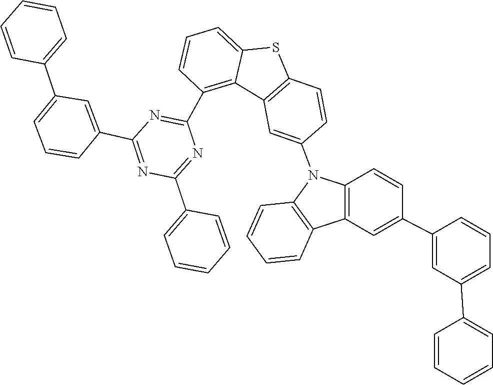 [SMILES: c1ccc(-c2cccc(-c3ccc4c(c3)c3ccccc3n4-c3ccc4sc5cccc(-c6nc(-c7ccccc7)nc(-c7cccc(-c8ccccc8)c7)n6)c5c4c3)c2)cc1]

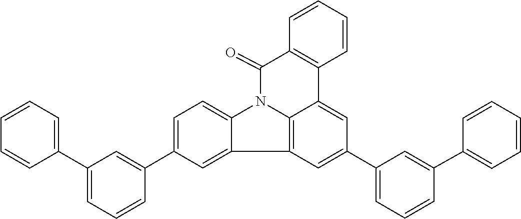 [SMILES: O=c1c2ccccc2c2cc(-c3cccc(-c4ccccc4)c3)cc3c4cc(-c5cccc(-c6ccccc6)c5)ccc4n1c23]

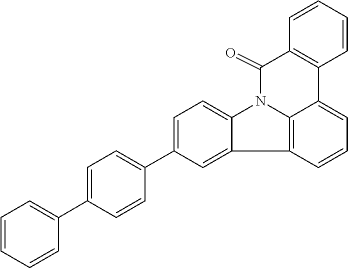 [SMILES: O=c1c2ccccc2c2cccc3c4cc(-c5ccc(-c6ccccc6)cc5)ccc4n1c23]

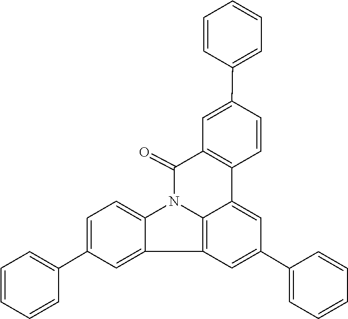 [SMILES: O=c1c2cc(-c3ccccc3)ccc2c2cc(-c3ccccc3)cc3c4cc(-c5ccccc5)ccc4n1c23]

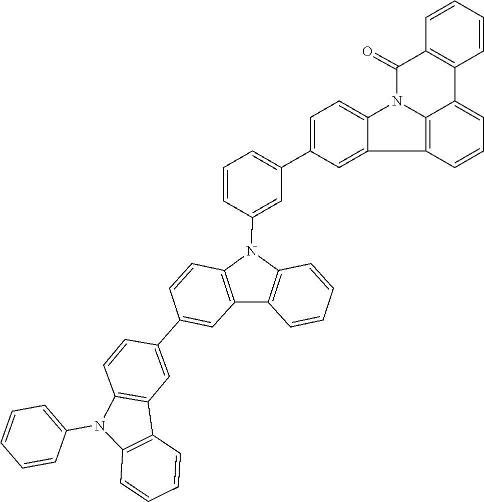 [SMILES: O=c1c2ccccc2c2cccc3c4cc(-c5cccc(-n6c7ccccc7c7cc(-c8ccc9c(c8)c8ccccc8n9-c8ccccc8)ccc76)c5)ccc4n1c23]

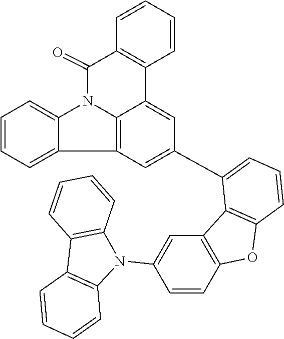 [SMILES: O=c1c2ccccc2c2cc(-c3cccc4oc5ccc(-n6c7ccccc7c7ccccc76)cc5c34)cc3c4ccccc4n1c23]

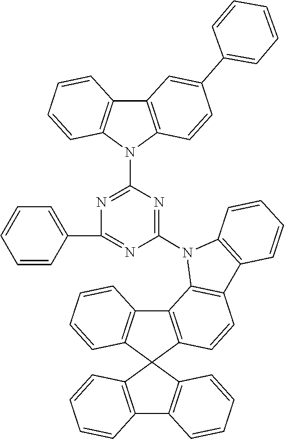 [SMILES: c1ccc(-c2ccc3c(c2)c2ccccc2n3-c2nc(-c3ccccc3)nc(-n3c4ccccc4c4ccc5c(c43)-c3ccccc3C53c4ccccc4-c4ccccc43)n2)cc1]

Examples of suitable hole transporting host materials are the compounds of the following formulas (hTMM-1) to (hTMM-6),

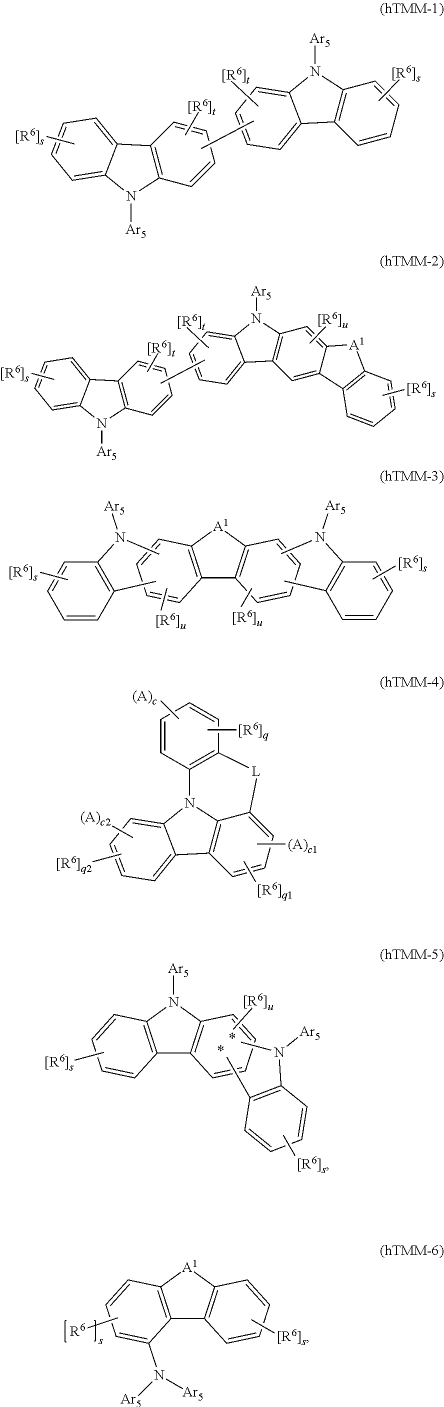

wherein the symbols and indices used are as follows:
A¹ is C(R⁷)₂, NR⁷, O or S;
L is a bond, O, S, C(R⁷)₂ or NR⁷;
A at each occurrence is independently a group of the formula (Carb-1) or (Carb-2),

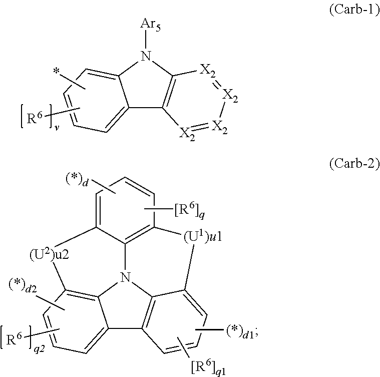

X₂ at each occurrence is the same or different and is CH, CR⁶ or N, wherein a maximum of 2 symbols X₂ can mean N;
* indicates the binding site to the formula (hTMM-4);
U¹, U² when present, are a bond, O, S, C(R)⁷₂ or NR⁷;
R⁶ at each occurrence is the same or different and is D, F, CN, a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R⁷ and wherein one or more non-adjacent CH₂ groups may be replaced by Si(R⁷)₂, C═O, NR⁷, O, S or CONR⁷, or an aromatic or hetero-aromatic ring system having 5 to 60 ring atoms, which may in each case be substituted by one or more radicals R⁷; two radicals R⁶ can also form an aromatic, heteroaromatic, aliphatic or heteroaliphatic ring system with one another;
Ar₅ at each occurrence is the same or different and independently represents an aromatic or heteroaromatic ring system having from 5 to 40 ring atoms, which may be substituted with one or more R⁷ radicals;
R⁷ at each occurrence is the same or different and is D, F, Cl, Br, I, N(R⁸)₂, CN, NO₂, OR⁸, SR⁸, Si(R⁸)₃, B(OR⁸)₂, C(═O)R⁸, P(═O)(R⁸)₂, S(═O)R⁸, S(═O)₂R⁸, OSO₂R⁸, a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R⁸, wherein one or more non-adjacent CH₂ groups may be replaced by Si(R⁸)₂, C═O, NR⁸, O, S or CONR⁸, or an aromatic or heteroaromatic ring system having 5 to 40 ring atoms, which may in each case be substituted by one or more radicals R⁸; wherein two or more radicals R⁷ can together form an aromatic, heteroaromatic, aliphatic or heteroaliphatic ring system, preferably the radicals R⁷ do not form such a ring system;
R⁸ at each occurrence is the same or different and is H, D, F or an aliphatic, aromatic or heteroaromatic organic radical, in particular a hydrocarbon radical, having 1 to 20 carbon atoms, in which one or more —H atoms may also be replaced by —F;
c, c1, and c2 at each occurrence independently means 0 or 1, wherein the sum of the indices, for each occurrence, equals c+c1+c2=1;
d, d1, d2 at each occurrence independently means 0 or 1, wherein the sum of the indices, for each occurrence, equals d+d1+d2=1;
q, q1, q2 at each occurrence independently means 0 or 1;
s at each occurrence is the same or different and is 0, 1, 2, 3, or 4;
t at each occurrence is the same or different and is 0, 1, 2, or 3;
u at each occurrence is the same or different and is 0, 1, or 2;
u1, u2 at each occurrence independently means 0 or 1, wherein the sum u1+u2=1; and
v is 0 or 1.

In compounds of the formulae (hTMM-1) to (hTMM-3), (hTMM-5) and (hTMM-6), s is preferably 0 or 1 if the radical R⁶ is different from D, or particularly preferably 0. In compounds of the formulae (hTMM-1) to (hTMM-3), t is preferably 0 or 1 if the radical R⁶ is different from D, or particularly preferably 0. In compounds of the formulae (hTMM-1) to (hTMM-3) or (hTMM-5), u is preferably 0 or 1 if the radical R⁶ is different from D, or particularly preferably 0. The sum of the indices s, t and u in compounds of the formulae (hTMM-1) to (hTMM-3), (hTMM-5) and (hTMM-6) is preferably at most 6, particularly preferably at most 4 and especially preferably at most 2. This applies preferably if R⁶ is different from D.

In compounds of the formula (hTMM-4), each occurrence of c, c1, c2 independently means 0 or 1 and the sum of the indices at each occurrence c+c1+c2 means 1. Preferably, c2 has the meaning 1. In compounds of the formula (hTMM-4), L is preferably a single bond or C(R⁷)₂, wherein R⁷ has the meaning given previously, particularly preferably L is a single bond.

In formula (Carb-2), U¹ or U² when occurring are preferably a single bond or C(R⁷)₂, wherein R⁷ has the meaning given previously, particularly preferred are U¹ or U² when occurring are a single bond.

In a preferred embodiment of the compounds of the formulae (hTMM-1) to (hTMM-6), R⁶ is the same or different at each occurrence selected from the group consisting of D, F, CN, a straight-chain alkyl group having 1 to 20 C atoms or a branched or cyclic alkyl group having 3 to 20 C atoms, wherein the alkyl group may in each case be substituted by one or more radicals R⁷, or an aromatic or heteroaromatic ring system having 5 to 60 ring atoms, preferably having 5 to 40 ring atoms, which may in each case be substituted by one or more radicals R⁷. In a particularly preferred embodiment of the compounds of the formulae (hTM-1) to (hTMM-6), which can be combined with compounds of the formula (1) according to the invention, as described above, each occurrence of R⁶ is the same or different and is selected from the group consisting of D or an aromatic or heteroaromatic ring system having 6 to 30 ring atoms, which can be substituted by one or more radicals R⁷.

Preferred is Ar₅ in compounds of the formulae (hTMM-1) to (hTMM-3), (hTMM-5) or (hTMM-6) selected from phenyl, biphenyl, in particular ortho-, meta- or para-biphenyl, terphenyl, in particular ortho-, meta-, para- or branched terphenyl, quaterphenyl, in particular ortho-, meta-, para- or branched quaterphenyl, fluorenyl, which can be linked via the 1-, 2-, 3- or 4-position, spirobifluorenyl, which can be linked via the 1-, 2-, 3- or 4-position, naphthyl, in particular 1- or 2-linked naphthyl, or radicals derived from indole, benzofuran, benzothiophene, carbazole, which can be linked via the 1-, 2-, 3- or 4-position, dibenzofuran, which can be linked via the 1-, 2-, 3- or 4-position, dibenzothiophene, which can be linked via the 1-, 2-, 3- or 4-position, indenocarbazole, indolocarbazole, pyridine, pyrimidine, pyrazine, pyridazine, triazine, quinoline, isoquinoline, quinazoline, quinoxaline, phenanthrene or triphenylene, each of which may be substituted with one or more R⁷ radicals. Preferably, Ar₅ is unsubstituted.

If A¹ in formula (hTMM-2), (hTMM-3) or (hTMM-6) stands for NR⁷, the substituent R⁷, which is bonded to the nitrogen atom, preferably stands for an aromatic or heteroaromatic ring system with 5 to 24 aromatic ring atoms, which can also be substituted by one or more radicals R⁸. In a particularly preferred embodiment, this substituent R⁷, wherein each occurrence may be the same or different, represents an aromatic or heteroaromatic ring system having 6 to 24 aromatic ring atoms, in particular having 6 to 18 aromatic ring atoms. Preferred embodiments for R⁷ are phenyl, biphenyl, terphenyl and quaterphenyl, which are preferably unsubstituted, as well as radicals derived from triazine, pyrimidine and quinazoline, which may be substituted by one or more radicals R⁸.

If A¹ in formula (hTMM-2), (hTMM-3) or (hTMM-6) stands for C(R⁷)₂, the substituents R⁷, which are bonded to this carbon atom, preferably identical or different in each occurrence, represent a linear alkyl group having 1 to 10 C atoms or a branched or cyclic alkyl group having 3 to 10 C atoms or an aromatic or heteroaromatic ring system having 5 to 24 aromatic ring atoms, which may also be substituted by one or more radicals R⁸. Very preferably, R⁷ represents a methyl group or a phenyl group. The radicals R⁷ can also form a ring system with one another, resulting in a spiro system.

In a preferred embodiment of the compounds of formulae (hTMM-1) to (hTMM-6), these compounds are partially or fully permanently deuterated, particularly preferably fully deuterated.

The preparation of the compounds of formulae (hTMM-1) to (hTMM-6) are generally known, and some of the compounds are commercially available.

Further examples of suitable host materials of formulae (hTMM-1) to (hTMM-6) for combination with compounds of formula (1) are the structures mentioned below.

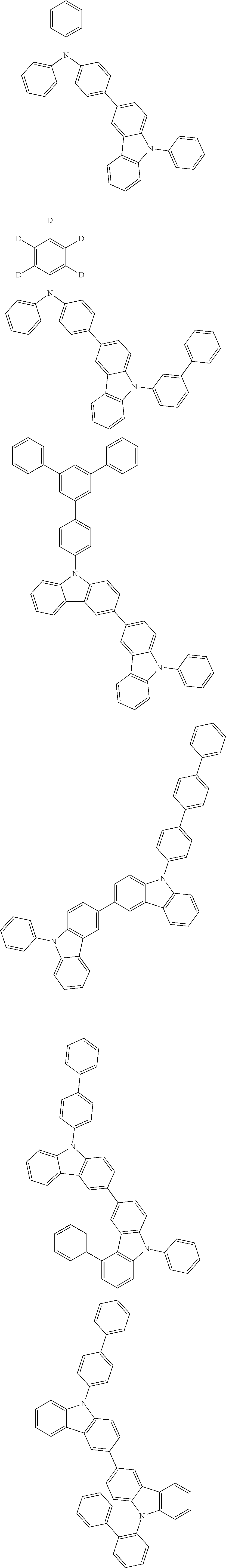

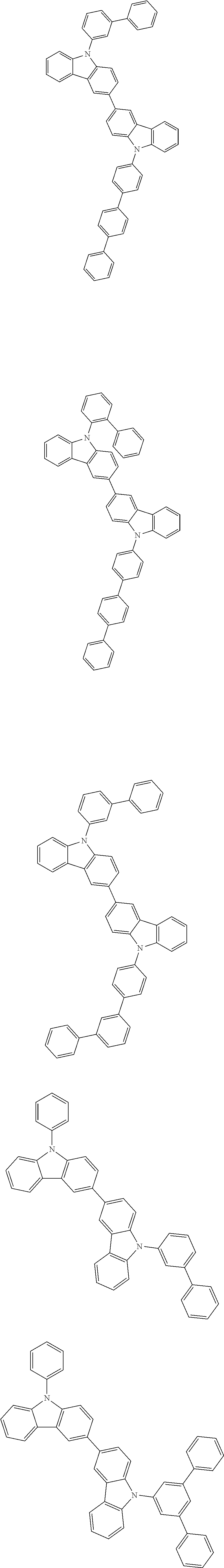 [SMILES: c1ccc(-c2ccc(-c3ccc(-n4c5ccccc5c5cc(-c6ccc7c(c6)c6ccccc6n7-c6cccc(-c7ccccc7)c6)ccc54)cc3)cc2)cc1 ; c1ccc(-c2ccc(-c3ccc(-n4c5ccccc5c5cc(-c6ccc7c(c6)c6ccccc6n7-c6ccccc6-c6ccccc6)ccc54)cc3)cc2)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1 ; c1ccc(-c2cccc(-n3c4ccccc4c4cc(-c5ccc6c(c5)c5ccccc5n6-c5ccccc5)ccc43)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

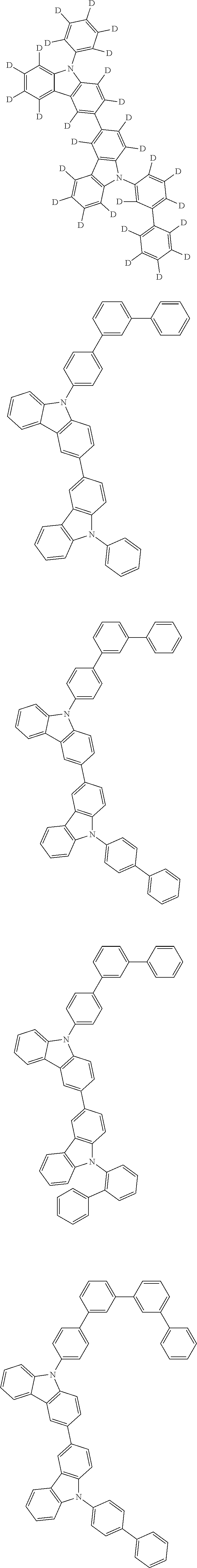

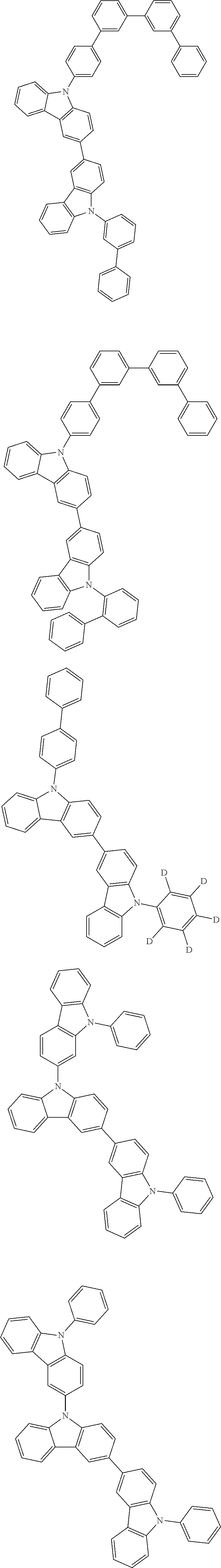

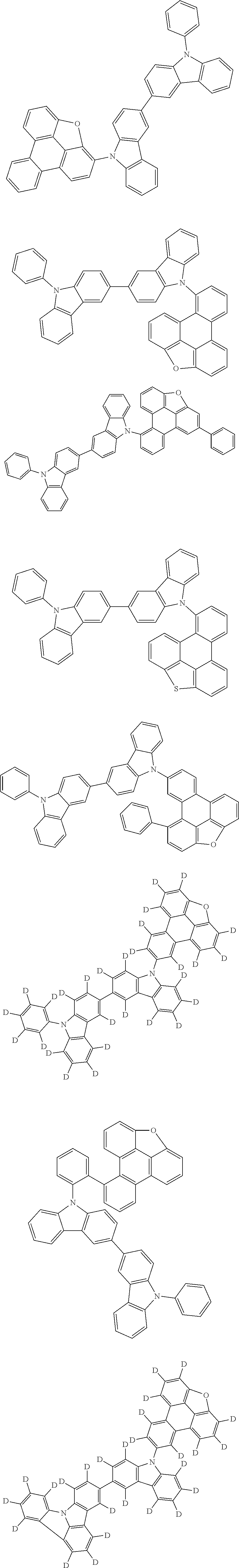

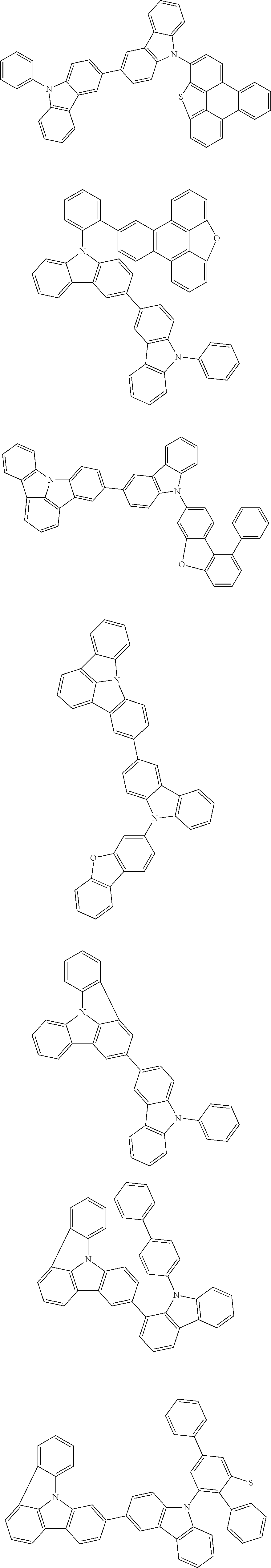

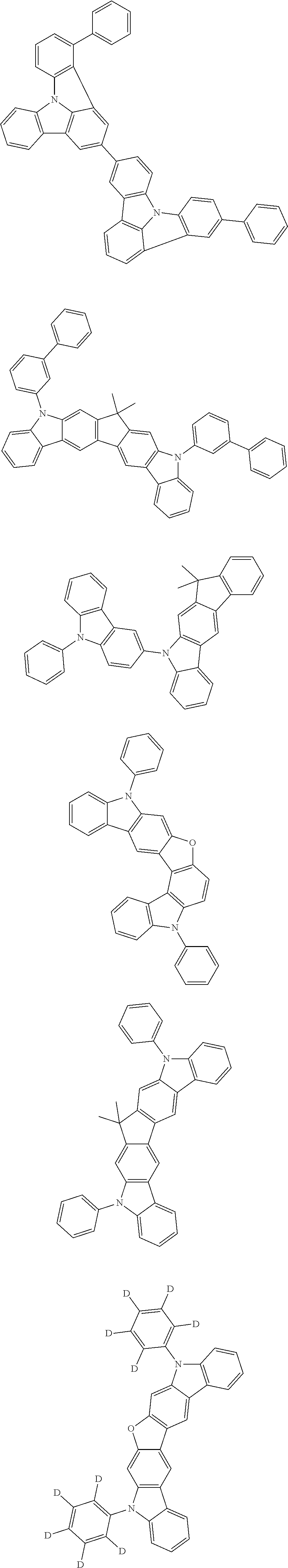

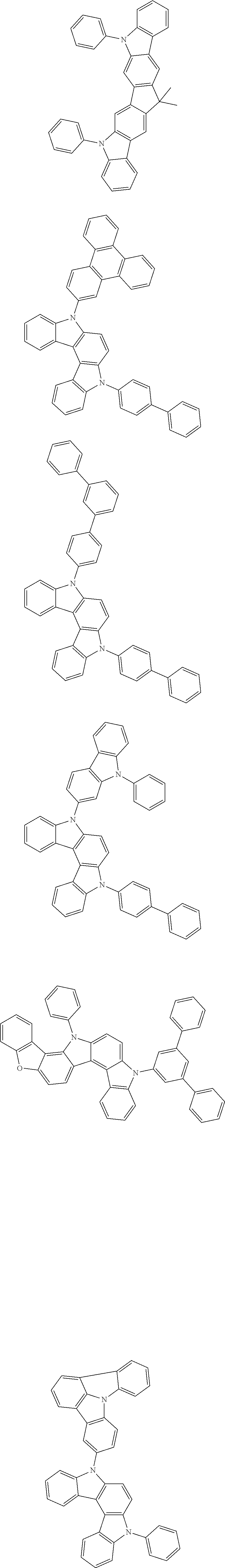

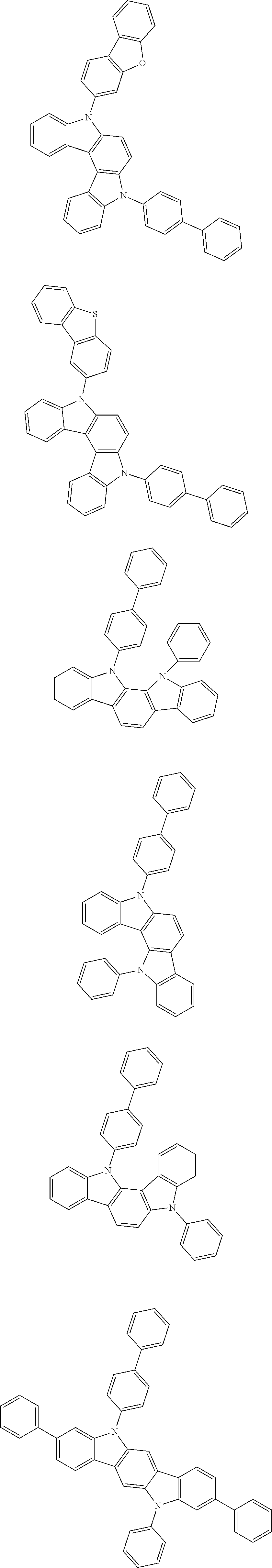

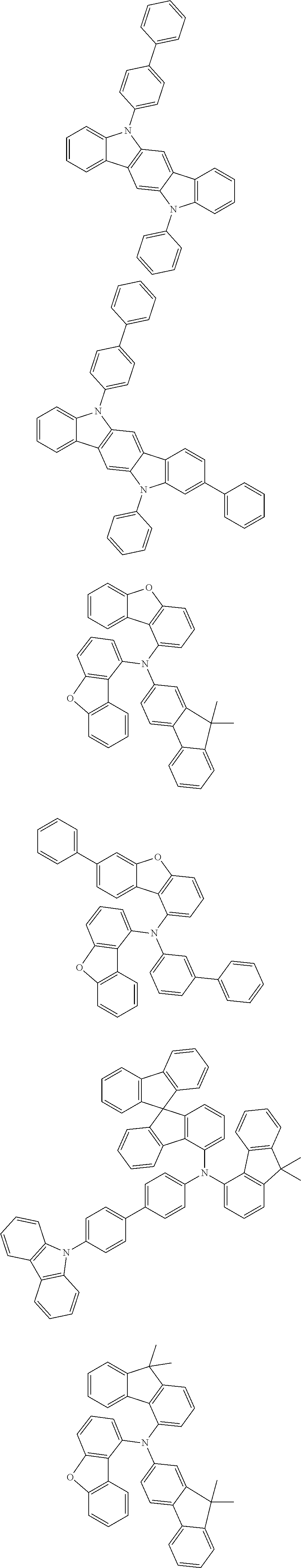

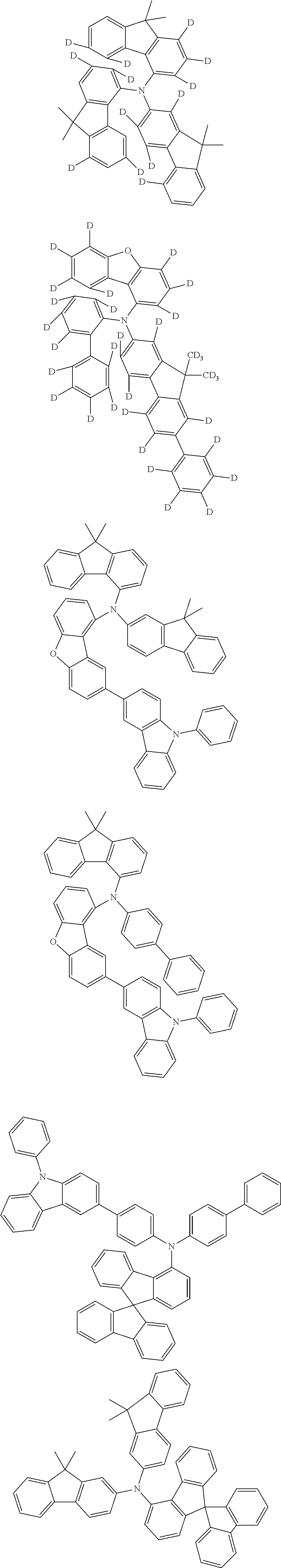

It is further preferred to use a mixture of two or more triplet emitters, in particular two or three triplet emitters, together with one or more matrix materials. In this case, the triplet emitter with the shorter-wavelength emission spectrum serves as a co-matrix for the triplet emitter with the longer-wavelength emission spectrum. For example, the metal complexes according to the invention can be combined with a shorter wavelength, e.g., blue, green or yellow emitting, metal complex as a co-matrix. For example, metal complexes according to the invention can also be used as a co-matrix for longer wavelength emitting triplet emitters, for example for red emitting triplet emitters. It may also be preferred if both the shorter wavelength and the longer wavelength emitting metal complex is a compound according to the invention. A preferred embodiment when using a mixture of three triplet emitters is when two are used as co-host and one as emitting material. These triplet emitters preferably have the emission colors green, yellow and red or blue, green and orange.

A preferred mixture in the emitting layer contains an electron transporting host material, a so-called “wide bandgap” host material, which due to its electronic properties is not or not substantially involved in charge transport in the layer, a co-dopant, which is a triplet emitter emitting at a shorter wavelength than the compound according to the invention, and a compound according to the invention.

Another preferred mixture in the emitting layer contains an electron transporting host material, a so-called “wide band gap” host material which, due to its electronic properties, is not or not substantially involved in charge transport in the layer, a hole transporting host material, a co-dopant which is a triplet emitter emitting at a shorter wavelength than the compound according to the invention, and a compound according to the invention.

The compounds according to the invention can also be used in other functions in the electronic device, for example as hole transport material in a hole injection or transport layer, as charge generation material, as electron blocking material, as hole blocking material or as electron transport material, for example in an electron transport layer. Similarly, the inventive compounds can be used as matrix materials for other phosphorescent metal complexes in an emitting layer.

In the further layers, generally all materials can be used as they are used for the layers according to the prior art, and the skilled person can combine any of these materials in an electronic device with the materials according to the invention without any inventive intervention.

Suitable charge transport materials, such as those that can be used in the hole injection or hole transport layer or electron blocking layer or in the electron transport layer of the organic electroluminescent device according to the invention, are, for example, the compounds disclosed in Y. Shirota et al, Chem. Rev. 2007, 107(4), 953-1010 or other materials as disclosed in the prior art used in these layers. Preferred hole transport materials that can be used in a hole transport-, hole injection, or electron blocking layer in the electroluminescent device of the invention are indenofluorenamine derivatives (e. g. e. according to WO 06/122630 or WO 06/100896), the amine derivatives disclosed in EP 1661888, hexaazatriphenylene derivatives (e. g. according to WO 01/049806), amine derivatives with condensed aromatics (e. g. according to U.S. Pat. No. 5,061,569), amine derivatives disclosed in WO 95/09147, monobenzo indenofluorenamines (e.g. according to WO 08/006449), dibenzoindenofluorenamines (e.g. according to WO 07/140847), spirobifluorenamines (e.g. according to WO 2012/034627, WO2014/056565), fluorene amines (e.g. according to EP 2875092, EP 2875699 and EP 2875004), spiro-dibenzopyran amines (e.g. EP 2780325) and dihydroacridine derivatives (e.g. according to WO 2012/150001).

The device is structured accordingly (depending on the application), contacted and finally hermetically sealed, as the service life of such devices is drastically reduced in the presence of water and/or air.

Further preferred is an organic electroluminescent device, characterized in that one or more layers are coated by a sublimation process. In this process, the materials are vapor deposited in vacuum sublimation systems at an initial pressure of usually less than 10⁻⁵ mbar, preferably less than 10⁻⁶ mbar. It is also possible for the initial pressure to be even lower or even higher, for example less than 10⁻⁷ mbar.

An organic electroluminescent device is also preferred, characterized in that one or more layers are coated using the OVPD (organic vapor phase deposition) process or with the aid of carrier gas sublimation. In this process, the materials are applied at a pressure between 10⁻⁵ mbar and 1 bar. A special case of this process is the OVJP (Organic Vapour Jet Printing) process, in which the materials are applied directly through a nozzle and thus patterned (e.g., M. S. Arnold et al., Appl. Phys. Lett. 2008, 92, 053301).

Further preferred is an organic electroluminescent device, characterized in that one or more layers are produced from solution, such as by spin coating, or by any printing process, such as screen printing, flexographic printing, offset printing or nozzle printing, but especially preferably LITI (Light Induced Thermal Imaging, Thermotransfer printing) or ink-jet printing. Soluble compounds are required for this, which can be, for example, obtained by suitable substitution.

The organic electroluminescent device can also be fabricated as a hybrid system by depositing one or more layers of solution and vapor depositing one or more other layers. For example, it is possible to deposit an emitting layer containing a metal complex of the invention and a matrix material of solution and to vacuum evaporate a hole-blocking layer and/or an electron transport layer on top of it.

These methods are generally known to those skilled in the art and can be readily applied by them to organic electroluminescent devices containing compounds according to formula (1) or the preferred embodiments listed above.

Compared with the corresponding compounds according to the prior art, which contain three —CH2CH₂— groups or three —C(CH₃)₂C(CH₃)₂— groups in the bridgehead instead of the bridgehead according to the invention, the compounds according to the invention are characterized by a significantly lower sublimation temperature, which leads to a significantly improved sublimability of the complexes in the production of the OLED. At the same time, the other properties of the OLED, such as efficiency, voltage and lifetime, are very good, and the above advantages are not accompanied by a deterioration of the other electronical properties.

The invention is explained in more detail by the following examples without wishing to limit it. The person skilled in the art can produce further electronic devices according to the invention from the descriptions without any inventive step and thus carry out the invention in the entire claimed field.

### EXPERIMENTAL EXAMPLES

The following syntheses are carried out under an inert gas atmosphere in dried solvents, unless otherwise specified. The metal complexes are additionally handled under exclusion of light or under yellow light. The solvents and reagents can be obtained, for example, from Sigma-ALDRICH and ABCR, respectively. The respective data in square brackets or the numbers given for individual compounds refer to the CAS numbers of the compounds known from literature. For compounds that may have several enantiomeric, diastereomeric or tautomeric forms, one form is shown as a representative.

A) Representation of Synthons S

### Example S1

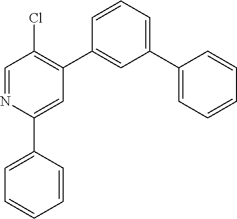 [SMILES: Clc1cnc(-c2ccccc2)cc1-c1cccc(-c2ccccc2)c1]

Preparation analogous to WO 2021/110720, Example S20, see p. 118, with 19.8 g (100 mmol) of 3-biphenylboronic acid [5122-95-2] being used in Step 20a instead of 4-biphenylboronic acid [5122-94-1] and Step 20b being carried out with the starting materials described. Yield: 28.8 g (96 mmol), 96%; purity: about 97% by ¹H NMR.

Similarly, the following compounds can be prepared in yields of 70-95% using the reactants shown.

| Ex. | Reactant | Product |
|---|---|---|
| S2 | 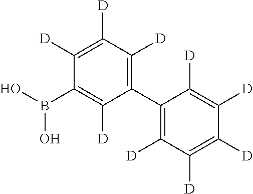 [SMILES: [2H]c1c([2H])c([2H])c(-c2c([2H])c([2H])c([2H])c(B(O)O)c2[2H])c([2H])c1[2H]] | 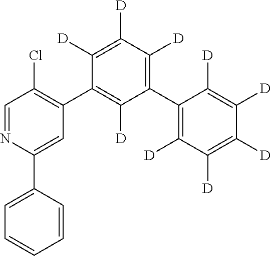 [SMILES: [2H]c1c([2H])c([2H])c(-c2c([2H])c([2H])c([2H])c(-c3cc(-c4ccccc4)ncc3Cl)c2[2H])c([2H])c1[2H]] |
| | 2368221-45-6 | |
| S3 | 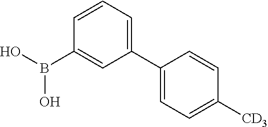 [SMILES: [2H]C([2H])([2H])c1ccc(-c2cccc(B(O)O)c2)cc1] | 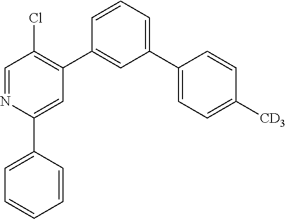 [SMILES: [2H]C([2H])([2H])c1ccc(-c2cccc(-c3cc(-c4ccccc4)ncc3Cl)c2)cc1] |
| | 2633724-66-8 | |
| S4 | 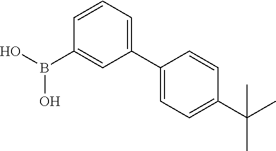 [SMILES: CC(C)(C)c1ccc(-c2cccc(B(O)O)c2)cc1] | 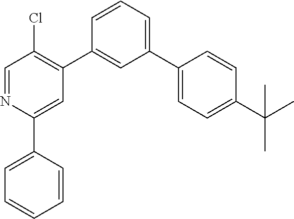 [SMILES: CC(C)(C)c1ccc(-c2cccc(-c3cc(-c4ccccc4)ncc3Cl)c2)cc1] |
| | 1107603-44-0 | |
| S5 | 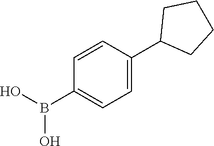 [SMILES: OB(O)c1ccc(C2CCCC2)cc1] | 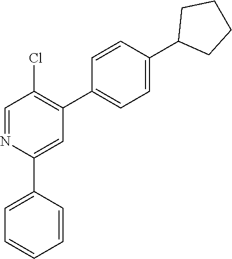 [SMILES: Clc1cnc(-c2ccccc2)cc1-c1ccc(C2CCCC2)cc1] |
| | 945837-57-0 | |
| S6 | 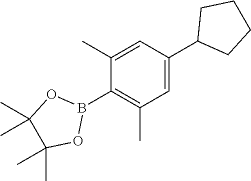 [SMILES: Cc1cc(C2CCCC2)cc(C)c1B1OC(C)(C)C(C)(C)O1] | 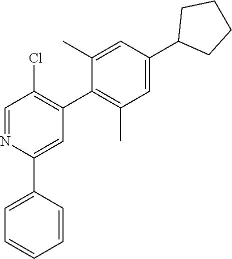 [SMILES: Cc1cc(C2CCCC2)cc(C)c1-c1cc(-c2ccccc2)ncc1Cl] |
| | 2230088-69-2 | |
| S7 | 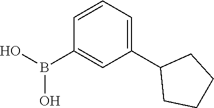 [SMILES: OB(O)c1cccc(C2CCCC2)c1] | 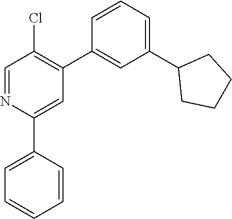 [SMILES: Clc1cnc(-c2ccccc2)cc1-c1cccc(C2CCCC2)c1] |
| | 2710297-29-1 | |
| S8 | 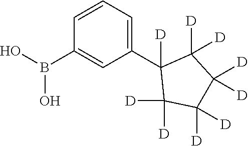 [SMILES: [2H]C1([2H])C([2H])([2H])C([2H])([2H])C([2H])(c2cccc(B(O)O)c2)C1([2H])[2H]] | 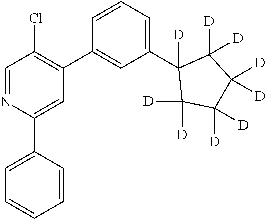 [SMILES: [2H]C1([2H])C([2H])([2H])C([2H])([2H])C([2H])(c2cccc(-c3cc(-c4ccccc4)ncc3Cl)c2)C1([2H])[2H]] |
| | 2710297-31-5 | |
| S9 | 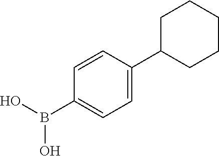 [SMILES: OB(O)c1ccc(C2CCCCC2)cc1] | 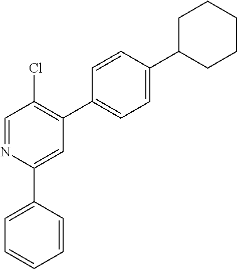 [SMILES: Clc1cnc(-c2ccccc2)cc1-c1ccc(C2CCCCC2)cc1] |
| | 374538-04-2 | |
| S10 | 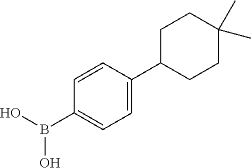 [SMILES: CC1(C)CCC(c2ccc(B(O)O)cc2)CC1] | 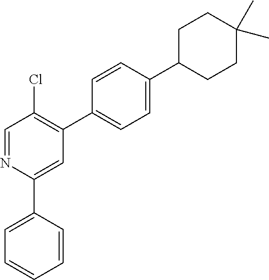 [SMILES: CC1(C)CCC(c2ccc(-c3cc(-c4ccccc4)ncc3Cl)cc2)CC1] |
| | 865360-61-8 | |
| S11 | 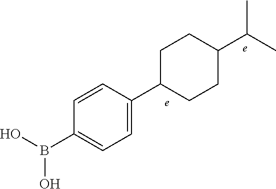 [SMILES: CC(C)C1CCC(c2ccc(B(O)O)cc2)CC1] | 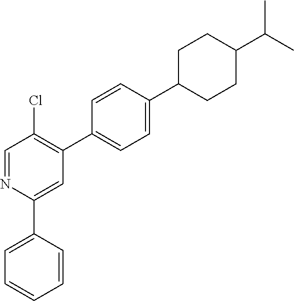 [SMILES: CC(C)C1CCC(c2ccc(-c3cc(-c4ccccc4)ncc3Cl)cc2)CC1] |
| | 2555576-51-5 | |
| S12 | 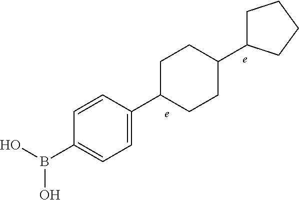 [SMILES: OB(O)c1ccc(C2CCC(C3CCCC3)CC2)cc1] | 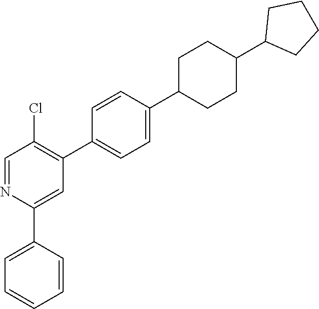 [SMILES: Clc1cnc(-c2ccccc2)cc1-c1ccc(C2CCC(C3CCCC3)CC2)cc1] |
| | 2682055-35-0 | |
| S13 | 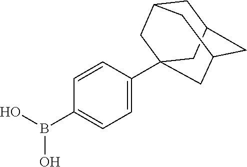 [SMILES: OB(O)c1ccc(C23CC4CC(CC(C4)C2)C3)cc1] | 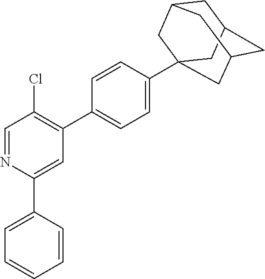 [SMILES: Clc1cnc(-c2ccccc2)cc1-c1ccc(C23CC4CC(CC(C4)C2)C3)cc1] |
| | 1527479-23-7 | |
| S14 | 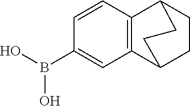 [SMILES: OB(O)c1ccc2c(c1)C1CCC2CC1] | 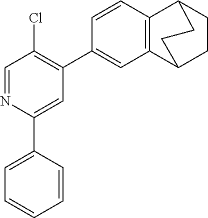 [SMILES: Clc1cnc(-c2ccccc2)cc1-c1ccc2c(c1)C1CCC2CC1] |
| | 1801624-60-1 | |
| S15 | 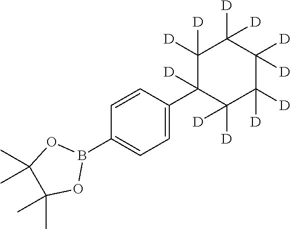 [SMILES: [2H]C1([2H])C([2H])([2H])C([2H])([2H])C([2H])(c2ccc(B3OC(C)(C)C(C)(C)O3)cc2)C([2H])([2H])C1([2H])[2H]] | 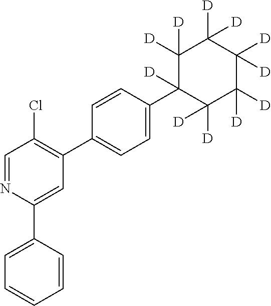 [SMILES: [2H]C1([2H])C([2H])([2H])C([2H])([2H])C([2H])(c2ccc(-c3cc(-c4ccccc4)ncc3Cl)cc2)C([2H])([2H])C1([2H])[2H]] |
| | 2648451-24-3 | |
| S16 | 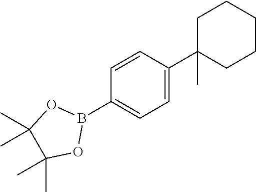 [SMILES: CC1(c2ccc(B3OC(C)(C)C(C)(C)O3)cc2)CCCCC1] | 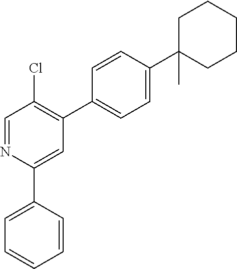 [SMILES: CC1(c2ccc(-c3cc(-c4ccccc4)ncc3Cl)cc2)CCCCC1] |
| | 1821303-97-2 | |
| S17 | 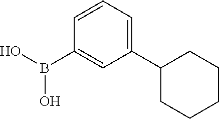 [SMILES: OB(O)c1cccc(C2CCCCC2)c1] | 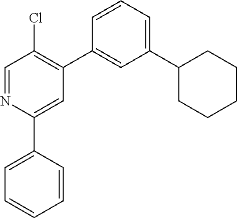 [SMILES: Clc1cnc(-c2ccccc2)cc1-c1cccc(C2CCCCC2)c1] |
| | 1565126-29-5 | |
| S18 | 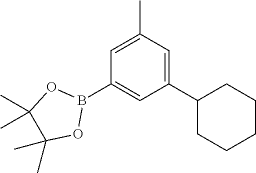 [SMILES: Cc1cc(B2OC(C)(C)C(C)(C)O2)cc(C2CCCCC2)c1] | 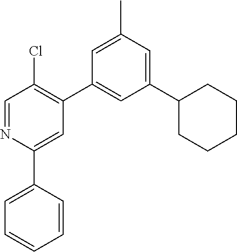 [SMILES: Cc1cc(-c2cc(-c3ccccc3)ncc2Cl)cc(C2CCCCC2)c1] |
| | 2446349-37-5 | |
| S19 | 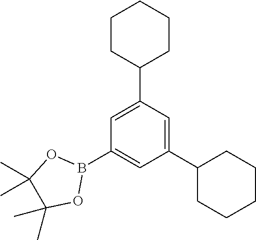 [SMILES: CC1(C)OB(c2cc(C3CCCCC3)cc(C3CCCCC3)c2)OC1(C)C] | 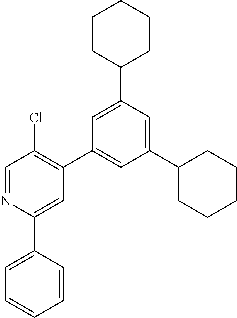 [SMILES: Clc1cnc(-c2ccccc2)cc1-c1cc(C2CCCCC2)cc(C2CCCCC2)c1] |
| | 1888456-79-8 | |
| S20 | 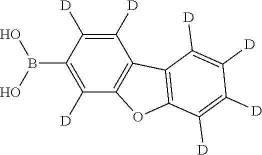 [SMILES: [2H]c1c([2H])c([2H])c2c(oc3c([2H])c(B(O)O)c([2H])c([2H])c32)c1[2H]] | 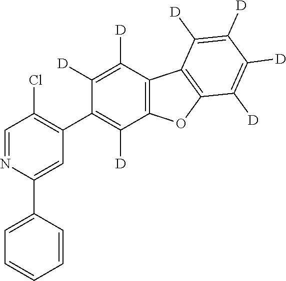 [SMILES: [2H]c1c([2H])c([2H])c2c(oc3c([2H])c(-c4cc(-c5ccccc5)ncc4Cl)c([2H])c([2H])c32)c1[2H]] |
| | 2377545-64-5 | |
| S21 | 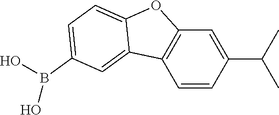 [SMILES: CC(C)c1ccc2c(c1)oc1ccc(B(O)O)cc12] | 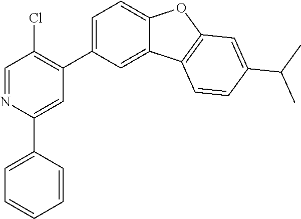 [SMILES: CC(C)c1ccc2c(c1)oc1ccc(-c3cc(-c4ccccc4)ncc3Cl)cc12] |
| | 2411321-83-8 | |
| S22 | 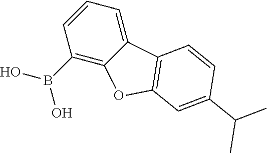 [SMILES: CC(C)c1ccc2c(c1)oc1c(B(O)O)cccc12] | 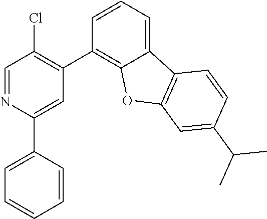 [SMILES: CC(C)c1ccc2c(c1)oc1c(-c3cc(-c4ccccc4)ncc3Cl)cccc12] |
| | 2777088-13-6 | |
| S23 | 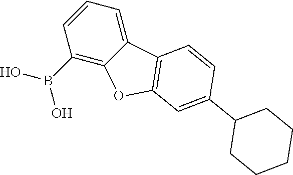 [SMILES: OB(O)c1cccc2c1oc1cc(C3CCCCC3)ccc12] | 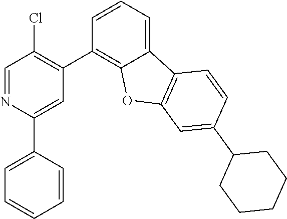 [SMILES: Clc1cnc(-c2ccccc2)cc1-c1cccc2c1oc1cc(C3CCCCC3)ccc12] |
| | 2377531-42-3 | |
| S24 | 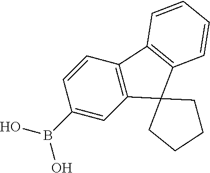 [SMILES: OB(O)c1ccc2c(c1)C1(CCCC1)c1ccccc1-2] | 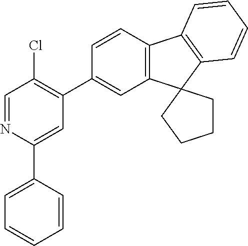 [SMILES: Clc1cnc(-c2ccccc2)cc1-c1ccc2c(c1)C1(CCCC1)c1ccccc1-2] |
| | 799559-86-7 | |
| S25 | 2633724-66-8 | 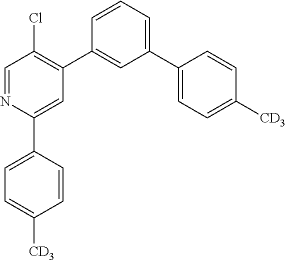 [SMILES: [2H]C([2H])([2H])c1ccc(-c2cccc(-c3cc(-c4ccc(C([2H])([2H])[2H])cc4)ncc3Cl)c2)cc1] |
| | 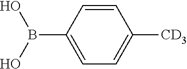 [SMILES: [2H]C([2H])([2H])c1ccc(B(O)O)cc1] | |
| | 1398503-82-6 | |
| S26 | 2230088-69-2 | 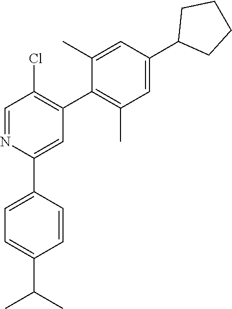 [SMILES: Cc1cc(C2CCCC2)cc(C)c1-c1cc(-c2ccc(C(C)C)cc2)ncc1Cl] |
| | 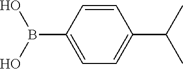 | |
| | 16152-51-5 | |
| S27 | 374538-04-2 | 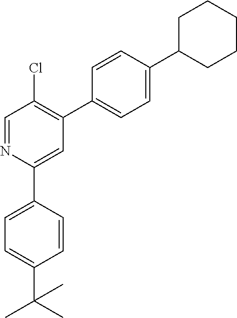 [SMILES: CC(C)(C)c1ccc(-c2cc(-c3ccc(C4CCCCC4)cc3)c(Cl)cn2)cc1] |
| | 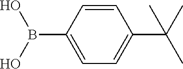 | |
| | 123324-71-0 | |
| S28 | 1565126-29-5 | 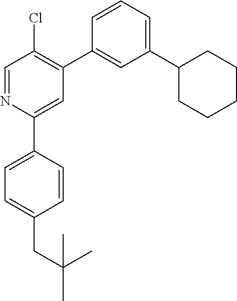 [SMILES: CC(C)(C)Cc1ccc(-c2cc(-c3cccc(C4CCCCC4)c3)c(Cl)cn2)cc1] |
| | 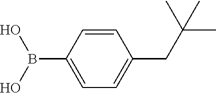 | |
| | 186498-04-4 | |
| S29 | 2710297-29-1 | 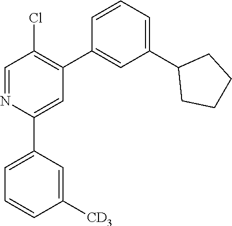 [SMILES: [2H]C([2H])([2H])c1cccc(-c2cc(-c3cccc(C4CCCC4)c3)c(Cl)cn2)c1] |
| | 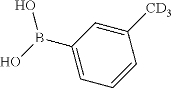 [SMILES: [2H]C([2H])([2H])c1cccc(B(O)O)c1] | |
| | 2241866-89-5 | |
| S30 | 945837-57-0 | 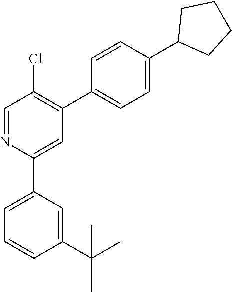 [SMILES: CC(C)(C)c1cccc(-c2cc(-c3ccc(C4CCCC4)cc3)c(Cl)cn2)c1] |
| | 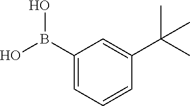 | |
| | 560132-24-3 | |
| S31 | 2555576-51-5 | 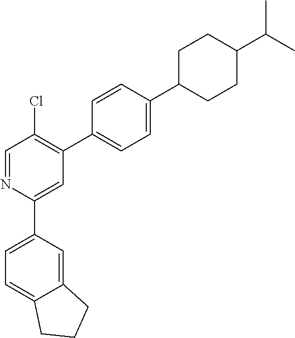 [SMILES: CC(C)C1CCC(c2ccc(-c3cc(-c4ccc5c(c4)CCC5)ncc3Cl)cc2)CC1] |
| | 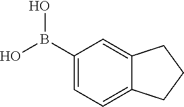 [SMILES: OB(O)c1ccc2c(c1)CCC2] | |
| | 196861-31-1 | |
| S32 | 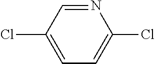 | 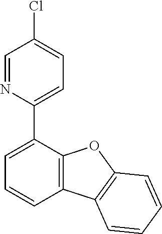 [SMILES: Clc1ccc(-c2cccc3c2oc2ccccc23)nc1] |
| | 16110-09-1 | |
| | 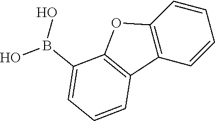 [SMILES: OB(O)c1cccc2c1oc1ccccc12] | |
| | 100124-06-9 | |
| S33 | 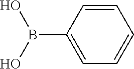 | 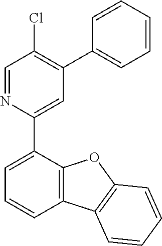 [SMILES: Clc1cnc(-c2cccc3c2oc2ccccc23)cc1-c1ccccc1] |
| | 98-80-6 | |
| | 100124-06-9 | |
| S34 | 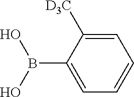 [SMILES: [2H]C([2H])([2H])c1ccccc1B(O)O] | 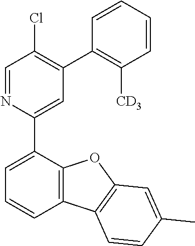 [SMILES: [2H]C([2H])([2H])c1ccccc1-c1cc(-c2cccc3c2oc2cc(C)ccc23)ncc1Cl] |
| | 2200293-21-4 | |
| | 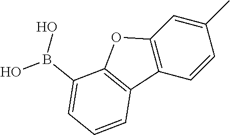 [SMILES: Cc1ccc2c(c1)oc1c(B(O)O)cccc12] | |
| | 2708239-91-0 | |
| S35 | 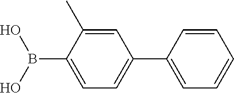 [SMILES: Cc1cc(-c2ccccc2)ccc1B(O)O] | 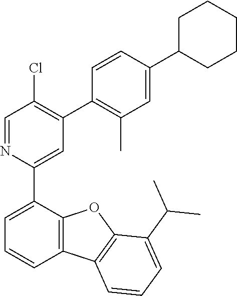 [SMILES: Cc1cc(C2CCCCC2)ccc1-c1cc(-c2cccc3c2oc2c(C(C)C)cccc23)ncc1Cl] |
| | 1383628-42-9 | |
| | 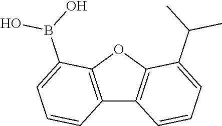 [SMILES: CC(C)c1cccc2c1oc1c(B(O)O)cccc12] | |
| | 1435893-11-0 | |
| S36 | 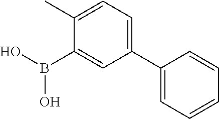 [SMILES: Cc1ccc(-c2ccccc2)cc1B(O)O] | 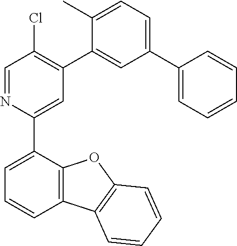 [SMILES: Cc1ccc(-c2ccccc2)cc1-c1cc(-c2cccc3c2oc2ccccc23)ncc1Cl] |
| | 1438810-09-3 | |
| | 100124-06-9 | |
| S37 | 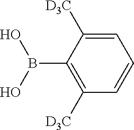 [SMILES: [2H]C([2H])([2H])c1cccc(C([2H])([2H])[2H])c1B(O)O] | 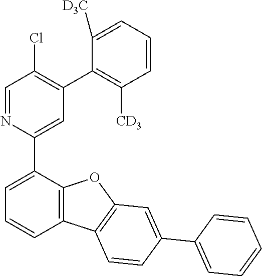 [SMILES: [2H]C([2H])([2H])c1cccc(C([2H])([2H])[2H])c1-c1cc(-c2cccc3c2oc2cc(-c4ccccc4)ccc23)ncc1Cl] |
| | 2496660-71-8 | |
| | 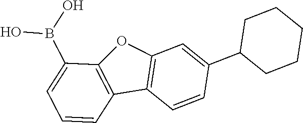 [SMILES: OB(O)c1cccc2c1oc1cc(C3CCCCC3)ccc12] | |
| | 2377531-42-3 | |
| S38 | 2200293-21-4 | 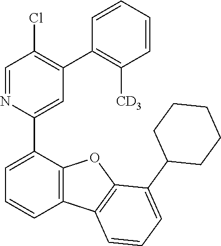 [SMILES: [2H]C([2H])([2H])c1ccccc1-c1cc(-c2cccc3c2oc2c(C4CCCCC4)cccc23)ncc1Cl] |
| | 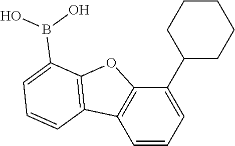 [SMILES: OB(O)c1cccc2c1oc1c(C3CCCCC3)cccc12] | |
| | 2397691-97-1 | |
| S39 | 2200293-21-4 | 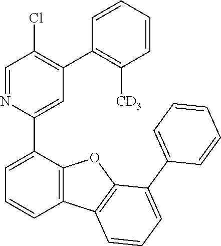 [SMILES: [2H]C([2H])([2H])c1ccccc1-c1cc(-c2cccc3c2oc2c(-c4ccccc4)cccc23)ncc1Cl] |
| | 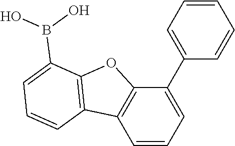 [SMILES: OB(O)c1cccc2c1oc1c(-c3ccccc3)cccc12] | |
| | 1010068-85-5 | |
| S40 | 98-80-6 | 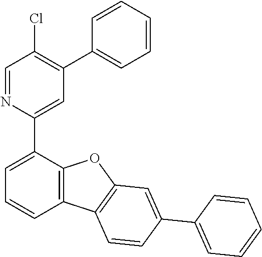 [SMILES: Clc1cnc(-c2cccc3c2oc2cc(-c4ccccc4)ccc23)cc1-c1ccccc1] |
| | 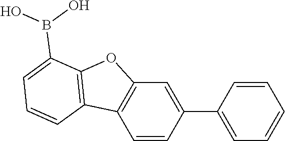 [SMILES: OB(O)c1cccc2c1oc1cc(-c3ccccc3)ccc12] | |
| | 2233599-85-2 | |
| S41 | 16110-09-1 | 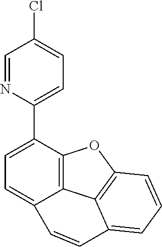 [SMILES: Clc1ccc(-c2ccc3ccc4cccc5oc2c3c45)nc1] |
| | 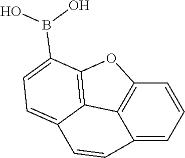 [SMILES: OB(O)c1ccc2ccc3cccc4oc1c2c34] | |
| | 2699668-31-8 | |
| S42 | 2200293-21-4 | 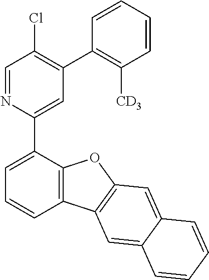 [SMILES: [2H]C([2H])([2H])c1ccccc1-c1cc(-c2cccc3c2oc2cc4ccccc4cc23)ncc1Cl] |
| | 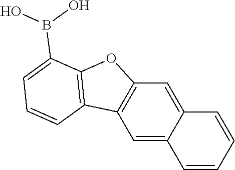 [SMILES: OB(O)c1cccc2c1oc1cc3ccccc3cc12] | |
| | 2170495-86-8 | |
| S43 | 2200293-21-4 | 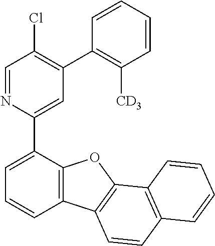 [SMILES: [2H]C([2H])([2H])c1ccccc1-c1cc(-c2cccc3c2oc2c4ccccc4ccc32)ncc1Cl] |
| | 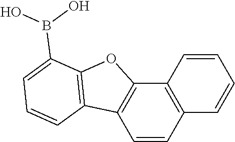 [SMILES: OB(O)c1cccc2c1oc1c3ccccc3ccc21] | |
| | 1548470-92-3 | |
| S44 | 2200293-21-4 | 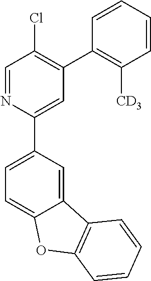 [SMILES: [2H]C([2H])([2H])c1ccccc1-c1cc(-c2ccc3oc4ccccc4c3c2)ncc1Cl] |
| | 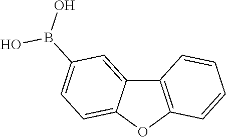 [SMILES: OB(O)c1ccc2oc3ccccc3c2c1] | |
| | 402936-15-6 | |
| S45 | 2200293-21-4 | 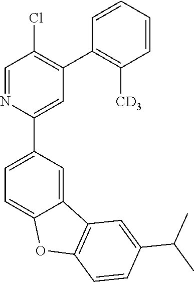 [SMILES: [2H]C([2H])([2H])c1ccccc1-c1cc(-c2ccc3oc4ccc(C(C)C)cc4c3c2)ncc1Cl] |
| | 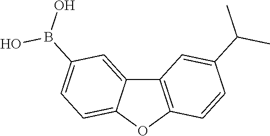 [SMILES: CC(C)c1ccc2oc3ccc(B(O)O)cc3c2c1] | |
| | 2411321-83-8 | |
| S46 | 2200293-21-4 | 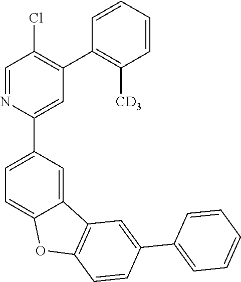 [SMILES: [2H]C([2H])([2H])c1ccccc1-c1cc(-c2ccc3oc4ccc(-c5ccccc5)cc4c3c2)ncc1Cl] |
| | 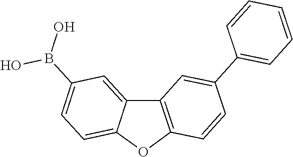 [SMILES: OB(O)c1ccc2oc3ccc(-c4ccccc4)cc3c2c1] | |
| | 1199349-99-9 | |
| S47 | 2200293-21-4 | 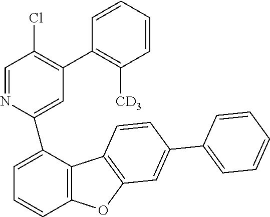 [SMILES: [2H]C([2H])([2H])c1ccccc1-c1cc(-c2cccc3oc4cc(-c5ccccc5)ccc4c23)ncc1Cl] |
| | 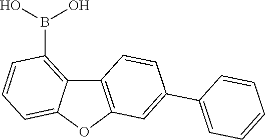 [SMILES: OB(O)c1cccc2oc3cc(-c4ccccc4)ccc3c12] | |
| | 1821233-94-6 | |
| S48 | 2200293-21-4 | 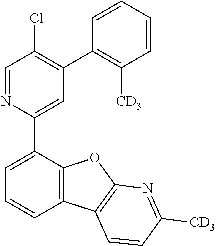 [SMILES: [2H]C([2H])([2H])c1ccc2c(n1)oc1c(-c3cc(-c4ccccc4C([2H])([2H])[2H])c(Cl)cn3)cccc12] |
| | 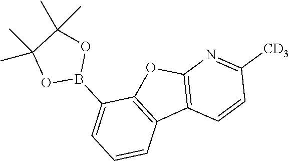 [SMILES: [2H]C([2H])([2H])c1ccc2c(n1)oc1c(B3OC(C)(C)C(C)(C)O3)cccc12] | |
| | 2415228-15-6 | |
| S49 | 2200293-21-4 | 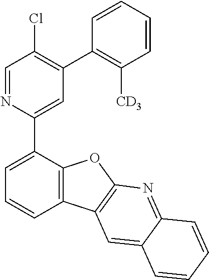 [SMILES: [2H]C([2H])([2H])c1ccccc1-c1cc(-c2cccc3c2oc2nc4ccccc4cc23)ncc1Cl] |
| | 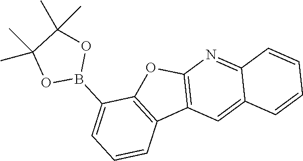 [SMILES: CC1(C)OB(c2cccc3c2oc2nc4ccccc4cc23)OC1(C)C] | |
| | 2218458-04-7 | |
| S50 | 16110-09-1 | 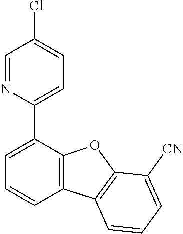 [SMILES: N#Cc1cccc2c1oc1c(-c3ccc(Cl)cn3)cccc12] |
| | 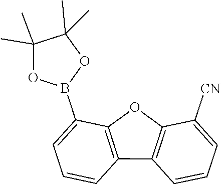 [SMILES: CC1(C)OB(c2cccc3c2oc2c(C#N)cccc23)OC1(C)C] | |
| | 1673545-14-6 | |
| S51 | 16110-09-1 | 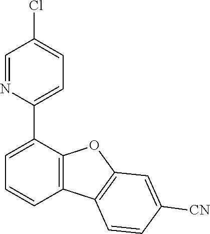 [SMILES: N#Cc1ccc2c(c1)oc1c(-c3ccc(Cl)cn3)cccc12] |
| | 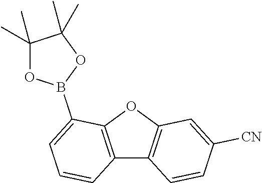 [SMILES: CC1(C)OB(c2cccc3c2oc2cc(C#N)ccc23)OC1(C)C] | |
| | 2458817-56-4 | |
| S52 | 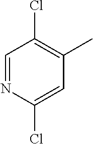 | 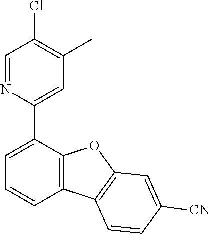 [SMILES: Cc1cc(-c2cccc3c2oc2cc(C#N)ccc23)ncc1Cl] |
| | 886365-00-0 | |
| | 2458817-56-4 | |
| S53 | 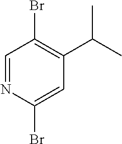 | 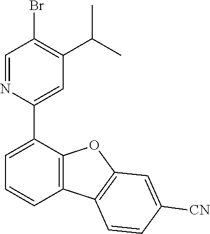 [SMILES: CC(C)c1cc(-c2cccc3c2oc2cc(C#N)ccc23)ncc1Br] |
| | 1256833-52-9 | |
| | 2458817-56-4 | |
| S54 | 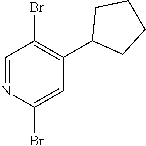 [SMILES: Brc1cc(C2CCCC2)c(Br)cn1] | 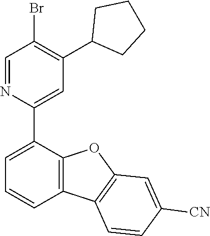 [SMILES: N#Cc1ccc2c(c1)oc1c(-c3cc(C4CCCC4)c(Br)cn3)cccc12] |
| | 1381942-00-2 | |
| | 2458817-56-4 | |
| S55 | 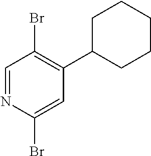 [SMILES: Brc1cc(C2CCCCC2)c(Br)cn1] | 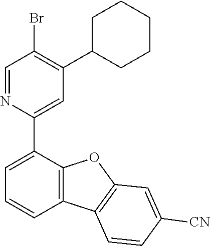 [SMILES: N#Cc1ccc2c(c1)oc1c(-c3cc(C4CCCCC4)c(Br)cn3)cccc12] |
| | 1381933-49-8 | |
| | 2458817-56-4 | |
| S56 | 2200293-21-4 2458817-56-4 | 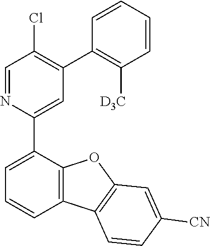 [SMILES: [2H]C([2H])([2H])c1ccccc1-c1cc(-c2cccc3c2oc2cc(C#N)ccc23)ncc1Cl] |
| S57 | 16110-09-1 | 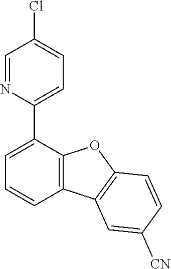 [SMILES: N#Cc1ccc2oc3c(-c4ccc(Cl)cn4)cccc3c2c1] |
| | 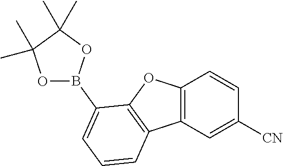 [SMILES: CC1(C)OB(c2cccc3c2oc2ccc(C#N)cc23)OC1(C)C] | |
| | 1638837-02-1 | |
| S58 | 16110-09-1 | 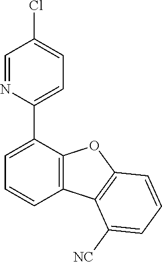 [SMILES: N#Cc1cccc2oc3c(-c4ccc(Cl)cn4)cccc3c12] |
| | 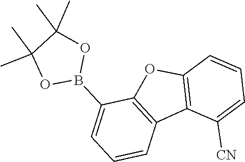 [SMILES: CC1(C)OB(c2cccc3c2oc2cccc(C#N)c23)OC1(C)C] | |
| | 2458817-52-0 | |
| S59 | 16110-09-1 | 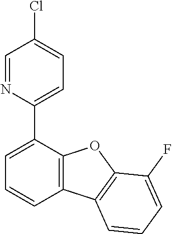 [SMILES: Fc1cccc2c1oc1c(-c3ccc(Cl)cn3)cccc12] |
| | 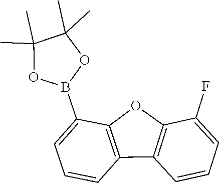 [SMILES: CC1(C)OB(c2cccc3c2oc2c(F)cccc23)OC1(C)C] | |
| | 2714359-25-6 | |
| S60 | 2200293-21-4 2714359-25-6 | 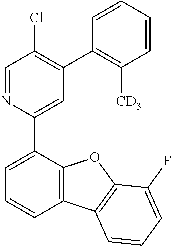 [SMILES: [2H]C([2H])([2H])c1ccccc1-c1cc(-c2cccc3c2oc2c(F)cccc23)ncc1Cl] |
| S61 | 16110-09-1 | 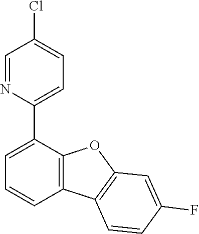 [SMILES: Fc1ccc2c(c1)oc1c(-c3ccc(Cl)cn3)cccc12] |
| | 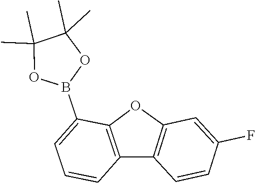 [SMILES: CC1(C)OB(c2cccc3c2oc2cc(F)ccc23)OC1(C)C] | |
| | 2412928-17-5 | |
| S62 | 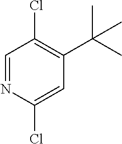 | 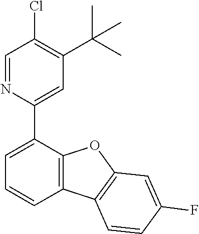 [SMILES: CC(C)(C)c1cc(-c2cccc3c2oc2cc(F)ccc23)ncc1Cl] |
| | 124420-75-3 | |
| | 2412928-17-5 | |
| S63 | 16110-09-1 | 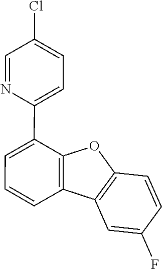 [SMILES: Fc1ccc2oc3c(-c4ccc(Cl)cn4)cccc3c2c1] |
| | 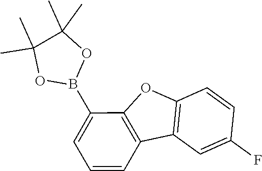 [SMILES: CC1(C)OB(c2cccc3c2oc2ccc(F)cc23)OC1(C)C] | |
| | 2229864-94-0 | |
| S64 | 16110-09-1 | 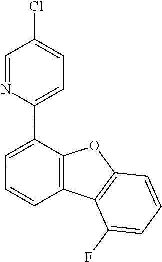 [SMILES: Fc1cccc2oc3c(-c4ccc(Cl)cn4)cccc3c12] |
| | 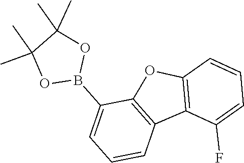 [SMILES: CC1(C)OB(c2cccc3c2oc2cccc(F)c23)OC1(C)C] | |
| | 2417213-49-9 | |
| S65 | 16110-09-1 | 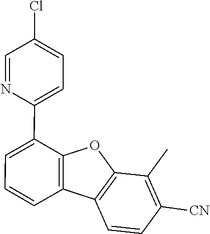 [SMILES: Cc1c(C#N)ccc2c1oc1c(-c3ccc(Cl)cn3)cccc12] |
| | 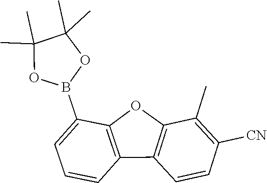 [SMILES: Cc1c(C#N)ccc2c1oc1c(B3OC(C)(C)C(C)(C)O3)cccc12] | |
| | Synthesized as in | |
| | US 2020/0251666 | |
| | from 1349716-12-6 | |
| S66 | 886365-00-0 | 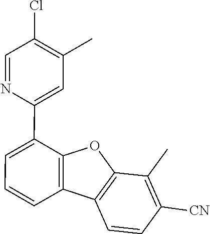 [SMILES: Cc1cc(-c2cccc3c2oc2c(C)c(C#N)ccc23)ncc1Cl] |
| | 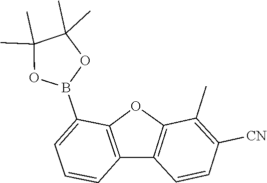 [SMILES: Cc1c(C#N)ccc2c1oc1c(B3OC(C)(C)C(C)(C)O3)cccc12] | |
| S67 | 1256833-52-9 | 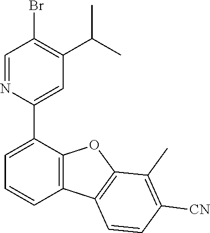 [SMILES: Cc1c(C#N)ccc2c1oc1c(-c3cc(C(C)C)c(Br)cn3)cccc12] |
| | 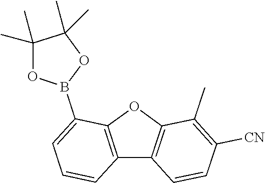 [SMILES: Cc1c(C#N)ccc2c1oc1c(B3OC(C)(C)C(C)(C)O3)cccc12] | |
| S68 | 1381942-00-2 | 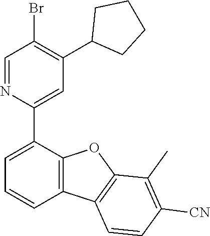 [SMILES: Cc1c(C#N)ccc2c1oc1c(-c3cc(C4CCCC4)c(Br)cn3)cccc12] |
| | 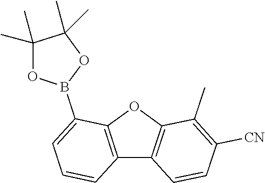 [SMILES: Cc1c(C#N)ccc2c1oc1c(B3OC(C)(C)C(C)(C)O3)cccc12] | |
| S69 | 16110-09-1 | 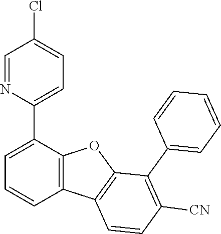 [SMILES: N#Cc1ccc2c(oc3c(-c4ccc(Cl)cn4)cccc32)c1-c1ccccc1] |
| | | Synthesized as in |
| | | US 2020/0091442 |
| S70 | 16110-09-1 | 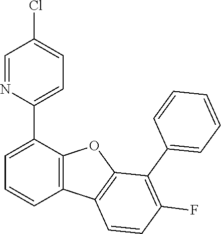 [SMILES: Fc1ccc2c(oc3c(-c4ccc(Cl)cn4)cccc32)c1-c1ccccc1] |
| | | Synthesized as in |
| | | US 2020/0091442 |
| S71 | 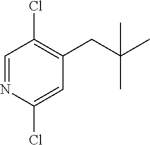 | 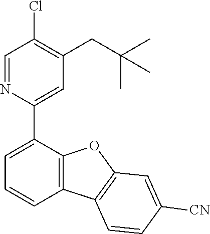 [SMILES: CC(C)(C)Cc1cc(-c2cccc3c2oc2cc(C#N)ccc23)ncc1Cl] |
| | Synthesized as in | |
| | CN11227980A, | |
| | Use of 72990-37-5 | |
| | 2458817-56-4 | |
| S72 | 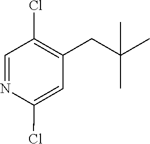 | 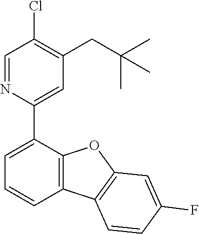 [SMILES: CC(C)(C)Cc1cc(-c2cccc3c2oc2cc(F)ccc23)ncc1Cl] |
| | 2412928-17-5 | |
| S73 | 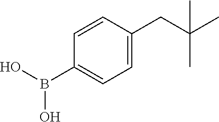 | 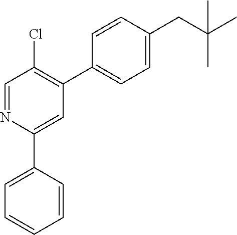 [SMILES: CC(C)(C)Cc1ccc(-c2cc(-c3ccccc3)ncc2Cl)cc1] |
| | 186498-04-4 | |
| S74 | 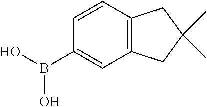 | 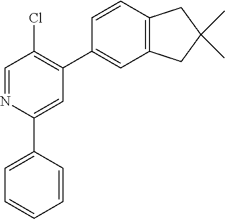 [SMILES: CC1(C)Cc2ccc(-c3cc(-c4ccccc4)ncc3Cl)cc2C1] |
| | 1616299-96-7 | |
| S75 | 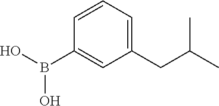 | 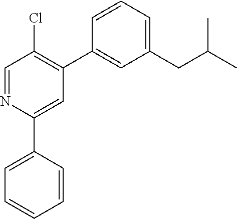 [SMILES: CC(C)Cc1cccc(-c2cc(-c3ccccc3)ncc2Cl)c1] |
| | 153624-42-1 | |
| S76 | 16110-09-1 | 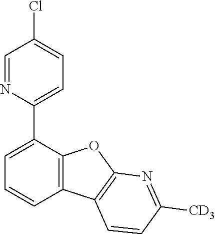 [SMILES: [2H]C([2H])([2H])c1ccc2c(n1)oc1c(-c3ccc(Cl)cn3)cccc12] |
| | 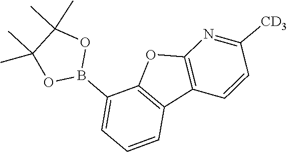 [SMILES: [2H]C([2H])([2H])c1ccc2c(n1)oc1c(B3OC(C)(C)C(C)(C)O3)cccc12] | |
| | 2415228-15-6 | |
| S100 | 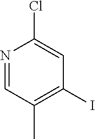 | 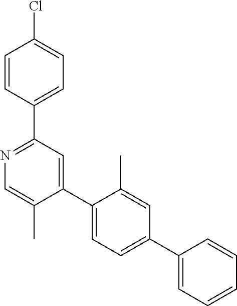 [SMILES: Cc1cc(-c2ccccc2)ccc1-c1cc(-c2ccc(Cl)cc2)ncc1C] |
| | 1197957-18-8 | |
| | 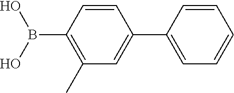 [SMILES: Cc1cc(-c2ccccc2)ccc1B(O)O] | |
| | 1383628-42-9 | |
| | 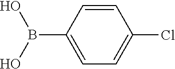 | |
| | 1679-18-1 | |
| S101 | 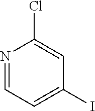 | 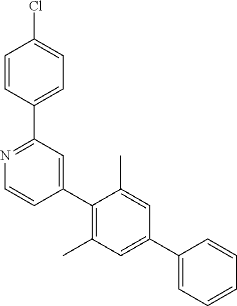 [SMILES: Cc1cc(-c2ccccc2)cc(C)c1-c1ccnc(-c2ccc(Cl)cc2)c1] |
| | 153034-86-7 | |
| | 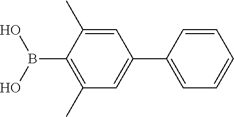 [SMILES: Cc1cc(-c2ccccc2)cc(C)c1B(O)O] | |
| | 1057654-43-9 | |
| | 1679-18-1 | |
| S102 | 153034-86-7 | 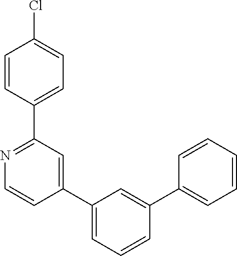 [SMILES: Clc1ccc(-c2cc(-c3cccc(-c4ccccc4)c3)ccn2)cc1] |
| | 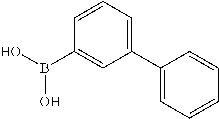 [SMILES: OB(O)c1cccc(-c2ccccc2)c1] | |
| | 5122-95-2 | |
| | 1679-18-1 | |
| S103 | 1197957-18-8 | 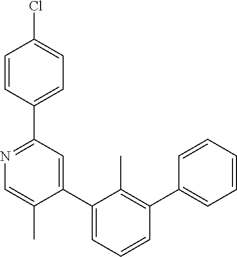 [SMILES: Cc1cnc(-c2ccc(Cl)cc2)cc1-c1cccc(-c2ccccc2)c1C] |
| | 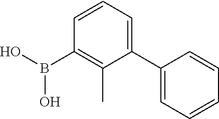 [SMILES: Cc1c(B(O)O)cccc1-c1ccccc1] | |
| | 1899060-83-3 | |
| | 1679-18-1 | |
| S104 | 1197957-18-8 2633724-66-8 1679-18-1 | 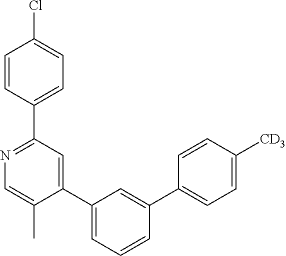 [SMILES: [2H]C([2H])([2H])c1ccc(-c2cccc(-c3cc(-c4ccc(Cl)cc4)ncc3C)c2)cc1] |
| S105 | 1197957-18-8 945837-57-0 1679-18-1 | 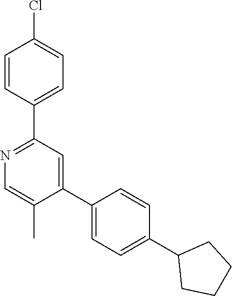 [SMILES: Cc1cnc(-c2ccc(Cl)cc2)cc1-c1ccc(C2CCCC2)cc1] |
| S106 | 153034-86-7 2230088-69-2 1679-18-1 | 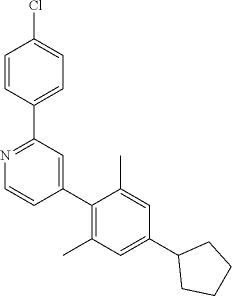 [SMILES: Cc1cc(C2CCCC2)cc(C)c1-c1ccnc(-c2ccc(Cl)cc2)c1] |
| S107 | 1197957-18-8 2710297-29-1 1679-18-1 | 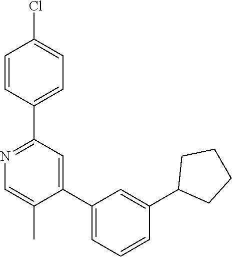 [SMILES: Cc1cnc(-c2ccc(Cl)cc2)cc1-c1cccc(C2CCCC2)c1] |
| S108 | 1197957-18-8 374538-04-2 1679-18-1 | 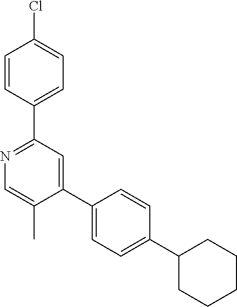 [SMILES: Cc1cnc(-c2ccc(Cl)cc2)cc1-c1ccc(C2CCCCC2)cc1] |
| S109 | 1197957-18-8 2555576-51-5 1679-18-1 | 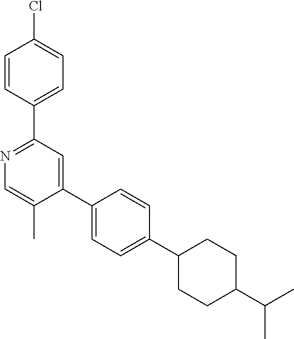 [SMILES: Cc1cnc(-c2ccc(Cl)cc2)cc1-c1ccc(C2CCC(C(C)C)CC2)cc1] |
| S110 | 1197957-18-8 2682055-35-0 1679-18-1 | 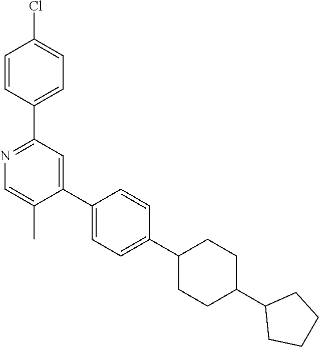 [SMILES: Cc1cnc(-c2ccc(Cl)cc2)cc1-c1ccc(C2CCC(C3CCCC3)CC2)cc1] |
| S111 | 153034-86-7 1565126-29-5 1679-18-1 | 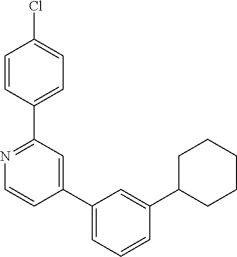 [SMILES: Clc1ccc(-c2cc(-c3cccc(C4CCCCC4)c3)ccn2)cc1] |
| S112 | 1197957-18-8 2377545-64-5 1679-18-1 | 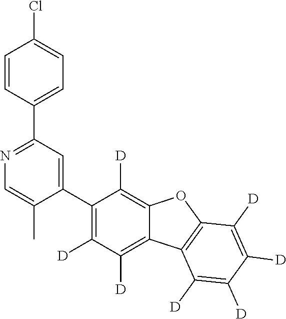 [SMILES: [2H]c1c([2H])c([2H])c2c(oc3c([2H])c(-c4cc(-c5ccc(Cl)cc5)ncc4C)c([2H])c([2H])c32)c1[2H]] |
| S113 | 1197957-18-8 2411321-83-8 1679-18-1 | 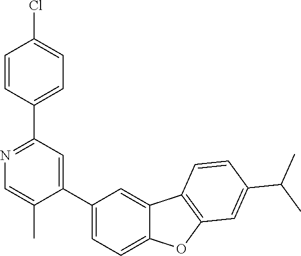 [SMILES: Cc1cnc(-c2ccc(Cl)cc2)cc1-c1ccc2oc3cc(C(C)C)ccc3c2c1] |
| S114 | 1197957-18-8 333432-28-3 1679-18-1 | 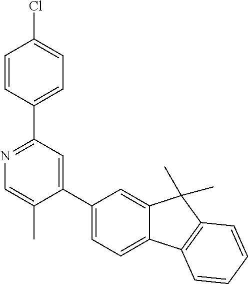 [SMILES: Cc1cnc(-c2ccc(Cl)cc2)cc1-c1ccc2c(c1)C(C)(C)c1ccccc1-2] |
| S115 | 1197957-18-8 186498-04-4 1679-18-1 | 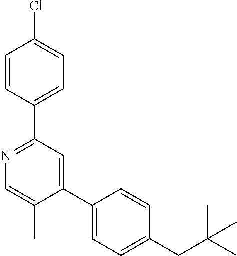 [SMILES: Cc1cnc(-c2ccc(Cl)cc2)cc1-c1ccc(CC(C)(C)C)cc1] |
| S116 | 1197957-18-8 1616299-96-7 1679-18-1 | 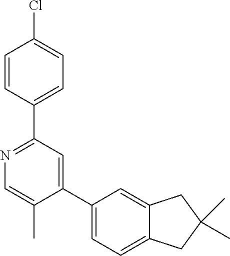 [SMILES: Cc1cnc(-c2ccc(Cl)cc2)cc1-c1ccc2c(c1)CC(C)(C)C2] |
| S117 | 1197957-18-8 153624-42-1 1679-18-1 | 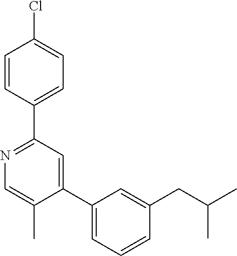 [SMILES: Cc1cnc(-c2ccc(Cl)cc2)cc1-c1cccc(CC(C)C)c1] |

B) Synthesis of Iridium Complexes According to the Invention:

### Example IrL1

a) Step 1a:

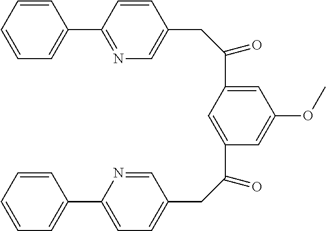 [SMILES: COc1cc(C(=O)Cc2ccc(-c3ccccc3)nc2)cc(C(=O)Cc2ccc(-c3ccccc3)nc2)c1]

A well-stirred mixture of 9.6 g (50 mmol) 1,1′-(5-methoxy-1,3-phenylene)bis-ethenone [35227-79-3], 23.4 g (100 mmol) 5-bromo-2-phenyl pyridine [27012-25-5], and 150 ml THF is mixed with 24.0 g (250 mmol) sodium tert-butanolate [865-48-5], 577 mg (1 mmol) XantPhos [161265-03-8], and 225 mg (1 mmol) palladium(II) acetate [3375-31-3], and then heated at reflux for 3 h. After cooling, the THF is removed in vacuo, the residue is taken up in 300 ml dichloromethane (DCM), the organic phase is washed twice with 150 ml water and once with 100 ml saturated saline, and dried over magnesium sulfate. Filter off the desiccant, remove the DCM in vacuo, and chromatograph the residue (Torrent automatic column machine from Semrau). Yield: 15.6 g (31 mmol) 62%; purity: ca. 97% by ¹H-NMR.

b) Step 1b:

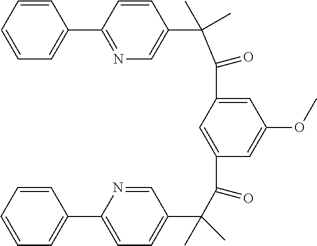 [SMILES: COc1cc(C(=O)C(C)(C)c2ccc(-c3ccccc3)nc2)cc(C(=O)C(C)(C)c2ccc(-c3ccccc3)nc2)c1]

To a well-stirred solution of 18.3 g (50 mmol) 1a in 1000 ml tetrahydrofuran (THF), maintained at 25° C., add dropwise for 5 min 100 ml (100 mmol) potassium hexamethyldisilazide (KHMDS) [40949-94-0], 1M in THF and stir for 15 min. Then add 3.4 ml (100 mmol) of methyl iodide [74-88-4] at one time and stir for 30 min. Then, 100 ml (100 mmol) of potassium hexamethyldisilazide (KHMDS), 1M in THF is added again to the reaction mixture during 5 min and stirring is continued for 15 min. Then add 3.4 ml (100 mmol) of methyl iodide at a time and stir for 30 min. Then, 10 ml (10 mmol) of potassium hexamethyldisilazaide KHMDS), 1M in THF is added to the reaction mixture again during 5 min and stirring is continued for 15 min. Then add 0.34 ml (10 mmol) methyl iodide at a time and stir for 1 h. Remove the THF in vacuo, take up the residue in 300 ml dichloromethane (DCM), wash the organic phase twice with 150 ml water each and once with 100 ml saturated brine, and dry over magnesium sulfate. Filter off the desiccant, remove the DCM in vacuo and chromatograph (Torrent columns automat from Semrau) the residue. Yield: 20.1 g (36 mmol) 72%; purity: ca. 97% by ¹H-NMR.

Step 1c:

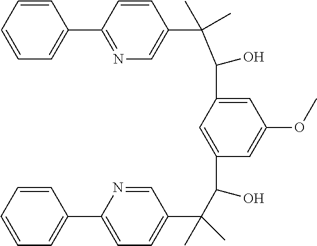 [SMILES: COc1cc(C(O)C(C)(C)c2ccc(-c3ccccc3)nc2)cc(C(O)C(C)(C)c2ccc(-c3ccccc3)nc2)c1]

To a well-stirred solution of 55.5 g (100 mmol) 1b in 1500 ml THF, cooled to 0° C., add 15.2 g (400 mmol) lithium aluminum hydride [16853-85-3] in portions and stir for 15 min. Allow the reaction mixture to warm to room temperature, stir for 1 h, cool again to 0° C., then add dropwise 15 ml water (caution: exothermic reaction, gas evolution!), 15 ml 15 wt % aqueous NaOH, and 45 ml water, and stir for 30 min. Filter off the precipitated aluminum salts, concentrate the filtrate to dryness, collect the residue in 300 ml DCM and 100 ml ethyl acetate (EA), filter over a silica gel bed pre-slurried with DCM:EE (3:1 vv), and remove the solvent in vacuo. Yield: 52.9 g (95 mmol), 95% diastereomer mixture; purity: ca. 97% by ¹H-NMR.

d) Step 1d:

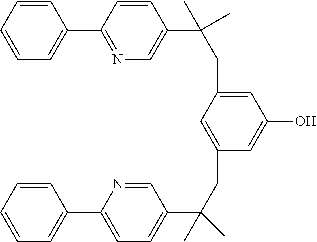 [SMILES: CC(C)(Cc1cc(O)cc(CC(C)(C)c2ccc(-c3ccccc3)nc2)c1)c1ccc(-c2ccccc2)nc1]

To a solution of 55.8 g (100 mmol) 1c in 500 ml glacial acetic acid, add 263.4 ml aqueous hydriodic acid 57 wt % and 49.3 ml aqueous hypophosphoric acid 50 wt %, and then stir for 60 h. The solution is then mixed with a solution of 1c in 500 ml glacial acetic acid. After cooling, pour onto 5 kg ice and then adjust to pH˜7 by adding solid NaOH in portions, extract the aqueous phase three times with 300 ml DCM, wash the combined organic phases two times with 200 ml water and once with 200 ml saturated brine, and then dry over magnesium sulfate. Filter off from the desiccant and concentrate the filtrate to dryness. Yield: 47.7 g (93 mmol), 93%; purity: approximately 97% by ¹H-NMR.

e) Step 1e:

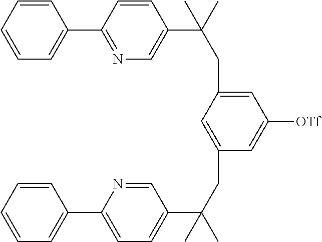 [SMILES: CC(C)(Cc1cc(CC(C)(C)c2ccc(-c3ccccc3)nc2)cc(OS(=O)(=O)C(F)(F)F)c1)c1ccc(-c2ccccc2)nc1]

To a well-stirred mixture of 51.3 g (100 mmol) of 1d, 10.5 ml (130 mmol) of pyridine [110-86-1], and 300 ml of DCM cooled to 0° C., add dropwise 21.9 ml (130 mmol) of trifluoromethanesulfonic anhydride [358-23-6], stir for 15 min at 0° C. and then for 16 h at room temperature. Hydrolyze by adding 200 g of ice, wash the combined organic phases twice with 150 ml of water and once with 100 ml of saturated brine, and then dry over magnesium sulfate. Filter off the desiccant and concentrate the filtrate to dryness. Yield: 61.5 g (95 mmol), 95%; purity: approximately 97% by ¹H-NMR.

f) Step 1f:

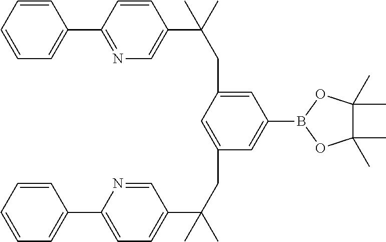 [SMILES: CC(C)(Cc1cc(CC(C)(C)c2ccc(-c3ccccc3)nc2)cc(B2OC(C)(C)C(C)(C)O2)c1)c1ccc(-c2ccccc2)nc1]

A well-stirred mixture of 64.5 g (100 mmol) 1e, 50.8 g (200 mmol) bis(pinacolato)diborane [73183-34-3], 29.5 g (300 mmol) potassium acetate, anhydrous [127-08-2], 200 g glass spheres (3 mm diameter), 3.7 g (5 mmol) bis(tricyclohexylphosphino)palladium(II) chloride [29934-17-6], and 1500 ml dioxane is stirred for 18 h at 100° C. Filter off while still warm over a Celite bed pre-slurried with dioxane, concentrate the filtrate in vacuo, collect the residue in 500 ml DCM, wash the organic phase twice with 300 ml water and once with 200 ml saturated saline, and dry over magnesium sulfate. Add 100 ml of EA, aspirate over a silica yellow bed pre-slurried with DCM:EA (3:1, vv), concentrate the filtrate to dryness and chromatograph (Torrent automatic column machine from Semrau) the residue. Yield: 50.5 g (76 mmol) 76%; purity: ca. 97% by ¹H-NMR.

g) Step 1g:

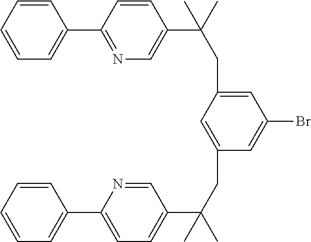 [SMILES: CC(C)(Cc1cc(Br)cc(CC(C)(C)c2ccc(-c3ccccc3)nc2)c1)c1ccc(-c2ccccc2)nc1]

A suspension of 62.3 g (100 mmol) 1f in 500 ml MeOH is heated to 40° C. and then a solution of 46.9 g (210 mmol) copper(II) bromide [7789-45-9] in 400 ml water is added dropwise for 30 min with good stirring. After completed addition, heat for 12 h under reflux, then distill off about 500 ml and substitute with 500 ml of water. Allow to cool to room temperature with stirring, aspirate from the precipitated solid, wash three times with 200 ml water each time, and aspirate dry. Suspend the solid in 600 ml DCM, add 200 ml conc. ammonia, stir for 2 h, separate the aqueous phase, wash the organic phase three times with 200 ml each of 2.5 N ammonia solution, twice with 200 ml each of water and once with saturated brine and dry over magnesium sulfate. Aspirate from the desiccant, add 200 ml MeOH to the filtrate and concentrate to about 200 ml. Aspirate from the crystallized product, wash twice with a little methanol and dry in vacuo. Yield: 48.2 g (84 mmol) 84%; purity: ca. 97% by ¹H NMR.

h) Step 1h:

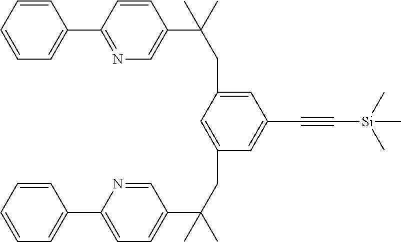 [SMILES: CC(C)(Cc1cc(C#C[Si](C)(C)C)cc(CC(C)(C)c2ccc(-c3ccccc3)nc2)c1)c1ccc(-c2ccccc2)nc1]

A mixture of 57.6 g (100 mmol) 1g, 28.6 ml (200 mmol) trimethyl silylacetylene [1066-54-2], 64.1 ml (500 mmol) triethylamine [121-44-8], 300 ml DMF, 572 mg (3 mmol) copper (1) iodide [7681-65-4], and 2.1 g (3 mmol) bis(triphenylphosphino)palladium dichloride [13965-03-2] is stirred for 12 h at 75° C. The reaction mixture is largely concentrated in vacuo, the residue is taken up in 500 ml DCM, washed three times each with 200 ml water and once with 200 ml saturated brine, and dried over magnesium sulfate. Add 100 ml of EA, filter from the desiccant over a Celite bed pre-slurried with DCM:EA (5:1 vv) and concentrate the filtrate in vacuo. The crude product obtained is further reacted without further purification. Yield: 53.6 g (90 mmol) 90%. Purity ca. 95% by ¹H NMR.

i) Step 1i:

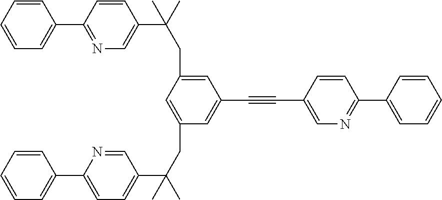 [SMILES: CC(C)(Cc1cc(C#Cc2ccc(-c3ccccc3)nc2)cc(CC(C)(C)c2ccc(-c3ccccc3)nc2)c1)c1ccc(-c2ccccc2)nc1]

To a well-stirred solution of 59.3 g (100 mmol) 1 h in 500 ml of acetonitrile or dimethylacetamide (DMAC, for halobenzenes) and 4.3 ml (105 mmol) of methanol, add 13.8 g (100 mmol) of potassium carbonate and 100 g of glass beads (3 mm diameter) at room temperature. After weakly exothermic reaction, stir for 1 h more, add 23.4 g (100 mmol) 5-bromo-2-phenylpyridine [27012-25-5], 20.7 g (150 mmol) potassium carbonate, 1.91 g (4 mmol) XPhos [564483-18-7], and 449 mg (2 mmol) palladium(II) acetate or Pd₂dba₃ [51364-51-3] (for halobenzenes), and stir for 16 h under reflux. Draw off while still warm over a Celite bed pre-slurried with acetonitrile, concentrate the filtrate in vacuo at 40° C., collect the residue in 600 ml DCM, wash three times with 200 ml water each and once with 200 ml saturated brine, and dry over magnesium sulfate. Add 200 ml of EA, filter off over a silica gel bed pre-slurried with DCM/EA (3:1 vv), concentrate the filtrate to about 150 ml in vacuo, draw off from the precipitated product, wash three times with 100 ml of methanol each, and dry in vacuo at 40° C. The product is immediately hydrogenated or deuterated. Yield: 51.4 g (76 mmol) 76%; purity: ca. 97% by ¹H NMR.

j) Step 1j: Ligand L1

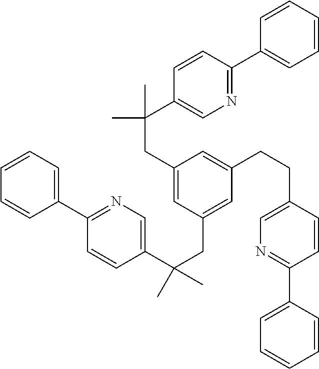 [SMILES: CC(C)(Cc1cc(CCc2ccc(-c3ccccc3)nc2)cc(CC(C)(C)c2ccc(-c3ccccc3)nc2)c1)c1ccc(-c2ccccc2)nc1]

67.4 g (100 mmol) of 1i is hydrogenated in a mixture of 500 ml THF and 300 ml MeOH with the addition of 2 g palladium (5 wt %) on charcoal and 16.1 g (300 mmol) NH₄Cl at 40° C. under 1.5 bar hydrogen atmosphere until hydrogen uptake is completed (about 12 h). Filter off from the catalyst over a Celite bed pre-slurried with THF, remove the solvent in vacuo and chromatograph (Torrent automatic column machine from Semrau) the residue. Yield: 52.6 g (78 mmol), 78%; purity: ca. 98% by ¹HNMR-.

Analogously, the deuteration of the alkyne can also be carried out using deuterium D₂, where, instead of the —CH₂CH₂— bridge/s, —CD₂CD₂- bridge/s are obtained.

k) Stage 1k: Complex IrL1

Variant A:

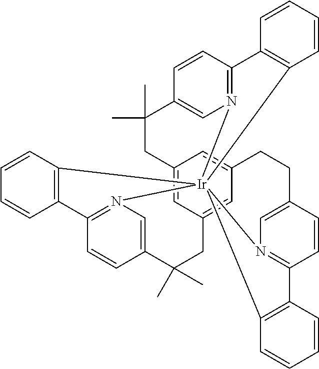

A mixture of 6.80 g (10 mmol) 1j, 4.89 g (10 mmol) tris(2,4-pentanedionato-κO²,κO⁴)-iridium [15635-87-7], and 100 g hydroquinone [123-31-9] are placed in a 500 mL two-necked round-bottom flask with a glass-jacketed magnetic core. The flask is equipped with a water separator (for media of lower density than water) and an air cooler with argon overlay. The flask is placed in a metal heating dish. The apparatus is purged with argon from above via the argon overlay for 15 min, allowing the argon to flow out of the side neck of the two-necked flask. Insert a glass-jacketed Pt-100 thermocouple into the flask via the side neck of the two neck flask and place the end just above the magnetic stirrer core. The apparatus is then thermally insulated with several loose wraps of household aluminum foil, with the insulation extending to the center of the riser tube of the water separator. The apparatus is then rapidly heated with a laboratory heating stirrer to 245-250° C. as measured by the Pt-100 thermal probe immersed in the molten, stirred reaction mixture. During the next 1.5 h, the reaction mixture is maintained at 245-250° C., with condensate distilling off and collecting in the water separator and draining from time to time. After 1.5 h, allow to cool to about 130° C. and then slowly add 50 ml of ethylene glycol and then 300 ml of ethanol (EtOH) from 100° C. The resulting yellow suspension is filtered through a reverse frit, the yellow solid is washed three times with 30 ml EtOH and then dried in vacuo. The resulting solid is dissolved in 1000 ml of DCM and filtered over 800 g of silica gel (column diameter about 12 cm) pre-slurried with DCM, excluding air and light. The core fraction is separated and concentrated by the rotary evaporator, with EtOH being added continuously at the same time until crystallization. After aspiration, washing with a little EtOH and drying in vacuo, further purification of the yellow product is carried out by continuous hot extraction twice with DCM/iso-propanol 2:1 (vv) and then hot extraction four times with DCM/acetonitrile 1:1 (vv) (reference amount in each case approx. 200 ml, extraction sleeve: standard cellulose Soxhlet sleeves from Whatman) under careful air and light from closure. Finally, the product is fractionally sublimed under high vacuum. Yield: 6.43 g (7.4 mmol), 74%; purity: >99.9% by HPLC.

Variant B:

Ligands L bearing a cyano group (—CN) can be reacted as described in A, wherein the tris(2,4-pentanedionato-κO²,κO⁴)-iridium is replaced by 7.42 g (10 mmol) tris(2,2,6,6-tetramethyl-3,5-heptanedionato-κO³,κO⁵)-iridium [99581-86-9] and adding 50 g 2,6-diisopropylphenol [2078-54-8] to the reaction mixture.

Variant C:

Alternatively, ligands that do not carry a cyano group (—CN) can be reacted as follows: A 500 ml four-neck flask with KPG stirrer, water separator (10 ml reservoir), reflux condenser, and argon via storage is charged under argon atmosphere with 6.80 g (10 mmol) 1j, 3.69 g (10 mmol) iridium(III) acetate Ir(OAc)₃, 50 g salicylic acid and 50 ml mesitylene and heated for 22 h under weak reflux (inner tempera tur about 158° C.). The initially blue solution becomes a yellow suspension over time, except that some acetic acid initially precipitates, which is drained off. After 22 h, allow to cool to 90° C., carefully add 200 ml ethanol, allow to cool to 40° C. while stirring, aspirate the yellow solid, rewash three times with 30 ml ethanol each time and dry in vacuo. Further purification of the crude product as described under variant A. Yield: 7.11 g (8.2 mmol), 82%. Purity: >99.9% n. HPLC.

The metal complexes usually occur as a 1:1 mixture of the Λ and Δ isomers/enantiomers according to the procedures used above. The figures of the complexes given below usually show only one isomer. If ligands with three different partial ligands are used, or if chiral ligands are used as racemates, the derived metal complexes are obtained as a diastereomeric mixture. These can be separated by fractional crystallization or chromatographically, e.g., with an automatic column machine (CombiFlash from A. Semrau). If chiral ligands are used enantiomerically pure, the derived metal complexes accrue as a diastereomeric mixture, whose separation by fractional crystallization or chromatography leads to pure enantiomers. The separated diastereomers or enantiomers can be further purified as described above, e.g., by hot extraction.

) Stage 1l: Complex IrL1D

Deuteration of Iridium Complexes

The non-deuterated or partially deuterated iridium complexes can be further deuterated according to WO 2019/158453. The exact deuteration degree can be followed spectroscopically by ¹H-NMR spectroscopy or mass. Each proton of the C₁-symmetric iridium complexes has its own exchange kinetics, which depends on the reaction temperature and the reaction time. In the structures shown below, deuterated alkyl positions with a degree of deuteration of about 90% or greater or deuterated aryl positions with a degree of deuteration of about 80% or greater are indicated by the element symbol D; individual further positions may also be partially deuterated.

### Example Ir1

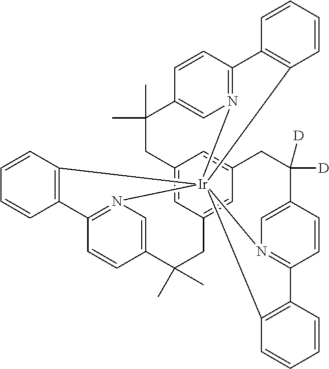

Implementation analogous to V. Salamanca, Eur. J. Org. Chem. 2020, 3206.

A well-stirred mixture of 867 mg (1.0 mmol) of the neat complex IrL1 (purity >99.9%), 425 mg (2.0 mmol) of tripotassium phosphate, anhydrous, 20 g of glass beads (1.5 mm diameter) and 100 ml of DMSO-D6 (degree of deuteration >99.8%) is stirred at 100-120° C. for 10-20 h until the desired degree of deuteration (monitoring via ¹H-NMR) is achieved. Instead of tripotassium phosphate, anhydrous, cesium carbonate, anhydrous can also be used in catalytic amount (10-20 mol %) at temperatures of 70-100° C., selectively exchanging the -aromatic positions on the dibenzofuran ortho to the —CN or —F group, respectively. It is then cooled using a cold water bath, starting at about 60° C. dropwise addition of 6 ml of 1 N acetic acid-D1 in 12 ml of D₂ O, and then 200 ml of water (H₂O), allowed to cool to room temperature, stirred for 5 h, exhausted from the solid and washed three times with 10 ml each of H₂O/EtOH (1:1, vv) and then three times with 10 ml each of EtOH, and dried in vacuo. The solid is dissolved in DCM, the solution is filtered over silica gel, the core fraction is separated and reduced on the rotary evaporator, while at the same time EtOH is continuously added until crystallization. After aspiration, washing with a little EtOH and drying in vacuo, further purification of the yellow product is carried out by continuous hot extraction four times with dichloromethane/acetonitrile 1:1 (vv) (reference volume approx. 30 ml each, extraction sleeve: standard Soxhlet sleeves made of cellulose from Whatman) under careful air and light from closure. Finally, the product is fractionally sublimed under high vacuum. Yield: 792 mg (0.91 mmol), 91%. Purity: >99.9% by HPLC.

Analogous to steps a) to k) and l), respectively, the following compounds can be presented using the indicated modified reactants in the corresponding steps, with the stoichiometry of the components adjusted according to the functionalities of the building blocks:

| Ex. | Stage-reactants | Product |
|---|---|---|
| IrL2 | 1a: 27012-25-5 1b: 75-03-6 | 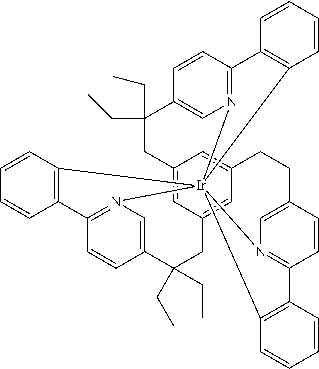 |
| | 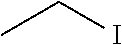 | |
| | 1i: 27012-25-5 | |
| | 1j: 133-74-0 | |
| | H₂ | |
| IrL2D | 1a: 27012-25-5 1b: 75-03-6 | 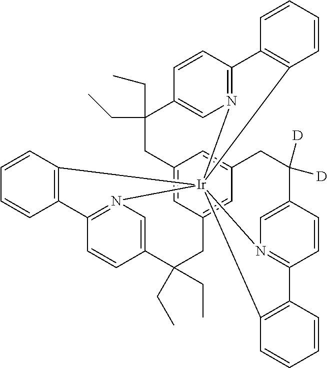 |
| | 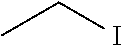 | |
| | 1i: 27012-25-5 | |
| | 1j: 133-74-0 | |
| | H2 | |
| | 1l: yes | |
| IrL3 | 1a: 867380-38-9 | 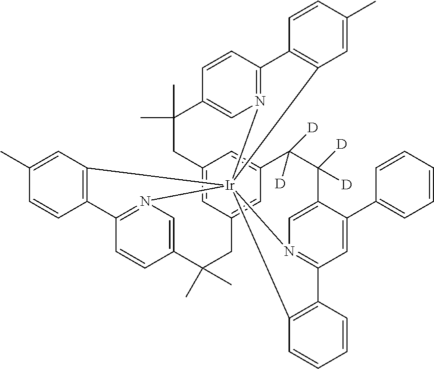 |
| | 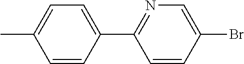 | |
| | 1b: 74-88-4 | |
| | 1i: 1989596-06-6 | |
| | 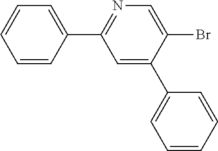 [SMILES: Brc1cnc(-c2ccccc2)cc1-c1ccccc1] | |
| | 1j: 7782-39-0 | |
| | D₂ | |
| IrL4 | 1a: 27012-25-5 1b: 74-88-4 1i: 2375161-92-3 | 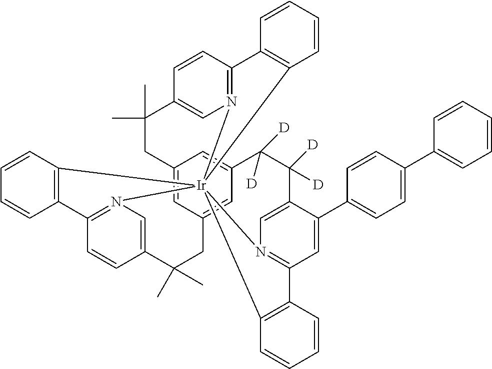 |
| | 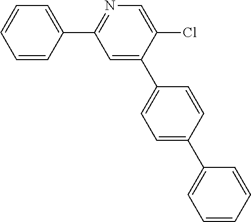 [SMILES: Clc1cnc(-c2ccccc2)cc1-c1ccc(-c2ccccc2)cc1] | |
| | 1j: 7782-39-0 | |
| IrL5 | 1a: 1215073-45-2 | 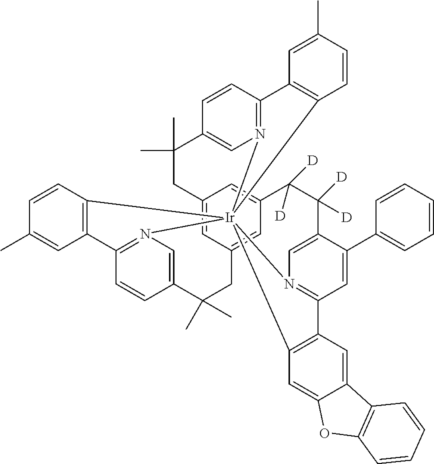 |
| | 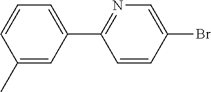 | |
| | 1b: 74-88-4 | |
| | 1i: 1934293-38-5 | |
| | 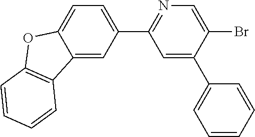 [SMILES: Brc1cnc(-c2ccc3oc4ccccc4c3c2)cc1-c1ccccc1] | |
| | 1j: 7782-39-0 | |
| IrL6D | 1a: 31686-64-3 | 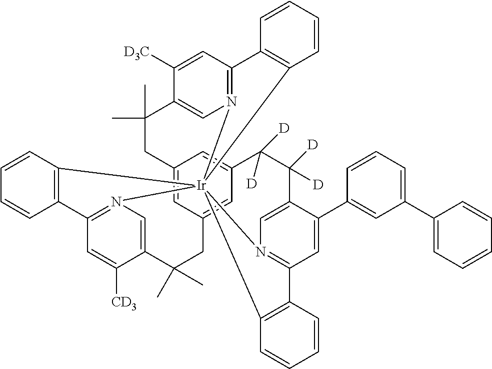 |
| | 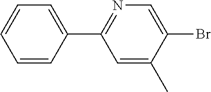 | |
| | 1b: 74-88-4 | |
| | 1i: S1 | |
| | 1j: 7782-39-0 | |
| | 1l: yes | |
| IrL7D | 1a: 1448777-16-9 | 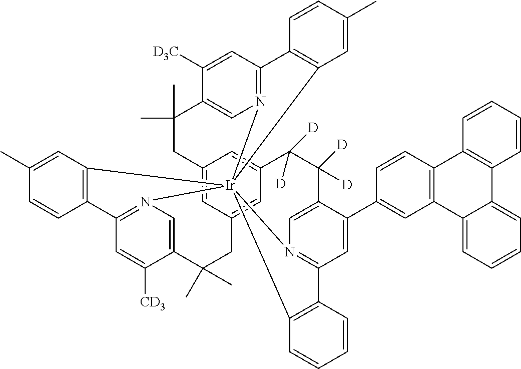 |
| | 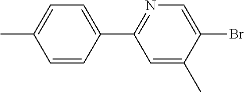 | |
| | 1b: 74-88-4 | |
| | 1i: 2648459-47-4 | |
| | 1j: 7782-39-0 | |
| | 1l: yes | |
| IrL8 | 1a: 2340379-18-0 | 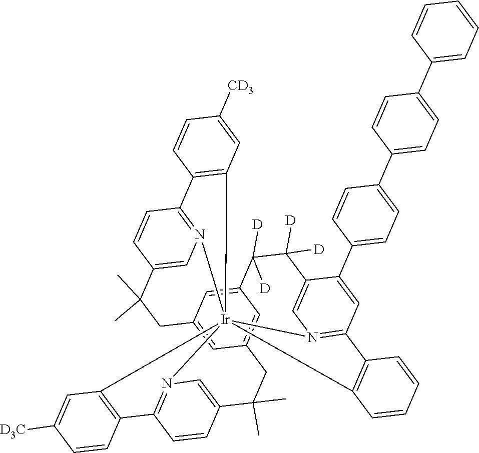 |
| | 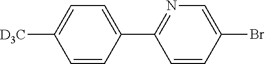 [SMILES: [2H]C([2H])([2H])c1ccc(-c2ccc(Br)cn2)cc1] | |
| | 1b: 74-88-4 | |
| | 1i: 2710315-39-0 | |
| | 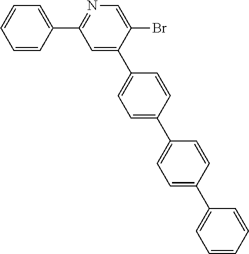 [SMILES: Brc1cnc(-c2ccccc2)cc1-c1ccc(-c2ccc(-c3ccccc3)cc2)cc1] | |
| | 1j: 7782-39-0 | |
| IrL9D | 1a: 1783999-34-7 | 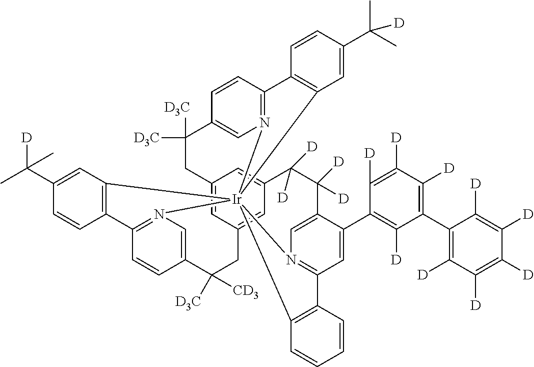 |
| | 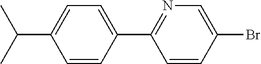 [SMILES: CC(C)c1ccc(-c2ccc(Br)cn2)cc1] | |
| | 1b: 86-50-9 | |
| | D₃C—I | |
| | 1i: S2 | |
| | 1j: 7782-39-0 | |
| | 1l: yes | |
| IrL 10 | 1a: 1215073-34-9 | 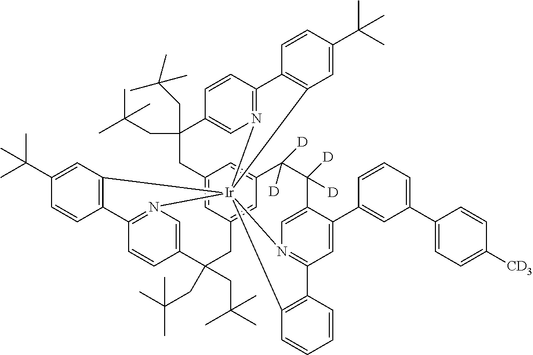 |
| | 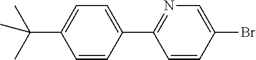 [SMILES: CC(C)(C)c1ccc(-c2ccc(Br)cn2)cc1] | |
| | 1b: 15501-33-4 | |
| | 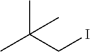 | |
| | 1i: S3 | |
| | 1j: 7782-39-0 | |
| IrL11 | 1a: 1914960-25-0 | 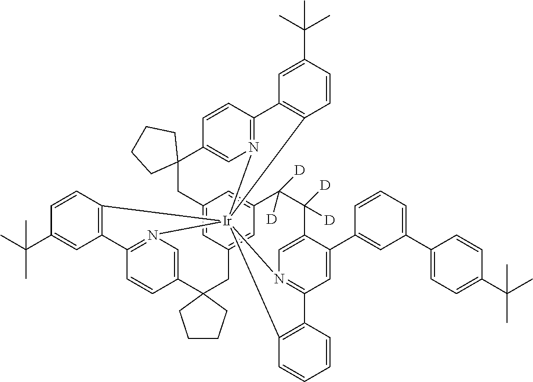 |
| | 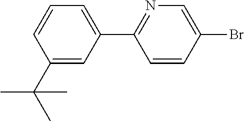 [SMILES: CC(C)(C)c1cccc(-c2ccc(Br)cn2)c1] | |
| | 1b: 628-21-7 | |
| | 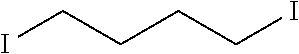 | |
| | 1i: S4 | |
| | 1j: 7782-39-0 | |
| IrL 12 | 1a: 1782005-73-5 | 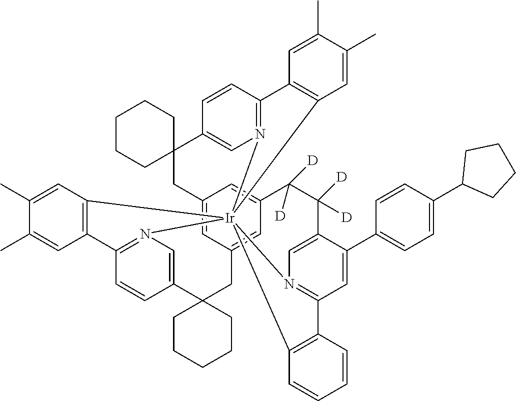 |
| | 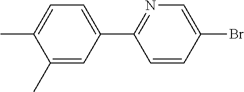 | |
| | 1b: 628-77-3 | |
| | 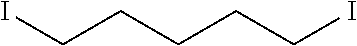 | |
| | 1i: S4 | |
| | 1j: 7782-39-0 | |
| IrL 13 | 1a: 1783998-65-1 | |
| | 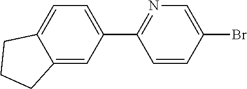 [SMILES: Brc1ccc(-c2ccc3c(c2)CCC3)nc1] | 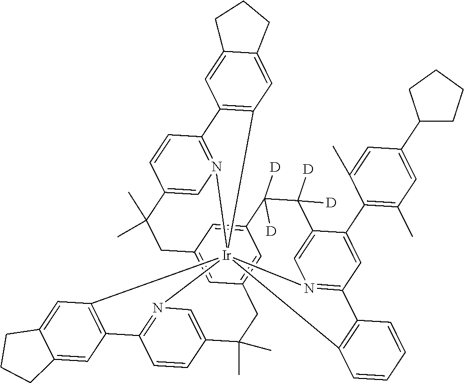 |
| | 1b: 74-88-4 | |
| | 1i: S6 | |
| | 1j: 7782-39-0 | |
| IrL 14 | 1a: 1821675-85-7 | 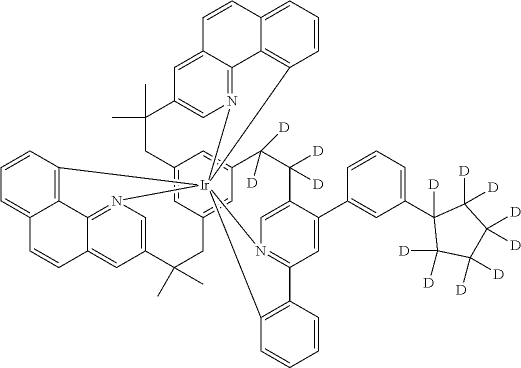 |
| | 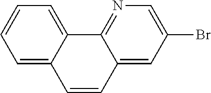 [SMILES: Brc1cnc2c(ccc3ccccc32)c1] | |
| | 1b: 74-88-4 | |
| | 1i: S8 | |
| | 1j: 7782-39-0 | |
| IrL 15 | 1a: 463336-07-4 | 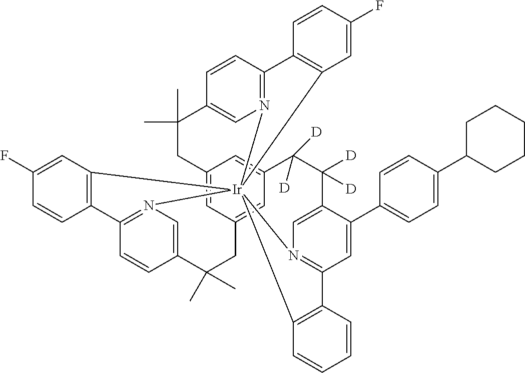 |
| | 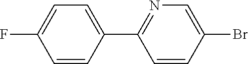 [SMILES: Fc1ccc(-c2ccc(Br)cn2)cc1] | |
| | 1b: 74-88-4 | |
| | 1i: S9 | |
| | 1j: 7782-39-0 | |
| IrL 16 | 1a: 875462-73-0 | 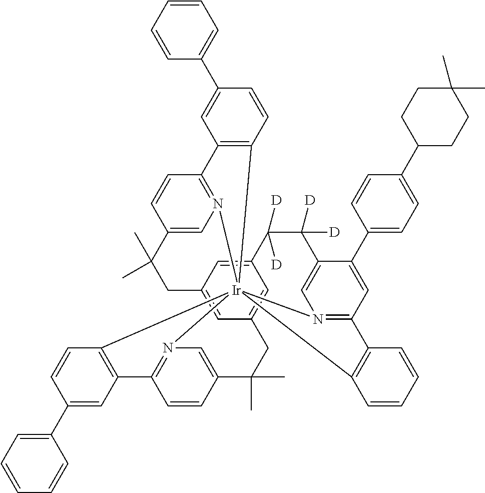 |
| | 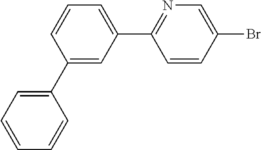 [SMILES: Brc1ccc(-c2cccc(-c3ccccc3)c2)nc1] | |
| | 1b: 74-88-4 | |
| | 1i: S10 | |
| | 1j: 7782-39-0 | |
| IrL 17 | 1a: 1989596-40-8 | 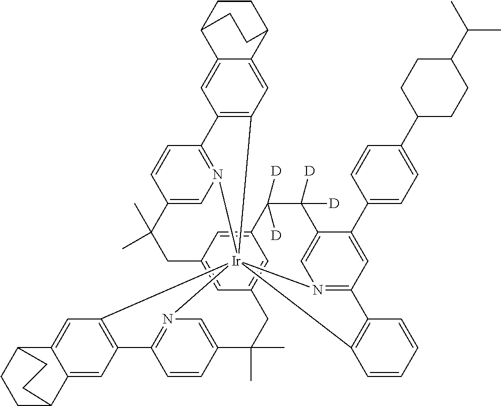 |
| | 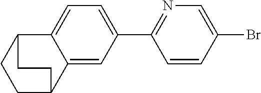 [SMILES: Brc1ccc(-c2ccc3c(c2)C2CCC3CC2)nc1] | |
| | 1b: 74-88-4 | |
| | 1i: S11 | |
| | 1j: 7782-39-0 | |
| IrL18 | 1a: 2215088-17-6 | 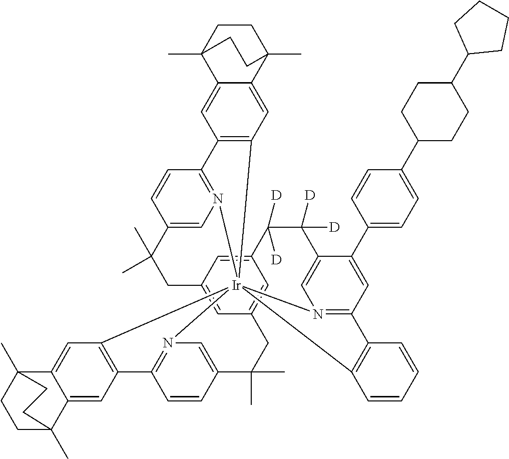 |
| | 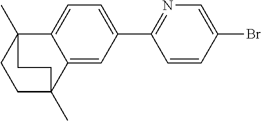 [SMILES: CC12CCC(C)(CC1)c1cc(-c3ccc(Br)cn3)ccc12] | |
| | 1b: 74-88-4 | |
| | 1i: S12 | |
| | 1j: 7782-39-0 | |
| IrL19 | 1a: 1870009-95-2 | 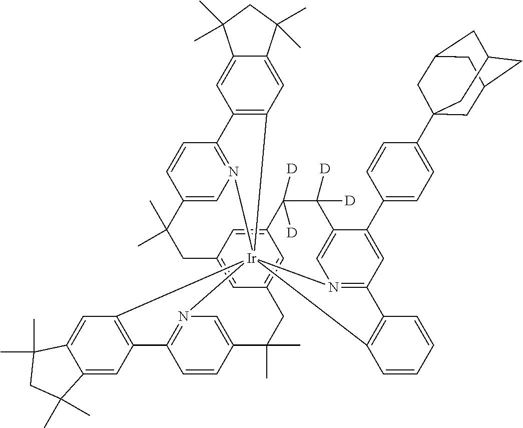 |
| | 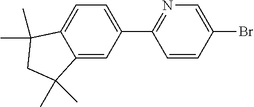 [SMILES: CC1(C)CC(C)(C)c2cc(-c3ccc(Br)cn3)ccc21] | |
| | 1b: 74-88-4 | |
| | 1i: S13 | |
| | 1j: 7782-39-0 | |
| IrL20 | 1a: 27012-25-5 | 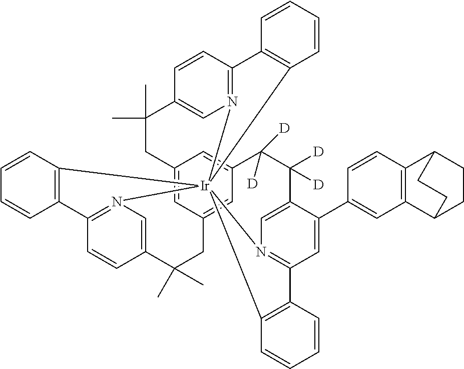 |
| | 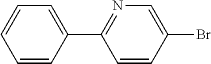 [SMILES: Brc1ccc(-c2ccccc2)nc1] | |
| | 1b: 74-88-4 | |
| | 1i: S14 | |
| | 1j: 7782-39-0 | |
| IrL21 | 1a: 27012-25-5 1b: 74-88-4 1i: S15 1j: 7782-39-0 | 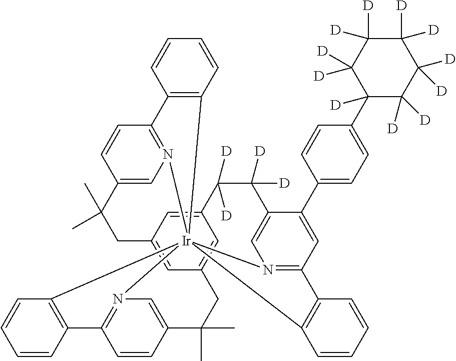 |
| IrL22 | 1a: 27012-25-5 1b: 74-88-4 1i: S16 1j: 7782-39-0 | 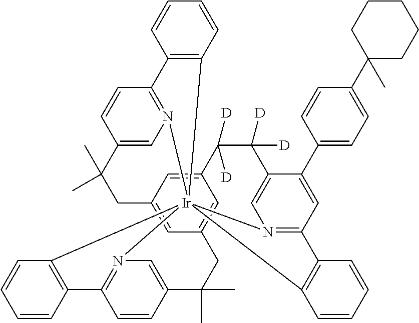 |
| IrL23 | 1a: 27012-25-5 1b: 74-88-4 1i: S17 1j: 7782-39-0 | 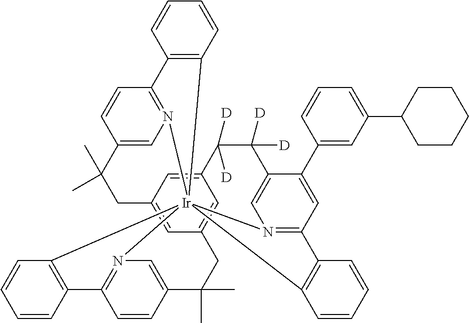 |
| IrL24 | 1a: 27012-25-5 1b: 74-88-4 1i: S18 1j: 7782-39-0 | 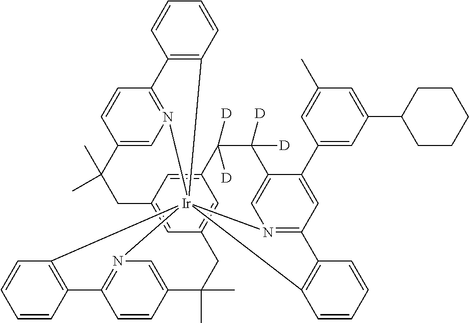 |
| IrL25 | 1a: 27012-25-5 1b: 74-88-4 1i: S19 1j: 7782-39-0 | 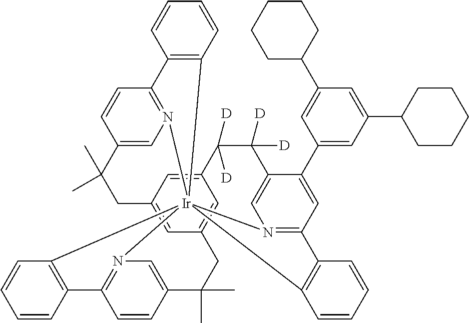 |
| IrL26 | 1a: 27012-25-5 1b: 74-88-4 1i: S20 1j: 7782-39-0 | 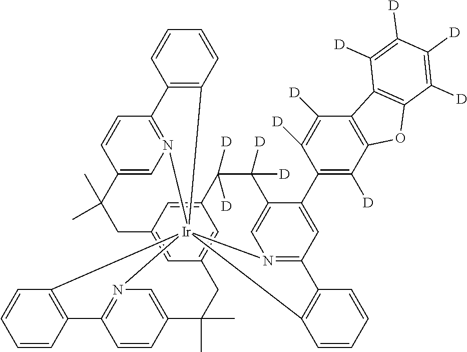 |
| IrL27D | 1a: 27012-25-5 1b: 74-88-4 1i: S21 1j: 7782-39-0 1l: yes | 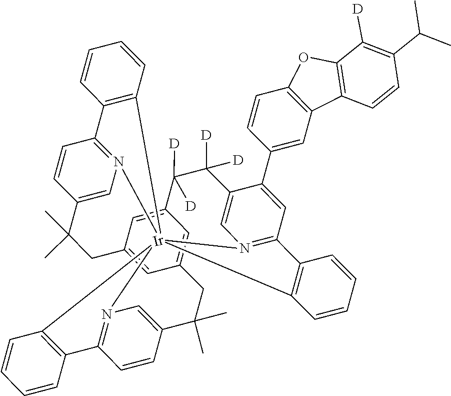 |
| IrL28 | 1a: 27012-25-5 1b: 74-88-4 1i: S22 1j: 7782-39-0 | 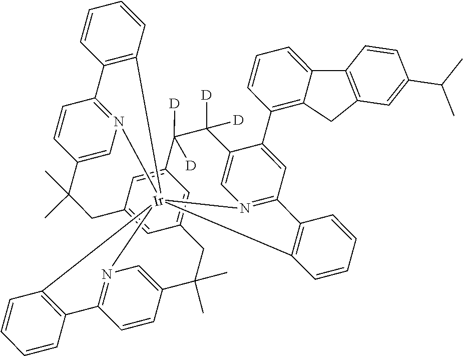 |
| IrL29 | 1a: 27012-25-5 1b: 74-88-4 1i: S23 1j: 7782-39-0 | 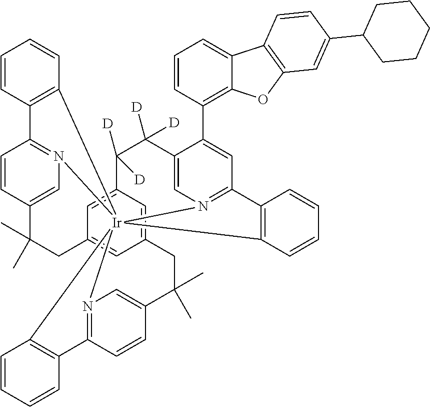 |
| IrL30 | 1a: 27012-25-5 1b: 74-88-4 1i: S24 1j: 7782-39-0 | 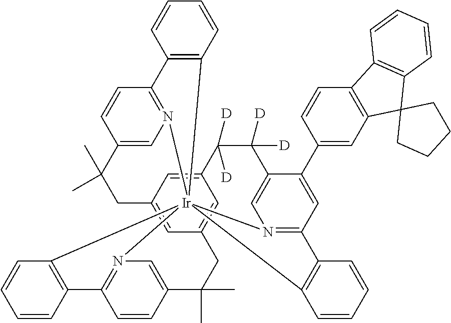 |
| IrL31 | 1a: 27012-25-5 1b: 74-88-4 1i: S25 1j: 7782-39-0 | 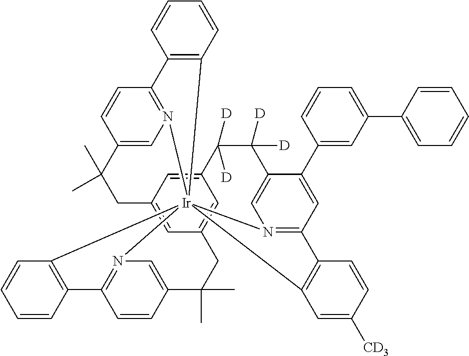 |
| IrL32 | 1a: 27012-25-5 1b: 74-88-4 1i: S26 1j: 7782-39-0 | 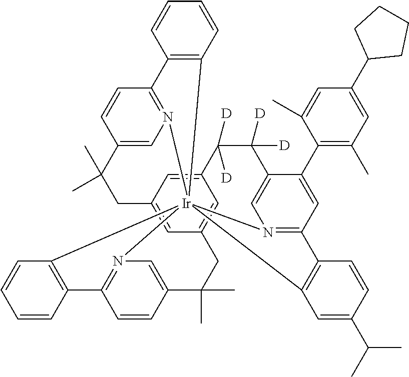 |
| IrL33 | 1a: 27012-25-5 1b: 74-88-4 1i: S27 1j: 7782-39-0 | 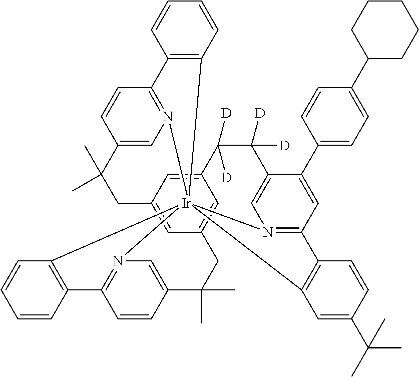 |
| IrL34 | 1a: 27012-25-5 1b: 74-88-4 1i: S28 1j: 7782-39-0 | 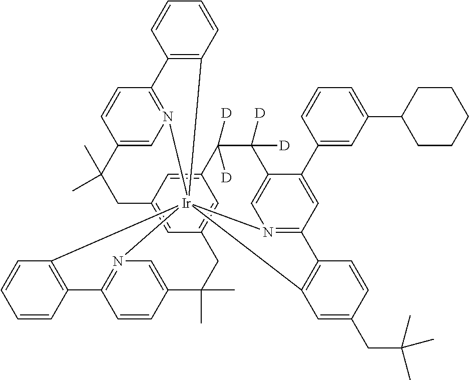 |
| IrL35 | 1a: 27012-25-5 1b: 74-88-4 1i: S29 1j: 7782-39-0 | 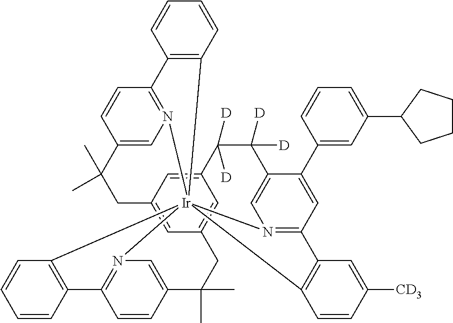 |
| IrL36 | 1a: 27012-25-5 1b: 74-88-4 1i: S30 1j: 7782-39-0 | 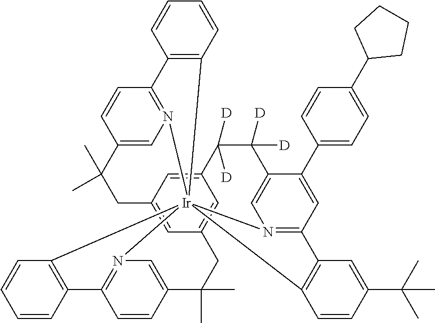 |
| IrL37 | 1a: 27012-25-5 1b: 74-88-4 1i: S31 1j: 7782-39-0 | 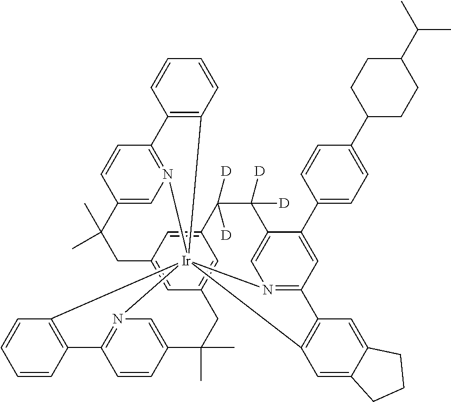 |
| IrL38 | 1a: 27012-25-5 1b: 74-88-4 1i: S32 1j: 7782-39-0 | 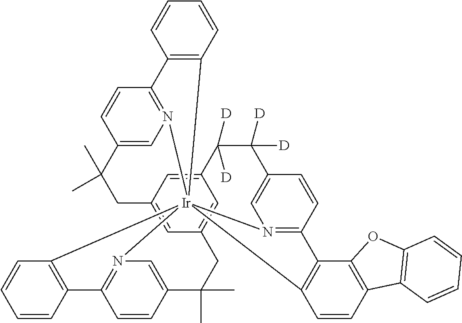 |
| IrL39 | 1a: 2340379-18-0 1b: 74-88-4 1i: S33 1j: 7782-39-0 | 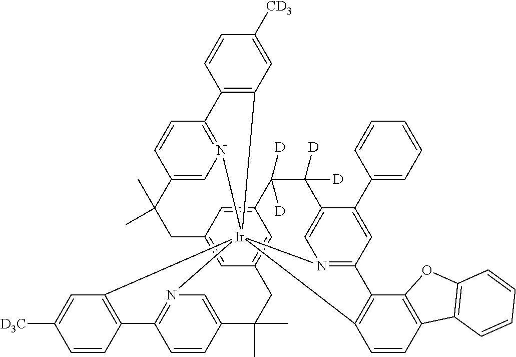 |
| IrL40 | 1a: 2340379-18-0 1b: 74-88-4 1i: S34 1j: 7782-39-0 | 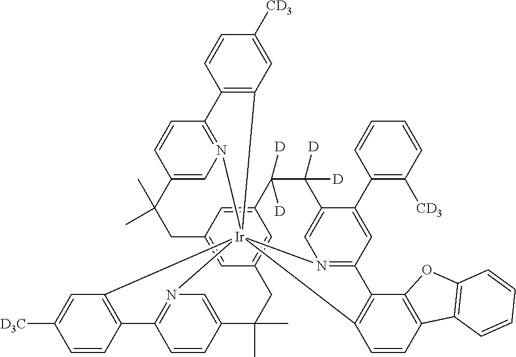 |
| IrL41D | 1a: 27012-25-5 1b: 74-88-4 1i: S35 1j: 7782-39-0 1l: yes | 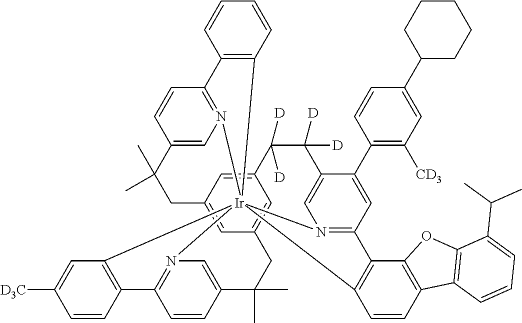 |
| IrL42D | 1a: 27012-25-5 1b: 74-88-4 1i: S36 1j: 7782-39-0 1l: yes | 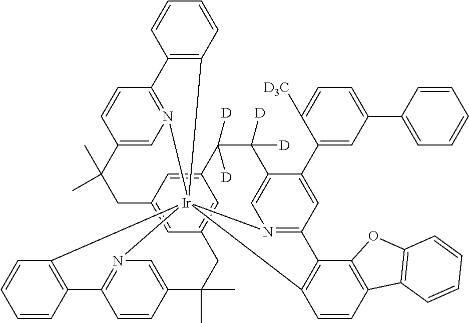 |
| IrL43 | 1a: 27012-25-5 1b: 74-88-4 1i: S37 1j: 7782-39-0 | 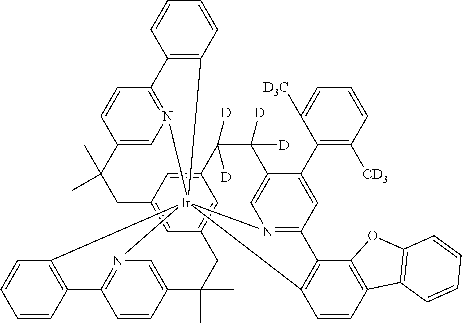 |
| IrL44 | 1a: 27012-25-5 1b: 74-88-4 1i: S38 1j: 7782-39-0 | 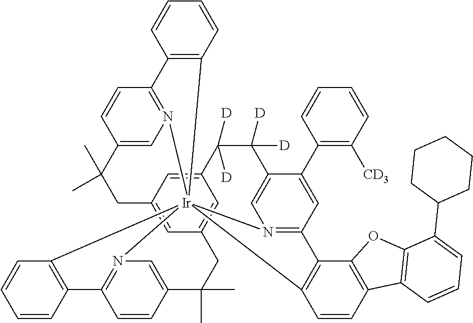 |
| IrL45 | 1a: 27012-25-5 1b: 74-88-4 1i: S39 1j: 7782-39-0 | 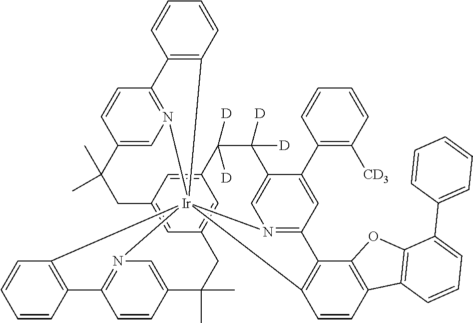 |
| IrL46 | 1a: 27012-25-5 1b: 74-88-4 1i: S40 1j: 7782-39-0 | 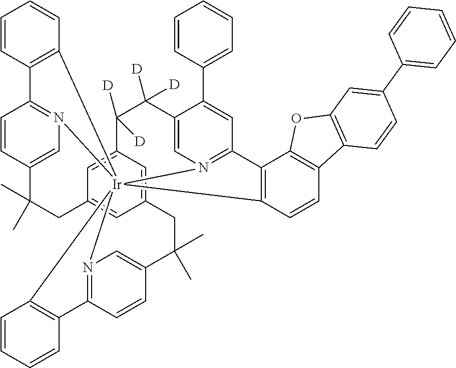 |
| IrL47 | 1a: 2340379-18-0 1b: 74-88-4 1i: S41 1j: 7782-39-0 | 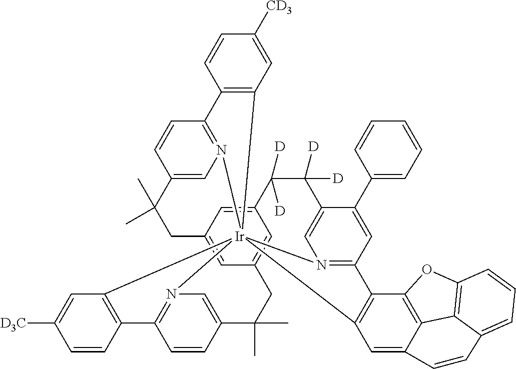 |
| IrL48 | 1a: 2340379-18-0 1b: 74-88-4 1i: S42 1j: 7782-39-0 | 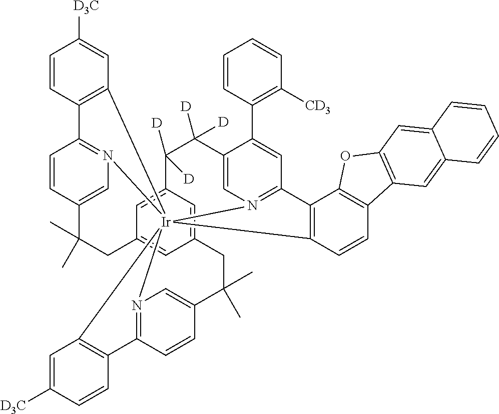 |
| IrL49 | 1a: 27012-25-5 1b: 74-88-4 1i: S43 1j: 7782-39-0 | 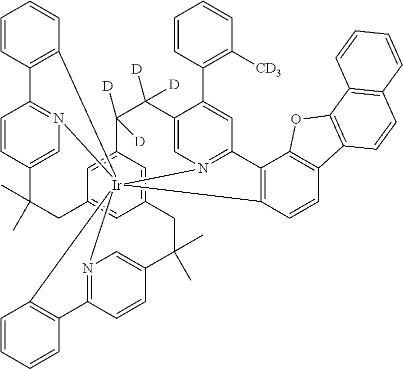 |
| IrL50 | 1a: 27012-25-5 1b: 74-88-4 1i: S44 1j: 7782-39-0 | 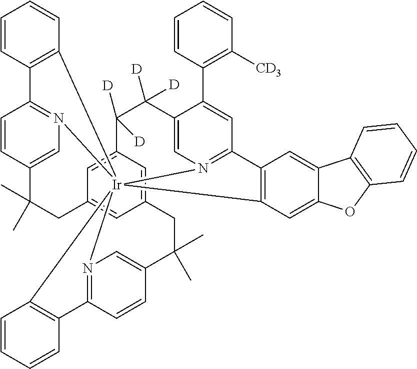 |
| IrL51 | 1a: 27012-25-5 1b: 74-88-4 1i: S45 1j: 7782-39-0 | 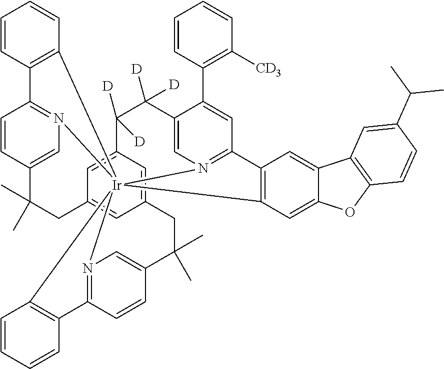 |
| IrL52 | 1a: 27012-25-5 1b: 74-88-4 1i: S46 1j: 7782-39-0 | 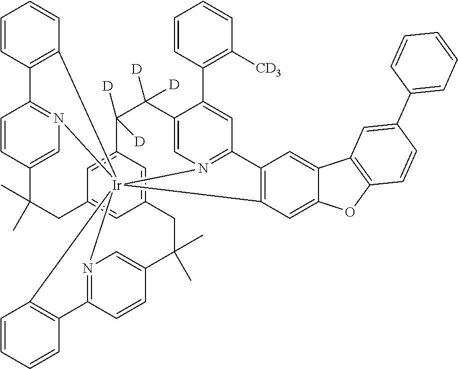 |
| IrL53 | 1a: 27012-25-5 1b: 74-88-4 1i: S47 1j: 7782-39-0 | 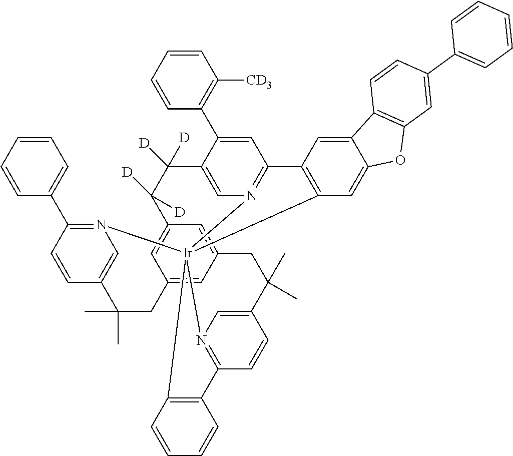 |
| IrL54 | 1a: 27012-25-5 1b: 74-88-4 1i: S48 1j: 7782-39-0 | 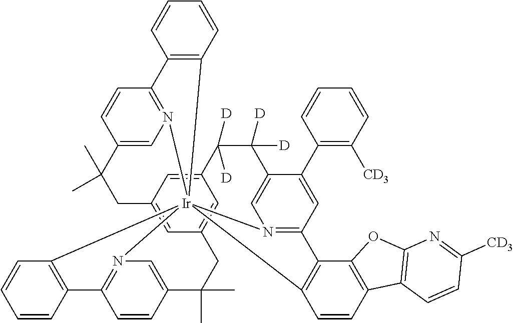 |
| IrL55 | 1a: 27012-25-5 1b: 75-03-6 1i: S49 1j: 7782-39-0 | 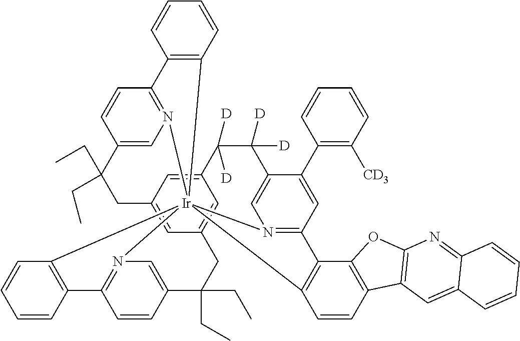 |
| IrL56 | 1a: 27012-25-5 1b: 86-50-9 1i: S50 1j: 7782-39-0 | 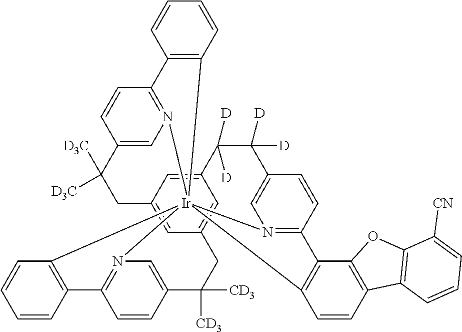 |
| IrL56D | 1a: 27012-25-5 1b: 86-50-9 1i: S50 1j: 7782-39-0 1l: yes | 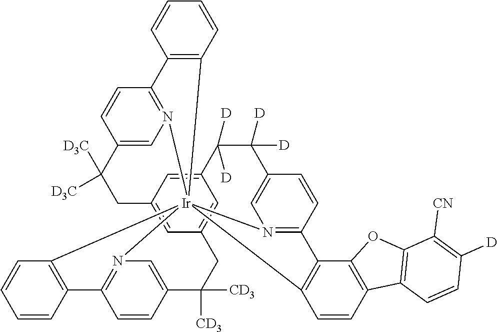 |
| IrL57D | 1a: 2340379-18-0 1b: 86-50-9 1i: S51 1j: 7782-39-0 1l: yes | 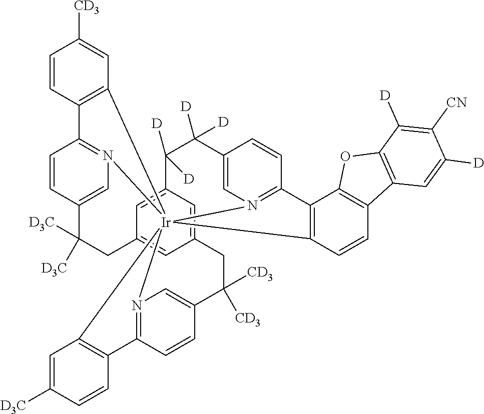 |
| IrL58D | 1a: 27012-25-5 1b: 74-88-4 1i: S52 1j: 7782-39-0 1l: yes | 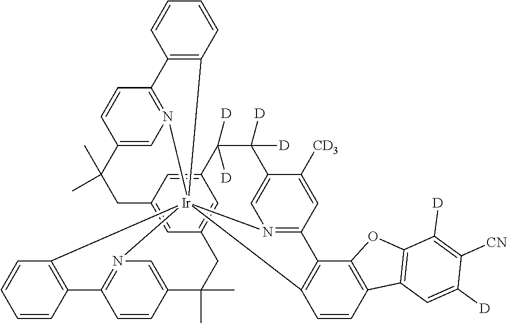 |
| IrL59D | 1a: 27012-25-5 1b: 74-88-4 1i: S53 1j: 7782-39-0 1l: yes | 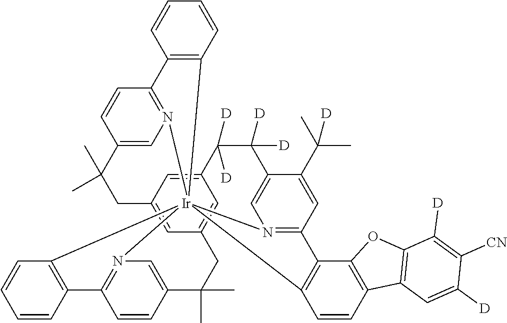 |
| IrL60D | 1a: 27012-25-5 1b: 74-88-4 1i: S54 1j: 7782-39-0 1l: yes | 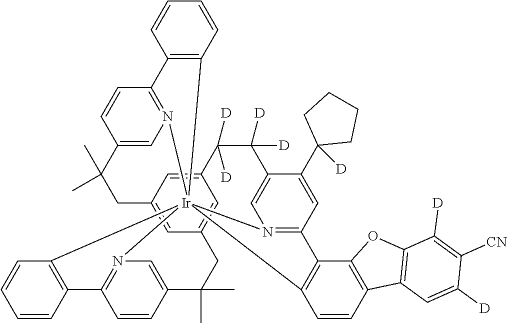 |
| IrL61D | 1a: 27012-25-5 1b: 74-88-4 1i: S55 1j: 7782-39-0 1l: yes | 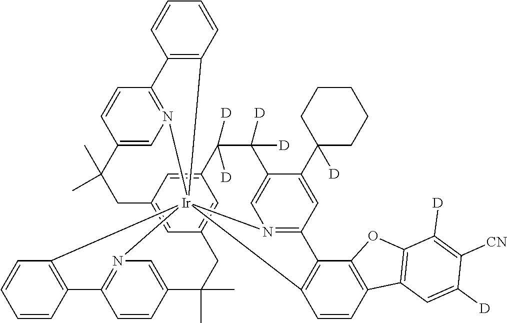 |
| IrL62D | 1a: 27012-25-5 1b: 74-88-4 1i: S56 1j: 7782-39-0 1l: yes | 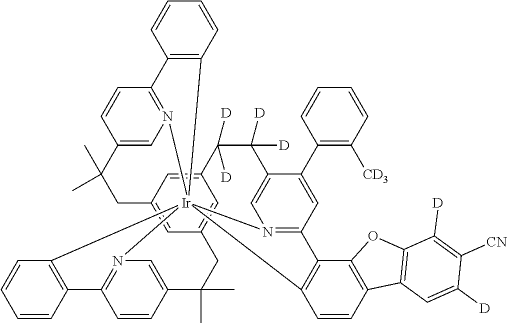 |
| IrL63D | 1a: 1783999-34-7 1b: 74-88-4 1i: S57 1j: 7782-39-0 1l: yes | 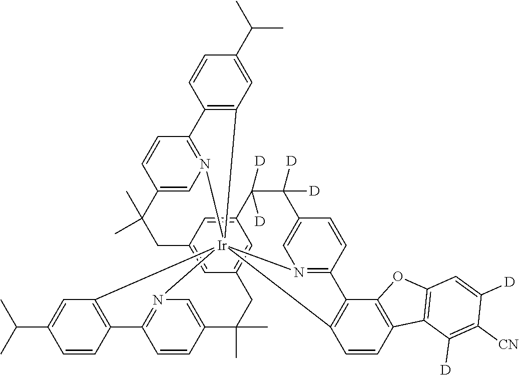 |
| IrL64D | 1a: 27012-25-5 1b: 628-21-7 1i: S58 1j: 7782-39-0 1l: yes | 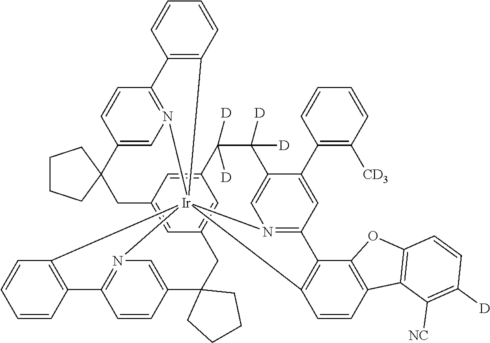 |
| IrL65D | 1a: 27012-25-5 1b: 74-88-4 1i: S59 1j: 7782-39-0 1l: yes | 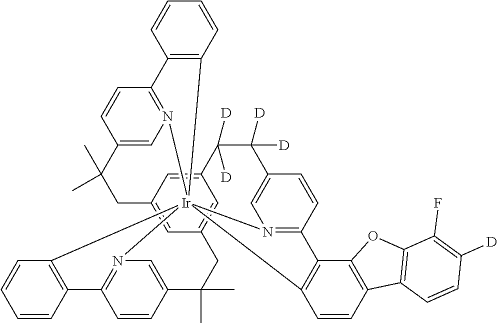 |
| IrL66D | 1a: 27012-25-5 1b: 74-88-4 1i: S60 1j: 7782-39-0 1l: yes | 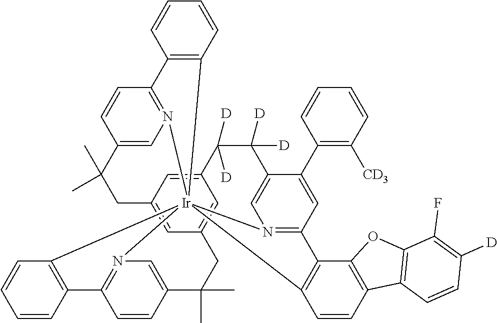 |
| IrL67D | 1a: 27012-25-5 1b: 74-88-4 1i: S61 1j: 7782-39-0 1l: yes | 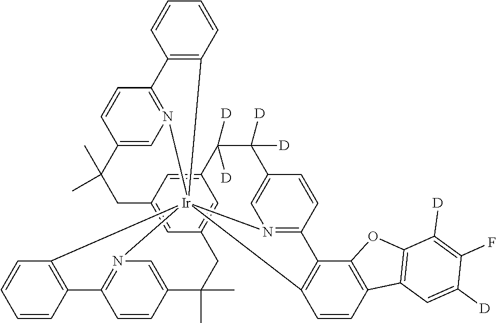 |
| IrL68D | 1a: 2340379-18-0 1b: 86-50-9 1i: S62 1j: 7782-39-0 1l: yes | 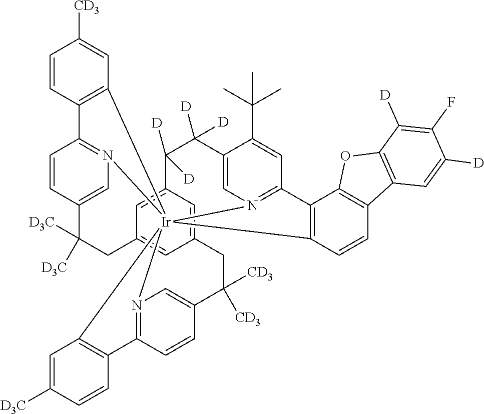 |
| IrL69D | 1a: 2340379-18-0 1b: 86-50-9 1i: S63 1j: 7782-39-0 1l: yes | 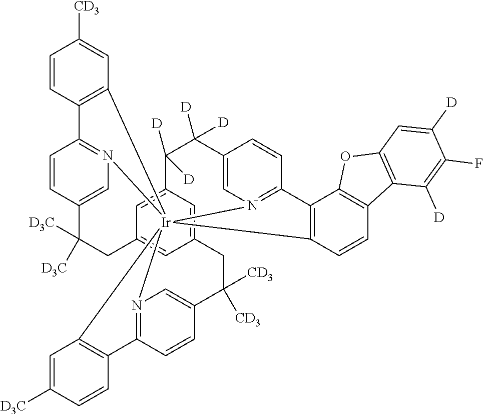 |
| IrL70D | 1a: 27012-25-5 1b: 74-88-4 1i: S64 1j: 7782-39-0 1l: yes | 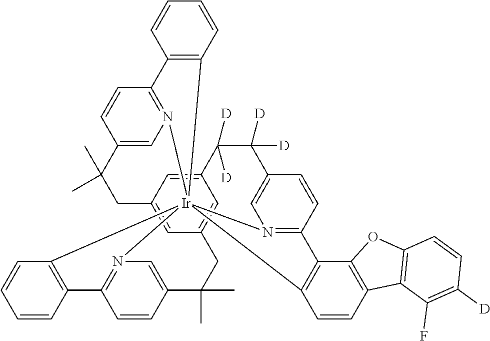 |
| IrL71D | 1a: 27012-25-5 1b: 74-88-4 1i: S65 1j: 7782-39-0 1l: yes | 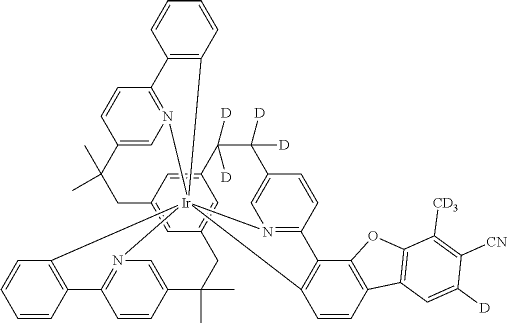 |
| IrL72D | 1a: 27012-25-5 1b: 74-88-4 1i: S66 1j: 7782-39-0 1l: yes | 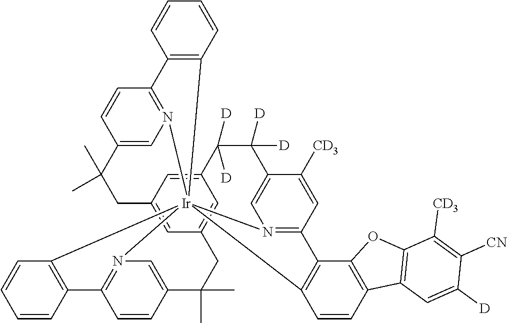 |
| IrL73D | 1a: 1783999-34-7 1b: 74-88-4 1i: S67 1j: 7782-39-0 1l: yes | 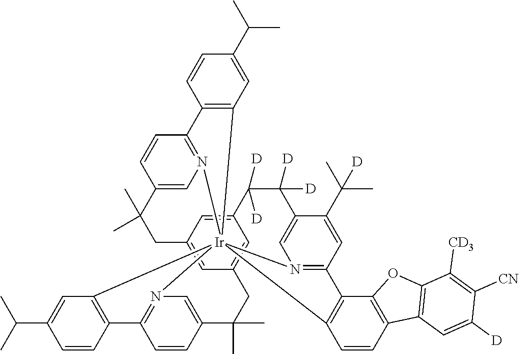 |
| IrL74D | 1a: 27012-25-5 1b: 74-88-4 1i: S68 1j: 7782-39-0 1l: yes | 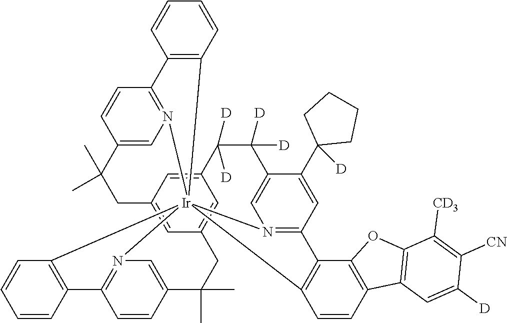 |
| IrL75D | 1a: 27012-25-5 1b: 74-88-4 1i: S69 1j: 7782-39-0 1l: yes | 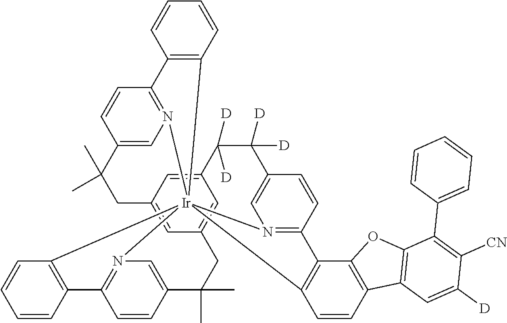 |
| IrL76D | 1a: 27012-25-5 1b: 74-88-4 1i: S70 1j: 7782-39-0 1l: yes | 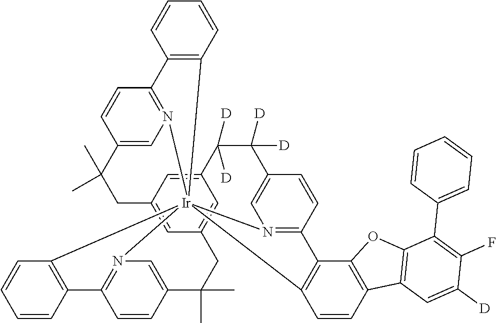 |
| IrL77D | 1a: 27012-25-5 1b: 74-88-4 1i: S71 1j: 7782-39-0 1l: yes | 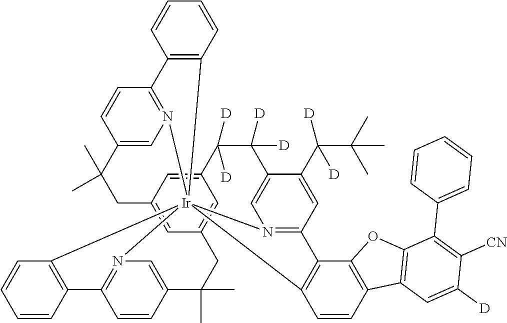 |
| IrL78D | 1a: 27012-25-5 1b: 74-88-4 1i: S72 1j: 7782-39-0 1l: yes | 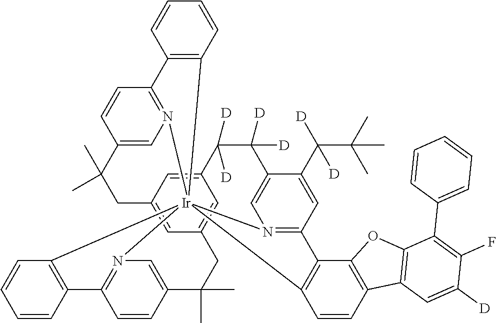 |
| IrL79D | 1a: 27012-25-5 1b: 74-88-4 1i: S73 1j: 7782-39-0 | 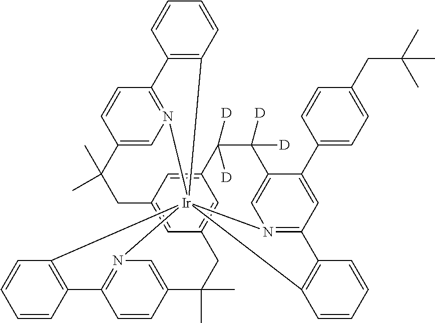 |
| IrL80D | 1a: 27012-25-5 1b: 74-88-4 1i: S74 1j: 7782-39-0 | 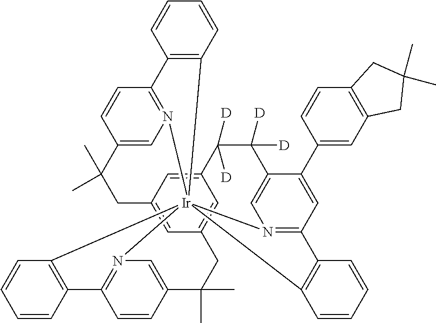 |
| IrL81D | 1a: 27012-25-5 1b: 74-88-4 1i: S75 1j: 7782-39-0 | 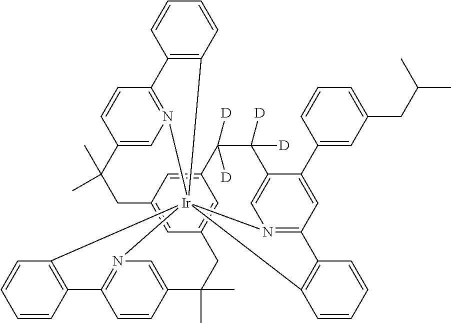 |
| IrL82 | 1a: 27012-25-5 1b: 74-88-4 1i: 1989596-06-6 | 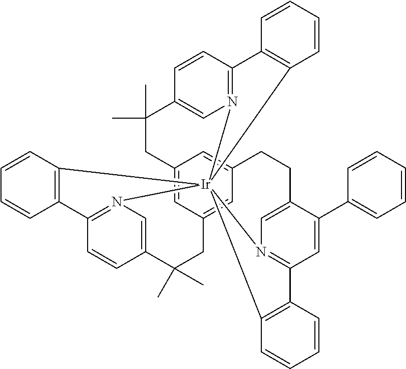 |
| IrL83D | 1a: 27012-25-5 1b: 74-88-4 1i: S76 1l: yes Cs₂CO₃, 1 h, 70° C. | 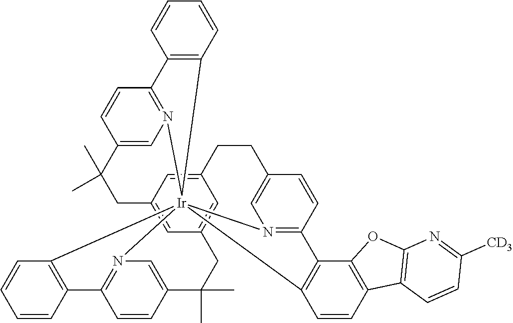 |
| IrL84 | 1a: 27012-25-5 1b: 74-88-4 1i: S51 | 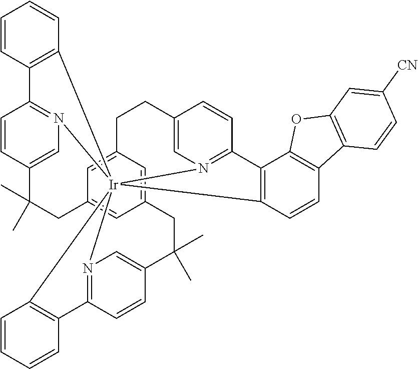 |
| IrL100 | 1a: 63996-36-1 | 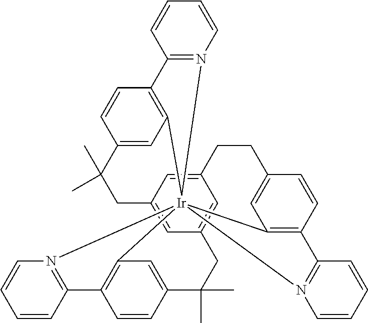 |
| | 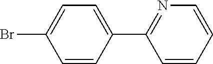 [SMILES: Brc1ccc(-c2ccccn2)cc1] | |
| | 1b: 74-88-4 | |
| | 1i: 63996-36-1 | |
| IrL101D | 1a: 63996-36-1 1b: 74-88-4 1i: 2452400-40-5 | 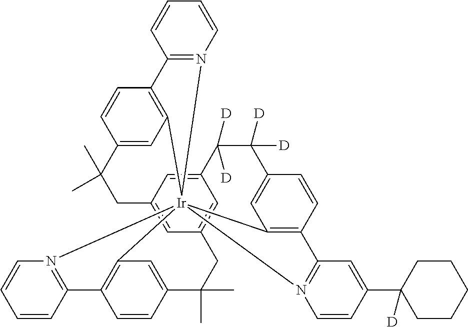 |
| | 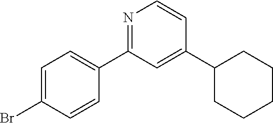 [SMILES: Brc1ccc(-c2cc(C3CCCCC3)ccn2)cc1] | |
| | 1j: 7782-39-0 | |
| | 1l: yes | |
| IrL 102D | 1a: 113744-24-4 | 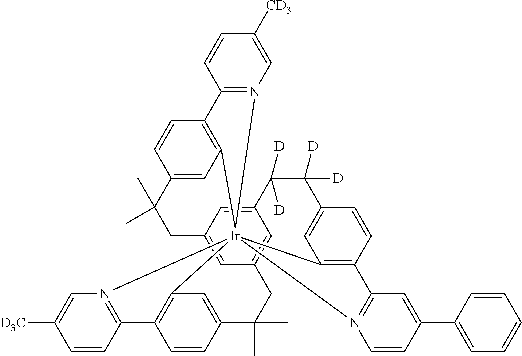 |
| | 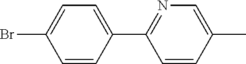 | |
| | 1b: 74-88-4 | |
| | 1i: 504413-43-8 | |
| | 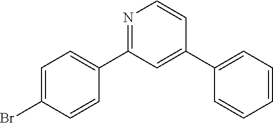 [SMILES: Brc1ccc(-c2cc(-c3ccccc3)ccn2)cc1] | |
| | 1j: 7782-39-0 | |
| | 1l: yes | |
| IrL103D | 1a: 313975-85-8 | 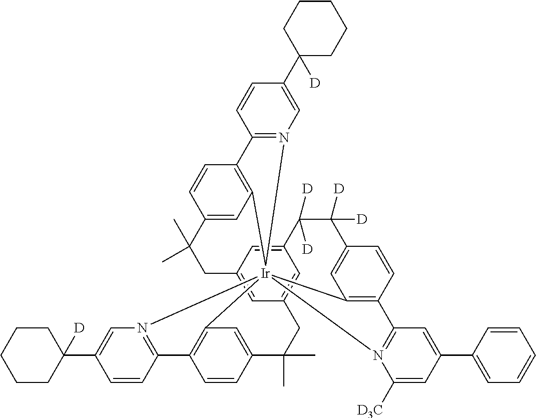 |
| | 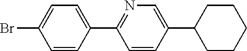 [SMILES: Brc1ccc(-c2ccc(C3CCCCC3)cn2)cc1] | |
| | 1b: 74-88-4 | |
| | 1i: 152361-37-0 | |
| | 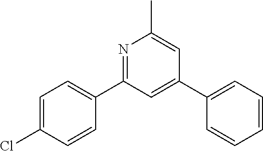 [SMILES: Cc1cc(-c2ccccc2)cc(-c2ccc(Cl)cc2)n1] | |
| | 1j: 7782-39-0 | |
| | 1l: yes | |
| IrL 104 | 1a: 2413601-09-7 N | 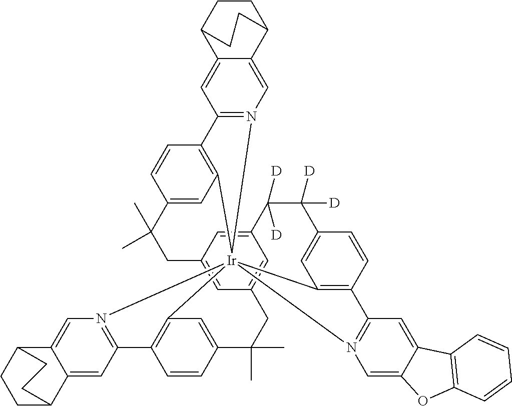 |
| | 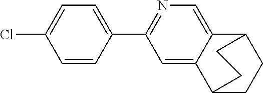 [SMILES: Clc1ccc(-c2cc3c(cn2)C2CCC3CC2)cc1] | |
| | 1b: 74-88-4 | |
| | 1i: 2762695-47-4 | |
| | 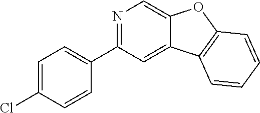 [SMILES: Clc1ccc(-c2cc3c(cn2)oc2ccccc23)cc1] | |
| | 1j: 7782-39-0 | |
| IrL 105D | 1a: 656257-50-0 | 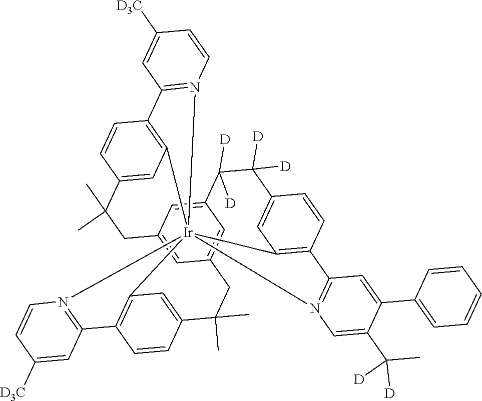 |
| | 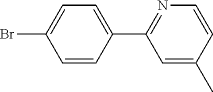 | |
| | 1b: 74-88-4 | |
| | 1i: 2202695-46-1 | |
| | 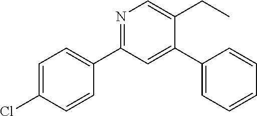 [SMILES: CCc1cnc(-c2ccc(Cl)cc2)cc1-c1ccccc1] | |
| | 1j: 7782-39-0 | |
| | 1l: yes | |
| IrL 106 | 1a: 1246851-70-6 | 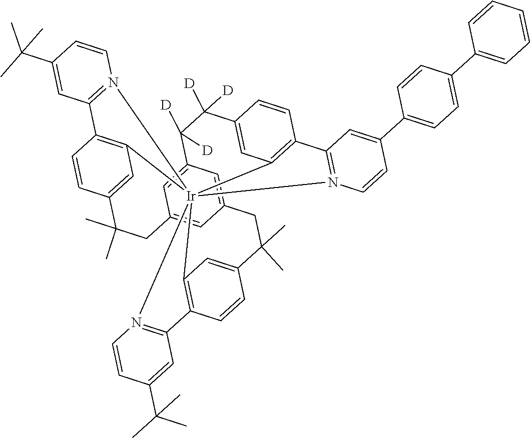 |
| | 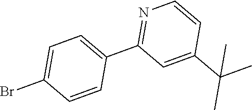 [SMILES: CC(C)(C)c1ccnc(-c2ccc(Br)cc2)c1] | |
| | 1b: 74-88-4 | |
| | 1i: 2202695-46-1 | |
| | 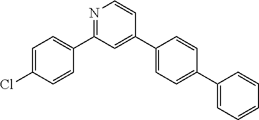 [SMILES: Clc1ccc(-c2cc(-c3ccc(-c4ccccc4)cc3)ccn2)cc1] | |
| | 1j: 7782-39-0 | |
| IrL 107D | 1a: 63996-36-1 1b: 74-88-4 1i: S100 1j: 7782-39-0 1l: yes | 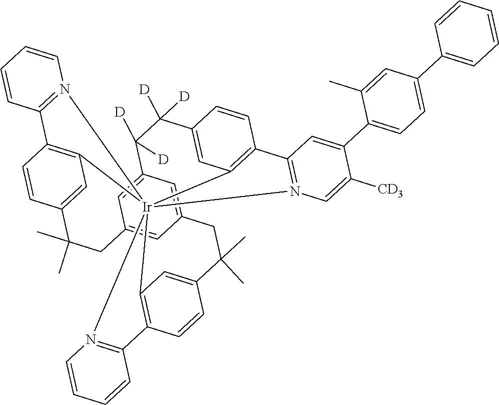 |
| IrL 108 | 1a: 63996-36-1 1b: 74-88-4 1i: S101 1j: 7782-39-0 | 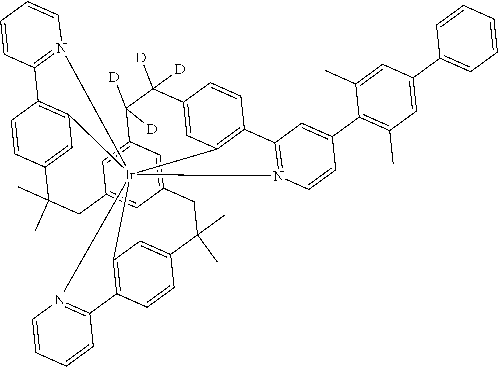 |
| IrL 109D | 1a: 113744-24-4 1b: 74-88-4 1i: S102 1j: 7782-39-0 1l: yes | 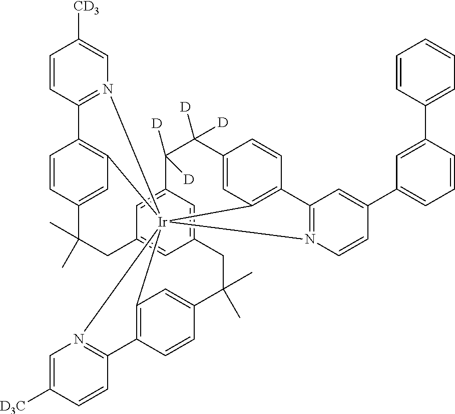 |
| IrL110D | 1a: 113744-24-4 1b: 74-88-4 1i: S103 1j: 7782-39-0 1l: yes | 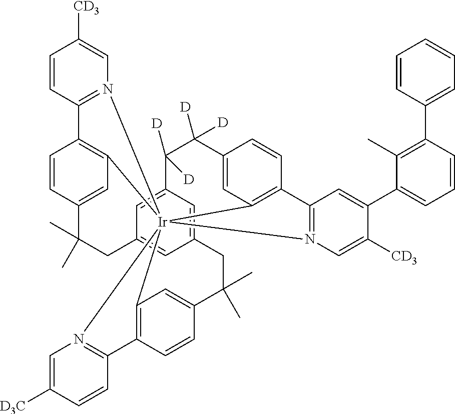 |
| IrL111D | 1a: 113744-24-4 1b: 74-88-4 1i: S104 1j: 7782-39-0 1l: yes | 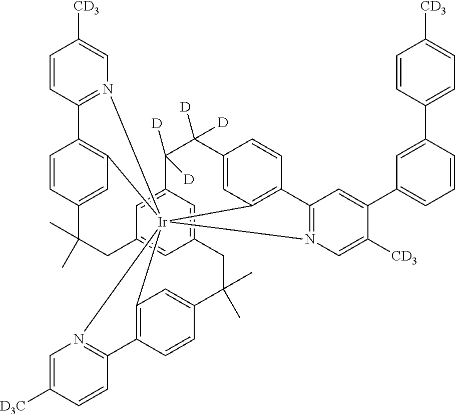 |
| IrL112D | 1a: 113744-24-4 1b: 74-88-4 1i: S105 1j: 7782-39-0 1l: yes | 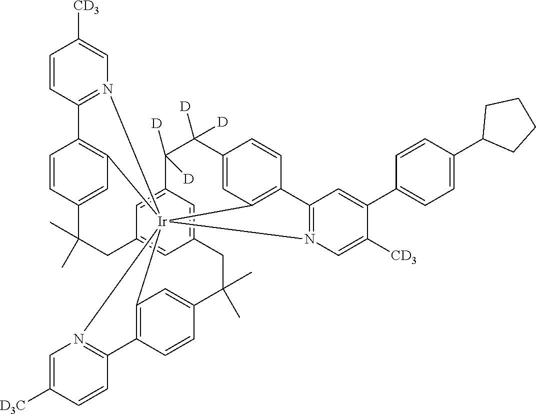 |
| IrL113D | 1a: 113744-24-4 1b: 74-88-4 1i: S106 1j: 7782-39-0 1l: yes | 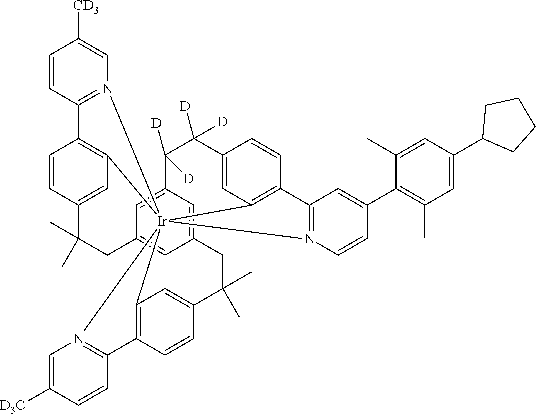 |
| IrL114D | 1a: 113744-24-4 1b: 74-88-4 1i: S107 1j: 7782-39-0 1l: yes | 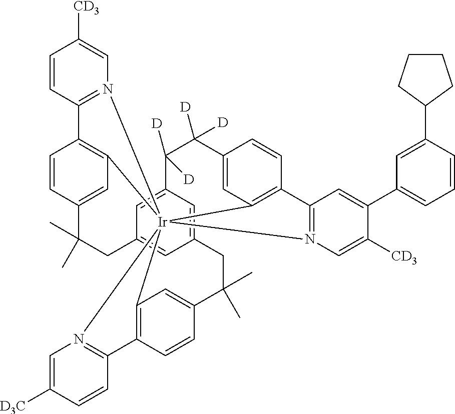 |
| IrL115D | 1a: 1246851-70-6 1b: 74-88-4 1i: S108 1j: 7782-39-0 1l: yes | 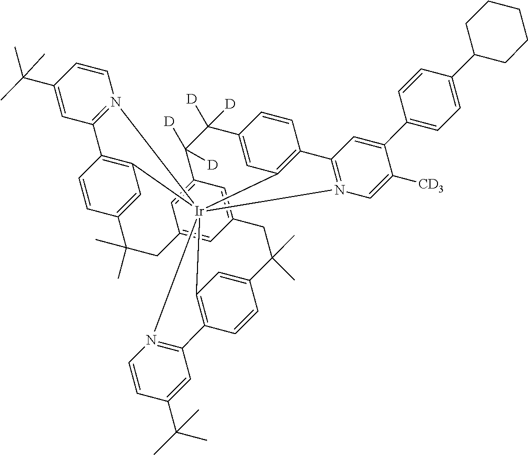 |
| IrL116D | 1a: 1246851-70-6 1b: 74-88-4 1i: S109 1j: 7782-39-0 1l: yes | 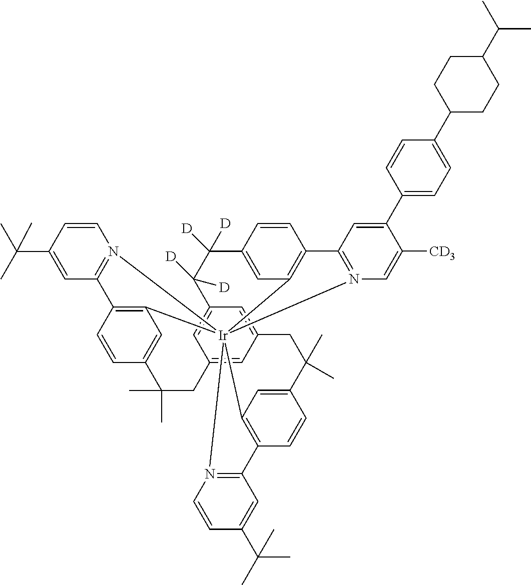 |
| IrL117D | 1a: 113744-24-4 1b: 74-88-4 1i: S110 1j: 7782-39-0 1l: yes | 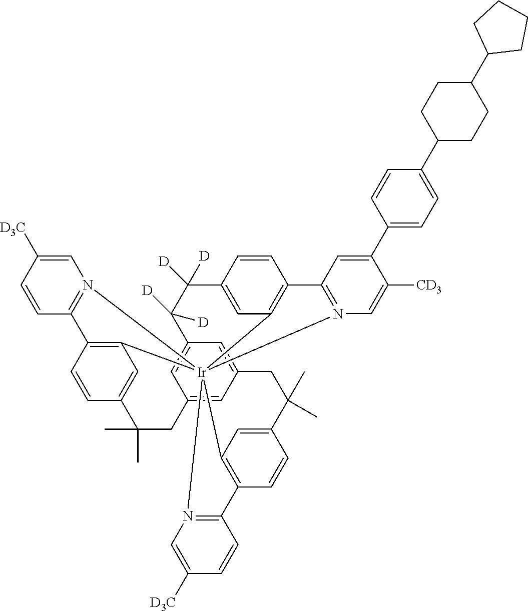 |
| IrL 118D | 1a: 113744-24-4 1b: 74-88-4 1i: S111 1j: 7782-39-0 1l: yes | 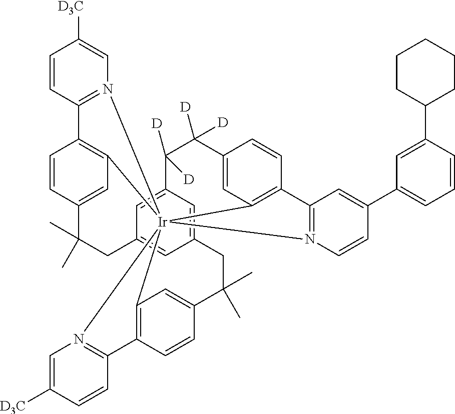 |
| IrL119D | 1a: 113744-24-4 1b: 74-88-4 1i: S112 1j: 7782-39-0 1l: yes | 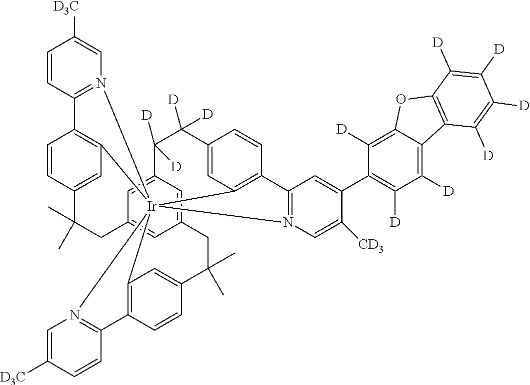 |
| IrL120D | 1a: 113744-24-4 1b: 74-88-4 1i: S113 1j: 7782-39-0 1l: yes | 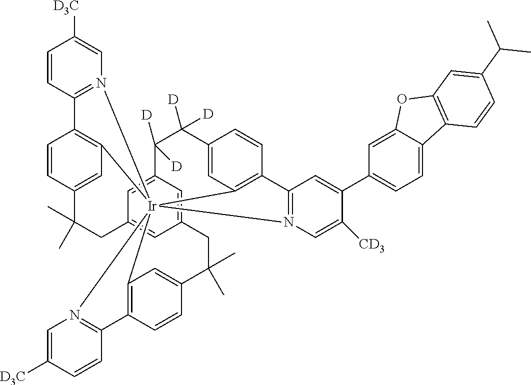 |
| IrL 121D | 1a: 113744-24-4 1b: 74-88-4 1i: S114 1j: 7782-39-0 1l: yes | 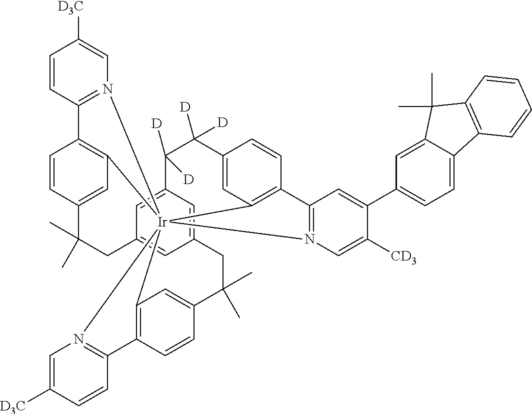 |
| IrL 122D | 1a: 113744-24-4 1b: 74-88-4 1i: S115 1j: 7782-39-0 1l: yes | 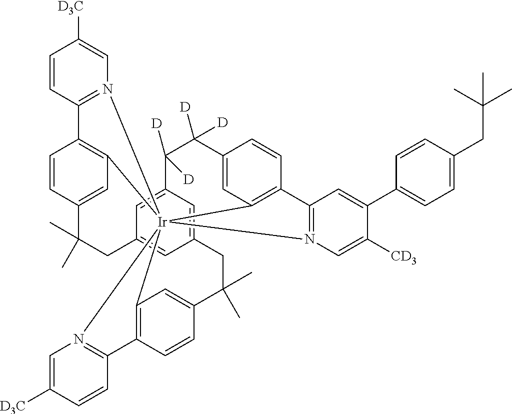 |
| IrL 123D | 1a: 113744-24-4 1b: 74-88-4 1i: S116 1j: 7782-39-0 1l: yes | 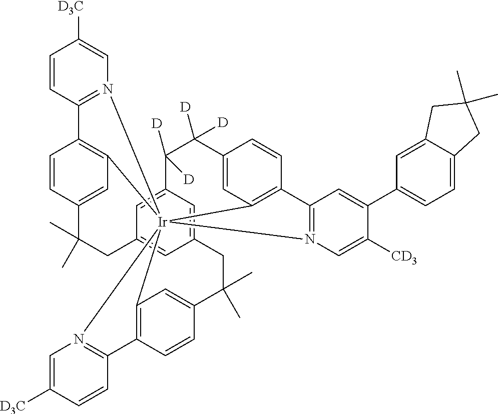 |
| IrL 124D | 1a: 113744-24-4 1b: 74-88-4 1i: S117 1j: 7782-39-0 1l: yes | 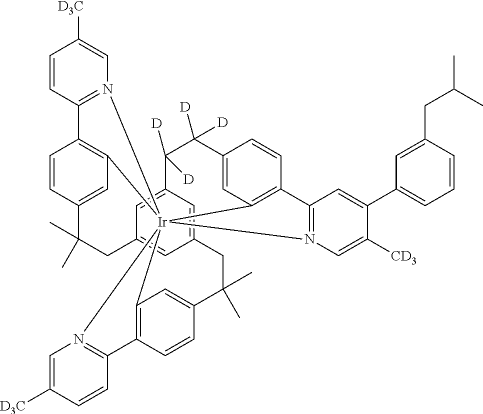 |
| IrL 125 | 1a: 63996-36-1 1b: 74-88-4 1i: 2202695-46-1 | 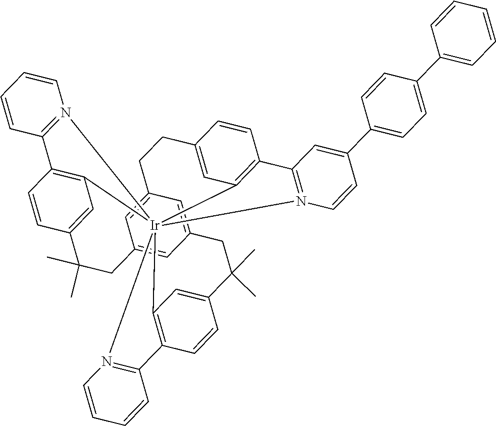 |
| IrL200 | 1a: 27012-25-5 39151-19-4 | 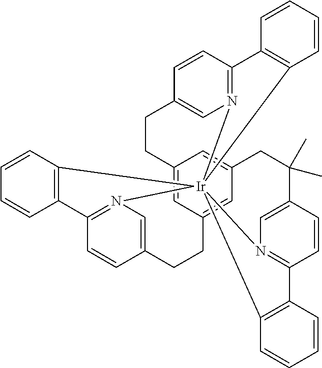 |
| | 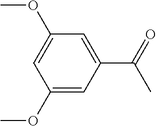 | |
| | 1b: 74-88-4 | |
| | 1i: 27012-25-5 | |
| IrL201D | 1a: 1989596-06-6 39151-19-4 1b: 74-88-4 1i: 867380-38-9 1j: 7782-39-0 1l: yes | 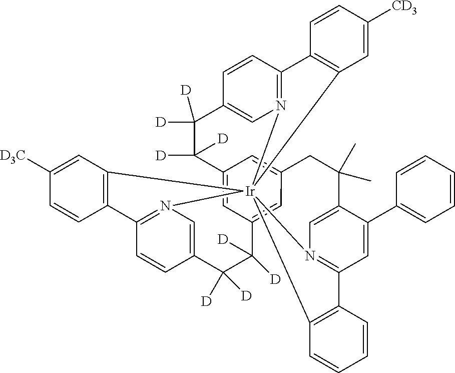 |
| IrL202 | 1a: 2375161-92-3 39151-19-4 1b: 74-88-4 1i: 27012-25-5 1j: 7782-39-0 | 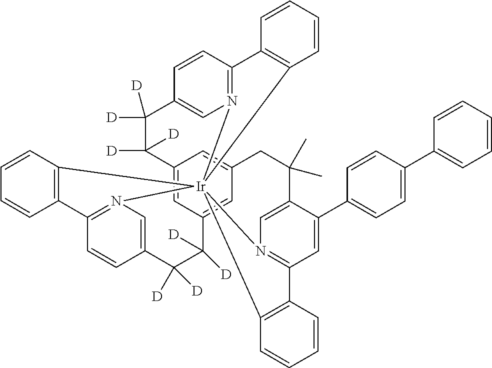 |
| IrL203 | 1a: S32 39151-19-4 1b: 74-88-4 1i: 27012-25-5 1j: 7782-39-0 | 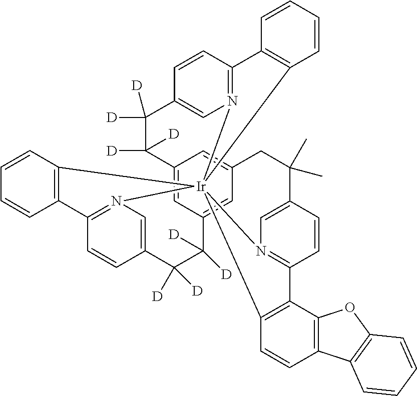 |
| IrL204D | 1a: S50 39151-19-4 1b: 74-88-4 1i: 27012-25-5 1j: 7782-39-0 1l: yes | 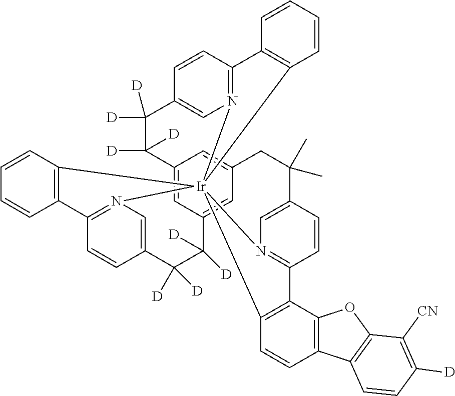 |
| IrL205D | 1a: S51 39151-19-4 1b: 86-50-9 1i: 2340379-18-0 1j: 7782-39-0 1l: yes | 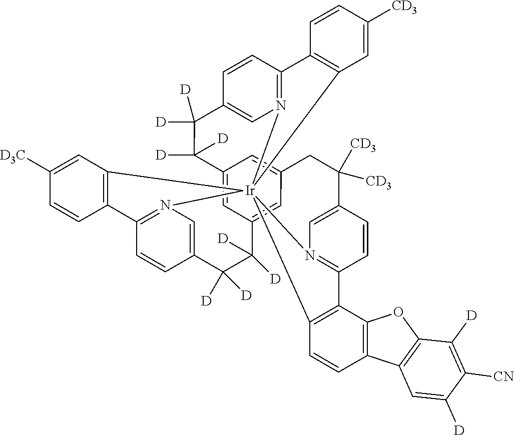 |
| IrL206D | 1a: S57 39151-19-4 1b: 74-88-4 1i: 27012-25-5 1j: 7782-39-0 1l: yes | 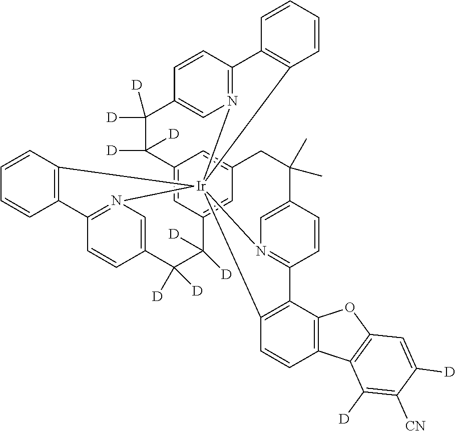 |
| IrL207D | 1a: S59 39151-19-4 1b: 74-88-4 1i: 27012-25-5 1j: 7782-39-0 1l: yes | 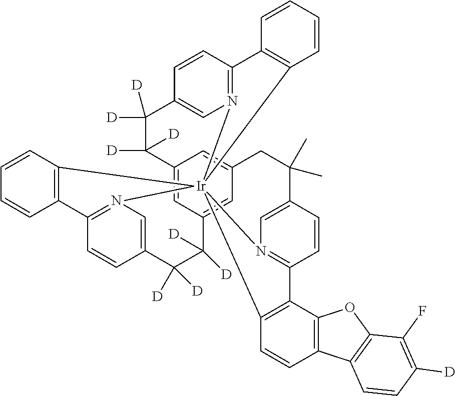 |
| IrL208D | 1a: S61 39151-19-4 1b: 74-88-4 1i: 27012-25-5 1j: 7782-39-0 1l: yes | 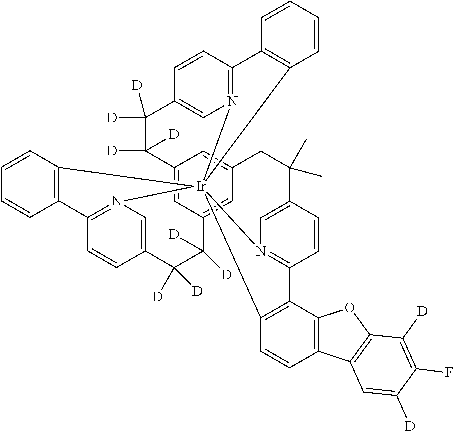 |
| IrL209D | 1a: S63 39151-19-4 1b: 74-88-4 1i: 27012-25-5 1j: 7782-39-0 1l: yes | 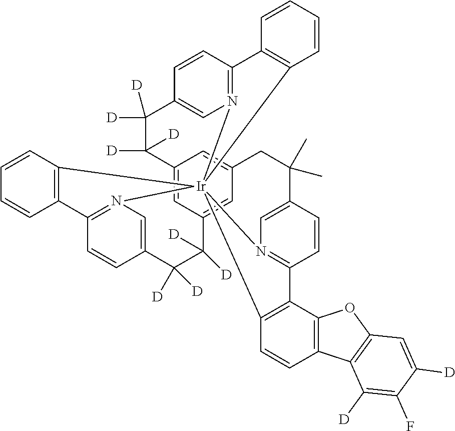 |
| IrL210D | 1a: S63 39151-19-4 1b: 74-88-4 1i: 2340379-18-0 1j: 7782-39-0 1l: yes | 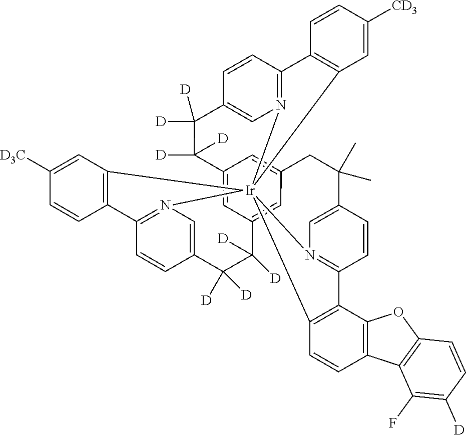 |
| IrL211D | 1a: S65 39151-19-4 1b: 74-88-4 1i: 31686-64-3 1j: 7782-39-0 1l: yes | 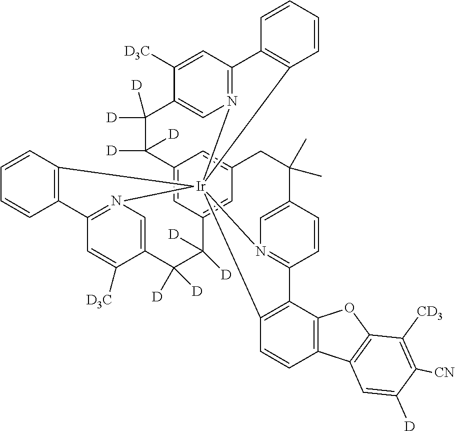 |
| IrL212D | 1a: S69 39151-19-4 1b: 74-88-4 1i: 27012-25-5 1j: 7782-39-0 1l: yes | 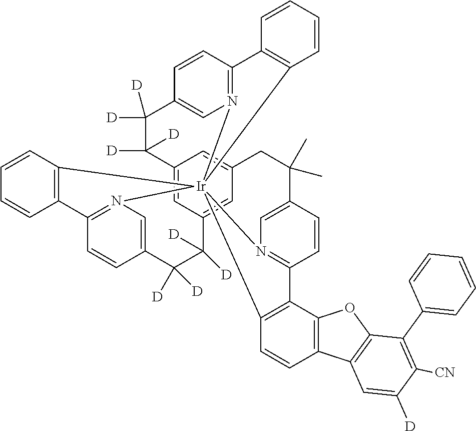 |
| IrL213D | 1a: S70 39151-19-4 1b: 74-88-4 1i: 31686-64-3 1j: 7782-39-0 1l: yes | 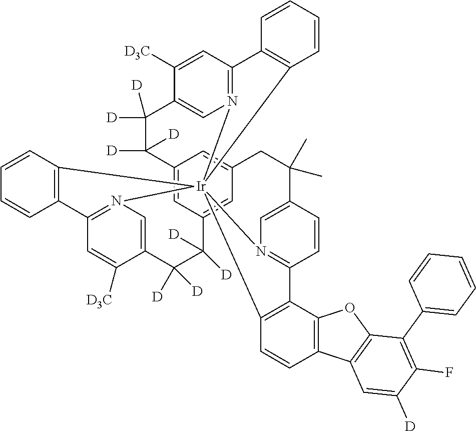 |
| IrL300 | 1a: 63996-36-1 39151-19-4 1b: 74-88-4 1i: 63996-36-1 1j: 7782-39-0 | 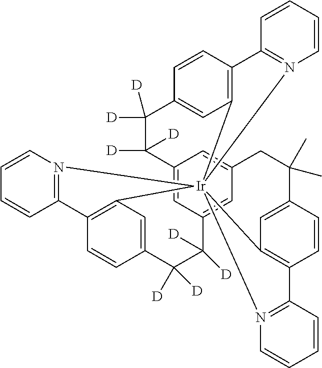 |
| IrL301D | 1a: 2452400-40-5 39151-19-4 1b: 74-88-4 1i: 63996-36-1 1j: 7782-39-0 1l: yes | 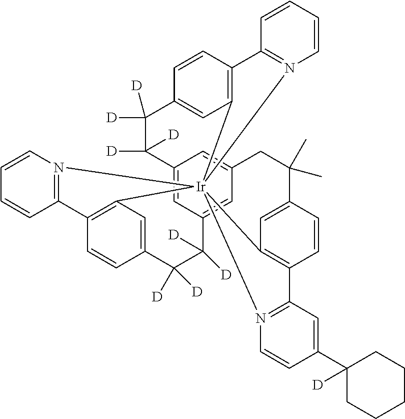 |
| IrL302D | 1a: 504413-43-8 39151-19-4 1b: 74-88-4 1i: 113744-24-4 1j: 7782-39-0 1l: yes | 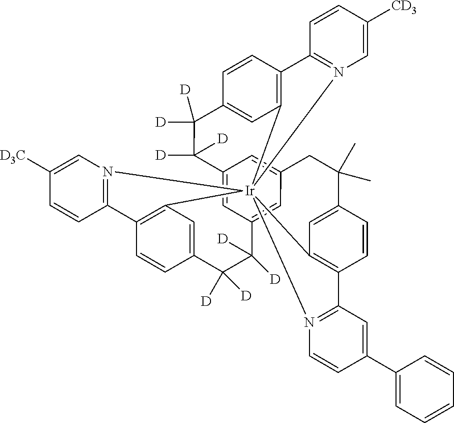 |
| IrL303 | 1a: 2762695-47-4 39151-19-4 1b: 74-88-4 1i: 2413601-09-7 1j: 7782-39-0 | 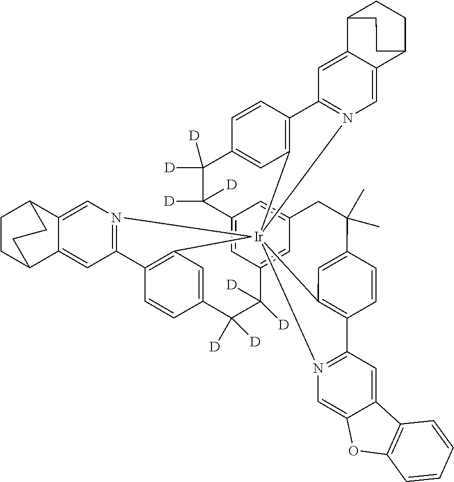 |
| IrL304 | 1a: 2202695-46-1 39151-19-4 1b: 74-88-4 1i: 1246851-70-6 1j: 7782-39-0 | 521 |
| IrL305D | 1a: S100 39151-19-4 1b: 74-88-4 1i: 63996-36-1 1j: 7782-39-0 1l: yes | 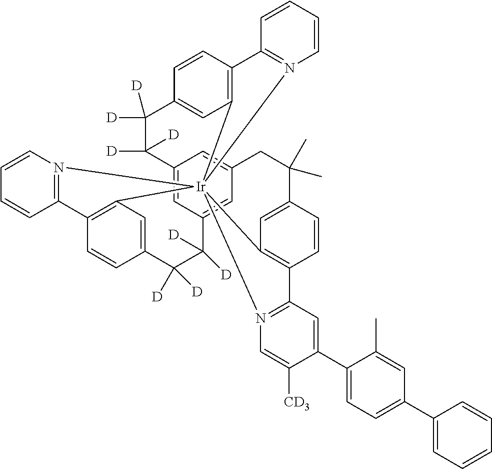 |
| IrL306 | 1a: S101 39151-19-4 1b: 74-88-4 1i: 63996-36-1 1j: 7782-39-0 | 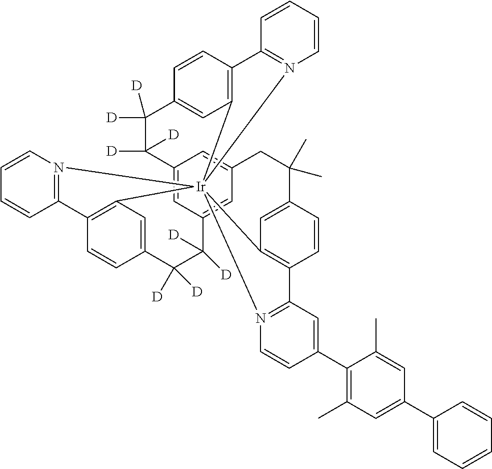 |
| IrL307D | 1a: S102 39151-19-4 1b: 74-88-4 1i: 113744-24-4 1j: 7782-39-0 1l: yes | 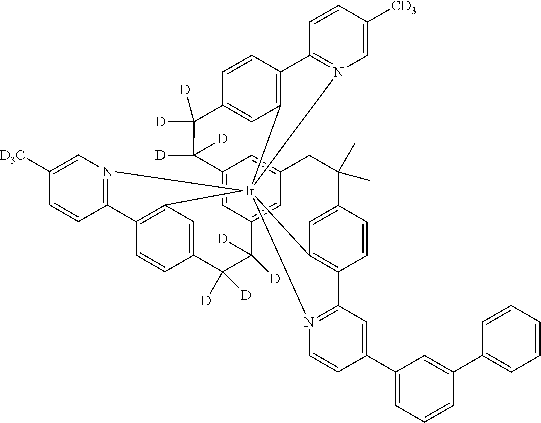 |
| IrL308D | 1a: S103 39151-19-4 1b: 74-88-4 1i: 113744-24-4 1j: 7782-39-0 1l: yes | 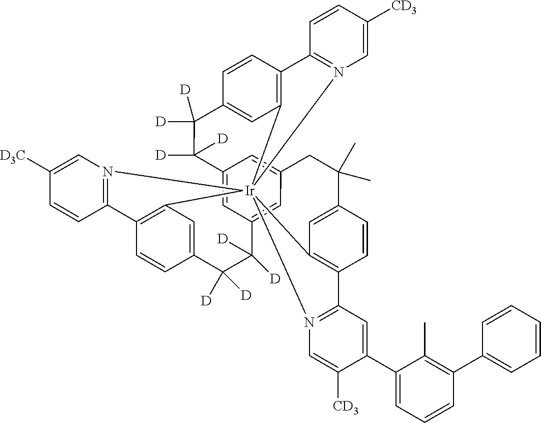 |
| IrL309D | 1a: S104 39151-19-4 1b: 74-88-4 1i: 113744-24-4 1j: 7782-39-0 1l: yes | 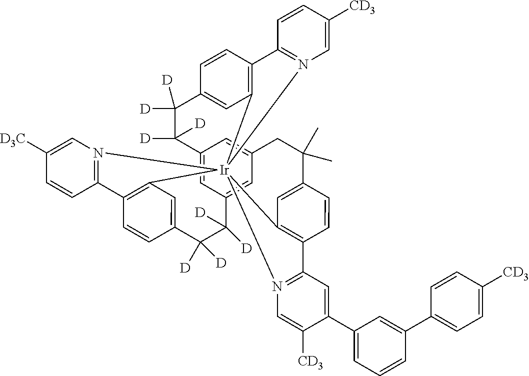 |
| IrL310D | 1a: S105 39151-19-4 1b: 74-88-4 1i: 63996-36-1 1j: 7782-39-0 1l: yes | 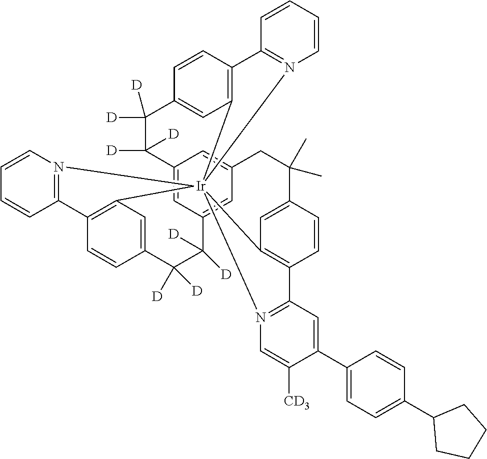 |
| IrL311 | 1a: S106 39151-19-4 1b: 74-88-4 1i: 63996-36-1 1j: 7782-39-0 | 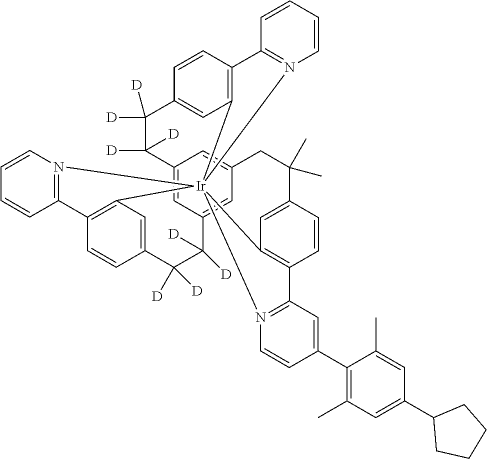 |
| IrL312D | 1a: S107 39151-19-4 1b: 74-88-4 1i: 63996-36-1 1j: 7782-39-0 1l: yes | 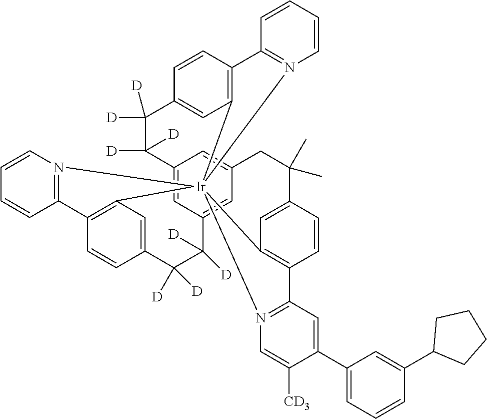 |
| IrL313D | 1a: S108 39151-19-4 1b: 74-88-4 1i: 63996-36-1 1j: 7782-39-0 1l: yes | 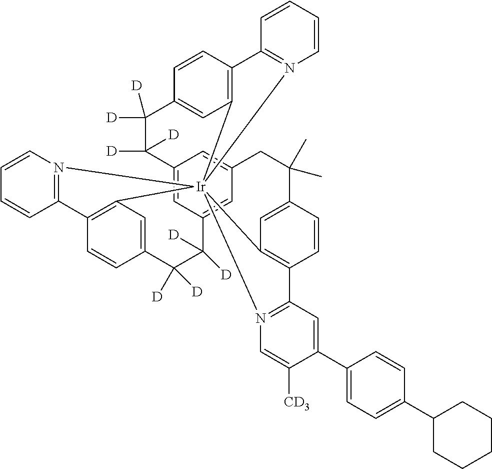 |
| IrL314D | 1a: S109 39151-19-4 1b: 74-88-4 1i: 63996-36-1 1j: 7782-39-0 1l: yes | 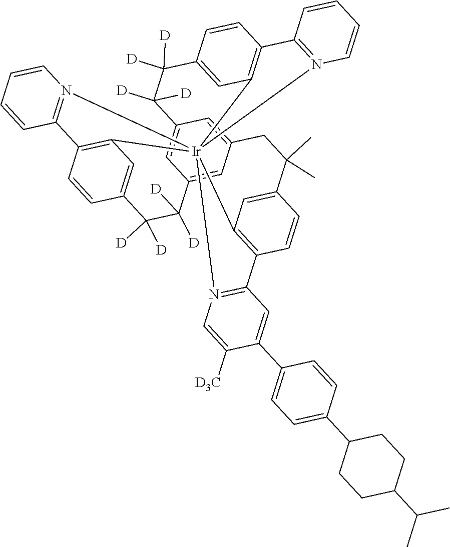 |
| IrL315D | 1a: S110 39151-19-4 1b: 74-88-4 1i: 63996-36-1 1j: 7782-39-0 1l: yes | 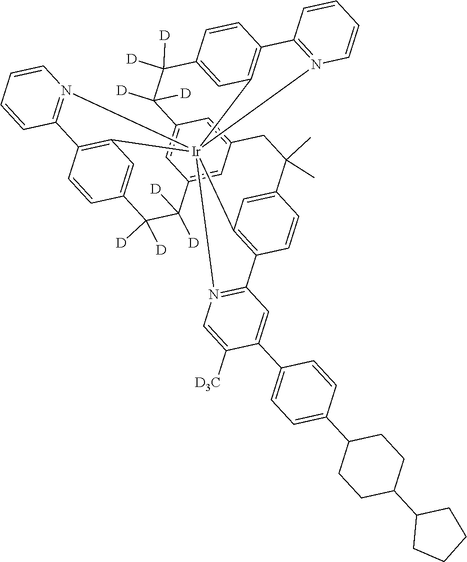 |
| IrL316D | 1a: S111 39151-19-4 1b: 74-88-4 1i: 113744-24-4 1j: 7782-39-0 1l: yes | 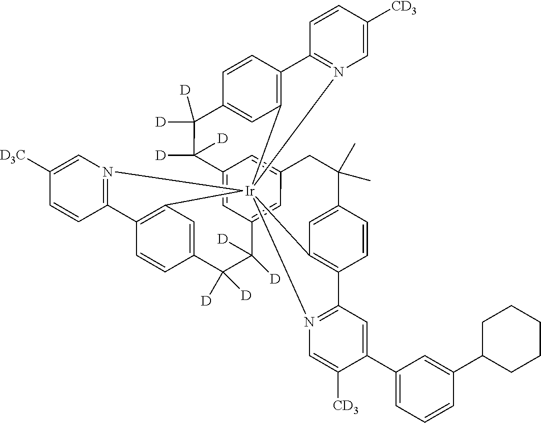 |
| IrL317D | 1a: S112 39151-19-4 1b: 74-88-4 1i: 113744-24-4 1j: 7782-39-0 1l: yes | 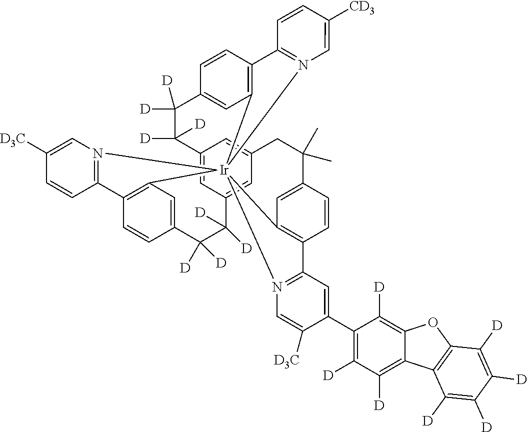 |
| IrL318D | 1a: S113 39151-19-4 1b: 74-88-4 1i: 113744-24-4 1j: 7782-39-0 1l: yes | 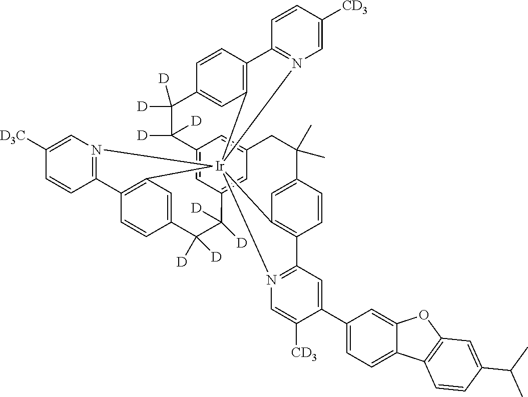 |
| IrL319D | 1a: S114 39151-19-4 1b: 74-88-4 1i: 113744-24-4 1j: 7782-39-0 1l: yes | 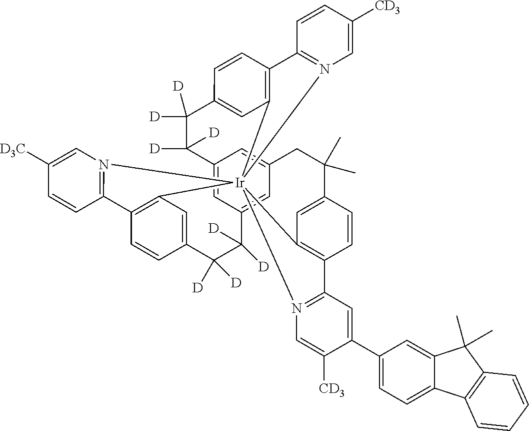 |

### Example IrL400

a) Step 1a:

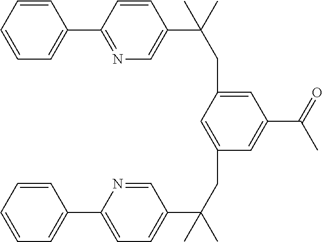 [SMILES: CC(=O)c1cc(CC(C)(C)c2ccc(-c3ccccc3)nc2)cc(CC(C)(C)c2ccc(-c3ccccc3)nc2)c1]

A well-stirred mixture of 64.5 g (100 mmol) example IrL1 compound 1e, 51.3 ml (400 mmol) n-butyl vinyl ether [111-34-2], 55.3 ml (400 mmol) triethylamine [121-44-8], 224 mg (1 mmol) palladium(II) acetate, 1.25 g (2 mmol) 1,3 bis(diphenyl-phosphino)propane (dppp) [6737-42-4] and 250 ml dimethylacetamide (DMAC) is heated at reflux for 16 h. The refluxed solution is then refluxed. After cooling, add 250 ml aqueous 2N HCl, stir for 2 h at 30° C., add 500 g ice, make weakly alkaline (pH˜8) with conc. ammonia, extract three times with 300 ml EA each, wash the combined organic phases twice with 300 ml water each and once with 300 ml saturated saline, and dry over magnesium sulfate. Filter off from the desiccant over a silica gel bed pre-slurried with EA, concentrate the filtrate to dryness and chromatograph (Torrent automatic column machine from Semrau) the residue. Yield: 43.7 g (81 mmol) 81%; purity: about 97% by ¹H-NMR.

b) Step 1b:

Carried out analogously to example IrL1, step 1a.

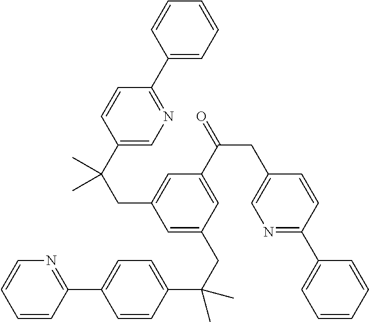 [SMILES: CC(C)(Cc1cc(CC(C)(C)c2ccc(-c3ccccc3)nc2)cc(C(=O)Cc2ccc(-c3ccccc3)nc2)c1)c1ccc(-c2ccccn2)cc1]

c) Step 1c:

Carried out analogously to example IrL1, step 1b, with stoichiometry adjusted to dimethylation.

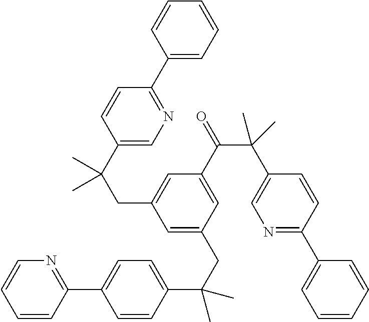 [SMILES: CC(C)(Cc1cc(CC(C)(C)c2ccc(-c3ccccc3)nc2)cc(C(=O)C(C)(C)c2ccc(-c3ccccc3)nc2)c1)c1ccc(-c2ccccn2)cc1]

d) Step 1d:

Carried out analogously to example IrL1, step c with stoichiometry adjusted to the monoketone.

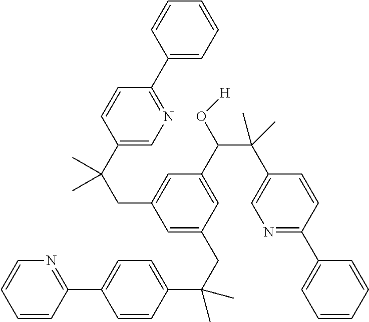 [SMILES: CC(C)(Cc1cc(CC(C)(C)c2ccc(-c3ccccc3)nc2)cc(C(O)C(C)(C)c2ccc(-c3ccccc3)nc2)c1)c1ccc(-c2ccccn2)cc1]

e) Step 1e:

Carried out analogously to example IrL1, step d with stoichiometry adjusted to the monoalcohol

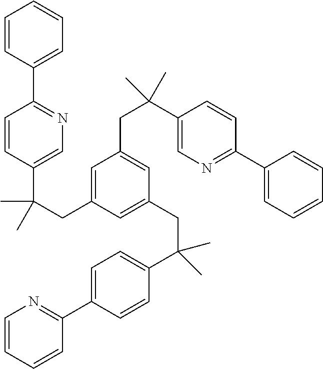 [SMILES: CC(C)(Cc1cc(CC(C)(C)c2ccc(-c3ccccc3)nc2)cc(CC(C)(C)c2ccc(-c3ccccc3)nc2)c1)c1ccc(-c2ccccn2)cc1]

f) Level 1f: IrL400

Carried out analogously to example IrL1, stage 1k.

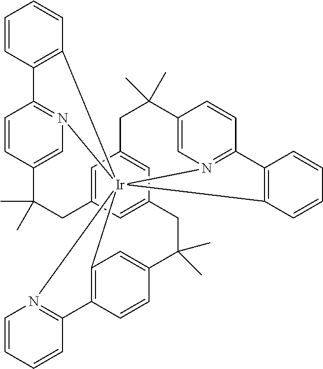

g) Stage 1g: Deuteration

Carried out analogously to example IrL1, stage 1l.

Similarly, the following compounds can be represented using the given modified reactants in the corresponding steps, adjusting the stoichiometry of the components according to the functionalities of the building blocks:

| Ex. | Educts | Product |
|---|---|---|
| IrL402 | IrL2, 1e 1b: 27012-25-5 1c: 75-03-6 | 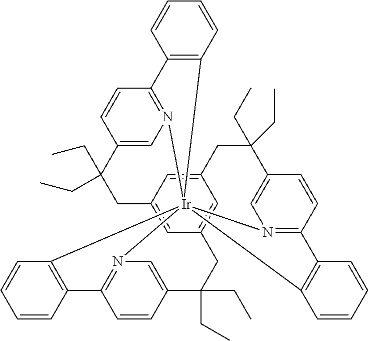 |
| IrL403 | IrL3, 1e 1b: 1989596-06-6 1c: 74-88-4 | 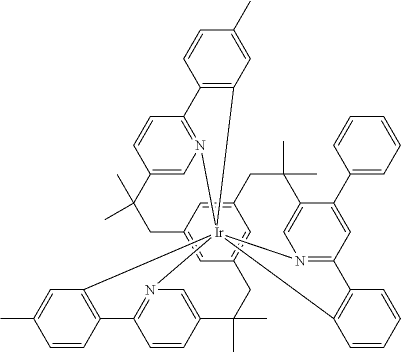 |
| IrL404 | IrL1, 1e 1b: 2375161-92-3 1c: 74-88-4 | 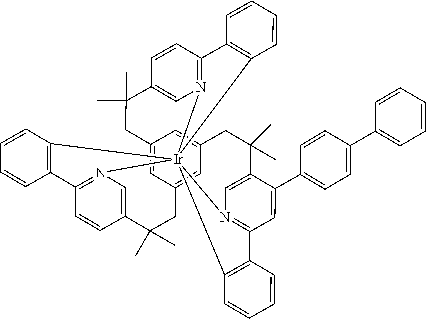 |
| IrL405D | IrL6, 1e 1b: S1 1c: 74-88-4 1g: yes | 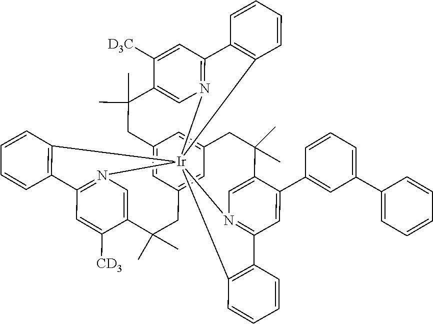 |
| IrL406 | IrL1, 1e 1b: S15 1c: 74-88-4 | 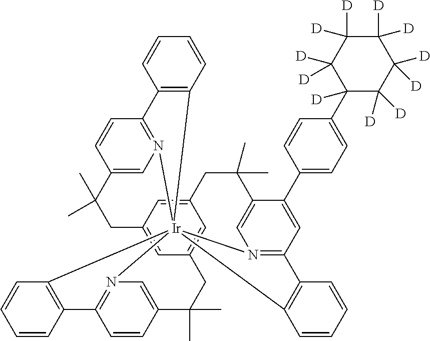 |
| IrL407 | IrL21, 1e 1b: S32 1c: 74-88-4 | 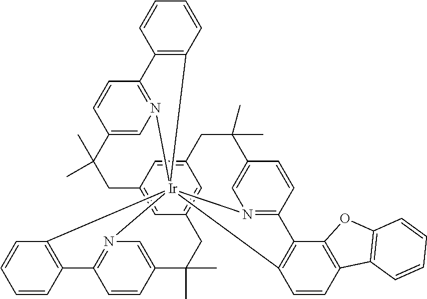 |
| IrL408 | IrL39, 1e 1b: S33 1c: 74-88-4 | 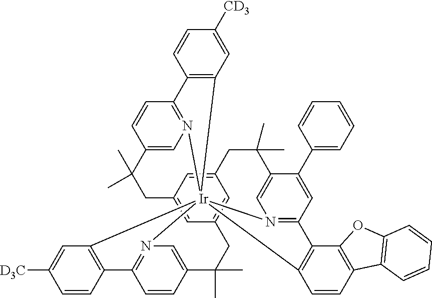 |
| IrL409D | IrL56, 1e 1b: S50 1c: 74-88-4 1g: yes | 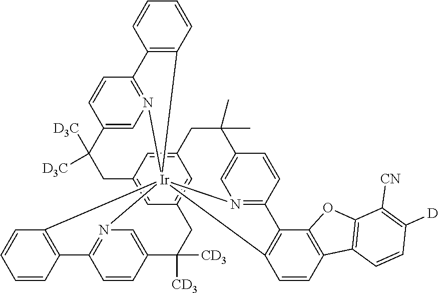 |
| IrL410D | IrL57, 1e 1b: S51 1c: 75-03-6 1g: yes | 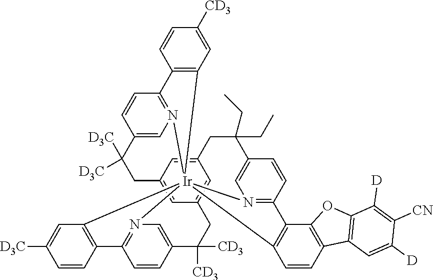 |
| IrL411D | IrL63, 1e 1b: S57 1c: 74-88-4 1g: yes | 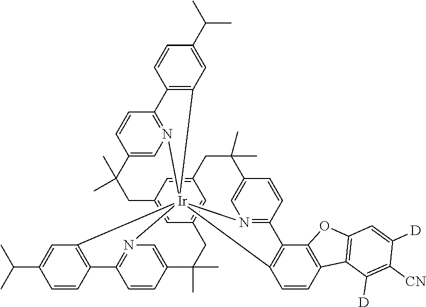 |
| IrL412D | IrL1, 1e 1b: S58 1c: 74-88-4 1g: yes | 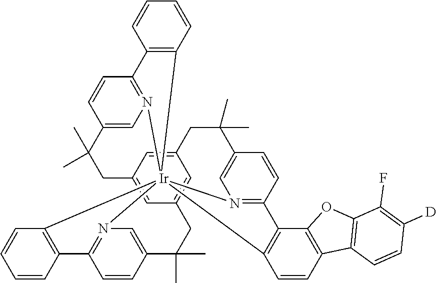 |
| IrL413D | IrL1, 1e 1b: S61 1c: 628-21-7 1g: yes | 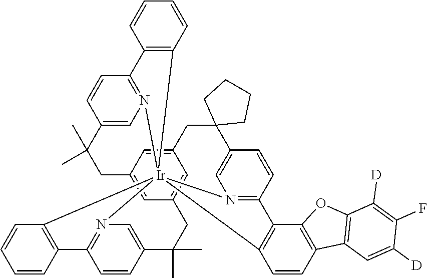 |
| IrL414D | IrL69, 1e 1b: S63 1c: 86-50-9 1g: yes | 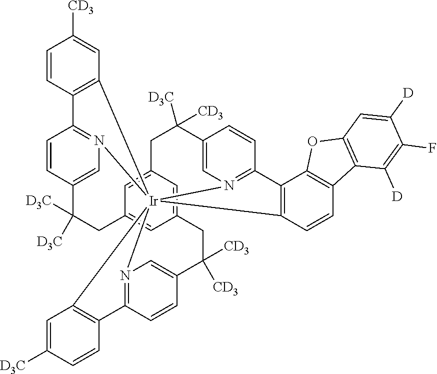 |
| IrL415D | IrL1, 1e 1b: S64 1c: 74-88-4 1g: yes | 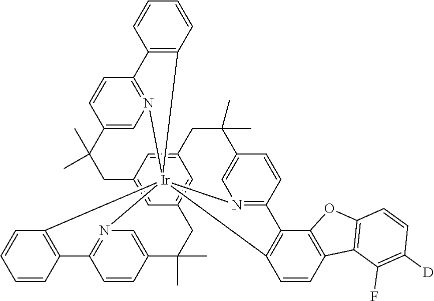 |
| IrL416D | IrL1, 1e 1b: S65 1c: 74-88-4 1g: yes | 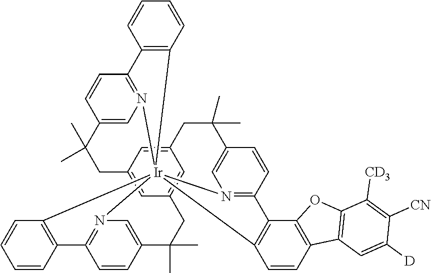 |
| IrL417D | IrL1, 1e 1b: S66 1c: 74-88-4 1g: yes | 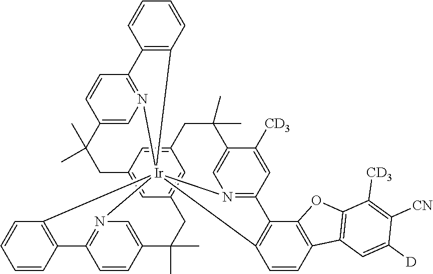 |
| IrL418D | IrL1, 1e 1b: S69 1c: 74-88-4 1g: yes | 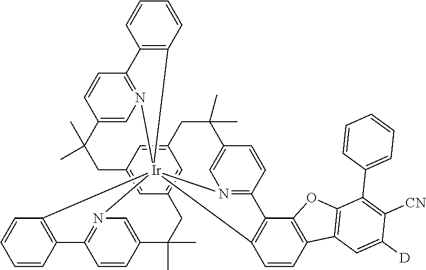 |
| IrL419D | IrL1, 1e 1b: S70 1c: 74-88-4 1g: yes | 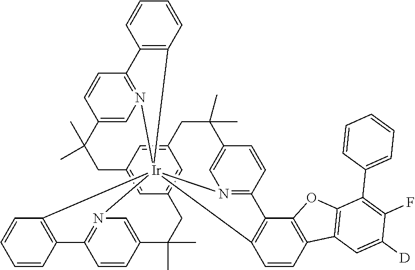 |
| IrL420D | IrL1, 1e 1b: S71 1c: 74-88-4 1g: yes | 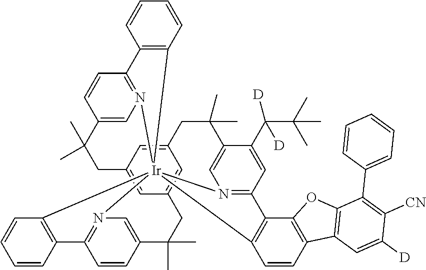 |
| IrL421D | IrL1, 1e 1b: S72 1c: 74-88-4 1g: yes | 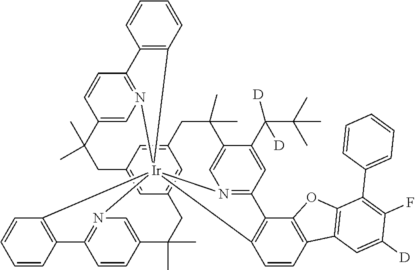 |
| IrL422 | IrL100, 1e 1b: 63996-36-1 1c: 74-88-4 | 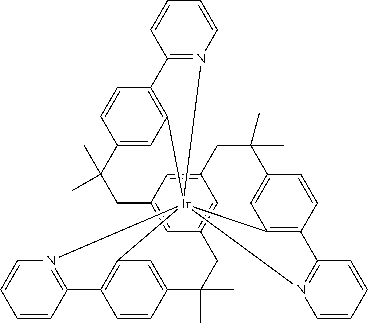 |
| IrL423D | IrL100, 1e 1b: 2452400-40-5 1c: 74-88-4 1g: yes | 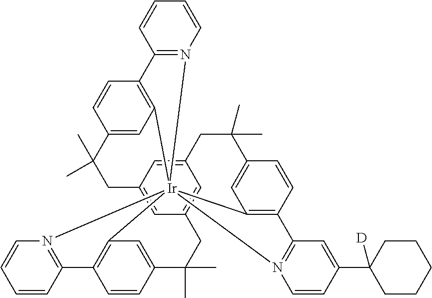 |
| IrL424D | IrL102, 1e 1b: 504413-43-8 1c: 74-88-4 1g: yes | 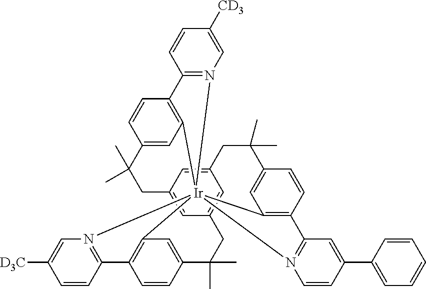 |
| IrL425 | IrL104, 1e 1b: 2762695-47-4 1c: 74-88-4 | 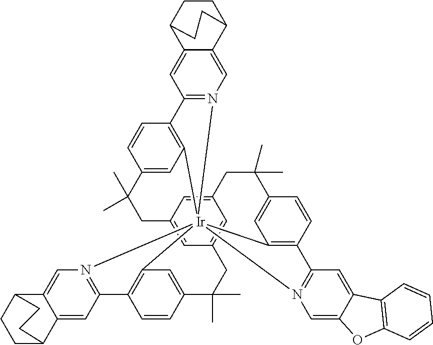 |
| IrL426D | IrL105, 1e 1b: 2202695-46-1 1c: 74-88-4 1g: yes | 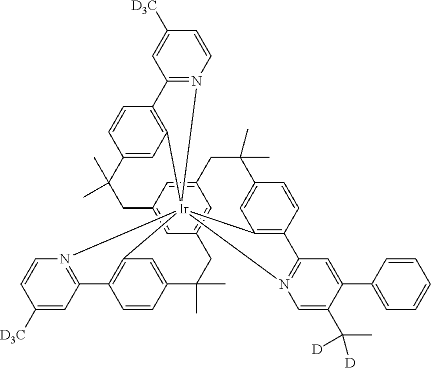 |
| IrL427 | IrL106, 1e 1b: 2202695-46-1 1c: 74-88-4 | 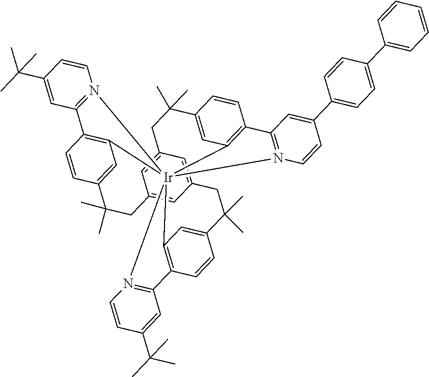 |
| IrL428D | IrL100, 1e 1b: S100 1c: 74-88-4 1g: yes | 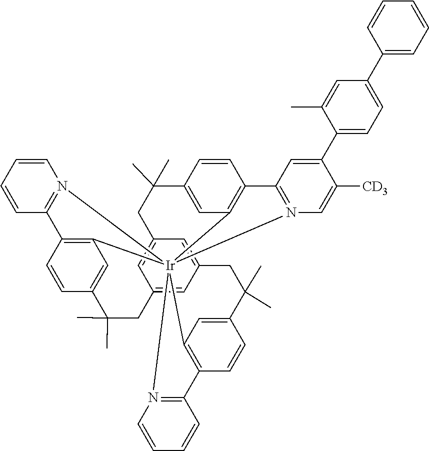 |
| IrL429 | IrL100, 1e 1b: S101 1c: 74-88-4 | 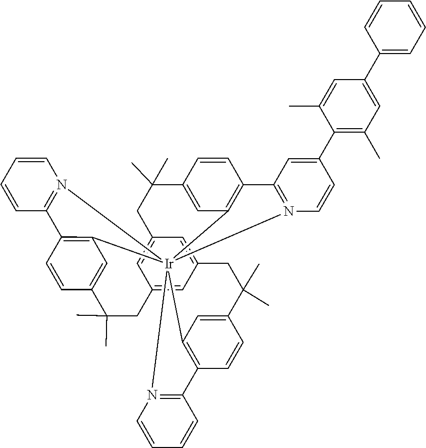 |
| IrL430D | IrL102, 1e 1b: S102 1c: 74-88-4 1g: yes | 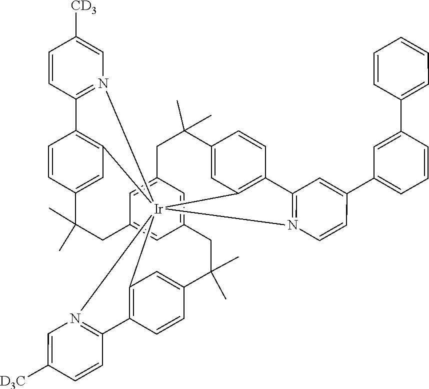 |
| IrL431D | IrL102, 1e 1b: S103 1c: 74-88-4 1g: yes | 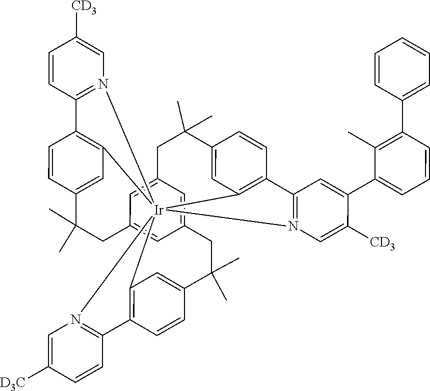 |
| IrL432D | IrL102, 1e 1b: S104 1c: 74-88-4 1g: yes | 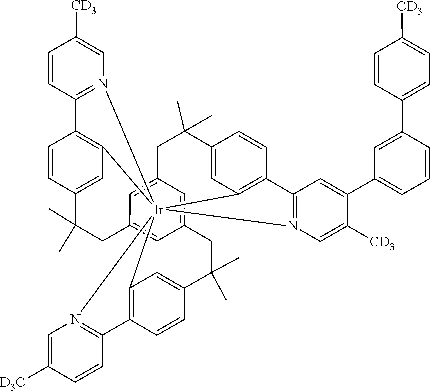 |
| IrL433D | IrL102, 1e 1b: S105 1c: 74-88-4 1g: yes | 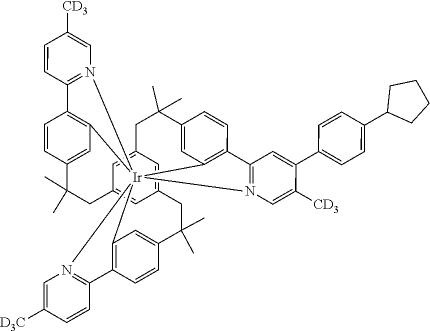 |
| IrL434D | IrL102, 1e 1b: S106 1c: 74-88-4 1g: yes | 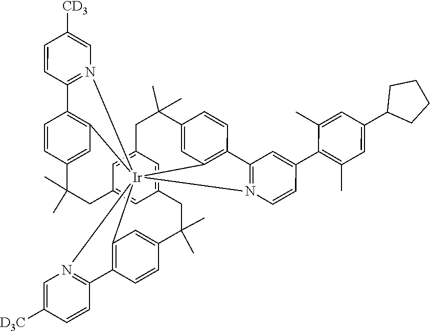 |
| IrL435D | IrL102, 1e 1b: S107 1c: 74-88-4 1g: yes | 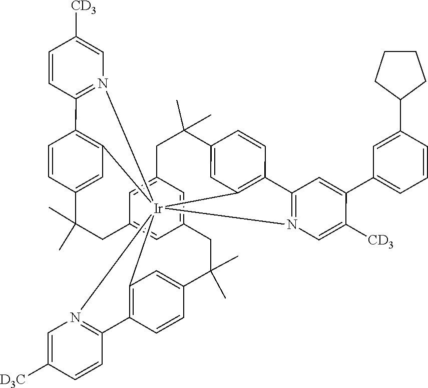 |
| IrL436D | IrL106, 1e 1b: S108 1c: 74-88-4 1g: yes | 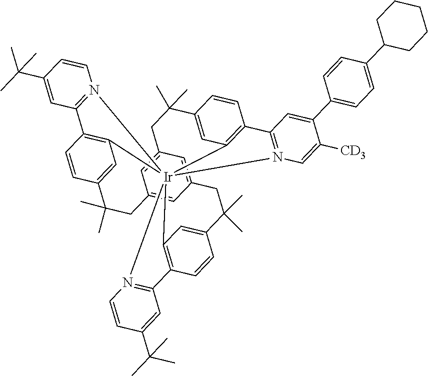 |
| IrL437D | IrL106, 1e 1b: S109 1c: 74-88-4 1g: yes | 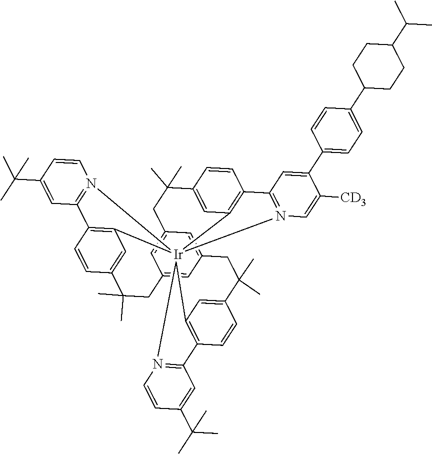 |
| IrL438D | IrL102, 1e 1b: S110 1c: 74-88-4 1g: yes | 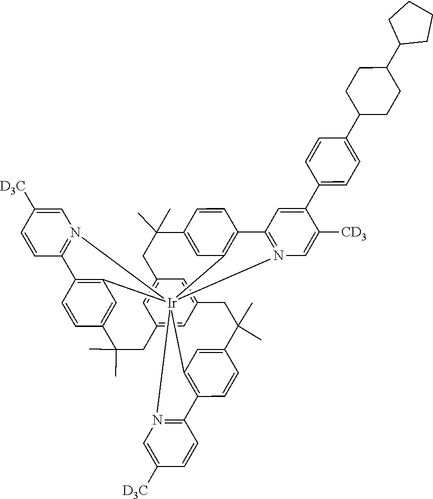 |
| IrL439D | IrL102, 1e 1b: S111 1c: 74-88-4 1g: yes | 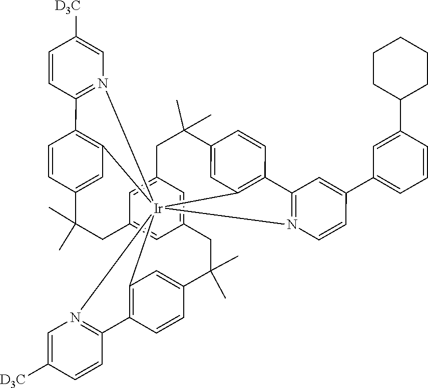 |
| IrL440D | IrL102, 1e 1b: S112 1c: 74-88-4 1g: yes | 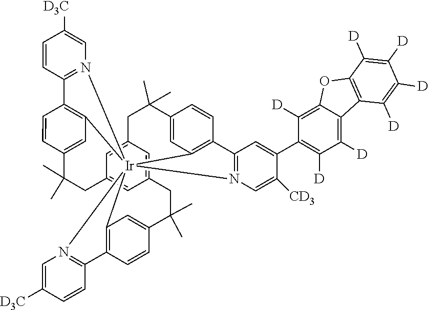 |
| IrL441D | IrL102, 1e 1b: S113 1c: 74-88-4 1g: yes | 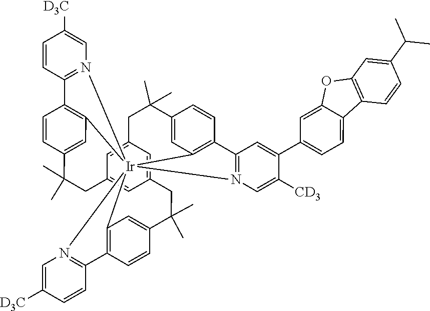 |
| IrL442D | IrL102, 1e 1b: S114 1c: 74-88-4 1g: yes | 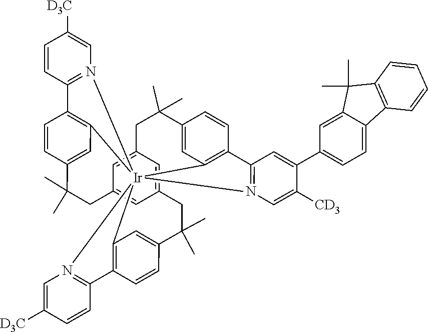 |

### Example: Production of the OLEDs

Vacuum Processed Devices:

OLEDs according to the invention as well as OLEDs according to the prior art are manufactured by a general process according to WO 2004/058911, which is adapted to the conditions described here (layer thickness variation, materials used).

In the following examples the results of different OLEDs are presented. Cleaned glass plates (cleaning in Miele laboratory dishwasher, cleaner Merck Extran) coated with structured ITO (Indium Tin Oxide) of thickness 50 nm are pretreated with UV-ozone for 25 minutes (UV-ozone generator PR-100, company UVP). These coated glass plates form the substrates onto which the OLEDs are deposited.

All materials are thermally evaporated in a vacuum chamber. The emission layer always consists of at least one or more matrix materials M and one of the phosphorescent dopants Ir according to the invention, which is added to the matrix material(s) by co-evaporation in a certain volume fraction. A specification such as M1:M2:Ir (55%:35%:10%) means here that the material M1 is present in the layer in a volume fraction of 55%, M2 in a volume fraction of 35% and Ir in a volume fraction of 10%. Similarly, the electron transport layer consists of a mixture of two materials. The exact structure of the OLEDs can be seen in Table 1. The materials used to fabricate the OLEDs are shown in Table 3.

The OLEDs are characterized as standard. For this purpose, the electroluminescence spectra, the current efficiency (measured in cd/A), the power efficiency (measured in lm/W) and the external quantum efficiency (EQE, measured in percent) are determined as a function of the luminance, calculated from current-voltage-luminance characteristics (IUL characteristics) assuming a Lambertian radiation pattern, as well as the lifetime. The eff. in (cd/A), EQE in (%), voltage in (V) and color are given for a luminance of 1000 cd/m².

The OLEDs have the Following Layer Structure:

Substrate

Hole injection layer (HIL) of HTM1 doped with 5% NDP-9 (commercially available from Novaled), 20 nm

Hole transport layer (HTL), see Table 1

Electron blocking layer (EBL), see Table 1

Emission Layer (EML), see Table 1

Hole blocker layer (HBL), see Table 1

Electron transport layer (ETL), made of ETM1:ETM2 (50%:50%), 30 nm

Electron injection layer (EIL) made of ETM2, 1 nm

Aluminum cathode, 100 nm

TABLE 1
Structure of phosphorescent OLED devices

| | HTL | EBL | EML | HBL |
|---|---|---|---|---|
| Ex. | Thickness | Thickness | Thickness | Thickness |
| Ref-GP1 | HTM1 | EBM1 | M1:M2:Ref-D7 | HBM1 |
| | 50 nm | 20 nm | (44%:50%:6%) 40 nm | 5 nm |
| Ref-GP2 | HTM1 | EBM1 | M1:M2:Ref-D8 | HBM1 |
| | 50 nm | 20 nm | (44%:50%:6%) 40 nm | 5 nm |
| GP1 | HTM1 | EBM1 | M1:M2:IrL83D | HBM1 |
| | 50 nm | 20 nm | (44%:50%:6%) 40 nm | 5 nm |
| GP2 | HTM1 | EBM1 | M1:M2:IrL84 | HBM1 |
| | 50 nm | 20 nm | (44%:50%:6%) 40 nm | 5 nm |
| GP3 | HTM1 | EBM1 | M1:M2:IrL4 | HBM1 |
| | 50 nm | 20 nm | (40%:45%:15%) 40 nm | 5 nm |
| GP4 | HTM1 | EBM1 | M1:M2:IrL6D | HBM1 |
| | 50 nm | 20 nm | (40%:45%:15%) 40 nm | 5 nm |
| GP5 | HTM1 | EBM1 | M1:M2:IrL21 | HBM1 |
| | 50 nm | 20 nm | (40%:45%:15%) 40 nm | 5 nm |
| GP6 | HTM1 | EBM1 | M1:M2:IrL34 | HBM1 |
| | 50 nm | 20 nm | (40%:45%:15%) 40 nm | 5 nm |
| GP7 | HTM1 | EBM1 | M1:M2:IrL44 | HBM1 |
| | 50 nm | 20 nm | (44%:50%:6%) 40 nm | 5 nm |
| GP8 | HTM1 | EBM1 | M1:M2:IrL49 | HBM1 |
| | 50 nm | 20 nm | (44%:50%:6%) 40 nm | 5 nm |
| GP9 | HTM1 | EBM1 | M1:M2:IrL56D | HBM1 |
| | 50 nm | 20 nm | (44%:50%:6%) 40 nm | 5 nm |
| GP10 | HTM1 | EBM1 | M1:M2:IrL62D | HBM1 |
| | 50 nm | 20 nm | (44%:50%:6%) 40 nm | 5 nm |
| GP11 | HTM1 | EBM1 | M1:M2:IrL67D | HBM1 |
| | 50 nm | 20 nm | (44%:50%:6%) 40 nm | 5 nm |
| GP12 | HTM1 | EBM1 | M1:M2:IrL76D | HBM1 |
| | 50 nm | 20 nm | (44%:50%:6%) 40 nm | 5 nm |
| GP13 | HTM1 | EBM1 | M1:M2:IrL78D | HBM1 |
| | 50 nm | 20 nm | (44%:50%:6%) 40 nm | 5 nm |
| GP14 | HTM1 | EBM1 | M1:M2:IrL102D | HBM1 |
| | 50 nm | 20 nm | (40%:45%:15%) 40 nm | 5 nm |
| GP15 | HTM1 | EBM1 | M1:M2:IrL107D | HBM1 |
| | 50 nm | 20 nm | (44%:50%:6%) 40 nm | 5 nm |
| GP16 | HTM1 | EBM1 | M1:M2:IrL207D | HBM1 |
| | 50 nm | 20 nm | (44%:50%:6%) 40 nm | 5 nm |
| GP17 | HTM1 | EBM1 | M1:M2:IrL213D | HBM1 |
| | 50 nm | 20 nm | (44%:50%:6%) 40 nm | 5 nm |
| GP18 | HTM1 | EBM1 | M1:M2:IrL307D | HBM1 |
| | 50 nm | 20 nm | (40%:45%:15%) 40 nm | 5 nm |
| GP19 | HTM1 | EBM1 | M1:M2:IrL410D | HBM1 |
| | 50 nm | 20 nm | (44%:50%:6%) 40 nm | 5 nm |
| GP20 | HTM1 | EBM1 | M1:M2:IrL419D | HBM1 |
| | 50 nm | 20 nm | (44%:50%:6%) 40 nm | 5 nm |
| GP21 | HTM1 | EBM1 | M1:M2:IrL439D | HBM1 |
| | 50 nm | 20 nm | (40%:45%:15%) 40 nm | 5 nm |

TABLE 2
Results phosphorescent OLED devices

| Ex. | EQE (%) | Voltage (V) | Color |
|---|---|---|---|
| Ref-GP1 | 26.1 | 3.1 | green |
| Ref-GP2 | 27.3 | 3.0 | green |
| GP1 | 26.4 | 2.9 | green |
| GP2 | 27.5 | 3.0 | green |
| GP3 | 31.3 | 2.8 | yellow |
| GP4 | 30.0 | 2.9 | yellow |
| GP5 | 30.5 | 2.8 | yellow |
| GP6 | 29.8 | 2.9 | yellow |
| GP7 | 27.9 | 3.0 | green |
| GP8 | 28.4 | 2.9 | green |
| GP9 | 26.7 | 2.9 | green |
| GP10 | 29.6 | 3.0 | green |
| GP11 | 26.8 | 2.9 | green |
| GP12 | 27.9 | 2.9 | green |
| GP13 | 28.2 | 3.0 | green |
| GP14 | 28.4 | 2.8 | yellow |
| GP15 | 30.6 | 2.9 | green |
| GP16 | 26.8 | 2.8 | green |
| GP17 | 28.4 | 2.9 | green |
| GP18 | 29.8 | 2.9 | yellow |
| GP19 | 27.2 | 3.0 | green |
| GP20 | 28.6 | 2.9 | green |
| GP21 | 30.1 | 2.8 | yellow |

The device lifetimes of the GP1 and GP2 OLED devices are comparable to the Ref-GP1 and Ref-GP2 OLED reference devices, respectively.

TABLE 3
Structural formulas of the materials used

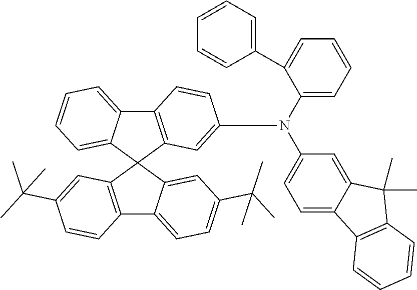 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

HTM1
1365840-52-3

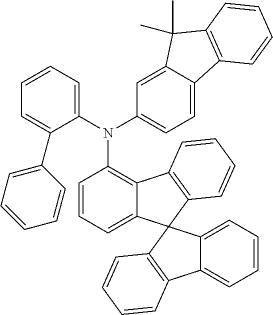 [SMILES: CC1(C)c2ccccc2-c2ccc(N(c3ccccc3-c3ccccc3)c3cccc4c3-c3ccccc3C43c4ccccc4-c4ccccc43)cc21]

EBM1
1450933-44-4

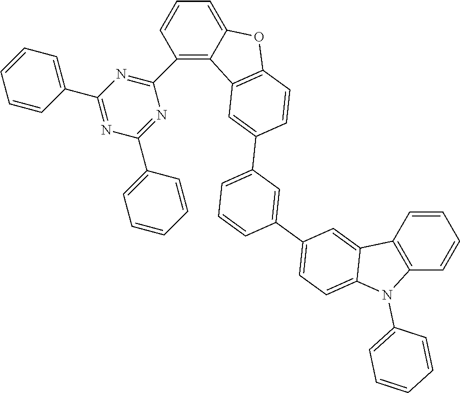 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

M1
1822310-86-0

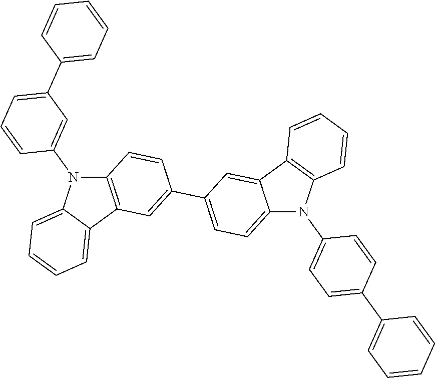 [SMILES: c1ccc(-c2ccc(-n3c4ccccc4c4cc(-c5ccc6c(c5)c5ccccc5n6-c5cccc(-c6ccccc6)c5)ccc43)cc2)cc1]

M2
1643479-47-3

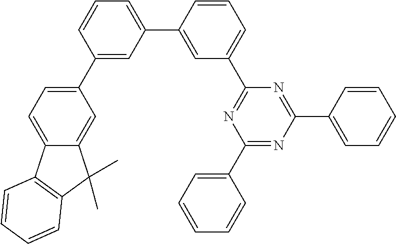 [SMILES: CC1(C)c2ccccc2-c2ccc(-c3cccc(-c4cccc(-c5nc(-c6ccccc6)nc(-c6ccccc6)n5)c4)c3)cc21]

HBM1
1955543-57-3

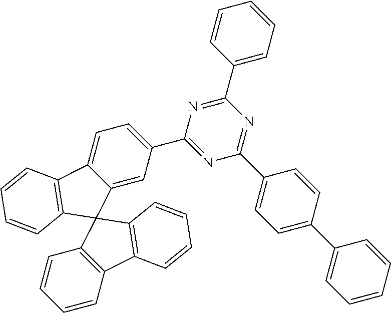 [SMILES: c1ccc(-c2ccc(-c3nc(-c4ccccc4)nc(-c4ccc5c(c4)C4(c6ccccc6-c6ccccc64)c4ccccc4-5)n3)cc2)cc1]

ETM1
1819335-36-8

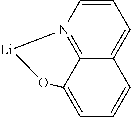

ETM2
25387-93-3

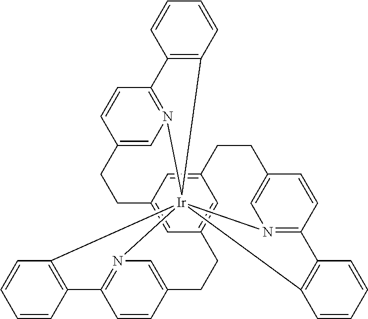

861806-70-4
Ref-D1

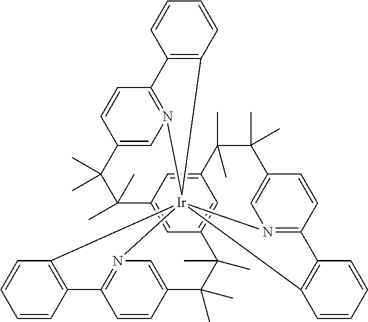

Synthesized as in
WO2014/024668
Ref-D2

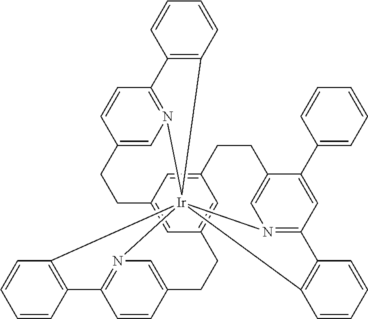

2173365-79-0
Ref-D3

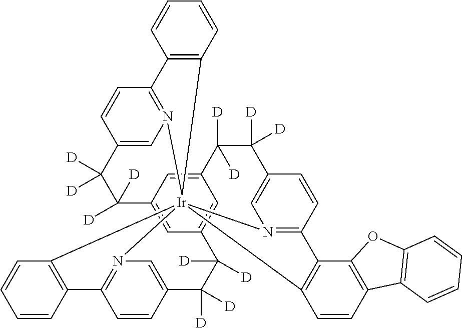

2173366-08-8
Ref-D4

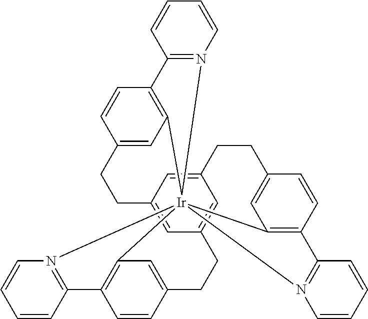

861806-74-8
Ref-D5

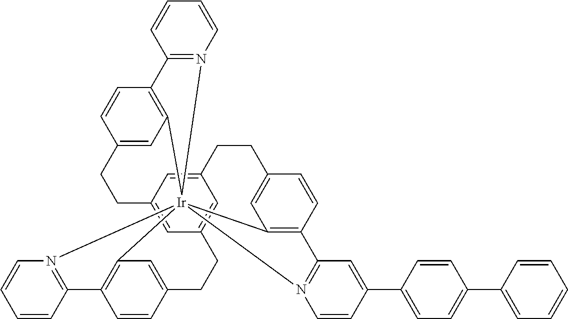

Synthesized as in US 2005/0170207
through the use of
63996-36-1 and 2202695-46-1
Ref-D6

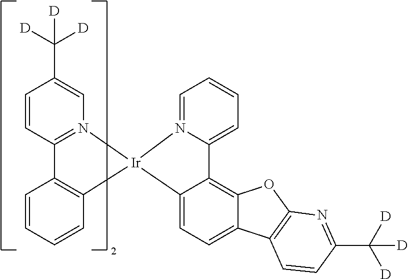

Ref-D7
1609368-32-2

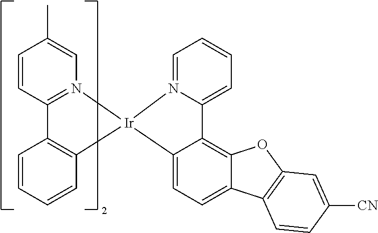

Ref-D8
2458813-55-1

Determination of the Evaporation Temperature:

The determination of the evaporation temperature Tevap. is carried out by means of a vacuum TGA measurement on a device of the manufacturer Netzsch Gerätebau GmbH, device: Libra 209 T, device type: thermobalance using the following devices and measuring parameters: Weighing-in: 1 mg+/−0.1 mg, atmosphere: vacuum approx. 10⁻² mbar, heating rate: 5 K/min, crucible material: aluminum, measuring range: 105-450° C. Tevap. is the temperature at which 5% of the original mass has evaporated (5% weight loss value).

| Material | Tevap. [C] |
|---|---|
| Ref-D1 | 318 |
| Ref-D2 | 292 |
| IrL 1 | 277 |
| IrL400 | 267 |
| Ref-D3 | 356 |
| IrL82 | 309 |
| Ref-D4 | 371 |
| IrL38 | 330 |
| Ref-D5 | 298 |
| IrL 100 | 271 |
| Ref-D6 | 367 |
| IrL 125 | 335 |

1. A compound of formula (1), 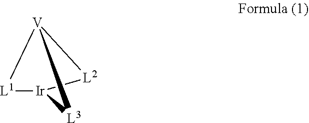
wherein the used symbols are defined as:
V is a group of formula (2), 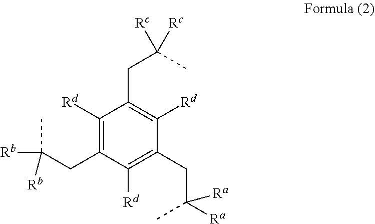
wherein the dashed bonds represent the bond to L¹, L² and L³, respectively, and the hydrogen atoms not shown may also be partially or completely replaced by deuterium;
R^{a} at each occurrence is the same or different and is a straight-chain alkyl group having 1 to 6 C atoms or a branched or cyclic alkyl group having 3 to 6 C atoms, wherein in each case one or more H atoms may be replaced by D or F; wherein two radicals R^{a}, which bond to the same carbon atom, may also form, together with one another and with the carbon atom to which they bond, a cyclopentyl or cyclohexyl group in which one or more H atoms may be replaced by D or F;
R^{b}, R^{c} at each occurrence is the same or different and is H, D, or R^{a};
R^{d} at each occurrence is the same or different and is H, D, or a methyl group, which may also be partially or fully deuterated;
L¹, L², L³ at each occurrence is the same or different and each is a bidentate monoanionic partial ligand according to formula (L-1) or (L-2), 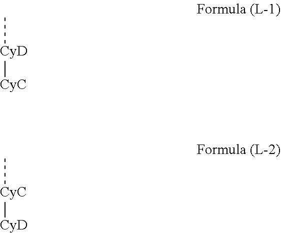
wherein the dashed bond represents the bond to V and the bond between CyC and CyD represents a covalent bond;
CyC at each occurrence is the same or different and is an aryl or heteroaryl group having 5 to 14 aromatic ring atoms, each of which is coordinated to the metal via a carbon atom, and which may be substituted by one or more R radicals;
CyD at each occurrence is the same or different and is a hetero aryl group with 5 to 14 aromatic ring atoms, which is coordinated to the metal via a nitrogen atom or via a carbene-carbon atom and which can be substituted by one or more radicals R;
R at each occurrence is the same or different and is H, D, F, Cl, Br, I, N(R¹)₂, OR¹, SR¹, CN, NO₂, COOH, C(═O)N(R¹)₂, Si(R¹)₃, Ge(R¹)₃, B(OR¹)₂, C(═O)R¹, P(═O)(R¹)₂, S(═O)R¹, S(═O)₂R¹, OSO₂R¹, a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R¹ and wherein one or more non-adjacent CH₂ groups may be replaced by Si(R¹)₂, C═O, NR¹, O, S or CONR¹, or an aromatic or hetero aromatic ring system having 5 to 40 aromatic ring atoms, which may in each case be substituted by one or more radicals R¹; wherein two radicals R can also form a ring system with one another;
R¹ at each occurrence is the same or different and is H, D, F, Cl, Br, I, N(R²)₂, OR², SR², CN, NO₂, Si(R²)₃, Ge(R²)₃, B(OR²)₂, C(═O)R², P(═O)(R²)₂, S(═O)R², S(═O)₂R², OSO₂R², a straight-chain alkyl group having 1 to 20 C atoms or an alkenyl or alkynyl group having 2 to 20 C atoms or a branched or cyclic alkyl group having 3 to 20 C atoms, wherein the alkyl, alkenyl or alkynyl group may in each case be substituted by one or more radicals R² and wherein one or more non-adjacent CH₂ groups may be replaced by Si(R²)₂, C═O, NR², O, S or CONR², or an aromatic or heteroaromatic ring system having 5 to 40 aromatic ring atoms, which may in each case be substituted by one or more radicals R²; wherein two or more radicals R¹ can form a ring system with one another;
R² at each occurrence is the same or different and is H, D, F or an aliphatic, aromatic and/or heteroaromatic organic radical, in particular a hydrocarbon radical, having 1 to 20 carbon atoms, in which one or more H atoms may also be replaced by D or F;
wherein the three bidentate partial ligands L¹, L² and L³ can be joined not only by the bridge V but also by a further bridge to form a cryptate.

2. The compound of claim 1, characterized in that the group V has a structure according to one of the formulas (2-1), (2-2) or (2-3), 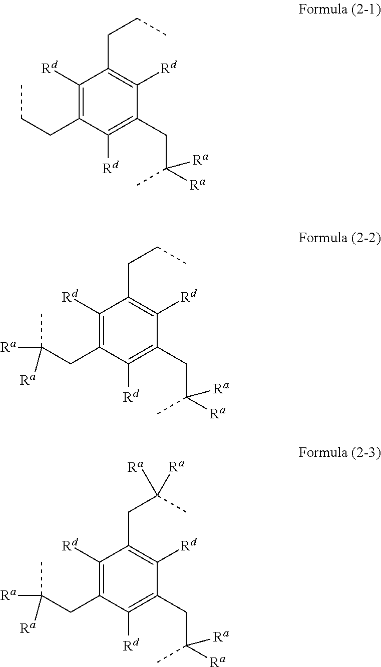
wherein the symbols used have the meanings given in claim 1 and the hydrogen atoms not drawn in may also be partially or completely replaced by deuterium.

3. The compound according to claim 1, characterized in that the group V has a structure according to one of the formulas (2-1-1) or (2-2-1), 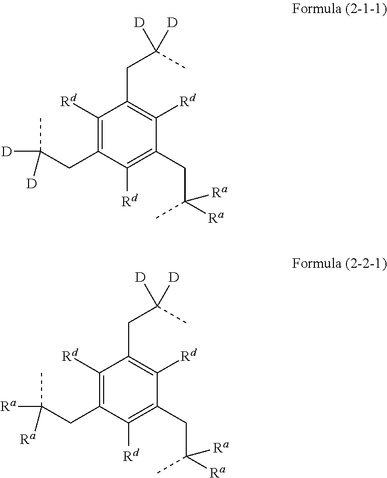
wherein the symbols used have the meanings given in claim 1 and the hydrogen atoms not drawn in may also be partially or completely replaced by deuterium.

4. The compound according to claim 1, characterized in that the group V has a structure according to one of the formulae (2-1a), (2-2a) or (2-3a), respectively, 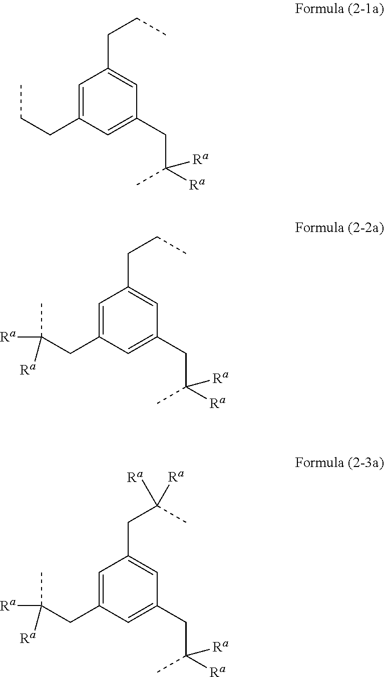
wherein the symbols used have the meanings given in claim 1 and the hydrogen atoms not drawn in may also be partially or completely replaced by deuterium.

5. The compound according to claim 1, characterized in that each pair of radicals R^{a} that are bonded to the same carbon atom are the same as each other.

6. The compound according to claim 1, characterized in that all radicals R^{a} are the same as each other.

7. The compound according to claim 1, characterized in that each occurrence of R^{a} is the same or different and is selected from the group consisting of methyl, ethyl, propyl, iso-propyl or neo-pentyl, or a pair of R^{a} that bind to the same carbon atom together form a cyclopentyl or cyclohexyl group, in all of which groups one or more H atoms may be replaced with D.

8. The compound according to claim 1, characterized in that all partial ligands L¹, L² and L³ have a structure of formula (L-1) or that all partial ligands L¹, L² and L³ have a structure of formula (L-2).

9. The compound according to claim 1, characterized in that CyC represents an aryl or heteroaryl group having 6 to 13 aromatic ring atoms and that CyD represents a heteroaryl group having 6 to 10 aromatic ring atoms.

10. The compound according to claim 1, characterized in that CyC represents a phenyl group, a dibenzofuran group or azadibenzofuran group, and that CyD represents a pyridine group, each of which groups may be substituted with one or more R radicals.

11. The compound according to claim 1, characterized in that the partial ligands (L-1) are selected from the structures of the formulae (L-1-1a) to (L-1-3b) and that the partial ligands (L2-) are selected from the structures of the formulae (L-2-1a) to (L-2-5b), 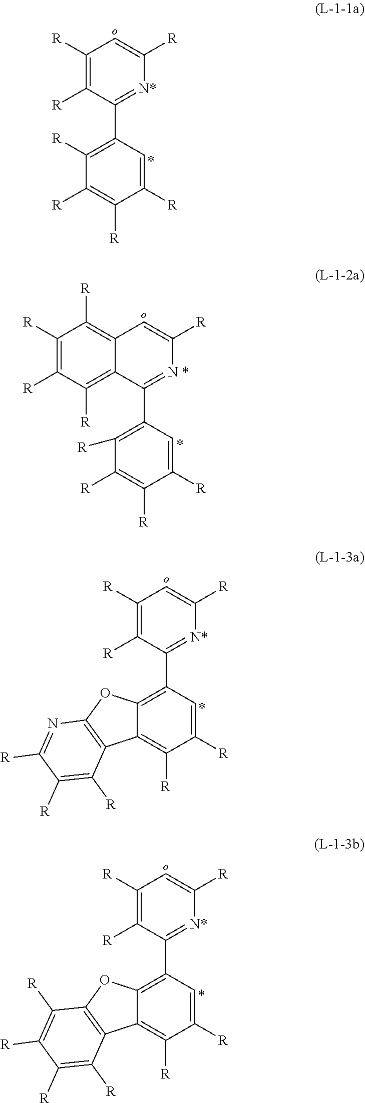 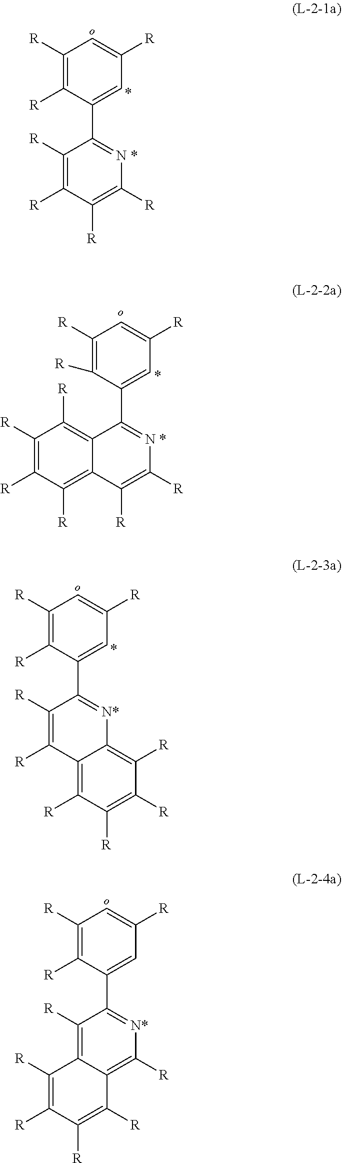 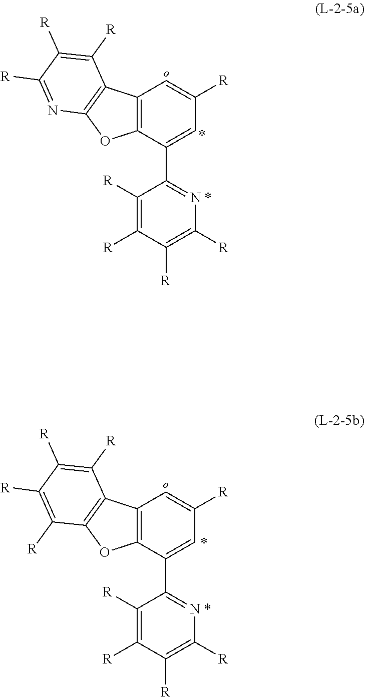
wherein the symbols used have the meanings given in claim 1, * represent the positions of coordination to the iridium and “o” represents the position of bonding to the bridge V.

12. The compound according to claim 1, characterized in that one of the partial ligands L¹, L² or L³ is a partial ligand according to formula (L-31) or (L-32), 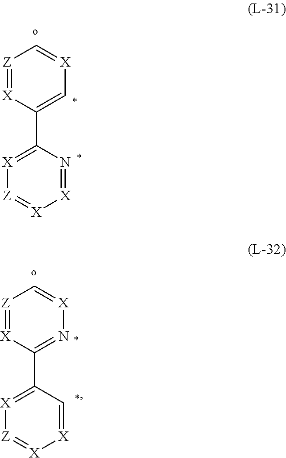
wherein * represent the positions of the coordination to the iridium, “o” denotes the position of the linkage to the bridge V and the following definitions apply:
X at each occurrence is the same or different and is CR or N;
Z at each occurrence is CR′, CR or N, with the proviso that exactly one Z stands for CR′ and the other Z stands for CR or N;
wherein a maximum of one of the symbols X or Z per ring stands for N;
R′ is a group according to one of the formulas (20), (21), (22), (23), (24), (25), (26) or (27), 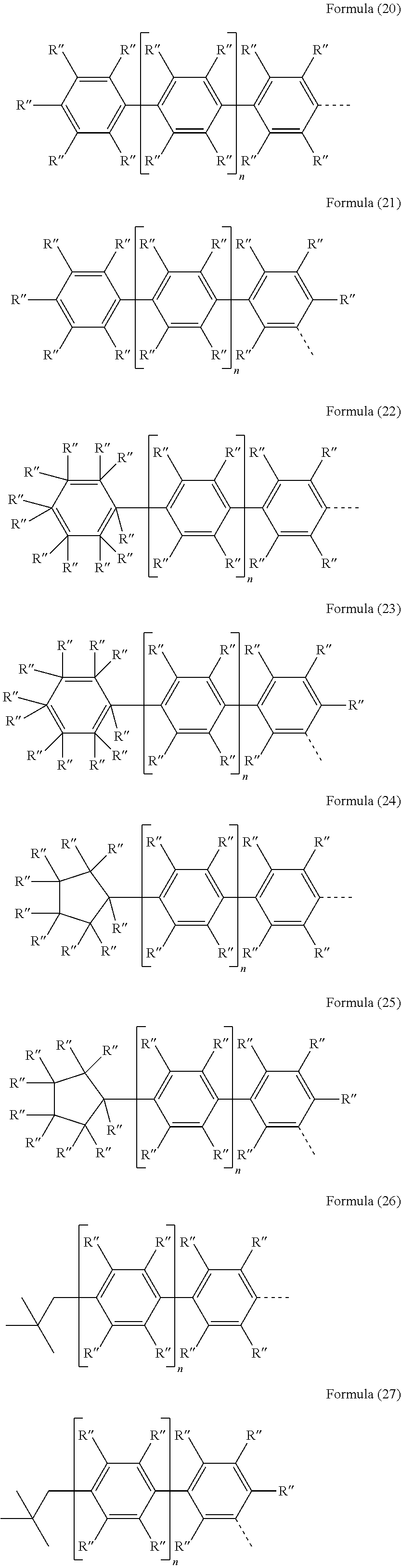
wherein the dashed bond indicates the linkage of the group to the partial ligands of formula (L-31) and (L-32), respectively, and the following definitions apply:
R″ at each occurrence is the same or different and is H, D, F, CN, a straight-chain alkyl group having 1 to 10 C atoms, in which one or more H atoms may also be replaced by D or F, or a branched or cyclic alkyl group having 3 to 10 C atoms, in which one or more H atoms may also be replaced by D or F, or an alkenyl group having 2 to 10 C atoms, in which one or more H atoms may also be replaced by D or F; wherein two adjacent radicals R″ or two radicals R″ on adjacent phenyl groups together form a ring system; or two R″ on adjacent phenyl groups together represent a group selected from C(R¹)₂, NR¹, O or S, so that the two phenyl rings together with the bridging group represent a carbazole, fluorene, dibenzofuran or dibenzothiophene, and the remaining R″ are as defined above;
n is 0, 1, 2, 3, 4 or 5.

13. A process for the preparation of a compound according to claim 1 by reacting the free ligand with iridium alkoxide of the formula (Ir-1), with iridium ketoketonates of the formula (Ir-2), with iridium halides of the formula (Ir-3) or with iridium carboxylates of the formula (Ir-4) or with iridium compounds bearing radicals selected from alkoxide and/or halide and/or hydroxy radicals as well as ketoketonate radicals, 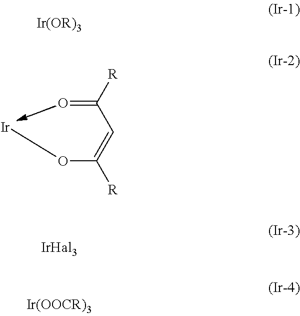
wherein R is as defined in claim 1, Hal=F, Cl, Br or I, and the iridium reagent may also be present as the corresponding hydrates.

14. A formulation comprising at least one compound according to claim 1 and at least one further compound selected from a solvent and a matrix material.

15. An oxygen sensor, electronic device, photoinitiator, or photo catalyst comprising the compound of claim 1.

16. An electronic device comprising at least one compound according to claim 1.

17. The electronic device of claim 16, wherein the device is an organic electroluminescent device, characterized in that the compound of one or more of claims 1 to 12 is an emitting compound in one or more emitting layers.
